(19) United States
(12) Patent Application Publication
(10) Pub. No.: US 2025/0054927 A1
(43) Pub. Date: Feb. 13, 2025

(54) SEMICONDUCTOR DEVICE

(71) Applicant: ROHM CO., LTD., Kyoto-shi, Kyoto (JP)

(72) Inventors: Yuji ISHIMATSU, Kyoto-shi (JP); Ryuichi FURUTANI, Kyoto-shi (JP)

(21) Appl. No.: 18/926,086

(22) Filed: Oct. 24, 2024

Related U.S. Application Data
(63) Continuation of application No. 18/464,169, filed on Sep. 8, 2023.
Application No. 18/464,169 is a continuation of application No. 17/852,026, filed on Jun. 28, 2022, now Pat. No. 11,804,478.
Application No. 17/852,026 is a continuation of application No. 17/055,044, filed on Nov. 12, 2020, now Pat. No. 11,437,354.

(30) Foreign Application Priority Data
Jun. 20, 2018 (JP) 2018-116658
Jun. 25, 2018 (JP) 2018-120290

(51) Int. Cl. H01L 25/16; H01L 23/00; H01L 23/31; H01L 23/495; H01L 23/522

(52) U.S. Cl. CPC H01L 25/16; H01L 23/3107; H01L 23/49562; H01L 23/49568; H01L 23/49575; H01L 23/5227; H01L 24/06; H01L 24/48; H01L 24/49; H01L 24/73; H01L 2224/0603; H01L 2224/48091; H01L 2224/48139; H01L 2224/48247; H01L 2224/4903; H01L 2224/49111; H01L 2224/49113; H01L 2224/49171; H01L 2224/73265; H01L 2924/182; H01L 2924/19042; H01L 2924/19105

(57) ABSTRACT

A semiconductor device A1 includes a substrate 3, a conductive section 5 formed on the substrate 3 and including a conductive material, a lead 1A located on the substrate 3, a semiconductor chip 4A located on the lead 1A, a control chip 4G located on the substrate 3 and electrically connected to the conductive section 5 and the semiconductor chip 4A for controlling an operation of the semiconductor chip 4A, and a resin 7 covering the semiconductor chip 4A, the control chip 4G, at least a part of the substrate 3 and a part of the lead 1A. This configuration contributes to achieving a higher level of integration of the semiconductor device.

### CROSS-REFERENCE TO RELATED APPLICATIONS

This application is a continuation application of U.S. application Ser. No. 18/464,169, filed Sep. 8, 2023, which is a continuation application of U.S. application Ser. No. 17/852,026, filed Jun. 28, 2022, which is a continuation application of U.S. application Ser. No. 17/055,044, filed Nov. 12, 2020, which is a National Stage Application of PCT/JP2018/044138, filed Nov. 30, 2018, which claims priority to Japan Patent Application No. 2018-116658 filed Jun. 20, 2018, and Japan Patent Application No. 2018-120290, filed Jun. 25, 2018, the entire contents of each of which are incorporated herein by reference, including the original claims.

### TECHNICAL FIELD

The present disclosure relates to a semiconductor device.

### BACKGROUND ART

As conventionally known, a semiconductor device may include a semiconductor chip, a control chip in which a control current for controlling an operation current of the semiconductor chip passes, and a resin member encapsulating the semiconductor chip and the control chip (see Patent Literature 1).

### CITATION LIST

### Patent Literature

PTL 1: JP-A-2015-220429

### SUMMARY

### Technical Problem

A plurality of types of control signals are inputted to and outputted from the control chip. It is necessary to increase the number of conduction paths to the control chip in order to cope with an increase in number of control signals. However, employing a plurality of metal leads to constitute the conduction paths as is conventionally done may make it difficult to achieve a higher level of integration for the semiconductor device.

The present disclosure has been presented under the foregoing situation and provides semiconductor devices capable of achieving a higher level of integration.

### Solution to Problem

In an aspect, the present disclosure provides a semiconductor device including: a substrate; a conductive section formed on the substrate and including a conductive material; a first lead located on the substrate and more heat-dissipative than the substrate; a semiconductor chip located on the first lead; a control chip that controls an operation of the semiconductor chip, where the chip is electrically connected to the conductive section and the semiconductor chip, and located on the substrate so as to be spaced apart from the semiconductor chip and the first lead in a plan view; and a resin covering the semiconductor chip, the control chip, at least a part of the substrate and a part of the lead.

### ADVANTAGEOUS EFFECTS OF INVENTION

The present disclosure provides a semiconductor device that enables a higher level of integration to be realized, without compromising heat dissipation characteristics.

Other features and advantages of the present disclosure will become more apparent through the detailed description, given hereunder with reference to the accompanying drawings.

### BRIEF DESCRIPTION OF DRAWINGS

FIG. 1 is a perspective view showing a semiconductor device according to a first embodiment of the present disclosure.

FIG. 2 is a plan view showing the semiconductor device according to the first embodiment of the present disclosure.

FIG. 3 is a bottom view showing the semiconductor device according to the first embodiment of the present disclosure.

FIG. 4 is a partial plan view of the semiconductor device according to the first embodiment of the present disclosure.

FIG. 5 is a cross-sectional view taken along a line V-V in FIG. 4.

FIG. 6 is an enlarged partial cross-sectional view of the semiconductor device according to the first embodiment of the present disclosure.

FIG. 7 is an enlarged partial cross-sectional view of the semiconductor device according to the first embodiment of the present disclosure.

FIG. 8 is an enlarged partial cross-sectional view of the semiconductor device according to the first embodiment of the present disclosure.

FIG. 9 is a cross-sectional view taken along a line IX-IX in FIG. 4.

FIG. 10 is an enlarged partial plan view of the semiconductor device according to the first embodiment of the present disclosure.

FIG. 11 is an enlarged partial plan view showing an end portion of a first wire 91A.

FIG. 12 is an enlarged partial cross-sectional view taken along a line XII-XII in FIG. 11.

FIG. 13 is an enlarged partial cross-sectional view taken along a line XIII-XIII in FIG. 11.

FIG. 14 is an enlarged partial plan view of the semiconductor device according to the first embodiment of the present disclosure.

FIG. 15 is an enlarged partial plan view of the semiconductor device according to the first embodiment of the present disclosure.

FIG. 16 is an enlarged partial plan view of a substrate of the semiconductor device according to the first embodiment of the present disclosure.

FIG. 17 is an enlarged partial cross-sectional view of the semiconductor device according to the first embodiment of the present disclosure.

FIG. 18 is a schematic circuit diagram showing an electrical configuration of the semiconductor device according to the first embodiment of the present disclosure.

FIG. 19 is a circuit diagram showing a part of the circuit configuration of the semiconductor device according to the first embodiment of the present disclosure.

FIG. 20 is a flowchart showing a manufacturing method of the semiconductor device according to the first embodiment of the present disclosure.

FIG. 21 is a plan view for explaining the manufacturing method of the semiconductor device according to the first embodiment of the present disclosure.

FIG. 22 is a plan view for explaining a process subsequent to FIG. 21.

FIG. 23 is a plan view for explaining a process subsequent to FIG. 22.

FIG. 24 is a plan view for explaining a process subsequent to FIG. 23.

FIG. 25 is a plan view for explaining a process subsequent to FIG. 24.

FIG. 26 is a plan view for explaining a process subsequent to FIG. 25.

FIG. 27 is a plan view for explaining a process subsequent to FIG. 26.

FIG. 28 is a plan view for explaining a process subsequent to FIG. 27.

FIG. 29 is a plan view for explaining a process subsequent to FIG. 28.

FIG. 30 is a plan view for explaining a process subsequent to FIG. 29.

FIG. 31 is a partial plan view showing a first variation of the semiconductor device according to the first embodiment of the present disclosure.

FIG. 32 is an enlarged partial cross-sectional view of a semiconductor chip of the first variation of the semiconductor device according to the first embodiment of the present disclosure.

FIG. 33 is an enlarged partial perspective view of a diode of the first variation of the semiconductor device according to the first embodiment of the present disclosure.

FIG. 34 is an enlarged partial cross-sectional view of the diode of the first variation of the semiconductor device according to the first embodiment of the present disclosure.

FIG. 35 is a perspective view showing a semiconductor device according to a second embodiment of the present disclosure.

FIG. 36 is a plan view showing the semiconductor device according to the second embodiment of the present disclosure.

FIG. 37 is a bottom view showing the semiconductor device according to the second embodiment of the present disclosure.

FIG. 38 is a side view showing the semiconductor device according to the second embodiment of the present disclosure.

FIG. 39 is a partial plan view of the semiconductor device according to the second embodiment of the present disclosure.

FIG. 40 is a cross-sectional view taken along a line XL-XL in FIG. 39.

FIG. 41 is a cross-sectional view taken along a line XLI-XLI in FIG. 39.

FIG. 42 is a partial plan view of the semiconductor device according to the second embodiment of the present disclosure.

FIG. 43 is a partial plan view of the semiconductor device according to the second embodiment of the present disclosure.

FIG. 44 is a schematic circuit diagram showing an electrical configuration of the semiconductor device according to the second embodiment of the present disclosure.

FIG. 45 is a partial plan view of the semiconductor device according to the second embodiment of the present disclosure.

FIG. 46 is an enlarged partial plan view of the semiconductor device according to the second embodiment of the present disclosure.

FIG. 47 is an enlarged view the partial plan of semiconductor device according to the second embodiment of the present disclosure.

FIG. 48 is an enlarged partial plan view of a substrate of the semiconductor device according to the second embodiment of the present disclosure.

FIG. 49 is a schematic circuit diagram showing an electrical configuration of the semiconductor device according to the second embodiment of the present disclosure.

FIG. 50 is a schematic circuit diagram showing an electrical configuration of a circuit board, on which the semiconductor device according to the second embodiment of the present disclosure is mounted.

FIG. 51 is a schematic perspective view showing a first transmission circuit chip, a primary-side circuit chip, and a control chip of the semiconductor device according to the second embodiment of the present disclosure.

FIG. 52 is a partial plan view of the first transmission circuit chip.

FIG. 53 is a partial bottom view of the first transmission circuit chip.

FIG. 54 is a partial plan view of the first transmission circuit chip.

FIG. 55 is a cross-sectional view taken along a line LV-LV in FIG. 52.

FIG. 56 is an enlarged partial cross-sectional view of the first transmission circuit chip.

FIG. 57 includes graphs indicating a relation between a thickness of an interlayer film and a breakdown voltage of the first transmission circuit chip.

FIG. 58 is a plan view showing a semiconductor device according to a seventh embodiment of the present disclosure.

FIG. 59 is an enlarged partial plan view of the semiconductor device according to the seventh embodiment of the present disclosure.

FIG. 60 is an enlarged partial plan view of the semiconductor device according to the seventh embodiment of the present disclosure.

FIG. 61 is a schematic circuit diagram showing an electrical configuration of the semiconductor device according to the seventh embodiment of the present disclosure.

FIG. 62 is a plan view showing a first variation of the semiconductor device according to the seventh embodiment of the present disclosure.

FIG. 63 is a plan view showing a second variation of the semiconductor device according to the seventh embodiment of the present disclosure.

FIG. 64 is an enlarged view of a control wiring region in a variation of the semiconductor package shown in FIG. 33.

### MODE FOR CARRYING OUT INVENTION

Preferable embodiments of the present disclosure will be described below with reference to the drawings.

The terms “first”, “second”, “third” and so forth used in the present disclosure merely serve as a label, and are not intended to specify any order with respect to the objects accompanied by these terms.

### First Embodiment

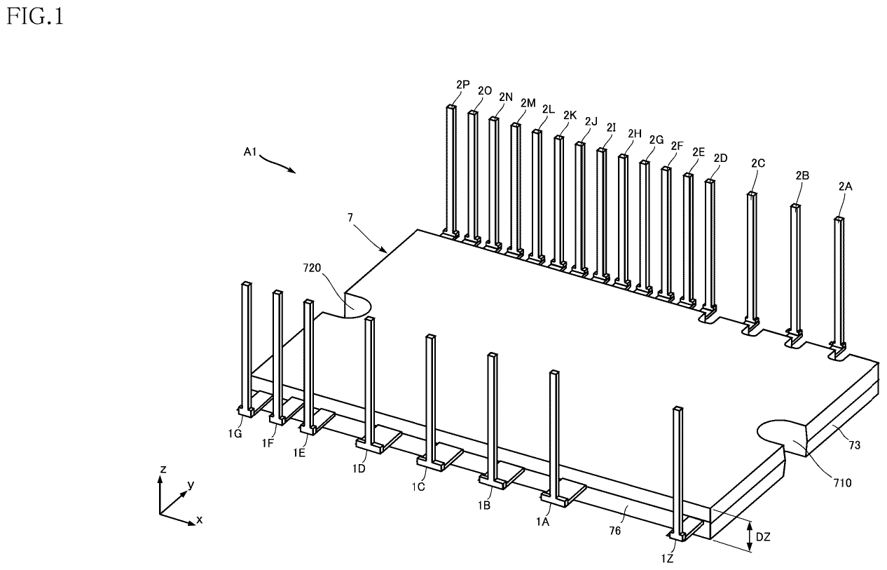

FIG. 1 to FIG. 19 illustrate a semiconductor device according to a first embodiment of the present disclosure. The semiconductor device A1 according to this embodiment includes a plurality of leads 1, a plurality of leads 2, a substrate 3, a plurality of semiconductor chips 4, a plurality of control chips 4, a plurality of diodes 49, a conductive section 5, a plurality of bonding sections 6, a plurality of first wires 91, a plurality of second wires 92, and an encapsulating resin 7. The semiconductor device A1 is applicable, for example, to a driver circuit that drives a compressor of an outdoor unit of an air-conditioning apparatus, or a driver circuit that drives compressor of a refrigerator, or a driver circuit that drives a fan. These driver circuits may be configured to drive a three-phase AC motor, for example.

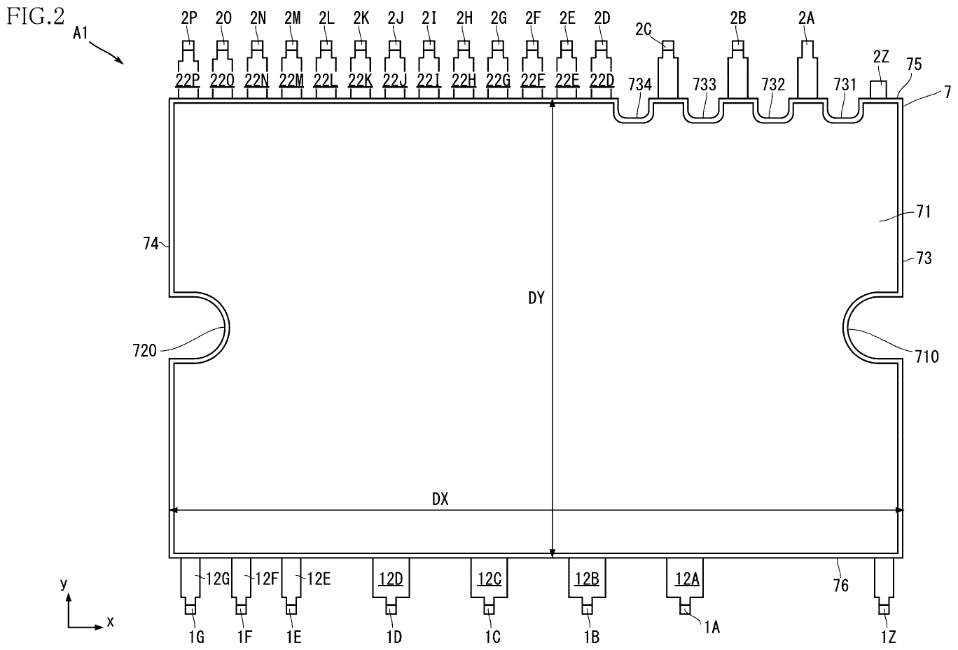

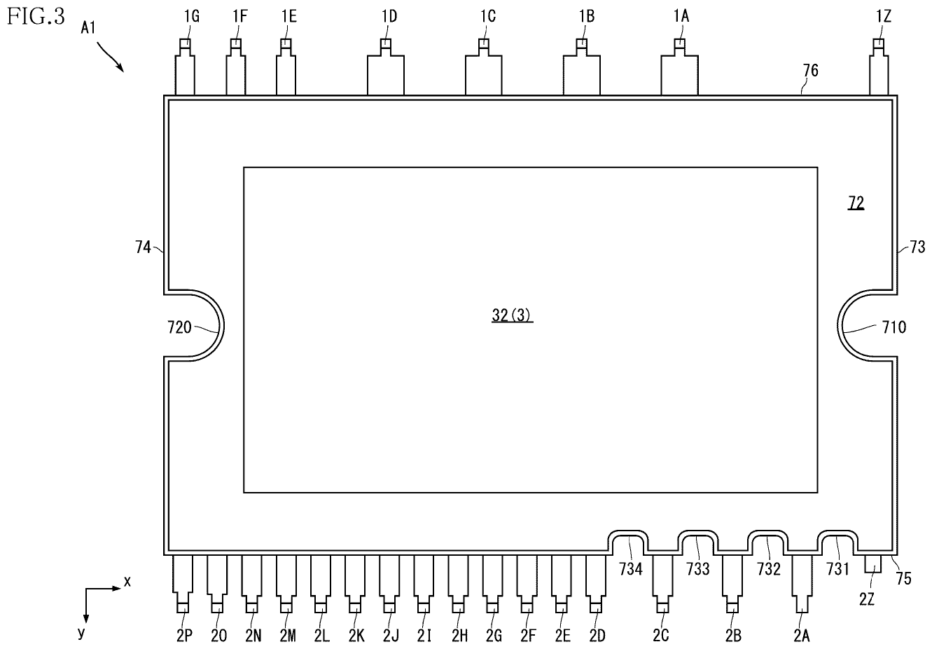

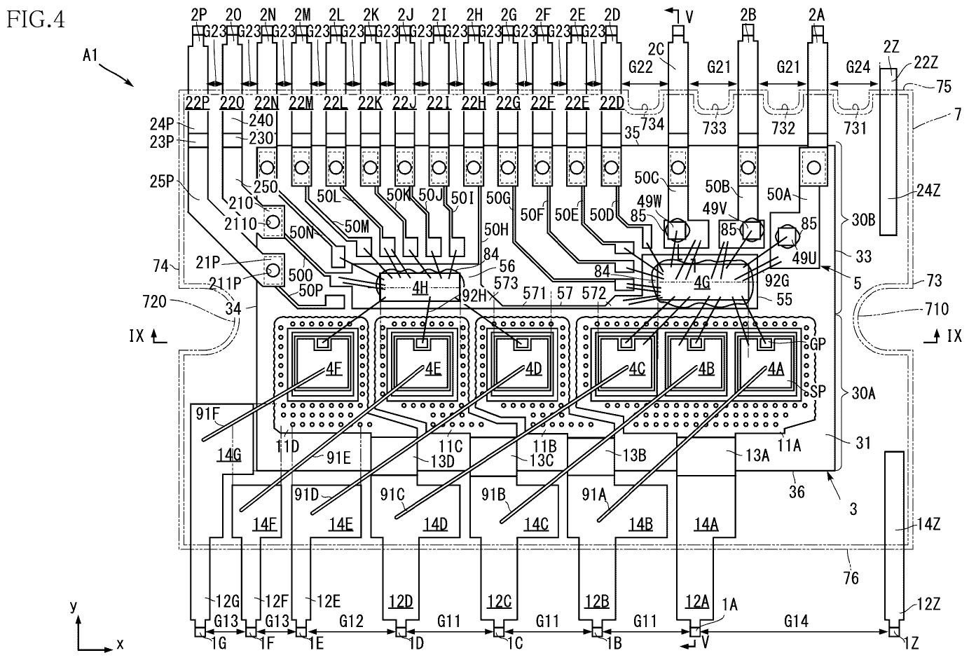

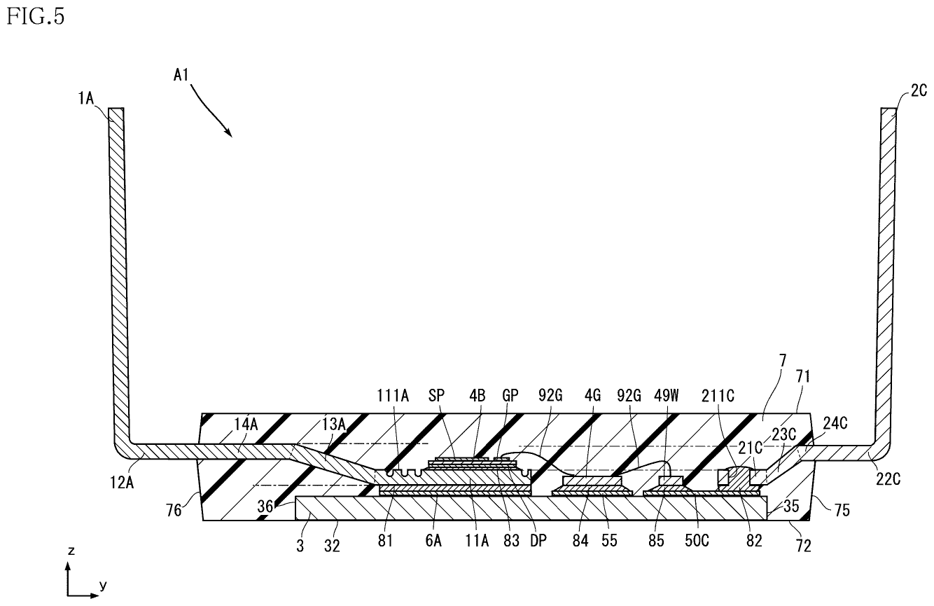

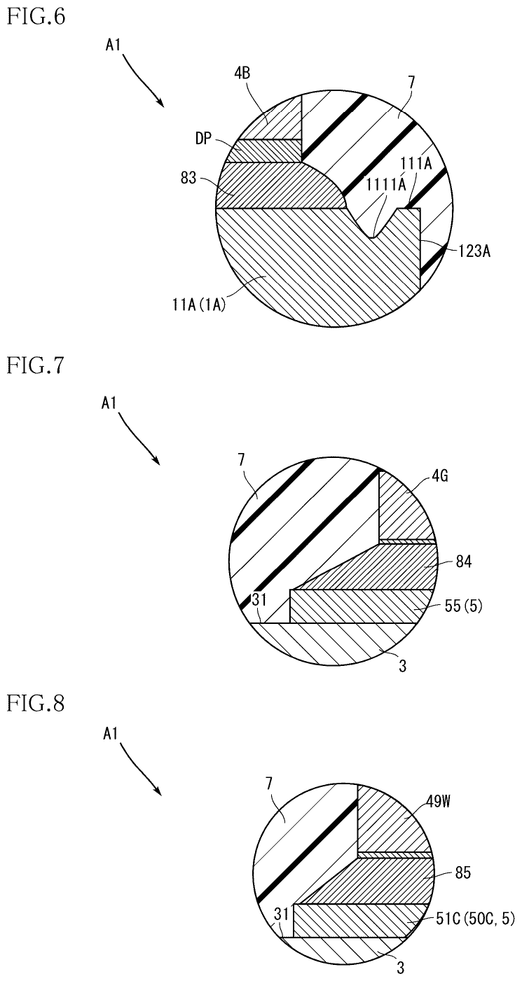

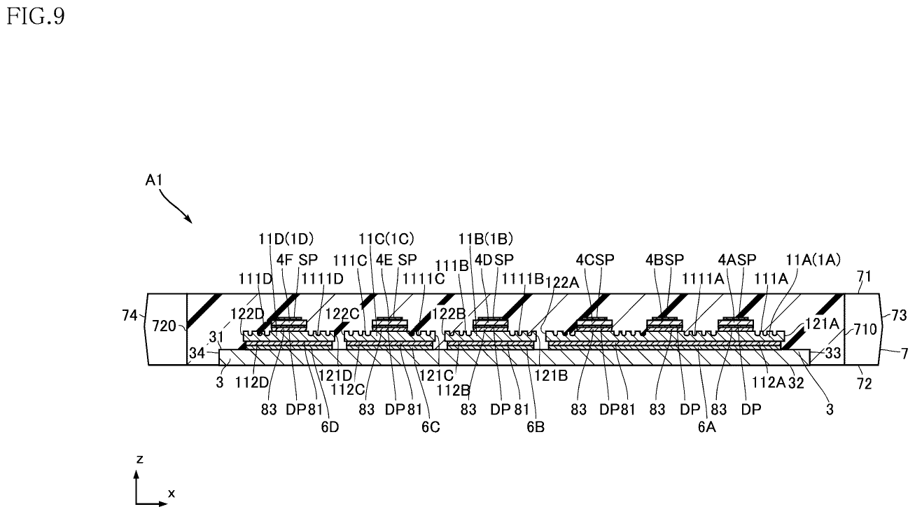

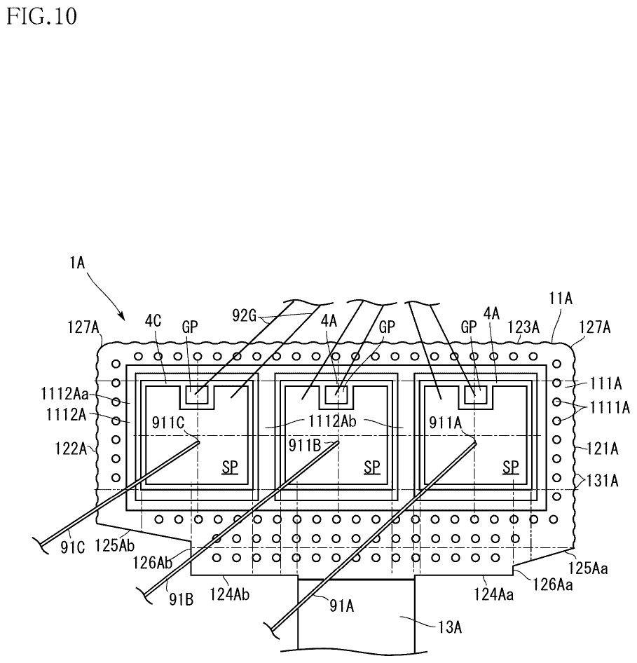

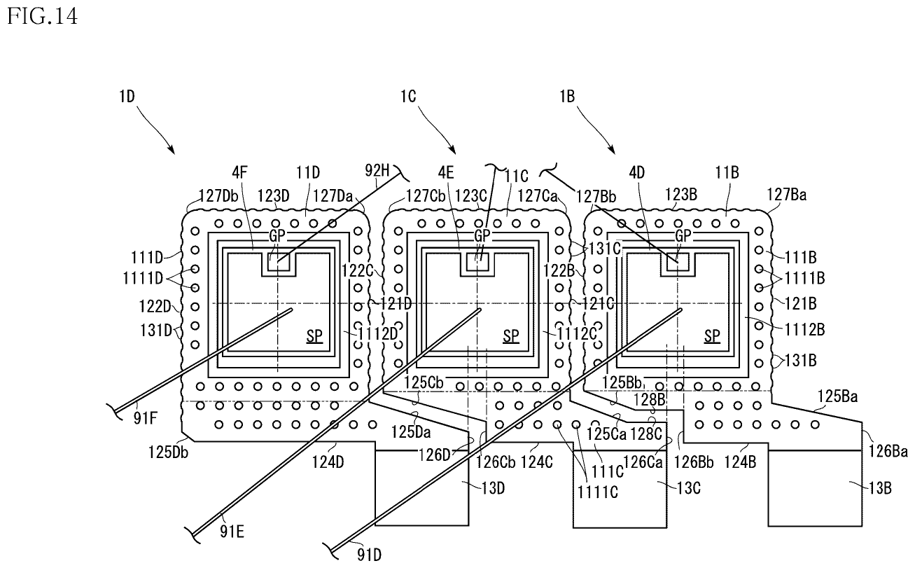

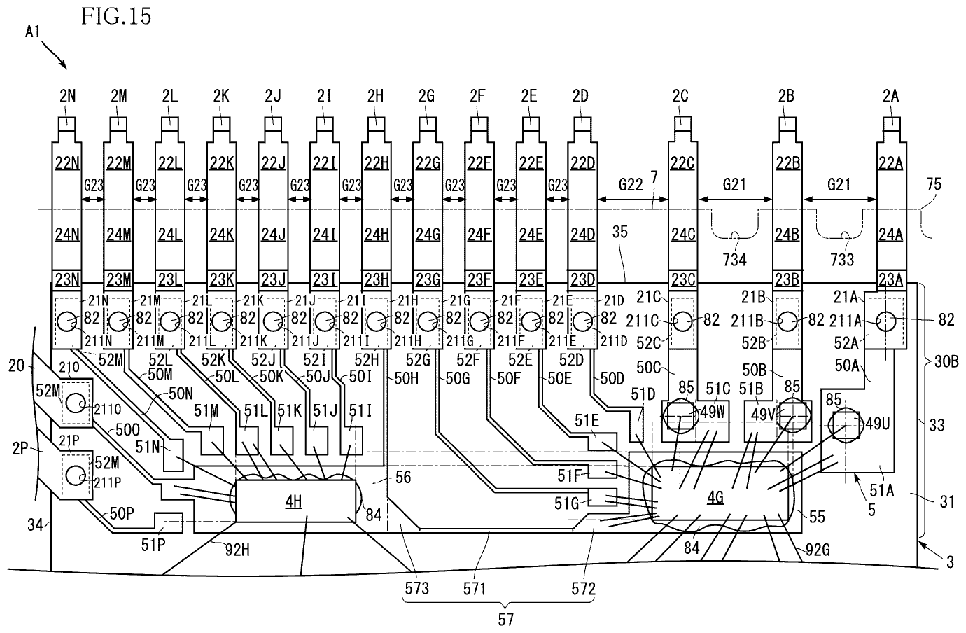

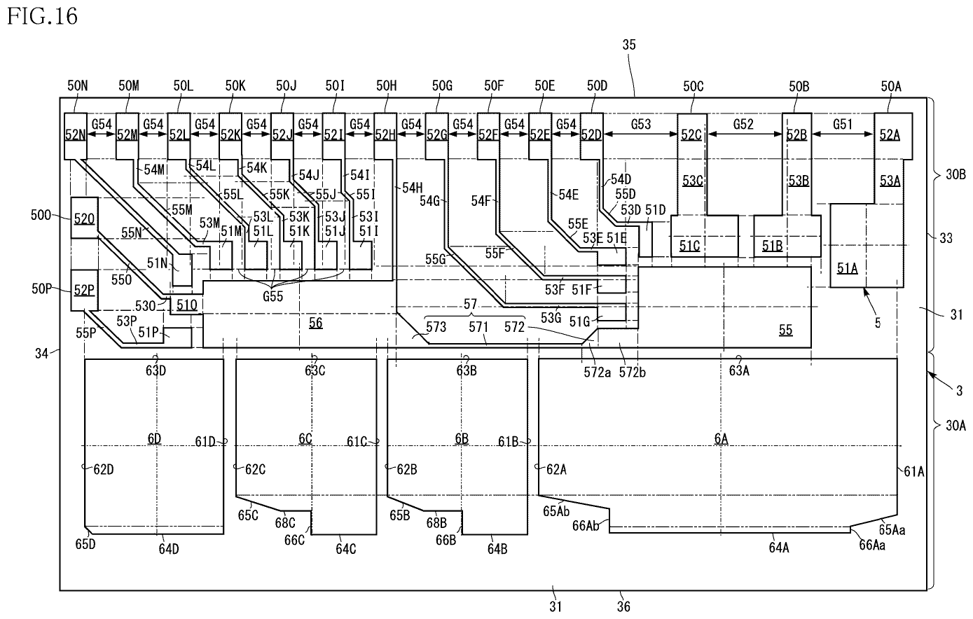

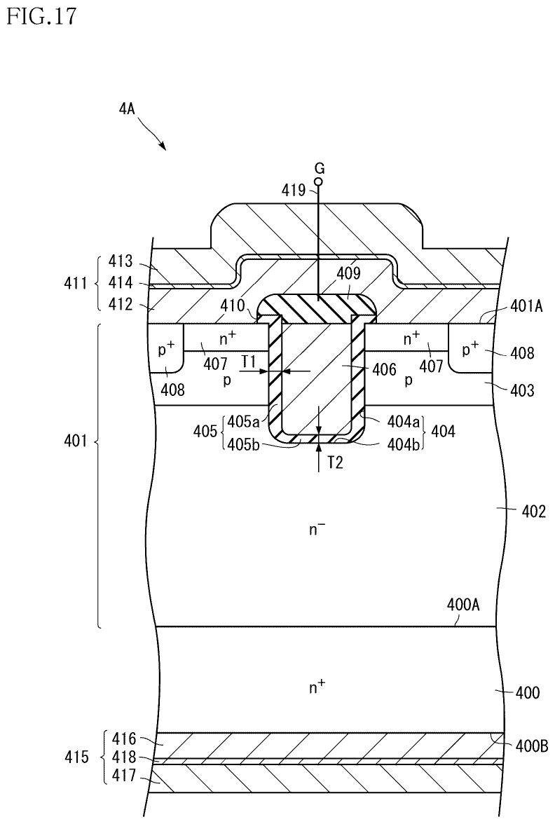

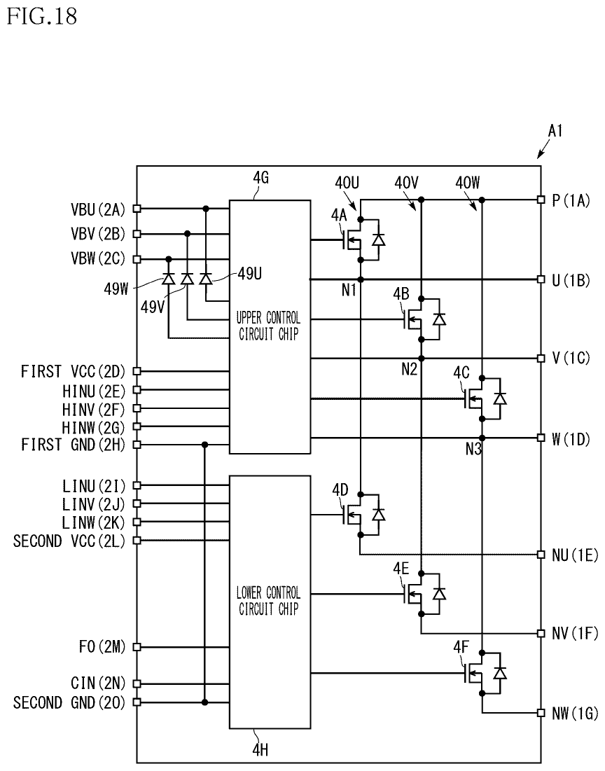

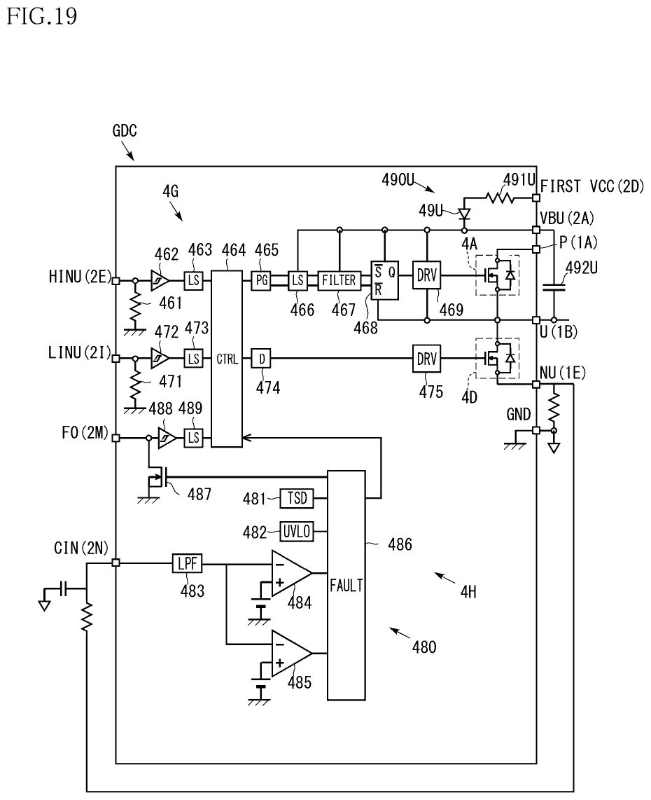

FIG. 1 is a perspective view showing the semiconductor device A1. FIG. 2 is a plan view showing the semiconductor device A1. FIG. 3 is a bottom view showing the semiconductor device A1. FIG. 4 is a partial plan view of the semiconductor device A1. FIG. 5 is a cross-sectional view taken along a line V-V in FIG. 4. FIG. 6 is an enlarged partial cross-sectional view of the semiconductor device A1. FIG. 7 is an enlarged partial cross-sectional view of the semiconductor device A1. FIG. 8 is an enlarged partial cross-sectional view of the semiconductor device A1. FIG. 9 is a cross-sectional view taken along a line IX-IX in FIG. 4. FIG. 10 is an enlarged partial plan view of the semiconductor device A1. FIG. 14 is an enlarged partial plan view of the semiconductor device A1. FIG. 15 is an enlarged partial plan view of the semiconductor device A1. FIG. 16 is an enlarged partial plan view of a substrate of the semiconductor device A1. FIG. 17 is an enlarged partial cross-sectional view of the semiconductor device A1. FIG. 18 is a schematic circuit diagram showing an electrical configuration of the semiconductor device A1. FIG. 19 is a circuit diagram showing a part of the circuit configuration of the semiconductor device A1.

In the mentioned drawings, a z-direction corresponds to a thickness direction of the substrate 3. An x-direction, which is orthogonal to the z-direction, corresponds to the first direction in the present disclosure. A y-direction is orthogonal to both of the z-direction and the x-direction.

### <Substrate 3>

The material of the substrate 3 is not specifically limited. It is preferable that the material of the substrate 3 has higher thermal conductivity, for example than the material of the resin 7. Examples of the material of the substrate 3 include ceramics such as alumina (Al₂O₃), silicon nitride (SiN), aluminum nitride (AlN), and zirconia-containing alumina. The thickness of the substrate 3 is not specifically limited, but may be, for example, approximately 0.1 mm to 1.0 mm.

The shape of the substrate 3 is not specifically limited. In this embodiment, as shown in FIG. 4 to FIG. 9, the substrate 3 includes a first face 31, a second face 32, a third face 33, a fourth face 34, a fifth face 35, and a sixth face 36. The first face 31 is oriented in the z-direction. The second face 32 is oriented to the opposite side of the first face 31, in the z-direction. The third face 33 is located between the first face 1 and the second face 32 in the z-direction and, in the illustrated example, connected to the first face 31 and the second face 32. The third face 33 is oriented in the x-direction. The fourth face 34 is located between the first face 31 and the second face 32 in the z-direction and, in the illustrated example, connected to the first face 31 and the second face 32. The fourth face 34 is oriented to the opposite side of the third face 33, in the x-direction. The fifth face 35 is located between the first face 31 and the second face 32 in the z-direction and, in the illustrated example, connected to the first face 31 and the second face 32. The fifth face 35 is oriented in the y-direction. The sixth face 36 is located between the first face 31 and the second face 32 in the z-direction and, in the illustrated example, connected to the first face 31 and the second face 32. The sixth face 36 is oriented to the opposite side of the fifth face 35, in the y-direction. In the illustrated example, the substrate 3 has a rectangular shape as viewed in the z-direction. The substrate 3 has an elongate rectangular shape, having the long sides extending along the x-direction, as viewed in the z-direction.

### <Conductive Section 5>

The conductive section 5 is formed on the substrate 3. In this embodiment, the conductive section 5 is formed on the first face 31 of the substrate 3. The conductive section 5 is formed of a conductive material. The conductive material to form the conductive section 5 is not specifically limited. Examples of the conductive material to form the conductive section 5 include materials containing silver (Ag), copper (Cu), or gold (Au). In the subsequent description, it will be assumed that the conductive section 5 contains silver. However, the conductive section 5 may contain copper instead of silver, or gold instead of silver or copper. Alternatively, the conductive section 5 may contain Ag—Pt or Ag—Pd. The forming method of the conductive section 5 is not limited. For example, the conductive section 5 may be formed by sintering a paste containing the mentioned metal. The thickness of the conductive section 5 is not specifically limited, but may be, for example, approximately 5 μm to 30 μm.

The shape of the conductive section 5 is not specifically limited. In this embodiment, for example as shown in FIG. 16, the conductive section 5 includes wirings 50A to 50P, a first base portion 55, a second base portion 56, and a connecting portion 57, each of which will be described hereunder.

The shape of the first base portion 55 is not specifically limited, and a desired shape may be selected from a rectangular shape, a polygonal shape, a circular shape, an elliptical shape, and so forth. In the illustrated example, the first base portion 55 has a rectangular shape. In the illustrated example, the first base portion 55 has an elongate rectangular shape, having the long sides extending along the x-direction.

The shape of the second base portion 56 is not specifically limited, and a desired shape may be selected from a rectangular shape, a polygonal shape, a circular shape, an elliptical shape, and so forth. In the illustrated example, the second base portion 56 has a rectangular shape. In the illustrated example, the second base portion 56 has an elongate rectangular shape, having the long sides extending along the x-direction.

The second base portion 56 is located on the side of the fourth face 34 with respect to the first base portion 55, in the x-direction. In the illustrated example, the edge of the second base portion 56 on the side of the sixth face 36 in the y-direction is located generally at the same position as the edge of the first base portion 55 on the side of the sixth face 36, in the y-direction. Here, the expression “located generally at the same position” in the y-direction refers to, for example, being located exactly at the same position, or being deviated by within ±5% of the characteristic size (size of the first base portion 55 or second base portion 56 in the y-direction). In the illustrated example, the edge of the second base portion 56 on the side of the fifth face 35 in the y-direction is located on the side of the sixth face 36, with respect to the edge of the first base portion 55 on the side of the fifth face 35. In the illustrated example, the center of the second base portion 56 in the y-direction is located on the side of the sixth face 36, with respect to the center of the first base portion 55 in the y-direction.

The connecting portion 57 is interposed between the first base portion 55 and the second base portion 56 and, in the illustrated example, connecting the first base portion 55 and the second base portion 56. In the illustrated example, the connecting portion 57 is located between the first base portion 55 and the second base portion 56, as viewed in the y-direction. The shape of the connecting portion 57 is not specifically limited. In the illustrated example, the connecting portion 57 includes a first portion 571, a second portion 572, and a third portion 573, each of which will be described hereunder.

The first portion 571 is located between the first base portion 55 and the second base portion 56, as viewed in the y-direction. The shape of the first portion 571 is not specifically limited. In the illustrated example, the first portion 571 has a strip shape extending along the x-direction. In the illustrated example, the size of the first portion 571 in the y-direction is constant.

The second portion 572 is interposed between the first portion 571 and the first base portion 55 and, in the illustrated example, connected to the first portion 571 and the first base portion 55. The second portion 572 is larger in size in the y-direction, than the first portion 571. The shape of the second portion 572 is not specifically limited. In the illustrated example, the second portion 572 includes a fourth portion 572a and a fifth portion 572b, each of which will be described hereunder. The fourth portion 572a is a portion where the size in the y-direction increases in the direction from the first portion 571 toward the first base portion 55. In the fifth portion 572b, the size in the y-direction is constant. The fifth portion 572b is larger in size in the x-direction, than the fourth portion 572a.

The third portion 573 is interposed between the first portion 571 and the second base portion 56 and, in the illustrated example, connected to the first portion 571 and the second base portion 56. The third portion 573 is larger in size in the y-direction, than the first portion 571. The shape of the third portion 573 is not specifically limited. In the illustrated example, the size of the third portion 573 in the y-direction increases in the direction from the first portion 571 toward the second base portion 56.

In the illustrated example, the respective edges of the first base portion 55, the second base portion 56, and the connecting portion 57 on the side of the sixth face 36 in the y-direction are located generally at the same position in the y-direction. Here, the expression “located generally at the same position” in the y-direction refers to, for example, being located exactly at the same position, or being deviated by within ±5% of the characteristic size (size of the first base portion 55 or second base portion 56 in the y-direction).

The wiring 50A includes a first portion 51A, a second portion 52A, and a third portion 53A, each of which will be described hereunder.

The shape of the first portion 51A is not specifically limited, and a desired shape may be selected from a rectangular shape, a polygonal shape, a circular shape, an elliptical shape, and so forth. In the illustrated example, the first portion 51A has a rectangular shape. In this embodiment, the first portion 51A is located on the side of the third face 33 in the x-direction with respect to the first base portion 55, and spaced therefrom. In the illustrated example, in addition, the first portion 51A partially overlaps with the first base portion 55, as viewed in the x-direction. The center of the first portion 51A in the y-direction is located on the side of the fifth face 35, with respect to the first base portion 55.

The second portion 52A is located on the side of the fifth face 35 with respect to the first portion 51A, in the y-direction. The shape of the second portion 52A is not specifically limited, and a desired shape may be selected from a rectangular shape, a polygonal shape, a circular shape, an elliptical shape, and so forth. In the illustrated example, the first portion 51A has a rectangular shape. In the illustrated example, an end portion of the second portion 52A in the x-direction includes a portion extending toward the third face 33 in the x-direction, with respect to the first portion 51A. An end portion of the first portion 51A in the x-direction includes a portion extending toward the fourth face 34 in the x-direction, with respect to the second portion 52A.

The third portion 53A is interposed between the first portion 51A and the second portion 52A and, in the illustrated example, connected to the first portion 51A and the second portion 52A. The shape of the third portion 53A is not specifically limited. In the illustrated example, the third portion 53A has a rectangular shape. In the illustrated example, the edge of the third portion 53A on the side of the fourth face 34 in the x-direction is linearly connected to the edge of the second portion 52A on the side of the fourth face 34. The edge of the third portion 53A on the side of the third face 33 in the x-direction is linearly connected to the edge of the first portion 51A on the side of the third face 33. In the illustrated example, the second portion 52A and the third portion 53A are located on the side of the third face 33 in the x-direction, with respect to the center of the first portion 51A in the x-direction.

The wiring 50B includes a first portion 51B, a second portion 52B, and a third portion 53B, each of which will be described hereunder.

The shape of the first portion 51B is not specifically limited, and a desired shape may be selected from a rectangular shape, a polygonal shape, a circular shape, an elliptical shape, and so forth. In the illustrated example, the first portion 51B has a rectangular shape. In this embodiment, the first portion 51B is located on the side of the fifth face 35 in the y-direction with respect to the first base portion 55, and spaced therefrom. In addition, the first portion 51B is located on the side of the fourth face 34 in the x-direction with respect to the first portion 51A, and spaced therefrom. In the illustrated example, the first portion 51B at least partially overlaps with the first portion 51A, as viewed in the x-direction, and generally the entirety of the first portion 51B overlaps with the first portion 51A. Here, the expression “generally the entirety overlaps” refers to completely overlapping in its entirety, or being deviated by within 5% from each other. In the illustrated example, the center the first portion 51B in the y-direction is located on the side of the fifth face 35, with respect to the center of the first portion 51A in the y-direction. In the illustrated example, an end portion of the first portion 51B in the x-direction includes a portion extending toward the third face 33 in the x-direction, with respect to the first base portion 55. In the illustrated example, the center of the first portion 51B in the x-direction overlaps with the first base portion 55, as viewed in the y-direction.

The second portion 52B is located on the side of the fifth face 35 with respect to the first portion 51B, in the y-direction. In addition, the second portion 52B is located on the side of the fourth face 34 in the x-direction with respect to the second portion 52A, and spaced therefrom by a clearance G51. The shape of the second portion 52B is not specifically limited, and a desired shape may be selected from a rectangular shape, a polygonal shape, a circular shape, an elliptical shape, and so forth. In the illustrated example, the second portion 52B has a rectangular shape. In the illustrated example, in addition, generally the entirety of the second portion 52B overlaps with the first portion 51B, as viewed in the y-direction. Here, the expression “generally the entirety overlaps” refers to completely overlapping in its entirety, or being deviated by within 5% from each other. In the illustrated example, the second portion 52B generally coincides with the second portion 52A, as viewed in the x-direction. Here, the expression “generally coincides” as viewed in the x-direction refers to, for example, exactly coinciding with each other, or being deviated by within ±5% of the characteristic size (size of the second portion 52A or second portion 52B in the y-direction). In the illustrated example, the second portion 52B is shifted toward the third face 33, from the center of the first portion 51B in the x-direction.

The third portion 53B is interposed between the first portion 51B and the second portion 52B and, in the illustrated example, connected to the first portion 51B and the second portion 52B. The shape of the third portion 53B is not specifically limited. In the illustrated example, the third portion 53B has a rectangular shape. In the illustrated example, the third portion 53B generally coincides with the second portion 52B, as viewed in the y-direction. Here, the expression “generally coincides” as viewed in the y-direction refers to, for example, exactly coinciding with each other, or being deviated by within ±5% of the characteristic size (size of the second portion 52B or third portion 53B in the x-direction). In the illustrated example, the third portion 53B is shifted toward the third face 33, from the center of the first portion 51B in the x-direction.

The wiring 50C includes a first portion 51C, a second portion 52C, and a third portion 53C, each of which will be described hereunder.

The shape of the first portion 51C is not specifically limited, and a desired shape may be selected from a rectangular shape, a polygonal shape, a circular shape, an elliptical shape, and so forth. In the illustrated example, the first portion 51C has a rectangular shape. In this embodiment, the first portion 51C is located on the side of the fifth face 35 in the y-direction with respect to the first base portion 55, and spaced therefrom. In addition, the first portion 51C is located on the side of the fourth face 34 in the x-direction with respect to the first portion 51A, and spaced therefrom. In the illustrated example, the first portion 51C generally coincides with the first portion 51B, as viewed in the x-direction. Here, the expression “generally coincides” as viewed in the x-direction refers to, for example, exactly coinciding with each other, or being deviated by within ±5% of the characteristic size (size of the first portion 51B or first portion 51C in the y-direction). In the illustrated example, the center the first portion 51C in the y-direction is located on the side of the fifth face 35, with respect to the center of the first portion 51A in the y-direction. In the illustrated example, the first portion 51C is shifted toward the fourth face 34, from the center of the first base portion 55 in the x-direction. In the illustrated example, the center of the first portion 51C in the x-direction overlaps with the first base portion 55, as viewed in the y-direction.

The second portion 52C is located on the side of the fifth face 35 with respect to the first portion 51C, in the y-direction. In addition, the second portion 52C is located on the side of the fourth face 34 in the x-direction with respect to the second portion 52B, and spaced therefrom by a clearance G52. In the illustrated example, the clearance G52 is wider than the clearance G51. The shape of the second portion 52C is not specifically limited, and a desired shape may be selected from a rectangular shape, a polygonal shape, a circular shape, an elliptical shape, and so forth. In the illustrated example, the second portion 52C has a rectangular shape. In the illustrated example, in addition, generally the entirety of the second portion 52C overlaps with the first portion 51C, as viewed in the y-direction. Here, the expression “generally the entirety overlaps” refers to completely overlapping in its entirety, or being deviated by within 5% from each other. In the illustrated example, the second portion 52C generally coincides with the second portion 52B, as viewed in the x-direction. Here, the expression “generally coincides” as viewed in the x-direction refers to, for example, exactly coinciding with each other, or being deviated by within ±5% of the characteristic size (size of the second portion 52B or second portion 52C in the y-direction). In the illustrated example, the second portion 52C is shifted toward the fourth face 34, from the center of the first portion 51C in the x-direction.

The third portion 53C is interposed between the first portion 51C and the second portion 52C and, in the illustrated example, connected to the first portion 51C and the second portion 52C. The shape of the third portion 53C is not specifically limited. In the illustrated example, the third portion 53C has a rectangular shape. In the illustrated example, the third portion 53C generally coincides with the second portion 52C, as viewed in the y-direction. Here, the expression “generally coincides” as viewed in the y-direction refers to, for example, exactly coinciding with each other, or being deviated by within ±5% of the characteristic size (size of the second portion 52C and the third portion 53C in the x-direction). In the illustrated example, the third portion 53C generally coincides with the third portion 53B, as viewed in the x-direction. Here, the expression “generally coincides” as viewed in the x-direction refers to, for example, exactly coinciding with each other, or being deviated by within ±5% of the characteristic size (size of the third portion 53B and the third portion 53C in the y-direction). In the illustrated example, the third portion 53C is shifted toward the fourth face 34, from the center of the first portion 51C in the x-direction.

The wiring 50D includes a first portion 51D, a second portion 52D, a third portion 53D, a fourth portion 54D, and a fifth portion 55D, each of which will be described hereunder.

The first portion 51D is located on the side of the fifth face 35 in the y-direction with respect to the first base portion 55, and spaced therefrom. The shape of the first portion 51C is not specifically limited, and a desired shape may be selected from a rectangular shape, a polygonal shape, a circular shape, an elliptical shape, and so forth. In the illustrated example, the first portion 51C has an elongate rectangular shape, having the long sides extending along the y-direction. In the illustrated example, the first portion 51D overlaps with the first base portion 55, as viewed in the y-direction. The edge of the first portion 51D on the side of the fourth face 34 in the x-direction generally coincides with the edge of the first base portion 55 on the side of the fourth face 34, as viewed in the y-direction. Here, the expression “generally coincides” as viewed in the y-direction refers to, for example, exactly coinciding with each other, or being deviated by within ±5% of the characteristic size (size of the first portion 51D and the first base portion 55 in the x-direction). The first portion 51D is smaller in size in the y-direction, than the first portion 51C.

The second portion 52D is located on the side of the fifth face 35 with respect to the first portion 51D, in the y-direction. In addition, the second portion 52D is located on the side of the fourth face 34 with respect to the first portion 51D, in the x-direction. The second portion 52D is located on the side of the fourth face 34 in the x-direction with respect to the second portion 52C, and spaced therefrom by a clearance G53. The clearance G53 is generally the same in size as the clearance G52 (exactly the same, or different by within ±5%). The shape of the second portion 52D is not specifically limited, and a desired shape may be selected from a rectangular shape, a polygonal shape, a circular shape, an elliptical shape, and so forth. In the illustrated example, the second portion 52D has an elongate rectangular shape, having the long sides extending along the y-direction. In the illustrated example, the second portion 52D is spaced apart from the first portion 51D, as viewed in the y-direction. In the illustrated example, the second portion 52D generally coincides with the second portion 52C, as viewed in the x-direction. Here, the expression “generally coincides” as viewed in the x-direction refers to, for example, exactly coinciding with each other, or being deviated by within ±5% of the characteristic size (size of the second portion 52C or second portion 52D in the y-direction).

The third portion 53D is interposed between the first portion 51D and the second portion 52D and, in the illustrated example, connected to the edge of the first portion 51D on the side of the fourth face 34 in the x-direction. The shape of the third portion 53D is not specifically limited. In the illustrated example, the third portion 53D has a strip shape extending along the x-direction. The third portion 53D is spaced apart from the second portion 52D, as viewed in the y-direction.

The fourth portion 54D is interposed between the first portion 51D and the second portion 52D and, in the illustrated example, connected to the edge of the second portion 52D on the side of the sixth face 36 in the y-direction. The shape of the fourth portion 54D is not specifically limited. In the illustrated example, the fourth portion 54D has a strip shape extending along the y-direction. The fourth portion 54D is spaced apart from the first portion 51D, as viewed in the x-direction.

The fifth portion 55D is interposed between the third portion 53D and the fourth portion 54D and, in the illustrated example, connected to the third portion 53D and the fourth portion 54D. The shape of the fifth portion 55D is not specifically limited. In the illustrated example, the fifth portion 55D has a strip shape inclined with respect to the x-direction and the y-direction.

The wiring 50E includes a first portion 51E, a second portion 52E, a third portion 53E, a fourth portion 54E, and a fifth portion 55E, each of which will be described hereunder.

The first portion 51E is spaced apart from the first base portion 55 toward the fifth face 35 in the y-direction, and toward the fourth face 34 in the x-direction. In addition, the first portion 51E is located on the side of the fourth face 34 in the x-direction with respect to the first portion 51D, and spaced therefrom. The shape of the first portion 51E is not specifically limited, and a desired shape may be selected from a rectangular shape, a polygonal shape, a circular shape, an elliptical shape, and so forth. In the illustrated example, the first portion 51E has an elongate rectangular shape, having the long sides extending along the x-direction. In the illustrated example, first portion 51E is spaced apart from the first base portion 55, as viewed in the y-direction. In the illustrated example, the first portion 51D overlaps with the first base portion 55, as viewed in the y-direction. The first portion 51E overlaps with the first portion 51D, as viewed in the x-direction. Further, the first portion 51E overlaps with the second portion 52D, as viewed in the y-direction.

The second portion 52E is located on the side of the fifth face 35 with respect to the first portion 51E, in the y-direction. In addition, the second portion 52E is located on the side of the fourth face 34 with respect to the first portion 51E, in the x-direction. The second portion 52E is located on the side of the fourth face 34 in the x-direction with respect to the second portion 52D, and spaced therefrom by a clearance G54. The clearance G54 is narrower than the clearance G53. Here, a difference in size of the clearance G54, referred to in relation to the wirings 50E to 50N, is within ±5%. The shape of the second portion 52E is not specifically limited, and a desired shape may be selected from a rectangular shape, a polygonal shape, a circular shape, an elliptical shape, and so forth. In the illustrated example, the second portion 52E has an elongate rectangular shape, having the long sides extending along the y-direction. In the illustrated example, the second portion 52E is spaced apart from the first portion 51E, as viewed in the y-direction. In the illustrated example, the second portion 52E generally coincides with the second portion 52D, as viewed in the x-direction. Here, the expression “generally coincides” as viewed in the x-direction refers to, for example, exactly coinciding with each other, or being deviated by within ±5% of the characteristic size (size of the second portion 52D or second portion 52E in the y-direction).

The third portion 53E is interposed between the first portion 51E and the second portion 52E and, in the illustrated example, connected to the edge of the first portion 51E on the side of the fourth face 34 in the x-direction. The shape of the third portion 53E is not specifically limited. In the illustrated example, the third portion 53E has a strip shape extending along the x-direction. The third portion 53E is spaced apart from the second portion 52E, as viewed in the y-direction.

The fourth portion 54E is interposed between the first portion 51E and the second portion 52E and, in the illustrated example, connected to the edge of the second portion 52E on the side of the sixth face 36 in the y-direction. The shape of the fourth portion 54E is not specifically limited. In the illustrated example, the fourth portion 54E has a strip shape extending along the y-direction. The fourth portion 54E is spaced apart from the first portion 51E, as viewed in the x-direction.

The fifth portion 55E is interposed between the third portion 53E and the fourth portion 54E and, in the illustrated example, connected to the third portion 53E and the fourth portion 54E. The shape of the fifth portion 55E is not specifically limited. In the illustrated example, the fifth portion 55E has a strip shape inclined with respect to the x-direction and the y-direction.

The wiring 50F includes a first portion 51F, a second portion 52F, a third portion 53F, a fourth portion 54F, and a fifth portion 55F, each of which will be described hereunder.

The first portion 51F is located on the side of the fourth face 34 in the x-direction with respect to the first base portion 55, and spaced therefrom. The first portion 51F overlaps with the first base portion 55, as viewed in the x-direction. The shape of the first portion 51F is not specifically limited, and a desired shape may be selected from a rectangular shape, a polygonal shape, a circular shape, an elliptical shape, and so forth. In the illustrated example, the first portion 51F has an elongate rectangular shape, having the long sides extending along the x-direction. In addition, the first portion 51F generally coincides with the first portion 51E, as viewed in the y-direction. Here, the expression “generally coincides” as viewed in the y-direction refers to, for example, exactly coinciding with each other, or being deviated by within ±5% of the characteristic size (size of the first portion 51E or first portion 51F in the y-direction).

The second portion 52F is located on the side of the fifth face 35 with respect to the first portion 51F, in the y-direction. In addition, the second portion 52F is located on the side of the fourth face 34 with respect to the first portion 51F, in the x-direction. The second portion 52F is located on the side of the fourth face 34 in the x-direction with respect to the second portion 52E, and spaced therefrom by the clearance G54. The shape of the second portion 52F is not specifically limited, and a desired shape may be selected from a rectangular shape, a polygonal shape, a circular shape, an elliptical shape, and so forth. In the illustrated example, the second portion 52F has an elongate rectangular shape, having the long sides extending along the y-direction. In the illustrated example, the second portion 52F is spaced apart from the first portion 51F, as viewed in the y-direction. In the illustrated example, the second portion 52F generally coincides with the second portion 52E, as viewed in the x-direction. Here, the expression “generally coincides” as viewed in the x-direction refers to, for example, exactly coinciding with each other, or being deviated by within ±5% of the characteristic size (size of the second portion 52E or second portion 52F in the y-direction).

The third portion 53F is interposed between the first portion 51F and the second portion 52F and, in the illustrated example, connected to the edge of the first portion 51F on the side of the fourth face 34 in the x-direction. The shape of the third portion 53F is not specifically limited. In the illustrated example, the third portion 53F has a strip shape extending along the x-direction. The third portion 53F is spaced apart from the second portion 52F, as viewed in the y-direction. The third portion 53F is larger in size in the x-direction, than the third portion 53E.

The fourth portion 54F is interposed between the first portion 51F and the second portion 52F and, in the illustrated example, connected to the edge of the second portion 52F on the side of the sixth face 36 in the y-direction. The shape of the fourth portion 54F is not specifically limited. In the illustrated example, the fourth portion 54F has a strip shape extending along the y-direction. The fourth portion 54F is spaced apart from the first portion 51F, as viewed in the x-direction. The fourth portion 54F is larger in size in the y-direction, than the fourth portion 54E.

The fifth portion 55F is interposed between the third portion 53F and the fourth portion 54F and, in the illustrated example, connected to the third portion 53F and the fourth portion 54F. The shape of the fifth portion 55F is not specifically limited. In the illustrated example, the fifth portion 55F has a strip shape inclined with respect to the x-direction and the y-direction.

The wiring 50G includes a first portion 51G, a second portion 52G, a third portion 53G, a fourth portion 54G, and a fifth portion 55G, each of which will be described hereunder.

The first portion 51G is located on the side of the fourth face 34 in the x-direction with respect to the first base portion 55, and spaced therefrom. The first portion 51G overlaps with the first base portion 55, as viewed in the x-direction. The shape of the first portion 51G is not specifically limited, and a desired shape may be selected from a rectangular shape, a polygonal shape, a circular shape, an elliptical shape, and so forth. In the illustrated example, the first portion 51G has an elongate rectangular shape, having the long sides extending along the x-direction. In addition, the first portion 51G generally coincides with the first portion 51F, as viewed in the y-direction. Here, the expression “generally coincides” as viewed in the y-direction refers to, for example, exactly coinciding with each other, or being deviated by within ±5% of the characteristic size (size of the first portion 51F or first portion 51G in the x-direction). The first portion 51G overlaps with the fifth portion 572b, as viewed in the y-direction.

The second portion 52G is located on the side of the fifth face 35 with respect to the first portion 51G, in the y-direction. In addition, the second portion 52G is located on the side of the fourth face 34 with respect to the first portion 51G, in the x-direction. The second portion 52G is located on the side of the fourth face 34 in the x-direction with respect to the second portion 52F, and spaced therefrom by the clearance G54. The shape of the second portion 52G is not specifically limited, and a desired shape may be selected from a rectangular shape, a polygonal shape, a circular shape, an elliptical shape, and so forth. In the illustrated example, the second portion 52G has an elongate rectangular shape, having the long sides extending along the y-direction. In the illustrated example, the second portion 52G is spaced apart from the first portion 51G, as viewed in the y-direction. In the illustrated example, the second portion 52G generally coincides with the second portion 52F, as viewed in the x-direction. Here, the expression “generally coincides” as viewed in the x-direction refers to, for example, exactly coinciding with each other, or being deviated by within ±5% of the characteristic size (size of the second portion 52F or second portion 52G in the y-direction).

The third portion 53G is interposed between the first portion 51G and the second portion 52G and, in the illustrated example, connected to the edge of the first portion 51G on the side of the fourth face 34 in the x-direction. The shape of the third portion 53G is not specifically limited. In the illustrated example, the third portion 53G has a strip shape extending along the x-direction. The third portion 53G is spaced apart from the second portion 52G, as viewed in the y-direction. The third portion 53G is larger in size in the x-direction, than the third portion 53F.

The fourth portion 54G is interposed between the first portion 51G and the second portion 52G and, in the illustrated example, connected to the edge of the second portion 52G on the side of the sixth face 36 in the y-direction. The shape of the fourth portion 54G is not specifically limited. In the illustrated example, the fourth portion 54G has a strip shape extending along the y-direction. The fourth portion 54G is spaced apart from the first portion 51G, as viewed in the x-direction. The fourth portion 54G is larger in size in the y-direction, than the fourth portion 54F.

The fifth portion 55G is interposed between the third portion 53G and the fourth portion 54G and, in the illustrated example, connected to the third portion 53G and the fourth portion 54G. The shape of the fifth portion 55G is not specifically limited. In the illustrated example, the fifth portion 55G has a strip shape inclined with respect to the x-direction and the y-direction.

The wiring 50H includes a second portion 52H and a fourth portion 54H, each of which will be described hereunder.

The second portion 52H is located on the side of the fifth face 35 with respect to the second base portion 56, in the y-direction. The second portion 52H is located on the side of the fourth face 34 in the x-direction with respect to the second portion 52G, and spaced therefrom by the clearance G54. The shape of the second portion 52H is not specifically limited, and a desired shape may be selected from rectangular shape, a polygonal shape, a circular shape, an elliptical shape, and so forth. In the illustrated example, the second portion 52H has an elongate rectangular shape, having the long sides extending along the y-direction. In addition, the second portion 52H overlaps with the second base portion 56, as viewed in the y-direction. In the illustrated example, the second portion 52H generally coincides with the second portion 52G, as viewed in the x-direction. Here, the expression “generally coincides” as viewed in the x-direction refers to, for example, exactly coinciding with each other, or being deviated by within ±5% of the characteristic size (size of the second portion 52G or second portion 52H in the y-direction).

The fourth portion 54H is interposed between the second base portion 56 and the second portion 52H and, in the illustrated example, connected to the second base portion 56 and the second portion 52H. The fourth portion 54H is connected to the edge of the second base portion 56 on the side of the fifth face 35 in the y-direction, and the edge of the second portion 52H on the side of the sixth face 36 in the y-direction. The shape of the fourth portion 54H is not specifically limited. In the illustrated example, the fourth portion 54H has a strip shape extending along the y-direction.

The wiring 50I includes a first portion 51I, a second portion 52I, a third portion 53I, a fourth portion 54I, and a fifth portion 55I, each of which will be described hereunder.

The first portion 51I is located on the side of the fifth face 35 in the y-direction with respect to the second base portion 56, and spaced therefrom. The shape of the first portion 51I is not specifically limited, and a desired shape may be selected from a rectangular shape, a polygonal shape, a circular shape, an elliptical shape, and so forth. In the illustrated example, the first portion 51I has an elongate rectangular shape, having the long sides extending along the x-direction. In the illustrated example, the first portion 51I overlaps with the second base portion 56, as viewed in the y-direction. In addition, the first portion 51I is spaced apart from the second portion 52H, as viewed in the y-direction.

The second portion 52I is located on the side of the fifth face 35 with respect to the first portion 51I, in the y-direction. In addition, the second portion 52I is located on the side of the fourth face 34 in the x-direction with respect to the second portion 52H, and spaced therefrom by the clearance G54. The shape of the second portion 52I is not specifically limited, and a desired shape may be selected from a rectangular shape, a polygonal shape, a circular shape, an elliptical shape, and so forth. In the illustrated example, the second portion 52I has an elongate rectangular shape, having the long sides extending along the y-direction. In the illustrated example, the second portion 52I is spaced apart from the first portion 51I, as viewed in the y-direction. In addition, generally the entirety of the second portion 52I overlaps with the second base portion 56, as viewed in the y-direction. Here, the expression “generally the entirety overlaps” refers to completely overlapping in its entirety, or being deviated by within 5% from each other. In the illustrated example, the second portion 52I generally coincides with the second portion 52H, as viewed in the x-direction. Here, the expression “generally coincides” as viewed in the x-direction refers to, for example, exactly coinciding with each other, or being deviated by within ±5% of the characteristic size (size of the second portion 52H or second portion 52I in the y-direction).

The third portion 53I is interposed between the first portion 51I and the second portion 52I and, in the illustrated example, connected to the edge of the first portion 51I on the side of the fifth face 35 in the y-direction. The shape of the third portion 53I is not specifically limited. In the illustrated example, the third portion 53I has a strip shape extending along the y-direction.

The fourth portion 54I is interposed between the first portion 51I and the second portion 52I and, in the illustrated example, connected to the edge of the second portion 52I on the side of the sixth face 36 in the y-direction. The shape of the fourth portion 54I is specifically limited. In the illustrated example, the fourth portion 54I has a strip shape extending along the y-direction.

The fifth portion 55I is interposed between the third portion 53I and the fourth portion 54I and, in the illustrated example, connected to the third portion 53I and the fourth portion 541. The shape of the fifth portion 55I is not specifically limited. In the illustrated example, the fifth portion 55I has a strip shape inclined with respect to the x-direction and the y-direction.

The wiring 50J includes a first portion 51J, a second portion 52J, a third portion 53J, a fourth portion 54J, and a fifth portion 55J, each of which will be described hereunder.

The first portion 51J is located on the side of the fourth face 34 in the x-direction with respect to the first portion 51I, and spaced therefrom by a clearance G55. In the illustrated example, the clearance G55 is narrower than the clearance G54. The first portion 51J is located on the side of the fifth face 35 in the y-direction with respect to the second base portion 56, and spaced therefrom. The shape of the first portion 51J is not specifically limited, and a desired shape may be selected from a rectangular shape, a polygonal shape, a circular shape, an elliptical shape, and so forth. In the illustrated example, the first portion 51J has an elongate rectangular shape, having the long sides extending along the y-direction. In the illustrated example, the first portion 51J overlaps with the second base portion 56, as viewed in the y-direction. In addition, the first portion 51J overlaps with the second portion 52I, as viewed in the y-direction. In the illustrated example, the first portion 51J generally coincides with the first portion 51I, as viewed in the x-direction. Here, the expression “generally coincides” as viewed in the x-direction refers to, for example, exactly coinciding with each other, or being deviated by within ±5% of the characteristic size (size of the first portion 51I or first portion 51J in the y-direction).

The second portion 52J is located on the side of the fifth face 35 with respect to the first portion 51J, in the y-direction. In addition, the second portion 52J is located on the side of the fourth face 34 in the x-direction with respect to the second portion 52I, and spaced therefrom by the clearance G54. The shape of the second portion 52J is not specifically limited, and a desired shape may be selected from a rectangular shape, polygonal shape, a circular shape, an elliptical shape, and so forth. In the illustrated example, the second portion 52J has an elongate rectangular shape, having the long sides extending along the y-direction. In the illustrated example, the second portion 52J is spaced apart from the first portion 51J, as viewed in the y-direction. In addition, generally the entirety of the second portion 52J overlaps with the second base portion 56, as viewed in the y-direction. Here, the expression “generally the entirety overlaps” refers to completely overlapping in its entirety, or being deviated by within 5% from each other. In the illustrated example, the second portion 52J generally coincides with the second portion 52I, as viewed in the x-direction. Here, the expression “generally coincides” as viewed in the x-direction refers to, for example, exactly coinciding with each other, or being deviated by within ±5% of the characteristic size (size of the first portion 51I or second portion 52J in the y-direction).

The third portion 53J is interposed between the first portion 51J and the second portion 52J and, in the illustrated example, connected to the edge of the first portion 51J on the side of the fifth face 35 in the y-direction. The shape of the third portion 53J is not specifically limited. In the illustrated example, the third portion 53J has a strip shape extending along the y-direction. The third portion 53J is smaller in size in the y-direction, than the third portion 53I.

The fourth portion 54J is interposed between the first portion 51J and the second portion 52J and, in the illustrated example, connected to the edge of the second portion 52J on the side of the sixth face 36 in the y-direction. The shape of the fourth portion 54J is not specifically limited. In the illustrated example, the fourth portion 54J has a strip shape extending along the y-direction. The fourth portion 54J is smaller in size in the y-direction, than the fourth portion 54I.

The fifth portion 55J is interposed between the third portion 53J and the fourth portion 54J and, in the illustrated example, connected to the third portion 53J and the fourth portion 54J. The shape of the fifth portion 55J is not specifically limited. In the illustrated example, the fifth portion 55J has a strip shape inclined with respect to the x-direction and the y-direction.

The wiring 50K includes a first portion 51K, a second portion 52K, a third portion 53K, a fourth portion 54K, and a fifth portion 55K, each of which will be described hereunder.

The first portion 51K is located on the side of the fourth face 34 in the x-direction with respect to the first portion 51J, and spaced therefrom by the clearance G55. The first portion 51K is located on the side of the fifth face 35 in the y-direction with respect to the second base portion 56, and spaced therefrom. The shape of the first portion 51K is not specifically limited, and a desired shape may be selected from a rectangular shape, a polygonal shape, a circular shape, an elliptical shape, and so forth. In the illustrated example, the first portion 51K has an elongate rectangular shape, having the long sides extending along the y-direction. In the illustrated example, the first portion 51K overlaps with the second base portion 56, as viewed in the y-direction. In addition, the first portion 51K overlaps with the second portion 52J, as viewed in the y-direction. In the illustrated example, the first portion 51K generally coincides with the first portion 51J, as viewed in the x-direction. Here, the expression “generally coincides” as viewed in the x-direction refers to, for example, exactly coinciding with each other, or being deviated by within ±5% of the characteristic size (size of the first portion 51J or first portion 51K in the y-direction).

The second portion 52K is located on the side of the fifth face 35 with respect to the first portion 51K, in the y-direction. In addition, the second portion 52K is located on the side of the fourth face 34 in the x-direction with respect to the second portion 52J, and spaced therefrom by the clearance G54. The shape of the second portion 52K is not specifically limited, and a desired shape may be selected from a rectangular shape, a polygonal shape, a circular shape, an elliptical shape, and so forth. In the illustrated example, the second portion 52K has an elongate rectangular shape, having the long sides extending along the y-direction. In the illustrated example, the second portion 52K is spaced apart from the first portion 51K, as viewed in the y-direction. In addition, generally the entirety of the second portion 52K overlaps with the second base portion 56, as viewed in the y-direction. Here, the expression “generally the entirety overlaps” refers to completely overlapping in its entirety, or being deviated by within 5% from each other. In the illustrated example, the second portion 52K generally coincides with the second portion 52J, as viewed in the x-direction. Here, the expression “generally coincides” as viewed in the x-direction refers to, for example, exactly coinciding with each other, or being deviated by within ±5% of the characteristic size (size of the second portion 52J or second portion 52K in the y-direction).

The third portion 53K is interposed between the first portion 51K and the second portion 52K and, in the illustrated example, connected to the edge of the first portion 51K on the side of the fifth face 35 in the y-direction. The shape of the third portion 53K is not specifically limited. In the illustrated example, the third portion 53K has a strip shape extending along the y-direction. The third portion 53K is smaller in size in the y-direction, than the third portion 53J.

The fourth portion 54K is interposed between the first portion 51K and the second portion 52K and, in the illustrated example, connected to the edge of the second portion 52K on the side of the sixth face 36 in the y-direction. The shape of the fourth portion 54K is not specifically limited. In the illustrated example, the fourth portion 54K has a strip shape extending along the y-direction. The fourth portion 54K is smaller in size in the y-direction, than the fourth portion 54J.

The fifth portion 55K is interposed between the third portion 53K and the fourth portion 54K and, in the illustrated example, connected to the third portion 53K and the fourth portion 54K. The shape of the fifth portion 55K is not specifically limited. In the illustrated example, the fifth portion 55K has a strip shape inclined with respect to the x-direction and the y-direction.

The wiring 50L includes a first portion 51L, a second portion 52L, a third portion 53L, a fourth portion 54L, and a fifth portion 55L, each of which will be described hereunder.

The first portion 51L is located on the side of the fourth face 34 in the x-direction with respect to the first portion 51K, and spaced therefrom by the clearance G55. The first portion 51L is located on the side of the fifth face 35 in the y-direction with respect to the second base portion 56, and spaced therefrom. The shape of the first portion 51L is not specifically limited, and a desired shape may be selected from a rectangular shape, a polygonal shape, a circular shape, an elliptical shape, and so forth. In the illustrated example, the first portion 51L has an elongate rectangular shape, having the long sides extending along the y-direction. In the illustrated example, the first portion 51L overlaps with the second base portion 56, as viewed in the y-direction. In addition, the first portion 51L is located between the second portion 52J and the second portion 52K, as viewed in the y-direction. In the illustrated example, the first portion 51L generally coincides with the first portion 51K, as viewed in the x-direction. Here, the expression “generally coincides” as viewed in the x-direction refers to, for example, exactly coinciding with each other, or being deviated by within ±5% of the characteristic size (size of the first portion 51K or first portion 51L in the y-direction).

The second portion 52L is located on the side of the fifth face 35 with respect to the first portion 51L, in the y-direction. In addition, the second portion 52L is located on the side of the fourth face 34 in the x-direction with respect to the second portion 52K, and spaced therefrom by the clearance G54. The shape of the second portion 52L is not specifically limited, and a desired shape may be selected from rectangular shape, a polygonal shape, a circular shape, an elliptical shape, and so forth. In the illustrated example, the second portion 52L has an elongate rectangular shape, having the long sides extending along the y-direction. In the illustrated example, the second portion 52L is spaced apart from the first portion 51L, as viewed in the y-direction. In addition, the second portion 52L is spaced apart from the second base portion 56, as viewed in the y-direction. In the illustrated example, the second portion 52L generally coincides with the second portion 52K, as viewed in the x-direction. Here, the expression “generally coincides” as viewed in the x-direction refers to, for example, exactly coinciding with each other, or being deviated by within ±5% of the characteristic size (size of the second portion 52K or second portion 52L in the y-direction).

The third portion 53L is interposed between the first portion 51L and the second portion 52L and, in the illustrated example, connected to the edge of the first portion 51L on the side of the fifth face 35 in the y-direction. The shape of the third portion 53L is not specifically limited. In the illustrated example, the third portion 53L has a strip shape extending along the y-direction. The third portion 53L is smaller in size in the y-direction, than the third portion 53K.

The fourth portion 54L is interposed between the first portion 51L and the second portion 52L and, in the illustrated example, connected to the edge of the second portion 52L on the side of the sixth face 36 in the y-direction. The shape of the fourth portion 54L is not specifically limited. In the illustrated example, the fourth portion 54L has a strip shape extending along the y-direction. The fourth portion 54L is smaller in size in the y-direction, than the fourth portion 54K.

The fifth portion 55L is interposed between the third portion 53L and the fourth portion 54L and, in the illustrated example, connected to the third portion 53L and the fourth portion 54L. The shape of the fifth portion 55L is not specifically limited. In the illustrated example, the fifth portion 55L has a strip shape inclined with respect to the x-direction and the y-direction.

The wiring 50M includes a first portion 51M, a second portion 52M, a third portion 53M, a fourth portion 54M, and a fifth portion 55M, each of which will be described hereunder.

The first portion 51M is located on the side of the fourth face 34 in the x-direction with respect to the first portion 51L, and spaced therefrom by the clearance G55. The first portion 51M is located on the side of the fifth face 35 in the y-direction with respect to the second base portion 56, and spaced therefrom. The shape of the first portion 51M is not specifically limited, and a desired shape may be selected from a rectangular shape, a polygonal shape, a circular shape, an elliptical shape, and so forth. In the illustrated example, the first portion 51M has a rectangular shape. In the illustrated example, the first portion 51M overlaps with the second base portion 56, as viewed in the y-direction. In addition, the first portion 51M overlaps with the second portion 52K, as viewed in the y-direction. In the illustrated example, the first portion 51M generally coincides with the first portion 51L, as viewed in the x-direction. Here, the expression “generally coincides” as viewed in the x-direction refers to, for example, exactly coinciding with each other, or being deviated by within ±5% of the characteristic size (size of the first portion 51L or first portion 51M in the y-direction).

The second portion 52M is located on the side of the fifth face 35 with respect to the first portion 51M, in the y-direction. In addition, the second portion 52M is located on the side of the fourth face 34 in the x-direction with respect to the second portion 52L, and spaced therefrom by the clearance G54. The shape of the second portion 52M is not specifically limited, and a desired shape may be selected from a rectangular shape, a polygonal shape, a circular shape, an elliptical shape, and so forth. In the illustrated example, the second portion 52M has an elongate rectangular shape, having the long sides extending along the y-direction. In the illustrated example, the second portion 52M is spaced apart from the first portion 51M, as viewed in the y-direction. In addition, the second portion 52M is spaced apart from the second base portion 56, as viewed in the y-direction. In the illustrated example, the second portion 52M generally coincides with the second portion 52L, as viewed in the x-direction. Here, the expression “generally coincides” as viewed in the x-direction refers to, for example, exactly coinciding with each other, or being deviated by within ±5% of the characteristic size (size of the second portion 52L or second portion 52M in the y-direction).

The third portion 53M is interposed between the first portion 51M and the second portion 52M and, in the illustrated example, connected to the edge of the first portion 51M on the side of the fourth face 34 in the x-direction. The shape of the third portion 53M is not specifically limited. In the illustrated example, the third portion 53M has a strip shape extending along the x-direction.

The fourth portion 54M is interposed between the first portion 51M and the second portion 52M and, in the illustrated example, connected to the edge of the second portion 52M on the side of the sixth face 36 in the y-direction. The shape of the fourth portion 54M is not specifically limited. In the illustrated example, the fourth portion 54M has a strip shape extending along the y-direction. The fourth portion 54M is larger in size in the y-direction, than the fourth portion 54L.

The fifth portion 55M is interposed between the third portion 53M and the fourth portion 54M and, in the illustrated example, connected to the third portion 53M and the fourth portion 54M. The shape of the fifth portion 55M is not specifically limited. In the illustrated example, the fifth portion 55M has a strip shape inclined with respect to the x-direction and the y-direction.

The wiring 50N includes a first portion 51N, a second portion 52N, and a fifth portion 55N, each of which will be described hereunder.

The first portion 51N is located on the side of the fifth face 35 with respect to the second base portion 56, in the y-direction. The shape of the first portion 51N is not specifically limited, and a desired shape may be selected from a rectangular shape, a polygonal shape, a circular shape, an elliptical shape, and so forth. In the illustrated example, the first portion 51N has a rectangular shape. In the illustrated example, the first portion 51N is spaced apart from the second base portion 56, as viewed in the y-direction. The first portion 51N overlaps with the second portion 52K, as viewed in the y-direction. Further, the first portion 51N overlaps with the second base portion 56 and the first portion 51M, as viewed in the x-direction.

The second portion 52N is located on the side of the fifth face 35 with respect to the first portion 51N, in the y-direction. In addition, the second portion 52N is located on the side of the fourth face 34 in the x-direction with respect to the second portion 52M, and spaced therefrom by the clearance G54. The shape of the second portion 52N is not specifically limited, and a desired shape may be selected from a rectangular shape, a polygonal shape, a circular shape, an elliptical shape, and so forth. In the illustrated example, the second portion 52N has an elongate rectangular shape, having the long sides extending along the y-direction. In the illustrated example, the second portion 52N is spaced apart from the first portion 51N, as viewed in the y-direction. In addition, the second portion 52N is spaced apart from the second base portion 56, as viewed in the y-direction. In the illustrated example, the second portion 52N generally coincides with the second portion 52M, as viewed in the x-direction. Here, the expression “generally coincides” as viewed in the x-direction refers to, for example, exactly coinciding with each other, or being deviated by within ±5% of the characteristic size (size of the second portion 52M or second portion 52N in the y-direction).

The fifth portion 55N is interposed between the first portion 51N and the second portion 52N and, in the illustrated example, connected to the first portion 51N and the second portion 52N. The shape of the fifth portion 55N is not specifically limited. In the illustrated example, the fifth portion 55N has a strip shape inclined with respect to the x-direction and the y-direction.

The wiring 50O includes a first portion 51O, a second portion 52O, a third portion 53O, and a fifth portion 55O, each of which will be described hereunder.

The first portion 51O is located on the side of the fourth face 34 in the x-direction with respect to the second base portion 56, and connected thereto. The shape of the first portion 51O is not specifically limited, and a desired shape may be selected from a rectangular shape, a polygonal shape, a circular shape, an elliptical shape, and so forth. In the illustrated example, the first portion 51O has an elongate rectangular shape, having the long sides extending along the x-direction. In the illustrated example, the first portion 51O overlaps with the second base portion 56, as viewed in the x-direction.

The second portion 52O is located on the side of the fifth face 35 in the y-direction, and on the side of the fourth face 34 in the x-direction, with respect to the first portion 51O. The second portion 52O is located on the side of the sixth face 36 with respect to the second portion 52N, in the y-direction. The shape of the second portion 52O is not specifically limited, and a desired shape may be selected from a rectangular shape, a polygonal shape, a circular shape, an elliptical shape, and so forth. In the illustrated example, the second portion 52O has an elongate rectangular shape, having the long sides extending along the y-direction. In the illustrated example, the second portion 52O is spaced apart from the first portion 51O and the first portion 51M, as viewed in the y-direction. In addition, the second portion 52O is spaced apart from the second base portion 56, and overlaps with the second portion 52N, as viewed in the y-direction.

The third portion 53O is interposed between the first portion 51O and the second portion 52O and, in the illustrated example, connected to the edge of the first portion 51O on the side of the fourth face 34 in the x-direction. The shape of the third portion 53O is not specifically limited. In the illustrated example, the third portion 53O has a strip shape extending along the x-direction.

The fifth portion 55O is interposed between the first portion 51O and the third portion 53O and, in the illustrated example, connected to the first portion 51O and the third portion 53O. The shape of the fifth portion 55O is not specifically limited. In the illustrated example, the fifth portion 55O has a strip shape inclined with respect to the x-direction and the y-direction.

The wiring 50P includes a first portion 51P, a second portion 52P, a third portion 53P, and a fifth portion 55P, each of which will be described hereunder.

The first portion 51P is located on the side of the fourth face 34 in the x-direction with respect to the second base portion 56, and spaced therefrom. The shape of the first portion 51P is not specifically limited, and a desired shape may be selected from a rectangular shape, a polygonal shape, a circular shape, an elliptical shape, and so forth. In the illustrated example, the first portion 51P has an elongate rectangular shape, having the long sides extending along the x-direction. In the illustrated example, the first portion 51P overlaps with the second base portion 56, as viewed in the x-direction. In addition, the first portion 51P overlaps with the first portion 51O, as viewed in the y-direction.

The second portion 52P is located on the side of the fifth face 35 in the y-direction, and on the side of the fourth face 34 in the x-direction, with respect to the first portion 51P. The second portion 52P is located on the side of the sixth face 36 with respect to the second portion 52O, in the y-direction. The shape of the second portion 52P is not specifically limited, and a desired shape may be selected from a rectangular shape, a polygonal shape, a circular shape, an elliptical shape, and so forth. In the illustrated example, the second portion 52P has an elongate rectangular shape, having the long sides extending along the y-direction. In the illustrated example, the second portion 52P is spaced apart from the first portion 51P and the second portion 52M, as viewed in the y-direction. In addition, the second portion 52P is spaced apart from the second base portion 56, and overlaps with the second portion 52N, as viewed in the y-direction. In the illustrated example, the second portion 52P generally coincides with the second portion 52O, as viewed in the y-direction. Here, the expression “generally coincides” as viewed in the y-direction refers to, for example, exactly coinciding with each other, or being deviated by within ±5% of the characteristic size (size of the second portion 52O or second portion 52P in the x-direction).

The third portion 53P is interposed between the first portion 51P and the second portion 52P and, in the illustrated example, connected to the edge of the first portion 51P on the side of the fourth face 34 in the x-direction. The shape of the third portion 53P is not specifically limited. In the illustrated example, the third portion 53P has a strip shape extending along the x-direction.

The fifth portion 55P is interposed between the first portion 51P and the third portion 53P and, in the illustrated example, connected to the first portion 51P and the third portion 53P. The shape of the fifth portion 55P is not specifically limited. In the illustrated example, the fifth portion 55P has a strip shape inclined with respect to the x-direction and the y-direction.

The wiring 50A to the wiring 50P are formed on a region in the substrate 3, on the side of the fifth face 35 in the y-direction. The region on the side of the fifth face 35 will be defined as a second region 30B.

### <Bonding Section 6>

The plurality of bonding sections 6 are formed on the substrate 3. In this embodiment, the plurality of bonding sections 6 are formed on the first face 31 of the substrate 3. The material of the bonding section 6 is not specifically limited, provided that the material is capable of bonding the substrate 3 and the lead 1 together. The bonding section 6 is formed of, for example, a conductive material. The conductive material to form the bonding section 6 is not specifically limited. Examples of the conductive material to form the bonding section 6 include materials containing silver (Ag), copper (Cu), or gold (Au). In the subsequent description, it will be assumed that the bonding section 6 contains silver. The bonding section 6 according to this embodiment contains the same conductive material as that employed to form the conductive section 5. However, the bonding section 6 may contain copper instead of silver, or gold instead of silver or copper. Alternatively, the bonding section 6 may contain Ag—Pt or Ag—Pd. The forming method of the bonding section 6 is not limited. For example, the bonding section 6 may be formed, like the conductive section 5, by sintering a paste containing the mentioned metal. The thickness of the bonding section 6 is not specifically limited, but may be, for example, approximately 5 μm to 30 μm.

In this embodiment, the plurality of bonding sections 6 include a bonding section 6A to a bonding section 6D.

The bonding section 6A is located on the side of the sixth face 36 with respect to the conductive section 5, in the y-direction. The bonding section 6A overlaps with the entirety of the first base portion 55, as viewed in the y-direction. The shape of the bonding section 6A is not specifically limited. In the illustrated example, the bonding section 6A includes a first edge 61A, a second edge 62A, a third edge 63A, a fourth edge 64A, a fifth edge 65Aa, a sixth edge 66Aa, a seventh edge 65Ab, and an eighth edge 66Ab.

The first edge 61A extends along the y-direction. In the illustrated example, the first edge 61A overlaps with the first portion 51A, as viewed in the y-direction.

The second edge 62A is located on the opposite side of the first edge 61A in the x-direction, across the center of the bonding section 6A in the x-direction, and extends along the y-direction. In the illustrated example, the second edge 62A overlaps with the first portion 571 of the connecting portion 57, as viewed in the y-direction. The second edge 62A is smaller in size in the y-direction, than the first edge 61A.

The third edge 63A is connected to the respective ends of the first edge 61A and the second edge 62A, on the side of the fifth face 35 in the y-direction. The third edge 63A extends along the x-direction. The third edge 63A is spaced apart from the first base portion 55, in the y-direction. In the illustrated example, the third edge 63A overlaps at least with the first portion 51A, the first base portion 55, and the first portion 571, as viewed in the y-direction.

The fourth edge 64A is located on the opposite side of the third edge 63A in the y-direction, across the center of the bonding section 6A in the y-direction. The fourth edge 64A extends along the x-direction. The fourth edge 64A is smaller in size in the x-direction, than the third edge 63A. The entirety of the fourth edge 64A overlaps with the third edge 63A, as viewed in the y-direction.

The fifth edge 65Aa is connected to the end of the first edge 61A on the side of the sixth face 36 in the y-direction. In the illustrated example, the fifth edge 65Aa is inclined with respect to the x-direction and the y-direction. The seventh edge 65Ab is connected to the end of the second edge 62A on the side of the sixth face 36 in the y-direction. In the illustrated example, the seventh edge 65Ab is inclined with respect to the x-direction and the y-direction.

The sixth edge 66Aa is connected to the end of the fifth edge 65Aa on the side of the sixth face 36 in the y-direction, and the end of the fourth edge 64A in the x-direction. In the illustrated example, the sixth edge 66Aa extends along the y-direction. The eighth edge 66Ab is connected to the end of the seventh edge 65Ab on the side of the sixth face 36 in the y-direction, and the end of the fourth edge 64A in the x-direction. In the illustrated example, the eighth edge 66Ab extends along the y-direction.

The bonding section 6B is located on the side of the sixth face 36 with respect to the conductive section 5, in the y-direction. The bonding section 6B is located on the side of the fourth face 34 with respect to the bonding section 6A, in the x-direction. In the illustrated example, the bonding section 6B overlaps with the first portion 571, the third portion 573, and the second base portion 56, as viewed in the y-direction. The shape of the bonding section 6B is not specifically limited. In the illustrated example, the bonding section 6B includes a first edge 61B, a second edge 62B, a third edge 63B, a fourth edge 64B, a fifth edge 65B, a sixth edge 66B, and an eighth edge 68B.

The first edge 61B extends along the y-direction. The first edge 61B is opposed to the second edge 62A. In the illustrated example, the first edge 61B overlaps with the first portion 571, as viewed in the y-direction.

The second edge 62B is located on the opposite side of the first edge 61B in the x-direction, across the center of the bonding section 6B in the x-direction, and extends along the y-direction. In the illustrated example, the second edge 62B overlaps with the second base portion 56, as viewed in the y-direction. The second edge 62B is smaller in size in the y-direction, than the first edge 61B. In addition, the second edge 62B is generally the same in size in the y-direction, as the second edge 62A (exactly the same, or different by within ±5%).

The third edge 63B is connected to the respective ends of the first edge 61B and the second edge 62B, on the side of the fifth face 35 in the y-direction. The third edge 63B extends along the x-direction. In the illustrated example, the third edge 63B overlaps at least with the first portion 571, the third portion 573, and the second base portion 56, as viewed in the y-direction. In the illustrated example, in addition, the third edge 63B is located generally at the same position as the third edge 63A, in the y-direction. Here, the expression “located generally at the same position” in the y-direction refers to, for example, being located at exactly the same position, or being deviated by within ±5% of the characteristic size (size of the bonding section 6A or bonding section 6B in the y-direction).

The fourth edge 64B is located on the opposite side of the third edge 63B in the y-direction, across the center of the bonding section 6B in the y-direction. The fourth edge 64B extends along the x-direction. The fourth edge 64B is connected to the end of the first edge 61B on the side of the sixth face 36 in the y-direction. The fourth edge 64B is smaller in size in the x-direction, than the third edge 63B. The entirety of the fourth edge 64B overlaps with the third edge 63B, as viewed in the y-direction.

The fifth edge 65B is connected to the end of the second edge 62B on the side of the sixth face 36 in the y-direction. In the illustrated example, the fifth edge 65B is inclined with respect to the x-direction and the y-direction.

The sixth edge 66B is connected to the end of the fourth edge 64B on the side of the fourth face 34 in the x-direction. In the illustrated example, the sixth edge 66B extends along the y-direction.

The eighth edge 68B is connected to the fifth edge 65B and the sixth edge 66B. In the illustrated example, the eighth edge 68B extends along the x-direction.

The bonding section 6C is located on the side of the sixth face 36 with respect to the conductive section 5, in the y-direction. The bonding section 6C is located on the side of the fourth face 34 with respect to the bonding section 6B, in the x-direction. In the illustrated example, the entirety of the bonding section 6C overlaps with the second base portion 56, as viewed in the y-direction. The shape of the bonding section 6C is not specifically limited. In the illustrated example, the bonding section 6C includes a first edge 61C, a second edge 62C, a third edge 63C, a fourth edge 64C, a fifth edge 65C, a sixth edge 66C, and an eighth edge 68C.

The first edge 61C extends along the y-direction. The first edge 61C is opposed to the second edge 62B. In the illustrated example, the first edge 61C overlaps with the second base portion 56, as viewed in the y-direction.

The second edge 62C is located on the opposite side of the first edge 61C in the x-direction, across the center of the bonding section 6C in the x-direction, and extends along the y-direction. In the illustrated example, the second edge 62C overlaps with the second base portion 56, as viewed in the y-direction. The second edge 62C is smaller in size in the y-direction, than the first edge 61C. In addition, the second edge 62C is generally the same in size in the y-direction, as the second edge 62B (exactly the same, or different by within ±5%).

The third edge 63C is connected to the respective ends of the first edge 61C and the second edge 62C, on the side of the fifth face 35 in the y-direction. The third edge 63C extends along the x-direction. In the illustrated example, the third edge 63C overlaps with the second base portion 56, as viewed in the y-direction. In the illustrated example, in addition, the third edge 63C is located generally at the same position as the third edge 63B, in the y-direction. Here, the expression “located generally at the same position” in the y-direction refers to, for example, being located at exactly the same position, or being deviated by within ±5% of the characteristic size (size of the bonding section 6B or bonding section 6C in the y-direction).

The fourth edge 64C is located on the opposite side of the third edge 63C in the y-direction, across the center of the bonding section 6C in the y-direction. The fourth edge 64C extends along the x-direction. The fourth edge 64C is connected to the end of the first edge 61C on the side of the sixth face 36 in the y-direction. The fourth edge 64C is smaller in size in the x-direction, than the third edge 63C. The entirety of the fourth edge 64C overlaps with the third edge 63C, as viewed in the y-direction.

The fifth edge 65C is connected to the end of the second edge 62C on the side of the sixth face 36 in the y-direction. In the illustrated example, the fifth edge 65C is inclined with respect to the x-direction and the y-direction.

The sixth edge 66C is connected to the end of the fourth edge 64C on the side of the fourth face 34 in the x-direction. In the illustrated example, the sixth edge 66C extends along the y-direction.

The eighth edge 68C is connected to the fifth edge 65C and the sixth edge 66C. In the illustrated example, the eighth edge 68C extends along the x-direction.

The bonding section 6D is located on the side of the sixth face 36 with respect to the conductive section 5, in the y-direction. The bonding section 6D is located on the side of the fourth face 34 with respect to the bonding section 6C, in the x-direction. In the illustrated example, the bonding section 6D overlaps with the second base portion 56, the first portion 51P, the third portion 53P, and the second portion 52P, as viewed in the y-direction. The shape of the bonding section 6D is not specifically limited. In the illustrated example, the bonding section 6D includes a first edge 61D, a second edge 62D, a third edge 63D, a fourth edge 64D, and a fifth edge 65D.

The first edge 61D extends along the y-direction. The first edge 61D is opposed to the second edge 62C. In the illustrated example, the first edge 61D overlaps with the second base portion 56, as viewed in the y-direction.

The second edge 62D is located on the opposite side of the first edge 61D in the x-direction, across the center of the bonding section 6D in the x-direction, and extends along the y-direction. In the illustrated example, the second edge 62D overlaps with the second portion 52P, as viewed in the y-direction. The second edge 62D is smaller in size in the y-direction, than the first edge 61D.

The third edge 63D is connected to the respective ends of the first edge 61D and the second edge 62D, on the side of the fifth face 35 in the y-direction. The third edge 63D extends along the x-direction. In the illustrated example, the third edge 63D overlaps with the second base portion 56, the first portion 51P, the third portion 53P, and the second portion 52P, as viewed in the y-direction. In the illustrated example, in addition, the third edge 63D is located generally at the same position as the third edge 63C, in the y-direction. Here, the expression “located generally at the same position” in the y-direction refers to, for example, being located at exactly the same position, or being deviated by within of the characteristic size (size of the bonding section 6C or bonding section 6D in the y-direction).

The fourth edge 64D is located on the opposite side of the third edge 63D in the y-direction, across the center of the bonding section 6D in the y-direction. The fourth edge 64D extends along the x-direction. The fourth edge 64D is connected to the end of the first edge 61D on the side of the sixth face 36 in the y-direction. The fourth edge 64D is smaller in size in the x-direction, than the third edge 63D. The entirety of the fourth edge 64D overlaps with the third edge 63D, as viewed in the y-direction.

The fifth edge 65D is connected to the second edge 62D and the fourth edge 64D. In the illustrated example, the fifth edge 65D is inclined with respect to the x-direction and the y-direction.

The bonding section 6A to the bonding section 6D are formed on a region in the substrate 3 on the side of the sixth face 36, with respect to the conductive section 5 in the y-direction. The region in the substrate 3 on the side of the sixth face 36 in a plan view, where the bonding sections 6 are formed, will be defined as a first region 30A.

### <Leads 1>

The plurality of leads 1 contain a metal, and have higher heat dissipation characteristics, for example than the substrate 3. The metal to form the lead 1 is not specifically limited, and may be, for example, copper (Cu), aluminum, iron (Fe), oxygen-free copper, or an alloy of the cited metals, such as a Cu—Sn alloy, a Cu—Zr alloy, or a Cu—Fe alloy. The plurality of leads 1 may be plated with nickel (Ni). Examples of the forming method of the plurality of leads 1 include pressing a metal plate with a die, and patterning a metal plate by etching, without limitation thereto. The thickness of the lead 1 is not specifically limited, but may be, for example, approximately 0.4 mm to 0.8 mm.

In this embodiment, the plurality of leads 1 include a plurality of leads 1A to 1G, and 1Z, as shown in FIG. 1 to FIG. 4. The plurality of leads 1A to 1G constitute conduction paths, for example to the semiconductor chips 4A to 4F.

The lead 1A is located on the substrate 3 and, in this embodiment, on the first face 31. The lead 1A exemplifies a first lead in the present disclosure. The lead 1A is bonded to the bonding section 6A, via a bonding material 81. The bonding material 81 may be any material that is capable of bonding the lead 1A to the bonding section 6A. From the viewpoint of efficient heat transmission from the lead 1A to the substrate 3, it is preferable to employ a material having high thermal conductivity as the bonding material 81, such as silver paste, copper paste, or solder. However, the bonding material 81 may be an insulative material such as an epoxy-based resin or a silicone-based resin. In the case where the bonding section 6A is not provided on the substrate 3, the lead 1A may be bonded to the substrate 3.

The configuration of the lead 1A is not specifically limited and, in this embodiment, the lead 1A includes a first portion 11A, a second portion 12A, a third portion 13A, and a fourth portion 14A, each of which will be described hereunder.

As shown in FIG. 5, FIG. 9, and FIG. 10, the first portion 11A includes a main surface 111A, a back surface 112A, a first face 121A, a second face 122A, a third face 123A, a fourth face 124Aa, a fifth face 125Aa, a sixth face 126Aa, a seventh face 127Aa, an eighth face 124Ab, a ninth face 125Ab, a tenth face 126Ab, an eleventh face 127Ab, a plurality of recesses 1111A, and a groove 1112A.

The main surface 111A is oriented in the same direction as the first face 31, in the z-direction.

The back surface 112A is oriented to the opposite side of the main surface 111A in the z-direction and, in the illustrated example, a planar surface. The back surface 112A is bonded to the bonding section 6A via the bonding material 81, as shown in FIG. 5 and FIG. 9.

The first face 121A is located between the main surface 111A and the back surface 112A in the z-direction, and oriented in the same direction as the third face 33 as a whole, in the x-direction. In the illustrated example, the first face 121A is connected to the main surface 111A and the back surface 112A.

The second face 122A is located on the opposite side of the first face 121A in the x-direction, and oriented in the same direction as the fourth face 34, in the x-direction. The second face 122A is located between the main surface 111A and the back surface 112A in the z-direction and, in the illustrated example, connected to the main surface 111A and the back surface 112A. The second face 122A is smaller in size in the y-direction, than the first face 121A.

The third face 123A is located between the first face 121A and the second face 122A in the x-direction, and oriented in the same direction as the fifth face 35, in the y-direction. The third face 123A is located between the main surface 111A and the back surface 112A in the z-direction and, in the illustrated example, connected to the main surface 111A and the back surface 112A.

The fourth face 124Aa and the eighth face 124Ab are located on the opposite side of the third face 123A in the y-direction, and oriented in the same direction as the sixth face 36 in the y-direction. The fourth face 124Aaa and the eighth face 124Ab are spaced apart from each other in the x-direction. The fourth face 124A is located between the main surface 111A and the back surface 112A in the z-direction and, in the illustrated example, connected to the main surface 111A and the back surface 112A. The fourth face 124Aa and the eighth face 124Ab are located generally at the same position in the y-direction. Here, the expression “generally at the same position” in the y-direction refers to, for example, being at exactly the same position, or being deviated by within ±5% of the characteristic size (size of the first portion 11A in the y-direction).

The fifth face 125Aa and the ninth face 125Ab are located between the first face 121A and the second face 122A, in the x-direction. The fifth face 125Aa is connected to the end of the first face 121A on the side of the sixth face 36 in the y-direction. The ninth face 125Ab is connected to the end of the second face 122A on the side of the sixth face 36 in the y-direction. The fifth face 125Aa and the ninth face 125Ab are inclined with respect to the x-direction. The fifth face 125Aa and the ninth face 125Ab are located between the main surface 111A and the back surface 112A in the z-direction and, in the illustrated example, connected to the main surface 111A and the back surface 112A.

The sixth face 126Aa is located between the fifth face 125Aa and the fourth face 124Aa in the x-direction, and between the fifth face 125Aa and the fourth face 124Aa in the y-direction. In the illustrated example, the sixth face 126Aa is connected to the fourth face 124Aa and the fifth face 125Aa.

The tenth face 126Ab is located between the ninth face 125Ab and the eighth face 124Ab in the x-direction, and between the ninth face 125Ab and the eighth face 124Ab in the y-direction. In the illustrated example, the tenth face 126Ab is connected to the eighth face 124Ab and the ninth face 125Ab. The sixth face 126Aa and the tenth face 126Ab extend along the y-direction. The sixth face 126Aa and the tenth face 126Ab are located between the main surface 111A and the back surface 112A in the z-direction and, in the illustrated example, connected to the main surface 111A and the back surface 112A.

The seventh face 127Aa is located between the first face 121A and the third face 123A in the x-direction, and between the first face 121A and the third face 123A in the y-direction. The seventh face 127Aa is connected to the first face 121A and the third face 123A. In the illustrated example, the seventh face 127Aa forms a convex curved surface, as viewed in the z-direction. The seventh face 127Aa is located between the main surface 111A and the back e 112A in the z-direction and, in the illustrated example, connected to the main surface 111A and the back surface 112A. The eleventh face 127Ab is located between the second face 122A and the third face 123A in the x-direction, and between the second face 122A and the third face 123A in the y-direction. The eleventh face 127Ab is connected to the second face 122A and the third face 123A. In the illustrated example, the eleventh face 127Ab forms a convex curved surface, as viewed in the z-direction. The eleventh face 127Ab is located between the main surface 111A and the back surface 112A in the z-direction and, in the illustrated example, connected to the main surface 111A and the back surface 112A.

In the illustrated example, the first face 121A, the second face 122A, and the third face 123A each include a plurality of protrusions 131A. The plurality of protrusions 131A each protrude outwardly of the first portion 11A as viewed in the z-direction, and extend along the z-direction. Here, the plurality of protrusions 131A may be formed on the first portion 11A, in portions other than the first face 121A, the second face 122A, and the third face 123A. In addition, at least one of the first face 121A, the second face 122A, and the third face 123A may be without the plurality of protrusions 131A.

The plurality of recesses 1111A are each recessed from the main surface 111A in the z-direction. The shape of the recess 1111A in a z-direction view is not specifically limited, and may be, for example, circular, elliptical, rectangular, or triangular. In the illustrated example, the plurality of recesses 1111A are arranged in a matrix pattern.

The groove 1112A is recessed from the main surface 111A in the z-direction. In the illustrated example, the shape of the groove 1112A in a z-direction view is not specifically limited. In the illustrated example, the groove 1112A includes a first portion 1112Aa of a rectangular shape, and a pair of second portions 1112Ab extending along the y-direction in the rectangular shape. The cross-sectional shape of the groove 1112A is not specifically limited, and may be, for example, circular, elliptical, rectangular, or triangular.

The number of rows of the plurality of recesses 1111A in the y-direction is larger in the region between the groove 1112A, and the fourth face 124Aa and eighth face 124Ab, than in the region between the groove 1112A and the third face 123A.

The third portion 13A and the fourth portion 14A are covered with the encapsulating resin 7. The third portion 13A is connected to the first portion 11A and the fourth portion 14A. In the illustrated example, the third portion 13A is connected to a portion of the first portion 11A between the fourth face 124Aa and the eighth face 124Ab. In addition, the third portion 13A overlaps with the sixth face 36, as viewed in the z-direction. As shown in FIG. 5, the fourth portion 14A is shifted from the first portion 11A in the z-direction, to the side to which the main surface 111A is oriented. The end portion of the fourth portion 14A is flush with a sixth face 76 of the resin 7.

The second portion 12A is connected to the end portion of the fourth portion 14A, and corresponds to a portion of the lead 1A sticking out from the encapsulating resin 7. The second portion 12A sticks out to the opposite side of the first portion 11A, in the y-direction. The second portion 12A is used, for example, to electrically connect the semiconductor device A1 to an external circuit. In the illustrated example, the second portion 12A is bent in the z-direction, to the side to which the main surface 111A is oriented.

The lead 1B is located on the substrate 3 and, in this embodiment, on the first face 31. The lead 1B exemplifies a first lead in the present disclosure. The lead 1B is bonded to the bonding section 6B, via the bonding material 81. In the case where the bonding section 6B is not provided on the substrate 3, the lead 1B may be bonded to the substrate 3.

The configuration of the lead 1B is not specifically limited. In this embodiment the lead 1B includes, as shown in FIG. 4 and FIG. 14, a first portion 11B, a second portion 12B, a third portion 13B, and a fourth portion 14B, each of which will be described hereunder.

As shown in FIG. 9 and FIG. 14, the first portion 11B includes a main surface 111B, a back surface 112B, a first face 121B, a second face 122B, a third face 123B, a fourth face 124B, a fifth face 125B, a sixth face 126B, a seventh face 127B, an eighth face 128B, a ninth face 125Bb, a tenth face 126Bb, an eleventh face 127Bb, a plurality of recesses 1111B, and a groove 1112B.

The main surface 111B is oriented in the same direction as the first face 31, in the z-direction.

The back surface 112B is oriented to the opposite side of the main surface 111B in the z-direction and, in the illustrated example, a planar surface. The back surface 112B is bonded to the bonding section 6B via the bonding material 81, as shown in FIG. 9.

The first face 121B is located between the main surface 111B and the back surface 112B in the z-direction, and oriented in the same direction as the third face 33 as a whole, in the x-direction. In the illustrated example, the first face 121B is connected to the main surface 111B and the back surface 112B. The first face 121B is opposed to the second face 122A.

The second face 122B is located on the opposite side of the first face 121B in the x-direction, and oriented in the same direction as the fourth face 34, in the x-direction. The second face 122B is located between the main surface 111B and the back surface 112B in the z-direction and, in the illustrated example, connected to the main surface 111B and the back surface 112B. The second face 122B is smaller in size in the y-direction, than the first face 121B.

The third face 123B is located between the first face 121B and the second face 122B in the x-direction, and oriented in the same direction as the fifth face 35, in the y-direction. The third face 123B is located between the main surface 111B and the back surface 112B in the z-direction and, in the illustrated example, connected to the main surface 111B and the back surface 112B.

The fourth face 124B is located on the opposite side of the third face 123B in the y-direction, and oriented in the same direction as the sixth face 36 in the y-direction. The fourth face 124B is located between the main surface 111B and the back surface 112B in the z-direction and, in the illustrated example, connected to the main surface 111B and the back surface 112B. In the illustrated example, the fourth face 124B overlaps with the third face 123B, as viewed in the y-direction.

The fifth face 125Ba is connected to the end of the first face 121B on the side of the sixth face 36 in the y-direction. The fifth face 125Ba is opposed to the ninth face 125Ab. The fifth face 125Ba is inclined with respect to the x-direction. The fifth face 125Ba is spaced apart from the third face 123B, as viewed in the y-direction. The fifth face 125Ba is located between the main surface 111B and the back surface 112B in the z-direction and, in the illustrated example, connected to the main surface 111B and the back surface 112B. The ninth face 125Bb is connected to the end of the second face 122B on the side of the sixth face 36 in the y-direction. The ninth face 125Bb is inclined with respect to the x-direction and the y-direction. The ninth face 125Bb overlaps with the third face 123B, as viewed in the y-direction. The ninth face 125Bb is located between the main surface 111B and the back surface 112B in the z-direction and, in the illustrated example, connected to the main surface 111B and the back surface 112B.

The sixth face 126Ba extends along the y-direction. In the illustrated example, the sixth face 126Ba is connected to the fifth face 125Ba. The sixth face 126Ba is located between the main surface 111B and the back surface 112B in the z-direction and, in the illustrated example, connected to the main surface 111B and the back surface 112B. The tenth face 126Bb extends along the y-direction. In the illustrated example, the tenth face 126Bb is connected to the fourth face 124B. The tenth face 126Bb is located between the main surface 111B and the back surface 112B in the z-direction and, in the illustrated example, connected to the main surface 111B and the back surface 112B.

The seventh face 127Ba is located between the first face 121B and the third face 123B in the x-direction, and between the first face 121B and the third face 123B in the y-direction. The seventh face 127Ba is connected to the first face 121B and the third face 123B. In the illustrated example, the seventh face 127Ba forms a convex curved surface, as viewed in the z-direction. The seventh face 127Ba is located between the main surface 111B and the back surface 112B in the z-direction and, in the illustrated example, connected to the main surface 111B and the back surface 112B. The eleventh face 127Bb is located between the second face 122B and the third face 123B in the x-direction, and between the second face 122B and the third face 123B in the y-direction. The eleventh face 127Bb is connected to the second face 122B and the third face 123B. In the illustrated example, the eleventh face 127Bb forms a convex curved surface, as viewed in the z-direction. The eleventh face 127Bb is located between the main surface 111B and the back surface 112B in the z-direction and, in the illustrated example, connected to the main surface 111B and the back surface 112B.

The eighth face 128B is located between the tenth face 126Bb and the ninth face 125Bb in the x-direction and the y-direction, and connected to the tenth face 126Bb and the ninth face 125Bb. In the illustrated example, the eighth face 128B extends along the x-direction. The eighth face 128B is located between the main surface 111B and the back surface 112B in the z-direction and, in the illustrated example, connected to the main surface 111B and the back surface 112B.

In the illustrated example, the first face 121B, the second face 122B, and the third face 123B each include a plurality of protrusions 131B. The plurality of protrusions 131B each protrude outwardly of the first portion 11B as viewed in the z-direction, and extend along the z-direction. Here, the plurality of protrusions 131B may be formed on the first portion 11B, in portions other than the first face 121B, the second face 122B, and the third face 123B. In addition, at least one of the first face 121B, the second face 122B, and the third face 123B may be without the plurality of protrusions 131B.

The plurality of recesses 1111B are each recessed from the main surface 111B in the z-direction. The shape of the recess 1111B in a z-direction view is not specifically limited, and may be, for example, circular, elliptical, rectangular, or triangular. In the illustrated example, the plurality of recesses 1111B are arranged in a matrix pattern.

The groove 1112B is recessed from the main surface 111B in the z-direction. In the illustrated example, the shape of the groove 1112B in a z-direction view is not specifically limited and, the illustrated example, the groove 1112B has a rectangular shape. The cross-sectional shape of the groove 1112B is not specifically limited, and may be, for example, circular, elliptical, rectangular, or triangular.

The number of rows of the plurality of recesses 1111B in the y-direction is larger in the region between the groove 1112B and the fourth face 124B, than in the region between the groove 1112B and the third face 123B.

The third portion 13B and the fourth portion 14B are covered with the encapsulating resin 7. The third portion 13B is connected to the first portion 11B and the fourth portion 14B. In the illustrated example, the third portion 13B is connected to a portion of the first portion 11B adjacent to the fourth face 124B. In addition, the third portion 13B overlaps with the sixth face 36, as viewed in the z-direction. As shown in FIG. 5, the fourth portion 14B is, like the fourth portion 14A of the lead 1A, shifted from the first portion 11B in the z-direction, to the side to which the main surface 111B is oriented. The end portion of the fourth portion 14B is flush with the sixth face 76 of the resin 7.

The second portion 12B is connected to the end portion of the fourth portion 14B, and corresponds to a portion of the lead 1B sticking out from the encapsulating resin 7. The second portion 12B sticks out to the opposite side of the first portion 11B, in the y-direction. The second portion 12B is used, for example, to electrically connect the semiconductor device A1 to an external circuit. In the illustrated example, the second portion 12B is bent in the z-direction, to the side to which the main surface 111B is oriented.

The lead 1C is located on the substrate 3 and, in this embodiment, on the first face 31. The lead 1C exemplifies a first lead in the present disclosure. The lead 1C is bonded to the bonding section 6C, via the bonding material 81. In the case where the bonding section 6C is not provided on the substrate 3, the lead 1C may be bonded to the substrate 3.

The configuration of the lead 1C is not specifically limited. In this embodiment the lead 1C includes, as shown in FIG. 4 and FIG. 14, a first portion 11C, a second portion 12C, a third portion 13C, and a fourth portion 14C, each of which will be described hereunder.

As shown in FIG. 9 and FIG. 14, the first portion 11C includes a main surface 111C, a back surface 112C, a first face 121C, a second face 122C, a third face 123C, a fourth face 124C, a fifth face 125Ca, a sixth face 126Ca, a seventh face 127Ca, an eighth face 128C, a ninth face 125Cb, a tenth face 126Cb, an eleventh face 127Cb, a plurality of recesses 1111C, and a groove 1112C.

The main surface 111C is oriented in the same direction as the first face 31, in the z-direction.

The back surface 112C is oriented to the opposite side of the main surface 111C in the z-direction and, in the illustrated example, a planar surface. The back surface 112C is bonded to the bonding section 6C via the bonding material 81, as shown in FIG. 9.

The first face 121C is located between the main surface 111C and the back surface 112C in the z-direction, and oriented in the same direction as the third face 33 as a whole, in the x-direction. In the illustrated example, the first face 121C is connected to the main surface 111C and the back surface 112C. The first face 121C is opposed to the second face 122B.

The second face 122C is located on the opposite side of the first face 121C in the x-direction, and oriented in the same direction as the fourth face 34, in the x-direction. The second face 122C is located between the main surface 111C and the back surface 112C in the z-direction and, in the illustrated example, connected to the main surface 111C and the back surface 112C. The second face 122C is smaller in size in the y-direction, than the first face 121C.

The third face 123C is located between the first face 121C and the second face 122C in the x-direction, and oriented in the same direction as the fifth face 35, in the y-direction. The third face 123C is located between the main surface 111C and the back surface 112C in the z-direction and, in the illustrated example, connected to the main surface 111C and the back surface 112C.

The fourth face 124C is located on the opposite side of the third face 123C in the y-direction, and oriented in the same direction as the sixth face 36 in the y-direction. The fourth face 124C is located between the main surface 111C and the back surface 112C in the z-direction and, in the illustrated example, connected to the main surface 111C and the back surface 112C. In the illustrated example, the fourth face 124C overlaps with the third face 123C, as viewed in the y-direction.

The fifth face 125Ca is connected to the end of the first face 121C on the side of the sixth face 36 in the y-direction. The fifth face 125Ca is opposed to the ninth face 125Bb. The fifth face 125Ca is inclined with respect to the x-direction and the y-direction. The fifth face 125Ca is spaced apart from the third face 123C, as viewed in the y-direction. The fifth face 125Ca is located between the main surface 111C and the back surface 112C in the z-direction and, in the illustrated example, connected to the main surface 111C and the back surface 112C. The ninth face 125Cb is connected to the end of the second face 122C on the side of the sixth face 36 in the y-direction. The ninth face 125Cb is inclined with respect to the x-direction and the y-direction. The ninth face 125Cb overlaps with the third face 123C, as viewed in the y-direction. The ninth face 125Cb is located between the main surface 111C and the back surface 112C in the z-direction and, in the illustrated example, connected to the main surface 111C and the back surface 112C.

The sixth face 126Ca is located on the opposite side of the third face 123C with respect to the fifth face 125Ca, in the y-direction. In the illustrated example, the sixth face 126Ca is opposed to the tenth face 126Bb. The sixth face 126Ca extends along the y-direction. The sixth face 126Ca is located between the main surface 111C and the back surface 112C in the z-direction and, in the illustrated example, connected to the main surface 111C and the back surface 112C. The tenth face 126Cb is located on the opposite side of the third face 123C with respect to the ninth face 125Cb, in the y-direction. In the illustrated example, the tenth face 126Cb is connected to the fourth face 124C and the ninth face 125Cb. The tenth face 126Cb extends along the y-direction. The tenth face 126Cb is located between the main surface 111C and the back surface 112C in the z-direction and, in the illustrated example, connected to the main surface 111C and the back surface 112C.

The seventh face 127Ca is located between the first face 121C and the third face 123C in the x-direction, and between the first face 121C and the third face 123C in the y-direction. The seventh face 127Ca is connected to the first face 121C and the third face 123C. In the illustrated example, the seventh face 127Ca forms a convex curved surface, as viewed in the z-direction. The seventh face 127Ca is located between the main surface 111C and the back surface 112C in the z-direction and, in the illustrated example, connected to the main surface 111C and the back surface 112C. The eleventh face 127Cb is located between the second face 122C and the third face 123C in the x-direction, and between the second face 122C and the third face 123C in the y-direction. The eleventh face 127Cb is connected to the second the eleventh face 127Cb forms a convex curved surface, as viewed in the z-direction. The eleventh face 127Cb is located between the main surface 111C and the back surface 112C in the z-direction and, in the illustrated example, connected to the main surface 111C and the back surface 112C.

The eighth face 128C is located between the fifth face 125Ca and the sixth face 126Ca in the x-direction and the y-direction, and connected to the fifth face 125Ca and the sixth face 126Ca. In the illustrated example, the eighth face 128C extends along the x-direction, and is opposed to the eighth face 128B. The eighth face 128C is located between the main surface 111C and the back surface 112C in the z-direction and, in the illustrated example, connected to the main surface 111C and the back surface 112C.

In the illustrated example, the first face 121C, the second face 122C, and the third face 123C each include a plurality of protrusions 131C. The plurality of protrusions 131C each protrude outwardly of the first portion 11C as viewed in the z-direction, and extend along the z-direction. Here, the plurality of protrusions 131C may be formed on the first portion 11C, in portions other than the first face 121C, the second face 122C, and the third face 123C. In addition, at least one of the first face 121C, the second face 122C, and the third face 123C may be without the plurality of protrusions 131C.

The plurality of recesses 1111C are each recessed from the main surface 111C in the z-direction. The shape of the recess 1111C in a z-direction view is not specifically limited, and may be, for example, circular, elliptical, rectangular, or triangular. In the illustrated example, the plurality of recesses 1111C are arranged in a matrix pattern.

The groove 1112C is recessed from the main surface 111C in the z-direction. In the illustrated example, the shape of the groove 1112C in a z-direction view is not specifically limited and, in the illustrated example, the groove 1112C has a rectangular shape. The cross-sectional shape of the groove 1112C is not specifically limited, and may be, for example, circular, elliptical, rectangular, or triangular.

The number of rows of the plurality of recesses 1111C in the y-direction is larger in the region between the groove 1112C and the fourth face 124C, than in the region between the groove 1112C and the third face 123C.

The third portion 13C and the fourth portion 14C are covered with the encapsulating resin 7. The third portion 13C is connected to the first portion 11C and the fourth portion 14C. In the illustrated example, the third portion 13C is connected to a portion of the first portion 11C adjacent to the fourth face 124C. In addition, the third portion 13C overlaps with the sixth face 36, as viewed in the z-direction. The fourth portion 14C is, like the fourth portion 14A of the lead 1A, shifted from the first portion 11C in the z-direction, to the side to which the main surface 111C is oriented, and connected to the second portion 12C. The end portion of the fourth portion 14C is flush with the sixth face 76 of the resin 7.

The second portion 12C is connected to the end portion of the fourth portion 14C, and corresponds to a portion of the lead 1C sticking out from the encapsulating resin 7. The second portion 12C sticks out to the opposite side of the first portion 11C, in the y-direction. The second portion 12C is used, for example, to electrically connect the semiconductor device A1 to an external circuit. In the illustrated example, the second portion 12C is bent in the z-direction, to the side to which the main surface 111C is oriented.

The lead 1D is located on the substrate 3 and, in this embodiment, on the first face 31. The lead 1D exemplifies a first lead in the present disclosure. The lead 1D is bonded to the bonding section 6D, via the bonding material 81. In the case where the bonding section 6D is not provided on the substrate 3, the lead 1D may be bonded to the substrate 3.

The configuration of the lead 1D is not specifically limited. In this embodiment the lead 1D includes, as shown in FIG. 4 and FIG. 14, a first portion 11D, a second portion 12D, a third portion 13D, and a fourth portion 14D, each of which will be described hereunder.

As shown in FIG. 9 and FIG. 14, the first portion 11D includes a main surface 111D, a back surface 112D, a first face 121D, a second face 122D, a third face 123D, a fourth face 124D, a fifth face 125Da, a sixth face 126D, a seventh face 127Da, an eighth face 125Db, a ninth face 127Db, a plurality of recesses 1111D, and a groove 1112D.

The main surface 111D is oriented in the same direction as the first face 31, in the z-direction.

The back surface 112D is oriented to the opposite side of the main surface 111D in the z-direction and, in the illustrated example, a planar surface. The back surface 112D is bonded to the bonding section 6D via the bonding material 81, as shown in FIG. 9.

The first face 121D is located between the main surface 111D and the back surface 112D in the z-direction, and oriented in the same direction as the third face 33 as a whole, in the x-direction. In the illustrated example, the first face 121D is connected to the main surface 111D and the back surface 112D. The first face 121D is opposed to the second face 122C.

The second face 122D is located on the opposite side of the first face 121D in the x-direction, and oriented in the same direction as the fourth face 34, in the x-direction. The second face 122D is located between the main surface 111D and the back surface 112D in the z-direction and, in the illustrated example, connected to the main surface 111D and the back surface 112D. The second face 122D is larger in size in the y-direction, than the first face 121D.

The third face 123D is located between the first face 121D and the second face 122D in the x-direction, and oriented in the same direction as the fifth face 35, in the y-direction. The third face 123D is located between the main surface 111D and the back surface 112D in the z-direction and, in the illustrated example, connected to the main surface 111D and the back surface 112D.

The fourth face 124D is located on the opposite side of the third face 123D in the y-direction, and oriented in the same direction as the sixth face 36 in the y-direction. The fourth face 124D is located between the main surface 111D and the back surface 112D in the z-direction and, in the illustrated example, connected to the main surface 111D and the back surface 112D. In the illustrated example, the fourth face 124D overlaps with the third face 123D, as viewed in the y-direction.

The fifth face 125Da is connected to the end of the first face 121D on the side of the sixth face 36 in the y-direction. The fifth face 125Da is opposed to the ninth face 125Cb. The fifth face 125Da is inclined with respect to the x-direction and the y-direction. The fifth face 125Da is spaced apart from the third face 123D, as viewed in the y-direction. The fifth face 125Da is located between the main surface 111D and the back surface 112D in the z-direction and, in the illustrated example, connected to the main surface 111D and the back surface 112D. The eighth face 125Db is connected to the end of the second face 122D on the side of the sixth face 36 in the y-direction. The eighth face 125Db is inclined with respect to the x-direction and the y-direction. The eighth face 125Db overlaps with the third face 123D, as viewed in the y-direction. The eighth face 125Db is located between the main surface 111D and the back surface 112D in the z-direction and, in the illustrated example, connected to the main surface 111D and the back surface 112D.x

The sixth face 126D is located on the opposite side of the third face 123D with respect to the fifth face 125Da, in the y-direction. In the illustrated example, the sixth face 126D is opposed to the sixth face 126C. The sixth face 126D is connected to the fifth face 125Da. The sixth face 126D extends along the y-direction. The sixth face 126D is located between the main surface 111D and the back surface 112D in the z-direction and, in the illustrated example, connected to the main surface 111D and the back surface 112D.

The seventh face 127Da is located between the first face 121D and the third face 123D in the x-direction, and between the first face 121D and the third face 123D in the y-direction. The seventh face 127Da is connected to the first face 121D and the third face 123D. In the illustrated example, the seventh face 127Da forms a convex curved surface, as viewed in the z-direction. The seventh face 127Da is located between the main surface 111D and the back surface 112D in the z-direction and, in the illustrated example, connected to the main surface 111D and the back surface 112D. The ninth face 127Db is located between the second face 122D and the third face 123D in the x-direction, and between the second face 122D and the third face 123D in the y-direction. The ninth face 127Db is connected to the second face 122D and the third face 123D. In the illustrated example, the ninth face 127Db forms a convex curved surface, as viewed in the z-direction. The ninth face 127Db is located between the main surface 111D and the back surface 112D in the z-direction and, in the illustrated example, connected to the main surface 111D and the back surface 112D.

In the illustrated example, the first face 121D, the second face 122D, and the third face 123D each include a plurality of protrusions 131D. The plurality of protrusions 131D each protrude outwardly of the first portion 11D as viewed in the z-direction, and extend along the z-direction. Here, the plurality of protrusions 131D may be formed on the first portion 11D, in portions other than the first face 121D, the second face 122D, and the third face 123D. In addition, at least one of the first face 121D, the second face 122D, and the third face 123D may be without the plurality of protrusions 131D.

The plurality of recesses 1111D are each recessed from the main surface 111D in the z-direction. The shape of the recess 1111D in a z-direction view is not specifically limited, and may be, for example, circular, elliptical, rectangular, or triangular. In the illustrated example, the plurality of recesses 1111D are arranged in a matrix pattern.

The groove 1112D is recessed from the main surface 111D in the z-direction. In the illustrated example, the shape of the groove 1112D in a z-direction view is not specifically limited and, in the illustrated example, the groove 1112D has a rectangular shape. The cross-sectional shape of the groove 1112D is not specifically limited, and may be, for example, circular, elliptical, rectangular, or triangular.

The number of rows of the plurality of recesses 1111D in the y-direction is larger in the region between the groove 1112D and the fourth face 124D, than in the region between the groove 1112D and the third face 123D.

Regarding the third portion 13D and the fourth portion 14D, the third portion 13D is connected to the first portion 11D and the fourth portion 14D. In the illustrated example, the third portion 13D is connected to a portion of the first portion 11D adjacent to the fourth face 124D. In addition, the third portion 13D overlaps with the sixth face 36, as viewed in the z-direction, and is covered with the encapsulating resin 7. The fourth portion 14D is, like the fourth portion 14A of the lead 1A, shifted from the first portion 11D in the z-direction, to the side to which the main surface 111D is oriented, and connected to the second portion 12D. The end portion of the fourth portion 14D is flush with the sixth face 76 of the resin 7.

The second portion 12D is connected to the end portion of the fourth portion 14D, and corresponds to a portion of the lead 1D sticking out from the encapsulating resin 7. The second portion 12D sticks out to the opposite side of the first portion 11D, in the y-direction. The second portion 12D is used, for example, to electrically connect the semiconductor device A1 to an external circuit. In the illustrated example, the second portion 12D is bent in the z-direction, to the side to which the main surface 111D is oriented.

The lead 1E is spaced apart from the substrate 3, as viewed in the z-direction. In this embodiment, the lead 1E is located on the side to which the sixth face 36 is oriented, with respect to the substrate 3 in the y-direction.

The configuration of the lead 1E is not specifically limited. In this embodiment the lead 1E includes, as shown in FIG. 4, a second portion 12E and a fourth portion 14E, each of which will be described hereunder.

The fourth portion 14E is covered with the encapsulating resin 7. The fourth portion 14E is, like the fourth portion 14D of the lead 1D, shifted from the first portion 11D in the z-direction, to the side to which the main surface 111D is oriented. The end portion of the fourth portion 14E is flush with the sixth face 76 of the resin 7.

The second portion 12E is connected to the end portion of the fourth portion 14E, and corresponds to a portion of the lead 1E sticking out from the encapsulating resin 7. The second portion 12E sticks out to the opposite side of the fourth portion 14E, in the y-direction. The second portion 12E is used, for example, to electrically connect the semiconductor device A1 to an external circuit. In the illustrated example, the second portion 12E is bent in the z-direction, to the side to which the first face 31 is oriented.

The lead 1F is spaced apart from the substrate 3, as viewed in the z-direction. In this embodiment, the lead 1F is located on the side to which the sixth face 36 is oriented, with respect to the substrate 3 in the y-direction.

The configuration of the lead 1F is not specifically limited. In this embodiment the lead 1F includes, as shown in FIG. 4, a second portion 12F and a fourth portion 14F, each of which will be described hereunder.

The fourth portion 14F is covered with the encapsulating resin 7. The fourth portion 14F is, like the fourth portion 14D of the lead 1D, shifted from the first portion 11D in the z-direction, to the side to which the main surface 111D is oriented. The end portion of the fourth portion 14F is flush with the sixth face 76 of the resin 7.

The second portion 12F is connected to the end portion of the fourth portion 14F, and corresponds to a portion of the lead 1F sticking out from the encapsulating resin 7. The second portion 12F sticks out to the opposite side of the fourth portion 14F, in the y-direction. The second portion 12F is used, for example, to electrically connect the semiconductor device A1 to an external circuit. In the illustrated example, the second portion 12F is bent in the z-direction, to the side to which the first face 31 is oriented.

The lead 1G is spaced apart from the substrate 3, as viewed in the z-direction. In this embodiment, the lead 1G is located on the side to which the fourth face 34 is oriented, with respect to the substrate 3 in the x-direction. In addition, the lead 1G is located on the opposite side of the fourth portion 14D, with respect to the lead 1G in the x-direction.

The configuration of the lead 1G is not specifically limited. In this embodiment the lead 1G includes, as shown in FIG. 4, a second portion 12G and a fourth portion 14G, each of which will be described hereunder.

The fourth portion 14G is covered with the encapsulating resin 7. The fourth portion 14G is, like the fourth portion 14D of the lead 1D, shifted from the first portion 11D in the z-direction, to the side to which the main surface 111D is oriented. The fourth portion 14G overlaps with the fourth portion 14F, as viewed in the y-direction. The end portion of the fourth portion 14G is flush with the sixth face 76 of the resin 7.

The second portion 12G is connected to the end portion of the fourth portion 14G, and corresponds to a portion of the lead 1G sticking out from the encapsulating resin 7. The second portion 12G sticks out to the opposite side of the fourth portion 14G, in the y-direction. The second portion 12G is used, for example, to electrically connect the semiconductor device A1 to an external circuit. In the illustrated example, the second portion 12G is bent in the z-direction, to the side to which the first face 31 is oriented.

The lead 1Z is spaced apart from the substrate 3, as viewed in the z-direction. In this embodiment, the lead 1Z is located on the side to which the third face 33 is oriented, with respect to the substrate 3 in the x-direction. In addition, the lead 1Z is located on the opposite side of the lead 1B, with respect to the lead 1A in the x-direction.

The configuration of the lead 1Z is not specifically limited. In this embodiment the lead 1Z includes, as shown in FIG. 4, a second portion 122 and a fourth portion 142, each of which will be described hereunder. In this embodiment, the lead 1Z is insulated from the circuit of the semiconductor device A1.

The fourth portion 142 is covered with the encapsulating resin 7. The fourth portion 14Z is, like the fourth portion 14D of the lead 1D, shifted from the first portion 11D in the z-direction, to the side to which the main surface 111D is oriented. The shape of the fourth portion 14Z is not specifically limited and, in the illustrated example, the fourth portion 14Z has a strip shape extending along the y-direction. The end portion of the fourth portion 142 is flush with the sixth face 76 of the resin 7.

The second portion 122 is connected to the end portion of the fourth portion 14Z, and corresponds to a portion of the lead 1Z sticking out from the encapsulating resin 7. The second portion 122 sticks out to the opposite side of the fourth portion 14Z, in the y-direction. The second portion 122 is used, for example, when the semiconductor device A1 is mounted on an external circuit board. In the illustrated example, the second portion 122 is bent in the z-direction, to the side to which the first face 31 is oriented.

As shown in FIG. 4, the second portion 12A, the second portion 12B, the second portion 12C, and the second portion 12D are aligned in the x-direction, with clearances G11 between each other. The clearances G11 have generally the same width, with a difference within ±5% from each other. The second portion 12D and the second portion 12E are spaced apart from each other in the x-direction, by a clearance G12. The clearance G12 has generally the same width as the clearance G11, with a difference within ±5% from each other. The second portion 12E, the second portion 12F, and the second portion 12G are aligned in the x-direction, with clearances G13 between each other. The clearances G13 are narrower than the clearances G11, and the difference in length between the plurality of clearances G13 is within ±5%. The second portion 12A and the second portion 122 are spaced apart from each other in the x-direction, by a clearance G14. The clearance G14 is wider than the clearance G11.

### <Leads 2>

The plurality of leads 2 contain a metal, and have higher heat dissipation characteristics, for example than the substrate 3. The metal to form the lead 2 is not specifically limited, and may be, for example, copper (Cu), aluminum, iron (Fe), oxygen-free copper, or an alloy of the cited metals, such as a Cu—Sn alloy, a Cu—Zr alloy, or a Cu—Fe alloy. The plurality of leads 2 may be plated with nickel (Ni). Examples of the forming method of the plurality of leads 2 include pressing a metal plate with a die, and patterning a metal plate by etching, without limitation thereto. The thickness of the lead 2 is not specifically limited, but may be, for example, approximately 0.4 mm to 0.8 mm. The plurality of leads 2 are located so as to overlap with the second region 30B, as viewed in the z-direction.

In this embodiment, the plurality of leads 2 include a plurality of leads 2A to 2P, and 22, as shown in FIG. 1 to FIG. 4. The plurality of leads 2A to 2O constitute conduction paths, for example to the control chips 4G and 4H.

The lead 2A is spaced apart from the plurality of leads 1. The lead 2A is located on the conductive section 5. The lead 2A is electrically connected to the conductive section 5. The lead 2A exemplifies a second lead in the present disclosure. The lead 2A is bonded to the second portion 52A of the wiring 50A in the conductive section 5, via a conductive bonding material 82. The conductive bonding material 82 may be any material that is capable of bonding, and electrically connecting, the lead 2A to the second may be employed as the conductive bonding material 82. The conductive bonding material 82 corresponds to the first conductive bonding material in the present disclosure.

The configuration of the lead 2A is not specifically limited. In this embodiment the lead 2A includes, as shown in FIG. 15, a first portion 21A, a second portion 22A, a third portion 23A, and a fourth portion 24A, each of which will be described hereunder.

The first portion 21A is bonded to the second portion 52A of the wiring 50A. The shape of the first portion 21A is not specifically limited, and a desired shape may be selected from a rectangular shape, a polygonal shape, a circular shape, an elliptical shape, and so forth. In the illustrated example, the first portion 21A has an elongate rectangular shape, having the long sides extending along the y-direction. In the illustrated example, the first portion 21A overlaps with the second portion 52A, as viewed in the z-direction. In addition, the first portion 21A includes a through hole 211A. The through hole 211A is formed so as to penetrate through the first portion 21A, in the z-direction. The inside of the through hole 211A is filled with the conductive bonding material 82, like a through hole 211C in a first portion 21C of the lead 2C shown in FIG. 5. The conductive bonding material 82 covers a part of the surface of the lead 2A. However, the conductive bonding material 82 may be provided only inside the through hole 211A, so as not to reach the surface of the lead 2A.

The third portion 23A and the fourth portion 24A are covered with the encapsulating resin 7. The third portion 23A is connected to the first portion 21A and the fourth portion 24A. The fourth portion 24A is shifted in the z-direction with respect to the first portion 21A, to the side to which the first face 31 is oriented, like a third portion 23C and a fourth portion 24C of the lead 2C shown in FIG. 5. The end portion of the fourth portion 24A is flush with a fifth face 75 of the resin 7. In the illustrated example, the third portion 23A and the fourth portion 24A generally coincide with each other, as viewed in the y-direction. Here, the expression “generally coincide” as viewed in the y-direction refers to, for example, exactly coinciding with each other, or being deviated by within ±5% of the characteristic size (size of the third portion 23A, or fourth portion 24A in the x-direction). In addition, the third portion 23A and the fourth portion 24A are shifted toward the third face 33 in the x-direction, from the center of the first portion 21A in the x-direction. The third portion 23A overlaps with the fifth face 35 of the substrate 3, as viewed in the z-direction.

The second portion 22A is connected to the end portion of the fourth portion 24A, and corresponds to a portion of the lead 2A sticking out from the encapsulating resin 7 to the opposite side of the plurality of leads 1, as viewed in the y-direction. The second portion 22A sticks out to the opposite side of the first portion 21A, in the y-direction. The second portion 22A is used, for example, to electrically connect the semiconductor device A1 to an external circuit. In the illustrated example, the second portion 22A is bent in the z-direction, to the side to which the first face 31 is oriented. The second portion 22A, the third portion 23A, and the fourth portion 24A each include, on the respective sides thereof in the x-direction, edges extending along the y-direction.

The lead 2B is spaced apart from the plurality of leads 1. The lead 2B is located on the conductive section 5. The lead 2B is electrically connected to the conductive section 5. The lead 2B exemplifies a second lead in the present disclosure. The lead 2B is bonded to the second portion 52B of the wiring 50B in the conductive section 5, via the conductive bonding material 82.

The configuration of the lead 2B is not specifically limited. In this embodiment the lead 2B includes, as shown in FIG. 15, a first portion 21B, a second portion 22B, a third portion 23B, and a fourth portion 24B, each of which will be described hereunder.

The first portion 21B is bonded to the second portion 52B of the wiring 50B. The shape of the first portion 21B is not specifically limited, and a desired shape may be selected from a rectangular shape, a polygonal shape, a circular shape, an elliptical shape, and so forth. In the illustrated example, the first portion 21B has an elongate rectangular shape, having the long sides extending along the y-direction. In the illustrated example, the first portion 21B overlaps with the second portion 52B, as viewed in the z-direction. In addition, the first portion 21B includes a through hole 211B. The through hole 211B is formed so as to penetrate through the first portion 21B, in the z-direction. The inside of the through hole 211B is filled with the conductive bonding material 82, like the through hole 211C in the first portion 21C of the lead 2C shown in FIG. 5. The conductive bonding material 82 covers a part of the surface of the lead 2B. However, the conductive bonding material 82 may be provided only inside the through hole 211B, so as not to reach the surface of the lead 2B.

The third portion 23B and the fourth portion 24B are covered with the encapsulating resin 7. The third portion 23B is connected to the first portion 21B and the fourth portion 24B. The fourth portion 24B is shifted in the z-direction with respect to the first portion 21B, to the side to which the first face 31 is oriented, like the third portion 23C and the fourth portion 24C of the lead 2C shown in FIG. 5. The end portion of the fourth portion 24B is flush with the sixth face 75 of the resin 7. In the illustrated example, the first portion 21B, the third portion 23B, and the fourth portion 24B generally coincide with each other, as viewed in the y-direction. Here, the expression “generally coincide” as viewed in the y-direction refers to, for example, exactly coinciding with each other, or being deviated by within ±5% of the characteristic size (size of the first portion 21B, third portion 23B, or fourth portion 24B in the x-direction). The third portion 23B overlaps with the fifth face 35 of the substrate 3, as viewed in the z-direction.

The second portion 22B is connected to the end portion of the fourth portion 24B, and corresponds to a portion of the lead 2B sticking out from the encapsulating resin 7 to the opposite side of the plurality of leads 1, as viewed in the y-direction. The second portion 22B sticks out to the opposite side of the first portion 21B, in the y-direction. The second portion 22B is used, for example, to electrically connect the semiconductor device A1 to an external circuit. In the illustrated example, the second portion 22B is bent in the z-direction, to the side to which the first face 31 is oriented. The second portion 22B, the third portion 23B, and the fourth portion 24B each include, on the respective sides thereof in the x-direction, edges extending along the y-direction. The edges of the second portion 22B, the third portion 23B, and the fourth portion 24B, on the side of the third face 33 in the x-direction, are respectively opposed to the edges of the second portion 22A, the third portion 23A, and the fourth portion 24A, on the side of the fourth face 34 in the x-direction.

The lead 2C is spaced apart from the plurality of leads 1. The lead 2C is located on the conductive section 5. The lead 2C is electrically connected to the conductive section 5. The lead 2C exemplifies a second lead in the present disclosure. The lead 2C is bonded to the second portion 52C of the wiring 50C in the conductive section 5, via the conductive bonding material 82.

The configuration of the lead 2C is not specifically limited. In this embodiment the lead 2C includes, as shown in FIG. 15, a first portion 21C, a second portion 22C, a third portion 23C, and a fourth portion 24C, each of which will be described hereunder.

The first portion 21C is bonded to the second portion 52C of the wiring 50C. The shape of the first portion 21C is not specifically limited, and a desired shape may be selected from a rectangular shape, a polygonal shape, a circular shape, an elliptical shape, and so forth. In the illustrated example, the first portion 21C has an elongate rectangular shape, having the long sides extending along the y-direction. In the illustrated example, the first portion 21C overlaps with the second portion 52C, as viewed in the z-direction. In addition, the first portion 21C includes a through hole 211C. The through hole 211C is formed so as to penetrate through the first portion 21C, in the z-direction. The inside of the through hole 211C is filled with the conductive bonding material 82, as shown in FIG. 5. The conductive bonding material 82 covers a part of the surface of the lead 2C. However, the conductive bonding material 82 may be provided only inside the through hole 211C, so as not to reach the surface of the lead 2C.

The third portion 23C and the fourth portion 24C are covered with the encapsulating resin 7. The third portion 23C is connected to the first portion 21C and the fourth portion 24C. As shown in FIG. 5, the fourth portion 24C is shifted in the z-direction with respect to the first portion 21C, to the side to which the first face 31 is oriented. The end portion of the fourth portion 24C is flush with the sixth face 75 of the resin 7. In the illustrated example, the first portion 21C, the third portion 23C, and the fourth portion 24C generally coincide with each other, as viewed in the y-direction. Here, the expression “generally coincide” as viewed in the y-direction refers to, for example, exactly coinciding with each other, or being deviated by within ±5% of the characteristic size (size of the first portion 21C, third portion 23C, or fourth portion 24C in the x-direction). The third portion 23C overlaps with the fifth face 35 of the substrate 3, as viewed in the z-direction.

The second portion 22C is connected to the end portion of the fourth portion 24C, and corresponds to a portion of the lead 2C sticking out from the encapsulating resin 7 to the opposite side of the plurality of leads 1, as viewed in the y-direction. The second portion 22C sticks out to the opposite side of the first portion 21C, in the y-direction. The second portion 22C is used, for example, to electrically connect the semiconductor device A1 to an external circuit. In the illustrated example, the second portion 22C is bent in the z-direction, to the side to which the first face 31 is oriented. The second portion 22C, the third portion 23C, and the fourth portion 24C each include, on the respective sides thereof in the x-direction, edges extending along the y-direction. The edges of the second portion 22C, the third portion 23C, and the fourth portion 24C, on the side of the third face 33 in the x-direction, are respectively opposed to the edges of the second portion 22B, the third portion 23B, and the fourth portion 24B, on the side of the fourth face 34 in the x-direction.

The lead 2D is spaced apart from the plurality of leads 1. The lead 2D is located on the conductive section 5. The lead 2D is electrically connected to the conductive section 5. The lead 2D exemplifies a second lead in the present disclosure. The lead 2D is bonded to the second portion 52D of the wiring 50D in the conductive section 5, via the conductive bonding material 82.

The configuration of the lead 2D is not specifically limited. In this embodiment the lead 2D includes, as shown in FIG. 15, a first portion 21D, a second portion 22D, a third portion 23D, and a fourth portion 24D, each of which will be described hereunder.

The first portion 21D is bonded to the second portion 52D of the wiring 50D. The shape of the first portion 21D is not specifically limited, and a desired shape may be selected from a rectangular shape, a polygonal shape, a circular shape, an elliptical shape, and so forth. In the illustrated example, the first portion 21D has an elongate rectangular shape, having the long sides extending along the y-direction. In the illustrated example, the first portion 21D overlaps with the second portion 52D, as viewed in the z-direction. In addition, the first portion 21D includes a through hole 211D. The through hole 211D is formed so as to penetrate through the first portion 21D, in the z-direction. The inside of the through hole 211D is filled with the conductive bonding material 82, like the through hole 211C in the first portion 21C of the lead 2C shown in FIG. 5. The conductive bonding material 82 covers a part of the surface of the lead 2D. However, the conductive bonding material 82 may be provided only inside the through hole 211D, so as not to reach the surface of the lead 2D.

The third portion 23D and the fourth portion 24D are covered with the encapsulating resin 7. The third portion 23D is connected to the first portion 21D and the fourth portion 24D. The fourth portion 24D is shifted in the z-direction with respect to the first portion 21D, to the side to which the first face 31 is oriented, like the third portion 23C and the fourth portion 24C of the lead 2C shown in FIG. 5. The end portion of the fourth portion 24D is flush with the sixth face 75 of the resin 7. In the illustrated example, the first portion 21D, the third portion 23D, and the fourth portion 24D generally coincide with each other, as viewed in the y-direction. Here, the expression “generally coincide” as viewed in the y-direction refers to, for example, exactly coinciding with each other, or being deviated by within ±5% of the characteristic size (size of the first portion 21D, third portion 23D, or fourth portion 24D in the x-direction). The third portion 23D overlaps with the fifth face 35 of the substrate 3, as viewed in the z-direction.

The second portion 22D is connected to the end portion of the fourth portion 24D, and corresponds to a portion of the lead 2D sticking out from the encapsulating resin 7 to the opposite side of the plurality of leads 1, as viewed in the y-direction. The second portion 22D sticks out to the opposite side of the first portion 21D, in the y-direction. The second portion 22D is used, for example, to electrically connect the semiconductor device A1 to an external circuit. In the illustrated example, the second portion 22D is bent in the z-direction, to the side to which the first face 31 is oriented. The second portion 22D, the third portion 23D, and the fourth portion 24D each include, on the respective sides thereof in the x-direction, edges extending along the y-direction. The edges of the second portion 22D, the third portion 23D, and the fourth portion 24D, on the side of the third face 33 in the x-direction, are respectively opposed to the edges of the second portion 22C, the third portion 23C, and the fourth portion 24C, on the side of the fourth face 34 in the x-direction.

The lead 2E is spaced apart from the plurality of leads 1. The lead 2E is located on the conductive section 5. The lead 2E is electrically connected to the conductive section 5. The lead 2E exemplifies a second lead in the present disclosure. The lead 2E is bonded to the second portion 52E of the wiring 50E in the conductive section 5, via the conductive bonding material 82.

The configuration of the lead 2E is not specifically limited. In this embodiment the lead 2E includes, as shown in FIG. 15, a first portion 21E, a second portion 22E, a third portion 23E, and a fourth portion 24E, each of which will be described hereunder.

The first portion 21E is bonded to the second portion 52E of the wiring 50E. The shape of the first portion 21E is not specifically limited, and a desired shape may be selected from a rectangular shape, a polygonal shape, a circular shape, an elliptical shape, and so forth. In the illustrated example, the first portion 21E has an elongate rectangular shape, having the long sides extending along the y-direction. In the illustrated example, the first portion 21E overlaps with the second portion 52E, as viewed in the z-direction. In addition, the first portion 21E includes a through hole 211E. The through hole 211E is formed so as to penetrate through the first portion 21E, in the z-direction. The inside of the through hole 211E is filled with the conductive bonding material 82, like the through hole 211C in the first portion 21C of the lead 2C shown in FIG. 5. The conductive bonding material 82 covers a part of the surface of the lead 2E. However, the conductive bonding material 82 may be provided only inside the through hole 211E, so as not to reach the surface of the lead 2E.

The third portion 23E and the fourth portion 24E are covered with the encapsulating resin 7. The third portion 23E is connected to the first portion 21E and the fourth portion 24E. The fourth portion 24E is shifted in the z-direction with respect to the first portion 21E, to the side to which the first face 31 is oriented, like the fourth portion 24C of the lead 2C shown in FIG. 5. The end portion of the fourth portion 24E is flush with the sixth face 75 of the resin 7. In the illustrated example, the first portion 21E, the third portion 23E, and the fourth portion 24E generally coincide with each other, as viewed in the y-direction. Here, the expression “generally coincide” as viewed in the y-direction refers to, for example, exactly coinciding with each other, or being deviated by within ±5% of the characteristic size (size of the first portion 21E, third portion 23E, or fourth portion 24E in the x-direction). The third portion 23E overlaps with the fifth face 35 of the substrate 3, as viewed in the z-direction.

The second portion 22E is connected to the end portion of the fourth portion 24E, and corresponds to a portion of the lead 2E sticking out from the encapsulating resin 7 to the opposite side of the plurality of leads 1, as viewed in the y-direction. The second portion 22E sticks out to the opposite side of the first portion 21E, in the y-direction. The second portion 22E is used, for example, to electrically connect the semiconductor device A1 to an external circuit. In the illustrated example, the second portion 22E is bent in the z-direction, to the side to which the first face 31 is oriented. The second portion 22E, the third portion 23E, and the fourth portion 24E each include, on the respective sides thereof in the x-direction, edges extending along the y-direction. The edges of the second portion 22E, the third portion 23E, and the fourth portion 24E, on the side of the third face 33 in the x-direction, are respectively opposed to the edges of the second portion 22D, the third portion 23D, and the fourth portion 24D, on the side of the fourth face 34 in the x-direction.

The lead 2F is spaced apart from the plurality of leads 1. The lead 2F is located on the conductive section 5. The lead 2F is electrically connected to the conductive section 5. The lead 2F exemplifies a second lead in the present disclosure. The lead 2F is bonded to the second portion 52F of the wiring 50F in the conductive section 5, via the conductive bonding material 82.

The configuration of the lead 2F is not specifically limited. In this embodiment the lead 2F includes, as shown in FIG. 15, a first portion 21F, a second portion 22F, a third portion 23F, and a fourth portion 24F, each of which will be described hereunder.

The first portion 21F is bonded to the second portion 52F of the wiring 50F. The shape of the first portion 21F is not specifically limited, and a desired shape may be selected from a rectangular shape, a polygonal shape, a circular shape, an elliptical shape, and so forth. In the illustrated example, the first portion 21F has an elongate rectangular shape, having the long sides extending along the y-direction. In the illustrated example, the first portion 21F overlaps with the second portion 52F, as viewed in the z-direction. In addition, the first portion 21F includes a through hole 211F. The through hole 211F is formed so as to penetrate through the first portion 21F, in the z-direction. The inside of the through hole 211F is filled with the conductive bonding material 82, like the through hole 211E in the first portion 21E of the lead 2E shown in FIG. 5. The conductive bonding material 82 covers a part of the surface of the lead 2F. However, the conductive bonding material 82 may be provided only inside the through hole 211F, so as not to reach the surface of the lead 2F.

The third portion 23F and the fourth portion 24F are covered with the encapsulating resin 7. The third portion 23F is connected to the first portion 21F and the fourth portion 24F. The fourth portion 24F is shifted in the z-direction with respect to the first portion 21F, to the side to which the first face 31 is oriented, like the third portion 23E and the fourth portion 24E of the lead 2E shown in FIG. 5. The end portion of the fourth portion 24F is flush with the sixth face 75 of the resin 7. In the illustrated example, the first portion 21F, the third portion 23F, and the fourth portion 24F generally coincide with each other, as viewed in the y-direction. Here, the expression “generally coincide” as viewed in the y-direction refers to, for example, exactly coinciding with each other, or being deviated by within ±5% of the characteristic size (size of the first portion 21F, third portion 23F, or fourth portion 24F in the x-direction). The third portion 23F overlaps with the fifth face 35 of the substrate 3, as viewed in the z-direction.

The second portion 22F is connected to the end portion of the fourth portion 24F, and corresponds to a portion of the lead 2F sticking out from the encapsulating resin 7 to the opposite side of the plurality of leads 1, as viewed in the y-direction. The second portion 22F sticks out to the opposite side of the first portion 21F, in the y-direction. The second portion 22F is used, for example, to electrically connect the semiconductor device A1 to an external circuit. In the illustrated example, the second portion 22F is bent in the z-direction, to the side to which the first face 31 is oriented. The second portion 22F, the third portion 23F, and the fourth portion 24F each include, on the respective sides thereof in the x-direction, edges extending along the y-direction. The edges of the second portion 22F, the third portion 23F, and the fourth portion 24F, on the side of the third face 33 in the x-direction, are respectively opposed to the edges of the second portion 22E, the third portion 23E, and the fourth portion 24E, on the side of the fourth face 34 in the x-direction.

The lead 2G is spaced apart from the plurality of leads 1. The lead 2G is located on the conductive section 5. The lead 2G is electrically connected to the conductive section 5. The lead 2G exemplifies a second lead in the present disclosure. The lead 2G is bonded to the second portion 52G of the wiring 50G in the conductive section 5, via the conductive bonding material 82.

The configuration of the lead 2G is not specifically limited. In this embodiment the lead 2G includes, as shown in FIG. 15, a first portion 21G, a second portion 22G, a third portion 23G, and a fourth portion 24G, each of which will be described hereunder.

The first portion 21G is bonded to the second portion 52G of the wiring 50G. The shape of the first portion 21G is not specifically limited, and a desired shape may be selected from a rectangular shape, a polygonal shape, a circular shape, an elliptical shape, and so forth. In the illustrated example, the first portion 21G has an elongate rectangular shape, having the long sides extending along the y-direction. In the illustrated example, the first portion 21G overlaps with the second portion 52G, as viewed in the z-direction. In addition, the first portion 21G includes a through hole 211G. The through hole 211G is formed so as to penetrate through the first portion 21G, in the z-direction. The inside of the through hole 211G is filled with the conductive bonding material 82, like the through hole 211F in the first portion 21F of the lead 2F shown in FIG. 5. The conductive bonding material 82 covers a part of the surface of the lead 2G. However, the conductive bonding material 82 may be provided only inside the through hole 211G, so as not to reach the surface of the lead 2G.

The third portion 23G and the fourth portion 24G are covered with the encapsulating resin 7. The third portion 23G is connected to the first portion 21G and the fourth portion 24G. The fourth portion 24G is shifted in the z-direction with respect to the first portion 21G, to the side to which the first face 31 is oriented, like the third portion 23F and the fourth portion 24F of the lead 2F shown in FIG. 5. The end portion of the fourth portion 24G is flush with the sixth face 75 of the resin 7. In the illustrated example, the first portion 21G, the third portion 23G, and the fourth portion 24G generally coincide with each other, as viewed in the y-direction. Here, the expression “generally coincide” as viewed in the y-direction refers to, for example, exactly coinciding with each other, or being deviated by within ±5% of the characteristic size (size of the first portion 21G, third portion 23G, or fourth portion 24G in the x-direction). The third portion 23G overlaps with the fifth face 35 of the substrate 3, as viewed in the z-direction.

The second portion 22G is connected to the end portion of the fourth portion 24G, and corresponds to a portion of the lead 2G sticking out from the encapsulating resin 7 to the opposite side of the plurality of leads 1, as viewed in the y-direction. The second portion 22G sticks out to the opposite side of the first portion 21G, in the y-direction. The second portion 22G is used, for example, to electrically connect the semiconductor device A1 to an external circuit. In the illustrated example, the second portion 22G is bent in the z-direction, to the side to which the first face 31 is oriented. The second portion 22G, the third portion 23G, and the fourth portion 24G each include, on the respective sides thereof in the x-direction, edges extending along the y-direction. The edges of the second portion 22G, the third portion 23G, and the fourth portion 24G, on the side of the third face 33 in the x-direction, are respectively opposed to the edges of the second portion 22F, the third portion 23F, and the fourth portion 24F, on the side of the fourth face 34 in the x-direction.

The lead 2H is spaced apart from the plurality of leads 1. The lead 2H is located on the conductive section 5. The lead 2H is electrically connected to the conductive section 5. The lead 2H exemplifies a second lead in the present disclosure. The lead 2H is bonded to the second portion 52H of the wiring 50H in the conductive section 5, via the conductive bonding material 82.

The configuration of the lead 2H is not specifically limited. In this embodiment the lead 2H includes, as shown in FIG. 15, a first portion 21H, a second portion 22H, a third portion 23H, and a fourth portion 24H, each of which will be described hereunder.

The first portion 21H is bonded to the second portion 52H of the wiring 50H. The shape of the first portion 21H is not specifically limited, and a desired shape may be selected from a rectangular shape, a polygonal shape, a circular shape, an elliptical shape, and so forth. In the illustrated example, the first portion 21H has an elongate rectangular shape, having the long sides extending along the y-direction. In the illustrated example, the first portion 21H overlaps with the second portion 52H, as viewed in the z-direction. In addition, the first portion 21H includes a through hole 211H. The through hole 211H is formed so as to penetrate through the first portion 21H, in the z-direction. The inside of the through hole 211H is filled with the conductive bonding material 82, like the through hole 211G in the first portion 21G of the lead 2G shown in FIG. 5. The conductive bonding material 82 covers a part of the surface of the lead 2H. However, the conductive bonding material 82 may be provided only inside the through hole 211H, so as not to reach the surface of the lead 2H.

The third portion 23H and the fourth portion 24H are covered with the encapsulating resin 7. The third portion 23H is connected to the first portion 21H and the fourth portion 24H. The fourth portion 24H is shifted in the z-direction with respect to the first portion 21H, to the side to which the first face 31 is oriented, like the third portion 23G and the fourth portion 24G of the lead 2G shown in FIG. 5. The end portion of the fourth portion 24H is flush with the sixth face 75 of the resin 7. In the illustrated example, the first portion 21H, the third portion 23H, and the fourth portion 24H generally coincide with each other, as viewed in the y-direction. Here, the expression “generally coincide” as viewed in the y-direction refers to, for example, exactly coinciding with each other, or being deviated by within ±5% of the characteristic size (size of the first portion 21H, third portion 23H, or fourth portion 24H in the x-direction). The third portion 23H overlaps with the fifth face 35 of the substrate 3, as viewed in the z-direction.

The second portion 22H is connected to the end portion of the fourth portion 24H, and corresponds to a portion of the lead 2H sticking out from the encapsulating resin 7 to the opposite side of the plurality of leads 1, as viewed in the y-direction. The second portion 22H sticks out to the opposite side of the first portion 21H, in the y-direction. The second portion 22H is used, for example, to electrically connect the semiconductor device A1 to an external circuit. In the illustrated example, the second portion 22H is bent in the z-direction, to the side to which the first face 31 is oriented. The second portion 22H, the third portion 23H, and the fourth portion 24H each include, on the respective sides thereof in the x-direction, edges extending along the y-direction. The edges of the second portion 22H, the third portion 23H, and the fourth portion 24H, on the side of the third face 33 in the x-direction, are respectively opposed to the edges of the second portion 22G, the third portion 23G, and the fourth portion 24G, on the side of the fourth face 34 in the x-direction.

The lead 2I is spaced apart from the plurality of leads 1. The lead 2I is located on the conductive section 5. The lead 2I is electrically connected to the conductive section 5. The lead 2I exemplifies a second lead in the present disclosure. The lead 2I is bonded to the second portion 52I of the wiring 50I in the conductive section 5, via the conductive bonding material 82.

The configuration of the lead 2I is not specifically limited. In this embodiment the lead 2I includes, as shown in FIG. 15, a first portion 21I, a second portion 22I, a third portion 23I, and a fourth portion 24I, each of which will be described hereunder.

The first portion 21I is bonded to the second portion 52I of the wiring 50I. The shape of the first portion 21I is not specifically limited, and a desired shape may be selected from a rectangular shape, a polygonal shape, a circular shape, an elliptical shape, and so forth. In the illustrated example, the first portion 21I has an elongate rectangular shape, having the long sides extending along the y-direction. In the illustrated example, the first portion 21I overlaps with the second portion 52I, as viewed in the z-direction. In addition, the first portion 21I includes a through hole 211I. The through hole 211I is formed so as to penetrate through the first portion 21I, in the z-direction. The inside of the through hole 211I is filled with the conductive bonding material 82, like the through hole 211H in the first portion 21H of the lead 2H shown in FIG. 5. The conductive bonding material 82 covers a part of the surface of the lead 2I. However, the conductive bonding material 82 may be provided only inside the through hole 211I, so as not to reach the surface of the lead 2I.

The third portion 23I and the fourth portion 24I are covered with the encapsulating resin 7. The third portion 23I is connected to the first portion 21I and the fourth portion 24I. The fourth portion 24I is shifted in the z-direction with respect to the first portion 21I, to the side to which the first face 31 is oriented, like the third portion 23H and the fourth portion 24H of the lead 2H shown in FIG. 5. The end portion of the fourth portion 24I is flush with the sixth face 75 of the resin 7. In the illustrated example, the first portion 21I, the third portion 23I, and the fourth portion 24I generally coincide with each other, as viewed in the y-direction. Here, the expression “generally coincide” as viewed in the y-direction refers to, for example, exactly coinciding with each other, or being deviated by within ±5% of the characteristic size (size of the first portion 21I, third portion 23I, or fourth portion 24I in the x-direction). The third portion 23I overlaps with the fifth face 35 of the substrate 3, as viewed in the z-direction.

The second portion 22I is connected to the end portion of the fourth portion 24I, and corresponds to a portion of the lead 2I sticking out from the encapsulating resin 7 to the opposite side of the plurality of leads 1, as viewed in the y-direction. The second portion 22I sticks out to the opposite side of the first portion 21I, in the y-direction. The second portion 22I is used, for example, to electrically connect the semiconductor device A1 to an external circuit. In the illustrated example, the second portion 22I is bent in the z-direction, to the side to which the first face 31 is oriented. The second portion 22I, the third portion 23I, and the fourth portion 24I each include, on the respective sides thereof in the x-direction, edges extending along the y-direction. The edges of the second portion 22I, the third portion 23I, and the fourth portion 24I, on the side of the third face 33 in the x-direction, are respectively opposed to the edges of the second portion 22H, the third portion 23H, and the fourth portion 24H, on the side of the fourth face 34 in the x-direction.

The lead 2J is spaced apart from the plurality of leads 1. The lead 2J is located on the conductive section 5. The lead 2J is electrically connected to the conductive section 5. The lead 2J exemplifies a second lead in the present disclosure. The lead 2J is bonded to the second portion 52J of the wiring 50J in the conductive section 5, via the conductive bonding material 82.

The configuration of the lead 2J is not specifically limited. In this embodiment the lead 2J includes, as shown in FIG. 15, a first portion 21J, a second portion 22J, a third portion 23J, and a fourth portion 24J, each of which will be described hereunder.

The first portion 21J is bonded to the second portion 52J of the wiring 50J. The shape of the first portion 21J is not specifically limited, and a desired shape may be selected from a rectangular shape, a polygonal shape, a circular shape, an elliptical shape, and so forth. In the illustrated example, the first portion 21J has an elongate rectangular shape, having the long sides extending along the y-direction. In the illustrated example, the first portion 21J overlaps with the second portion 52J, as viewed in the z-direction. In addition, the first portion 21J includes a through hole 211J. The through hole 211J is formed so as to penetrate through the first portion 21J, in the z-direction. The inside of the through hole 211J is filled with the conductive bonding material 82, like the through hole 211I in the first portion 21I of the lead 2I shown in FIG. 5. The conductive bonding material 82 covers a part of the surface of the lead 2J. However, the conductive bonding material 82 may be provided only inside the through hole 211J, so as not to reach the surface of the lead 2J.

The third portion 23J and the fourth portion 24J are covered with the encapsulating resin 7. The third portion 23J is connected to the first portion 21J and the fourth portion 24J. The fourth portion 24J is shifted in the z-direction with respect to the first portion 21J, to the side to which the first face 31 is oriented, like the third portion 23I and the fourth portion 24I of the lead 2I shown in FIG. 5. The end portion of the fourth portion 24J is flush with the sixth face 75 of the resin 7. In the illustrated example, the first portion 21J, the third portion 23J, and the fourth portion 24J generally coincide with each other, as viewed in the y-direction. Here, the expression “generally coincide” as viewed in the y-direction refers to, for example, exactly coinciding with each other, or being deviated by within ±5% of the characteristic size (size of the first portion 21J, third portion 23J, or fourth portion 24J in the x-direction). The third portion 23J overlaps with the fifth face 35 of the substrate 3, as viewed in the z-direction.

The second portion 22J is connected to the end portion of the fourth portion 24J, and corresponds to a portion of the lead 2J sticking out from the encapsulating resin 7 to the opposite side of the plurality of leads 1, as viewed in the y-direction. The second portion 22J sticks out to the opposite side of the first portion 21J, in the y-direction. The second portion 22J is used, for example, to electrically connect the semiconductor device A1 to an external circuit. In the illustrated example, the second portion 22J is bent in the z-direction, to the side to which the first face 31 is oriented. The second portion 22J, the third portion 23J, and the fourth portion 24J each include, on the respective sides thereof in the x-direction, edges extending along the y-direction. The edges of the second portion 22J, the third portion 23J, and the fourth portion 24J, on the side of the third face 33 in the x-direction, are respectively opposed to the edges of the second portion 22I, the third portion 23I, and the fourth portion 24I, on the side of the fourth face 34 in the x-direction.

The lead 2K is spaced apart from the plurality of leads 1. The lead 2K is located on the conductive section 5. The lead 2K is electrically connected to the conductive section 5. The lead 2K exemplifies a second lead in the present disclosure. The lead 2K is bonded to the second portion 52K of the wiring 50K in the conductive section 5, via the conductive bonding material 82.

The configuration of the lead 2K is not specifically limited. In this embodiment the lead 2K includes, as shown in FIG. 15, a first portion 21K, a second portion 22K, a third portion 23K, and a fourth portion 24K, each of which will be described hereunder.

The first portion 21K is bonded to the second portion 52K of the wiring 50K. The shape of the first portion 21K is not specifically limited, and a desired shape may be selected from a rectangular shape, a polygonal shape, a circular shape, an elliptical shape, and so forth. In the illustrated example, the first portion 21K has an elongate rectangular shape, having the long sides extending along the y-direction. In the illustrated example, the first portion 21K overlaps with the second portion 52K, as viewed in the z-direction. In addition, the first portion 21K includes a through hole 211K. The through hole 211K is formed so as to penetrate through the first portion 21K, in the z-direction. The inside of the through hole 211K is filled with the conductive bonding material 82, like the through hole 211J in the first portion 21J of the lead 2J shown in FIG. 5. The conductive bonding material 82 covers a part of the surface of the lead 2K. However, the conductive bonding material 82 may be provided only inside the through hole 211K, so as not to reach the surface of the lead 2K.

The third portion 23K and the fourth portion 24K are covered with the encapsulating resin 7. The third portion 23K is connected to the first portion 21K and the fourth portion 24K. The fourth portion 24K is shifted in the z-direction with respect to the first portion 21K, to the side to which the first face 31 is oriented, like the third portion 23J and the fourth portion 24J of the lead 2J shown in FIG. 5. The end portion of the fourth portion 24K is flush with the sixth face 75 of the resin 7. In the illustrated example, the first portion 21K, the third portion 23K, and the fourth portion 24K generally coincide with each other, as viewed in the y-direction. Here, the expression “generally coincide” as viewed in the y-direction refers to, for example, exactly coinciding with each other, or being deviated by within ±5% of the characteristic size (size of the first portion 21K, third portion 23K, or fourth portion 24K in the x-direction). The third portion 23K overlaps with the fifth face 35 of the substrate 3, as viewed in the z-direction.

The second portion 22K is connected to the end portion of the fourth portion 24K, and corresponds to a portion of the lead 2K sticking out from the encapsulating resin 7 to the opposite side of the plurality of leads 1, as viewed in the y-direction. The second portion 22K sticks out to the opposite side of the first portion 21K, in the y-direction. The second portion 22K is used, for example, to electrically connect the semiconductor device A1 to an external circuit. In the illustrated example, the second portion 22K is bent in the z-direction, to the side to which the first face 31 is oriented. The second portion 22K, the third portion 23K, and the fourth portion 24K each include, on the respective sides thereof in the x-direction, edges extending along the y-direction. The edges of the second portion 22K, the third portion 23K, and the fourth portion 24K, on the side of the third face 33 in the x-direction, are respectively opposed to the edges of the second portion 22J, the third portion 23J, and the fourth portion 24J, on the side of the fourth face 34 in the x-direction.

The lead 2L is spaced apart from the plurality of leads 1. The lead 2L is located on the conductive section 5. The lead 2L is electrically connected to the conductive section 5. The lead 2L exemplifies a second lead in the present disclosure. The lead 2L is bonded to the second portion 52L of the wiring 50L in the conductive section 5, via the conductive bonding material 82.

The configuration of the lead 2L is not specifically limited. In this embodiment the lead 2L includes, as shown in FIG. 15, a first portion 21L, a second portion 22L, a third portion 23L, and a fourth portion 24L, each of which will be described hereunder.

The first portion 21L is bonded to the second portion 52L of the wiring 50L. The shape of the first portion 21L is not specifically limited, and a desired shape may be selected from a rectangular shape, a polygonal shape, a circular shape, an elliptical shape, and so forth. In the illustrated example, the first portion 21L has an elongate rectangular shape, having the long sides extending along the y-direction. In the illustrated example, the first portion 21L overlaps with the second portion 52L, as viewed in the z-direction. In addition, the first portion 21L includes a through hole 211L. The through hole 211L is formed so as to penetrate through the first portion 21L, in the z-direction. The inside of the through hole 211L is filled with the conductive bonding material 82, like the through hole 211K in the first portion 21K of the lead 2K shown in FIG. 5. The conductive bonding material 82 covers a part of the surface of the lead 2L. However, the conductive bonding material 82 may be provided only inside the through hole 211L, so as not to reach the surface of the lead 2L.

The third portion 23L and the fourth portion 24L are covered with the encapsulating resin 7. The third portion 23L is connected to the first portion 21L and the fourth portion 24L. The fourth portion 24L is shifted in the z-direction with respect to the first portion 21L, to the side to which the first face 31 is oriented, like the third portion 23K and the fourth portion 24K of the lead 2K shown in FIG. 5. The end portion of the fourth portion 24L is flush with the sixth face 75 of the resin 7. In the illustrated example, the first portion 21L, the third portion 23L, and the fourth portion 24L generally coincide with each other, as viewed in the y-direction. Here, the expression “generally coincide” as viewed in the y-direction refers to, for example, exactly coinciding with each other, or being deviated by within ±5% of the characteristic size (size of the first portion 21L, third portion 23L, or fourth portion 24L in the x-direction). The third portion 23L overlaps with the fifth face 35 of the substrate 3, as viewed in the z-direction.

The second portion 22L is connected to the end portion of the fourth portion 24L, and corresponds to a portion of the lead 2L sticking out from the encapsulating resin 7 to the opposite side of the plurality of leads 1, as viewed in the y-direction. The second portion 22L sticks out to the opposite side of the first portion 21L, in the y-direction. The second portion 22L is used, for example, to electrically connect the semiconductor device A1 to an external circuit. In the illustrated example, the second portion 22L is bent in the z-direction, to the side to which the first face 31 is oriented. The second portion 22L, the third portion 23L, and the fourth portion 24L each include, on the respective sides thereof in the x-direction, edges extending along the y-direction. The edges of the second portion 22L, the third portion 23L, and the fourth portion 24L, on the side of the third face 33 in the x-direction, are respectively opposed to the edges of the second portion 22K, the third portion 23K, and the fourth portion 24K, on the side of the fourth face 34 in the x-direction.

The lead 2M is spaced apart from the plurality of leads 1. The lead 2M is located on the conductive section 5. The lead 2M is electrically connected to the conductive section 5. The lead 2M exemplifies a second lead in the present disclosure. The lead 2M is bonded to the second portion 52M of the wiring 50M in the conductive section 5, via the conductive bonding material 82.

The configuration of the lead 2M is not specifically limited. In this embodiment the lead 2M includes, as shown in FIG. 15, a first portion 21M, a second portion 22M, a third portion 23M, and a fourth portion 24M, each of which will be described hereunder.

The first portion 21M is bonded to the second portion 52M of the wiring 50M. The shape of the first portion 21M is not specifically limited, and a desired shape may be selected from a rectangular shape, a polygonal shape, a circular shape, an elliptical shape, and so forth. In the illustrated example, the first portion 21M has an elongate rectangular shape, having the long sides extending along the y-direction. In the illustrated example, the first portion 21M overlaps with the second portion 52M, as viewed in the z-direction. In addition, the first portion 21M includes a through hole 211M. The through hole 211M is formed so as to penetrate through the first portion 21M, in the z-direction. The inside of the through hole 211M is filled with the conductive bonding material 82, like the through hole 211L in the first portion 21L of the lead 2L shown in FIG. 5. The conductive bonding material 82 covers a part of the surface of the lead 2M. However, the conductive bonding material 82 may be provided only inside the through hole 211M, so as not to reach the surface of the lead 2M.

The third portion 23M and the fourth portion 24M are covered with the encapsulating resin 7. The third portion 23M is connected to the first portion 21M and the fourth portion 24M. The fourth portion 24M is shifted in the z-direction with respect to the first portion 21M, to the side to which the first face 31 is oriented, like the third portion 23L and the fourth portion 24L of the lead 2L shown in FIG. 5. The end portion of the fourth portion 24M is flush with the sixth face 75 of the resin 7. In the illustrated example, the first portion 21M, the third portion 23M, and the fourth portion 24M generally coincide with each other, as viewed in the y-direction. Here, the expression “generally coincide” as viewed in the y-direction refers to, for example, exactly coinciding with each other, or being deviated by within ±5% of the characteristic size (size of the first portion 21M, third portion 23M, or fourth portion 24M in the x-direction). The third portion 23M overlaps with the fifth face 35 of the substrate 3, as viewed in the z-direction.

The second portion 22M is connected to the end portion of the fourth portion 24M, and corresponds to a portion of the lead 2M sticking out from the encapsulating resin 7 to the opposite side of the plurality of leads 1, as viewed in the y-direction. The second portion 22M sticks out to the opposite side of the first portion 21M, in the y-direction. The second portion 22M is used, for example, to electrically connect the semiconductor device A1 to an external circuit. In the illustrated example, the second portion 22M is bent in the z-direction, to the side to which the first face 31 is oriented. The second portion 22M, the third portion 23M, and the fourth portion 24M each include, on the respective sides thereof in the x-direction, edges extending along the y-direction. The edges of the second portion 22M, the third portion 23M, and the fourth portion 24M, on the side of the third face 33 in the x-direction, are respectively opposed to the edges of the second portion 22L, the third portion 23L, and the fourth portion 24L, on the side of the fourth face 34 in the x-direction.

The lead 2N is spaced apart from the plurality of leads 1. The lead 2N is located on the conductive section 5. The lead 2N is electrically connected to the conductive section 5. The lead 2N exemplifies a second lead in the present disclosure. The lead 2N is bonded to the second portion 52N of the wiring 50N in the conductive section 5, via the conductive bonding material 82.

The configuration of the lead 2N is not specifically limited. In this embodiment the lead 2N includes, as shown in FIG. 15, a first portion 21N, a second portion 22N, a third portion 23N, and a fourth portion 24N, each of which will be described hereunder.

The first portion 21N is bonded to the second portion 52N of the wiring 50N. The shape of the first portion 21N is not specifically limited, and a desired shape may be selected from a rectangular shape, a polygonal shape, a circular shape, an elliptical shape, and so forth. In the illustrated example, the first portion 21N has an elongate rectangular shape, having the long sides extending along the y-direction. In the illustrated example, the first portion 21N overlaps with the second portion 52N, as viewed in the z-direction. In addition, the first portion 21N includes a through hole 211N. The through hole 211N is formed so as to penetrate through the first portion 21N, in the z-direction. The inside of the through hole 211N is filled with the conductive bonding material 82, like the through hole 211M in the first portion 21M of the lead 2M shown in FIG. 5. The conductive bonding material 82 covers a part of the surface of the lead 2N. However, the conductive bonding material 82 may be provided only inside the through hole 211N, so as not to reach the surface of the lead 2N.

The third portion 23N and the fourth portion 24N are covered with the encapsulating resin 7. The third portion 23N is connected to the first portion 21N and the fourth portion 24N. The fourth portion 24N is shifted in the z-direction with respect to the first portion 21N, to the side to which the first face 31 is oriented, like the third portion 23M and the fourth portion 24M of the lead 2M shown in FIG. 5. The end portion of the fourth portion 24N is flush with the sixth face 75 of the resin 7. In the illustrated example, the first portion 21N, the third portion 23N, and the fourth portion 24N generally coincide with each other, as viewed in the y-direction. Here, the expression “generally coincide” as viewed in the y-direction refers to, for example, exactly coinciding with each other, or being deviated by within ±5% of the characteristic size (size of the first portion 21N, third portion 23N, or fourth portion 24N in the x-direction). The third portion 23N overlaps with the fifth face 35 of the substrate 3, as viewed in the z-direction.

The second portion 22N is connected to the end portion of the fourth portion 24N, and corresponds to a portion of the lead 2N sticking out from the encapsulating resin 7 to the opposite side of the plurality of leads 1, as viewed in the y-direction. The second portion 22N sticks out to the opposite side of the first portion 21N, in the y-direction. The second portion 22N is used, for example, to electrically connect the semiconductor device A1 to an external circuit. In the illustrated example, the second portion 22N is bent in the z-direction, to the side to which the first face 31 is oriented. The second portion 22N, the third portion 23N, and the fourth portion 24N each include, on the respective sides thereof in the x-direction, edges extending along the y-direction. The edges of the second portion 22N, the third portion 23N, and the fourth portion 24N, on the side of the third face 33 in the x-direction, are respectively opposed to the edges of the second portion 22M, the third portion 23M, and the fourth portion 24M, on the side of the fourth face 34 in the x-direction.

The lead 2O is spaced apart from the plurality of leads 1. The lead 2O is located on the conductive section 5, as shown in FIG. 4 and FIG. 15. The lead 2O is electrically connected to the conductive section 5. The lead 2O is bonded to the second portion 52O of the wiring 50O in the conductive section 5, via the conductive bonding material 82.

The configuration of the lead 2O is not specifically limited. In this embodiment the lead 2O includes, as shown in FIG. 4 and FIG. 15, a first portion 21O, a second portion 22O, a third portion 23O, a fourth portion 24O, and a fifth portion 25O, each of which will be described hereunder.

The first portion 21O is bonded to the second portion 52O of the wiring 50O. The shape of the first portion 21O is not specifically limited, and a desired shape may be selected from a rectangular shape, a polygonal shape, a circular shape, an elliptical shape, and so forth. In the illustrated example, the first portion 21O has an elongate rectangular shape, having the long sides extending along the y-direction. In the illustrated example, the first portion 21O overlaps with the second portion 52O, as viewed in the z-direction. In addition, the first portion 21O includes a through hole 211O. The through hole 211O is formed so as to penetrate through the first portion 21O, in the z-direction. The inside of the through hole 211O is filled with the conductive bonding material 82, like the through hole 211C in the first portion 21C of the lead 2C shown in FIG. 5. The conductive bonding material 82 covers a part of the surface of the lead 2O. However, the conductive bonding material 82 may be provided only inside the through hole 211O, so as not to reach the surface of the lead 2O.

The third portion 23O, the fourth portion 24O, and the fifth portion 25O are covered with the encapsulating resin 7. The fifth portion 25O is connected to the first portion 21O and the third portion 23O. In the illustrated example, the fifth portion 25O includes a portion extending along the y-direction and a portion inclined with respect to the y-direction. The third portion 23O is connected to the fourth portion 24O and the fifth portion 25O. The fifth portion 25O overlaps with the fourth face 34 of the substrate 3, as viewed in the z-direction. The fourth portion 24O is shifted in the z-direction with respect to the first portion 21O, to the side to which the first face 31 is oriented, like the third portion 23C and the fourth portion 24C of the lead 2C shown in FIG. 5. The end portion of the fourth portion 24O is flush with the sixth face 75 of the resin 7.

The second portion 22O is connected to the end portion of the fourth portion 24O, and corresponds to a portion of the lead 2O sticking out from the encapsulating resin 7 to the opposite side of the plurality of leads 1, as viewed in the y-direction. The second portion 22O sticks out to the opposite side of the first portion 21O, in the y-direction. The second portion 22O is used, for example, to electrically connect the semiconductor device A1 to an external circuit. In the illustrated example, the second portion 22O is bent in the z-direction, to the side to which the first face 31 is oriented. The second portion 22O, the third portion 23O, and the fourth portion 24O each include, on the respective sides thereof in the x-direction, edges extending along the y-direction. The edges of the second portion 22O, the third portion 23O, and the fourth portion 24O, on the side of the third face 33 in the x-direction, are respectively opposed to the edges of the second portion 22N, the third portion 23N, and the fourth portion 24N, on the side of the fourth face 34 in the x-direction.

The lead 2P is spaced apart from the plurality of leads 1. The lead 2P is located on the conductive section 5, as shown in FIG. 4 and FIG. 15. The lead 2P is electrically connected to the conductive section 5. The lead 2P is bonded to the second portion 52P of the wiring 50P in the conductive section 5, via the conductive bonding material 82.

The configuration of the lead 2P is not specifically limited. In this embodiment the lead 2P includes, as shown in FIG. 4 and FIG. 15, a first portion 21P, a second portion 22P, a third portion 23P, a fourth portion 24P, and a fifth portion 25P, each of which will be described hereunder.

The first portion 21P is bonded to the second portion 52P of the wiring 50P. The shape of the first portion 21P is not specifically limited, and a desired shape may be selected from a rectangular shape, a polygonal shape, a circular shape, an elliptical shape, and so forth. In the illustrated example, the first portion 21P has an elongate rectangular shape, having the long sides extending along the y-direction. In the illustrated example, the first portion 21P overlaps with the second portion 52P, as viewed in the z-direction. In addition, the first portion 21P includes a through hole 211P. The through hole 211P is formed so as to penetrate through the first portion 21P, in the z-direction. The inside of the through hole 211P is filled with the conductive bonding material 82, like the through hole 211C in the first portion 21C of the lead 2C shown in FIG. 5. The conductive bonding material 82 covers a part of the surface of the lead 2P. However, the conductive bonding material 82 may be provided only inside the through hole 211P, so as not to reach the surface of the lead 2P.

The third portion 23P, the fourth portion 24P, and the fifth portion 25P are covered with the encapsulating resin 7. The fifth portion 25P is connected to the first portion 21P and the third portion 23P. In the illustrated example, the fifth portion 25P includes a portion extending along the y-direction and a portion inclined with respect to the y-direction. The fifth portion 25P overlaps with the fourth face 34 of the substrate 3, as viewed in the z-direction. The third portion 23P is connected to the fourth portion 24P and the fifth portion 25P. The fourth portion 24P is shifted in the z-direction with respect to the first portion 21P, to the side to which the first face 31 is oriented, like the third portion 23C and the fourth portion 24C of the lead 2C shown in FIG. 5. The end portion of the fourth portion 24P is flush with the sixth face 75 of the resin 7.

The second portion 22P is connected to the end portion of the fourth portion 24P, and corresponds to a portion of the lead 2P sticking out from the encapsulating resin 7 to the opposite side of the plurality of leads 1, as viewed in the y-direction. The second portion 22P sticks out to the opposite side of the first portion 21P, in the y-direction. The second portion 22P is used, for example, to electrically connect the semiconductor device A1 to an external circuit. In the illustrated example, the second portion 22P is bent in the z-direction, to the side to which the first face 31 is oriented. The second portion 22P, the third portion 23P, and the fourth portion 24P each include, on the respective sides thereof in the x-direction, edges extending along the y-direction. The edges of the second portion 22P, the third portion 23P, and the fourth portion 24P, on the side of the third face 33 in the x-direction, are respectively opposed to the edges of the second portion 22O, the third portion 23O, and the fourth portion 24O, on the side of the fourth face 34 in the x-direction.

The lead 2Z is spaced apart from the substrate 3, as viewed in the z-direction. In this embodiment, the lead 2Z is located on the side to which the third face 33 is oriented, with respect to the substrate 3 in the x-direction. In addition, the lead 2Z is located on the opposite side of the lead 2B, with respect to the lead 2A in the x-direction.

The configuration of the lead 2Z is not specifically limited. In this embodiment the lead 2Z includes, as shown in FIG. 4, a second portion 22Z and a fourth portion 24Z, each of which will be described hereunder. In this embodiment, the lead 2Z is insulated from the circuit of the semiconductor device A1.

The fourth portion 242 is connected to the second portion 22Z, and covered with the encapsulating resin 7. The fourth portion 24Z is, like the fourth portion 24C of the lead 2C, shifted from the first portion 21A in the z-direction, to the side to which the first face 31 is oriented. The shape of the fourth portion 24Z is not specifically limited and, in the illustrated example, the fourth portion 24Z has a strip shape extending along the y-direction. The end portion of the fourth portion 24Z is flush with the sixth face 75 of the resin 7.

The second portion 22Z is connected to the end portion of the fourth portion 24Z, and corresponds to a portion of the lead 22 sticking out from the encapsulating resin 7. The second portion 22Z sticks out to the opposite side of the fourth portion 24Z, in the y-direction. The second portion 22Z is used, for example, when the semiconductor device A1 is mounted on an external circuit board. In the illustrated example, the second portion 22Z is bent in the z-direction, to the side to which the first face 31 is oriented.

As shown in FIG. 4 and FIG. 15, the second portions 22A, 22B, and 22C are aligned in the x-direction, with clearances G21. The clearances G21 have generally the same width, with a difference within ±5% from each other. The second portion 22C and the second portion 22D are aligned in the x-direction, with a clearance G22 therebetween. The clearance G22 has generally the same width as the clearance G21, with a difference within ±5% from each other. The second portions 22D to 22N are aligned in the x-direction, with clearances G23 between each other. The clearances G23 are narrower than the clearances G21, and the difference in length among the plurality of clearances G23 is within ±5%. The second portion 22A and the second portion 22Z are aligned in the x-direction, with a clearance G24 therebetween. The clearance G24 is different from the clearance G21, by within ±5%. In addition, the clearance G23 is narrower than the clearance G54 shown in FIG. 16.

### <Semiconductor Chips 4A to 4F>

The semiconductor chips 4A to 4F, located on the plurality of leads 1, each exemplify a semiconductor chip in the present disclosure. The type and the function of the semiconductor chips 4A to 4F are not specifically limited. In this embodiment, the semiconductor chips 4A to 4F are a transistor. Although six semiconductor chips 4A to 4F are provided in the illustrated example, the number of semiconductor chips is by no means limited.

The semiconductor chips 4A to 4F in the illustrated example are, for example, a metal-oxide-semiconductor field-effect transistor (MOSFET) formed on a silicon carbide (SiC) substrate, in other words SiC MOSFET. Here, the semiconductor chips 4A to 4F may be a MOSFET formed on a silicon (Si) substrate instead of the SiC substrate, and may be configured as, for example, an IGBT element. Alternatively, the semiconductor chips 4A to 4F may be a MOSFET containing GaN. In this embodiment, each of the semiconductor chips 4A to 4F is an N-type MOSFET. The semiconductor chips 4A to 4F according to this embodiment are the same MOSFET as each other. Hereunder, the semiconductor chip 4A will be described as an example, and the description of the remaining semiconductor chips 4B to 4F will be omitted.

As shown in FIG. 4, FIG. 5, and FIG. 9, the semiconductor chip 4A is located on the first portion 11A of the lead 1A. The semiconductor chip 4A includes a gate electrode GP, a source electrode SP, and a drain electrode DP. In the illustrated example, the source electrode SP and the gate electrode GP are located on the face of the semiconductor chip 4A oriented in the same direction as the main surface 111A. The drain electrode DP is formed on the face of the semiconductor chip 4A opposed to the main surface 111A. The gate electrode GP and the source electrode SP are formed of, for example, Al or an Al alloy (e.g., Al—Si, Al—Cu, and Al—Si—Cu). The drain electrode DP is formed of, for example, A1 or an Al alloy (e.g., Al—Si, Al—Cu, and Al—Si—Cu). The shape and size of the gate electrode GP, the source electrode SP, and the drain electrode DP are not specifically limited. In the illustrated example, the source electrode SP is larger than the gate electrode GP, as viewed in the z-direction. The gate electrode GP is located on the side of the fifth face 35 of the substrate 3, with respect to the center of the semiconductor chip 4A in the y-direction, as viewed in the z-direction. The source electrode SP includes a portion located on one side of the gate electrode GP in the y-direction, and on both sides thereof in the x-direction. Here, the position of the gate electrode GP with respect to the source electrode SP is not specifically limited. The gate electrode GP may be formed in a square shape. The source electrode SP includes a recess formed on the side opposed to the fifth face 35, and the gate electrode GP is located inside the recess.

FIG. 17 is an enlarged partial cross-sectional view schematically showing chip the semiconductor 4A. The semiconductor chip 4A according to this embodiment includes a substrate 400, an epitaxial layer 401, a source interconnect 411, a drain interconnect 415, and a gate interconnect 419.

The substrate 400 is formed of silicon carbide (SiC), and doped with an n-type impurity in high concentration (e.g., 1e18 to 1e21 cm⁻³). The substrate 400 includes a front surface 400A and a back surface 400B. The front surface 400A is a Si surface, and the back surface 400B is a C surface.

The epitaxial layer 401 is stacked on the front surface 400A of the substrate 400. The epitaxial layer 401 is an n⁻-type layer formed of SiC doped with the n-type impurity in low concentration than the substrate 400. The epitaxial layer 401 is formed through what is known as epitaxial growth, on the substrate 400. The epitaxial layer 401 formed on the front surface 400A, which is a Si surface, grows utilizing the Si surface as the main growth surface. Accordingly, a surface 401A of the epitaxial layer 401 formed through the growth is also a Si surface, like the front surface 400A of the substrate 400.

The epitaxial layer 401 includes a drain region 402, a body region 403, a source region 407, and a body contact region 408.

The drain region 402 corresponds to the portion on the side of the C surface (base portion), opposite to the surface 401A. The drain region 402 is an n′-type region, the entirety of which is maintained in the state after the epitaxial growth as it is. The n-type impurity concentration of the drain region 402 is, for example, 1e15 to 1e17 cm⁻³.

The body region 403 is formed on the side of the surface 401A of the epitaxial layer 401. The body region 403 is in contact with the drain region 402, from the side of the surface 401A (Si surface) of the epitaxial layer 401. The p-type impurity concentration of the body region 403 is, for example, 1e16 to 1e19 cm⁻³.

The epitaxial layer 401 includes a gate trench 404. The gate trench 404 is formed so as to recede from the surface 401A. Though not shown in FIG. 17, a plurality of gate trenches 404 are formed at certain intervals between each other, so as to extend in the same direction parallel to each other (direction perpendicular to the sheet face of FIG. 17, which may hereinafter be referred to as “direction along the gate width”), for example in a stripe pattern.

The gate trenches 404 each include two side faces 404a and a bottom face 404b. The two side faces 404a are opposed to each other with a clearance therebetween, and both are orthogonal to the surface 401A. The bottom face 404b is connected to the two side faces 404a, and includes a section parallel to the surface 401A. The gate trench 404 is formed so as to penetrate through the body region 403 in the layer thickness direction, such that a deepest portion (bottom face 404b) reaches the drain region 402.

A gate insulation film 405 is formed on the inner surface of the gate trench 404 and the surface 401A of the epitaxial layer 401, so as to cover the entirety of the inner surface of the gate trench 404 (side face 404a and bottom face 404b). The gate insulation film 405 is formed of an oxide film containing nitrogen (N), such as a silicon oxynitride film formed by thermal oxidation using a nitride-containing gas. The nitrogen content (nitrogen concentration) in the gate insulation film 405 is, for example, 0.1 to 10%.

The gate insulation film 405 includes an insulation film side portion 405a and an insulation film bottom portion 405b. The insulation film side portion 405a is provided over the side face 404a of the gate trench 404. The insulation film bottom portion 405b is provided over the bottom face 404b of the gate trench 404. In the illustrated example, the thickness T2 of the insulation film bottom portion 405b is equal to or thinner than the thickness T1 of the insulation film side portion 405a. More specifically, the ratio of the thickness T2 of the insulation film bottom portion 405b to the thickness 11 of the insulation film side portion 405a (thickness T2 of insulation film bottom portion 405b/thickness T1 of insulation film side portion 405a) is 0.3 to 1.0, and more preferably 0.5 to 1.0. The thickness T1 of the insulation film side portion 405a is, for example, 300 to 1000 Å, and the thickness T2 of insulation film bottom portion 405b is, for example, 150 to 500 Å.

A gate electrode 406 is buried inside the gate insulation film 405. The gate electrode 406 is formed by entirely filling the inside of the gate insulation film 405 with a polysilicon material doped with an N-type impurity in high concentration.

The source region 407 is located in an upper portion of the body region 403, and on both sides of the gate trench 404 in the direction orthogonal to the gate width (left-right direction in FIG. 17), and is an n⁺-type region. The source region 407 is doped with the n-type impurity in higher concentration than the n-type impurity concentration of the drain region 402. The n-type impurity concentration of the source region 407 is, for example, 1e18 to 1e21 cm⁻³. The source region 407 extends along the gate width direction, at the position adjacent to the gate trench 404.

The body contact region 408 penetrates through the central portion of the source region 407 in the direction orthogonal to the gate width, from the surface 401A, and is a p⁺-type region connected to the body region 403. The body contact region 408 is doped with the p-type impurity in higher concentration than the p-type impurity concentration of the body region 403. The p-type impurity concentration of the body contact region 408 is, for example, 1e18 to 1e21 cm⁻³.

The gate trench 404 and the source region 407 are alternately provided in the direction orthogonal to the gate width, and each extend along the gate width direction. Boundaries between unit cells, located adjacent to each other in the direction orthogonal to the gate width along the source region 407, are provided on the source region 407. At least one body contact region 408 is provided so as to span over the two unit cells located adjacent to each other in the direction orthogonal to the gate width. In addition, the boundary between the unit cells adjacent to each other along the direction of the gate width is provided such that a certain gate width is secured for the gate electrodes 406 of the respective unit cells.

An interlayer dielectric film 409 formed of silicon oxide (SiO₂) is stacked on the epitaxial layer 401. The interlayer dielectric film 409 and the gate insulation film 405 each include a contact hole 410, in which the surfaces of the source region 407 and the body contact region 408 are exposed.

The source interconnect 411 is formed on the interlayer dielectric film 409. The source interconnect 411 is brought into contact with (electrically connected to) the source region 407 and the body contact region 408, via the contact hole 410. The source interconnect 411 includes a polysilicon layer 412, a metal layer 413, and an intermediate layer 414.

The polysilicon layer 412 is in contact with the source region 407 and the body contact region 408. The polysilicon layer 412 is a doped layer formed of polysilicon doped with an impurity, and preferably a high-concentration doped layer, doped with an impurity in concentration as high as, for example, 1e19 to 1e21 cm⁻³. Examples of the impurity that may be employed to form the polysilicon layer 412 as a doped layer (high-concentration doped layer inclusive) include an N-type impurity such as phosphor (P) or arsenic (As), and a p-type impurity such as boron (B). In addition, the polysilicon layer 412 covers the entirety of the contact hole 410. The thickness of the polysilicon layer 412 formed as above is, for example, 500 to 1000 Å, depending on the depth of the contact hole 410.

The metal layer 413 is formed over the polysilicon layer 412. The metal layer 413 is, for example, formed of aluminum (A1), gold (Au), silver (Ag), copper (Cu), an alloy thereof, or a metal material containing the cited metals. The metal layer 413 constitutes the outermost layer of the source interconnect 411 and, for example, the first wire 91A is connected (bonded) to the metal layer 413. The thickness of the metal layer 413 is, for example, 1 to 5 μm.

The intermediate layer 414 is interleaved between the polysilicon layer 412 and the metal layer 413, and contains titanium (Ti). The intermediate layer 414 is formed of a layer containing titanium, or a plurality of layers including the mentioned layer. The layer containing titanium can be formed from titanium or titanium nitride (TiN). The thickness of the intermediate layer 414 is, for example, 200 to 500 nm.

Preferably, the source interconnect 411 including the polysilicon layer 412, the intermediate layer 414, and the metal layer 413 formed as above, may have a layered structure in which polysilicon (polysilicon layer 412), titanium (intermediate layer 414), titanium nitride (intermediate layer 414), and aluminum (metal layer 413) are sequentially stacked (Po—Si/Ti/TiN/A1).

The drain interconnect 415 is formed on the back surface 400B of the substrate 400. The drain interconnect 415 is in contact with (electrically connected to) the substrate 400. The drain interconnect 415 includes a polysilicon layer 416, a metal layer 417, and an intermediate layer 418.

The polysilicon layer 416 is in contact with the substrate 400. The polysilicon layer 416 may be formed of the material similar to that of the polysilicon layer 412. The thickness of the polysilicon layer 416 is, for example, 1000 to 2000 Å.

The metal layer 417 is formed over the polysilicon layer 416. The metal layer 417 may be formed of the material similar to that of the metal layer 413. The metal layer 417 constitutes the outermost layer of the drain interconnect 415, and is bonded to the first portion 11A, for example when the substrate 400 is mounted on the first portion 11A of the lead 1A. The thickness of the metal layer 417 is, for example, 0.5 to 1 μm.

The intermediate layer 418 is interleaved between the polysilicon layer 416 and the metal layer 417, and contains titanium (Ti). The intermediate layer 418 may be formed of the material similar to that of the intermediate layer 414.

The gate interconnect 419 is in contact with (electrically connected to) the gate electrode 406, via a contact hole (not shown) formed in the interlayer dielectric film 409. When a predetermined voltage (equal to or higher than a gate threshold voltage) is applied to the gate interconnect 419, with a predetermined potential difference generated between the source interconnect 411 and the drain interconnect 415 (between source-drain), a channel is formed in the vicinity of the interface between the body region 403 and the gate insulation film 405, by the electric field from the gate electrode 406. Accordingly, a current flows between the source interconnect 411 and the drain interconnect 415, so that the semiconductor chip 4A is turned on.

In this embodiment, as shown in FIG. 4, FIG. 5, FIG. 9, and FIG. 10, three semiconductor chips 4A, 4B, and 4C are provided on the main surface 111A of the first portion 11A of the lead 1A. The three semiconductor chips 4A, 4B, and 4C are spaced apart from each other in the x-direction, and overlap with each other as viewed in the x-direction. Here, the number of semiconductor chips to be mounted on the lead 1A is by no means limited. In a plan view, the three semiconductor chips 4A, 4B, and 4C are each located in a region of the main surface 111A surrounded by the groove 1112A. In the illustrated example, the semiconductor chips 4A, 4B, and 4C are arranged such that, as viewed in the z-direction, the respective gate electrodes GP are located on the side of the plurality of leads 2, with respect to the center of the semiconductor chips 4A, 4B, and 4C in the y-direction. In the illustrated example, in addition, the respective drain electrodes DP of the semiconductor chips 4A, 4B, and 4C are bonded to the main surface 111A, via the conductive bonding material 83.

The conductive bonding material 83 may be any material that is capable of bonding, and electrically connecting, the drain electrode DP of the semiconductor chips 4A, 4B, and 4C, to the main surface 111A. For example, silver paste, copper paste, or solder may be employed as the conductive bonding material 83. The conductive bonding material 83 corresponds to the second conductive bonding material in the present disclosure. In this embodiment, the conductive bonding material 83 extends outwardly from the outer periphery of the semiconductor chips 4A, 4B, and 4C, in a plan view. A reason of such a configuration is that, for example, when the conductive bonding material 83 performs the bonding function by curing after the fused state, the conductive bonding material 83 is apt to be formed in contact with the edge of the groove 1112A, as shown in FIG. 6. This is because the surface tension of the fused conductive bonding material 83, generated at the edge of the groove 1112A when the conductive bonding material 83 is about to spread around, prevents the conductive bonding material 83 from spreading further.

In this embodiment, as shown in FIG. 4, FIG. 5, FIG. 9, and FIG. 14, the semiconductor chip 4D is provided on the main surface 111B of the first portion 11B of the lead 1B. Here, the number of semiconductor chips to be mounted on the lead 1B is by no means limited. The semiconductor chip 4D is located in a region of the main surface 111B surrounded by the groove 1112B, in a plan view. In the illustrated example, the semiconductor chip 4D is arranged such that, as viewed in the z-direction, the gate electrode GP is located on the side of the plurality of leads 2, with respect to the center of the semiconductor chip 4D in the y-direction. In the illustrated example, in addition, the drain electrode DP of the semiconductor chip 4D is bonded to the main surface 111B, via the conductive bonding material 83.

In this embodiment, as shown in FIG. 4, FIG. 5, FIG. 9, and FIG. 14, the semiconductor chip 4E is provided on the main surface 111C of the first portion 11C of the lead 1C. Here, the number of semiconductor chips to be mounted on the lead 1C is by no means limited. The semiconductor chip 4E is located in a region of the main surface 111C surrounded by the groove 1112C, in a plan view. In the illustrated example, the semiconductor chip 4E is arranged such that, as viewed in the z-direction, the gate electrode GP is located on the side of the plurality of leads 2, with respect to the center of the semiconductor chip 4E in the y-direction. In the illustrated example, in addition, the drain electrode DP of the semiconductor chip 4E is bonded to the main surface 111C, via the conductive bonding material 83.

In this embodiment, as shown in FIG. 4, FIG. 5, FIG. 9, and FIG. 14, the semiconductor chip 4F is provided on the main surface 111D of the first portion 11D of the lead 1D. Here, the number of semiconductor chips to be mounted on the lead 1D is by no means limited. The semiconductor chip 4F is located in a region of the main surface 111D surrounded by the groove 1112D, in a plan view. In the illustrated example, the semiconductor chip 4F is arranged such that, as viewed in the z-direction, the gate electrode GP is located on the side of the plurality of leads 2, with respect to the center of the semiconductor chip 4F in the y-direction. In the illustrated example, in addition, the drain electrode DP of the semiconductor chip 4F is bonded to the main surface 111D, via the conductive bonding material 83. In the illustrated example, as shown in FIG. 4, 4 the semiconductor chip 4C and the semiconductor chip 4D overlap with the connecting portion 57 of the conductive section 5, as viewed in the y-direction. As shown in FIG. 5, the semiconductor chip 4B is located on the side of the substrate 3 with respect to the upper face of the fourth portion 14A, in the z-direction.

### <Control Chips 4G, 4H>

The control chips 4G and 4H serve to control the operation of at least one of the semiconductor chips 4A to 4F. As shown in FIG. 4 and FIG. 15, the control chips 4G and 4H are electrically connected to the conductive section 5 and at least one of the semiconductor chips 4A to 4F, and provided on the substrate 3. In this embodiment, the control chip 4G controls the operation of three semiconductor chips 4A, 4B, and 4C. The control chip 4H controls the operation of three semiconductor chips 4D, 4E, and 4F. The shape and size of the control chips 4G and 4H are not specifically limited. In the illustrated example, the control chips 4G and 4H have an elongate rectangular shape, having the long sides extending along the x-direction, as viewed in the z-direction.

In this embodiment, the control chip 4G is mounted on the first base portion 55 of the conductive section 5. The control chip 4H is mounted on the second base portion 56 of the conductive section 5. In this embodiment, the control chip 4G is bonded to the first base portion 55, via a conductive bonding material 84. The control chip 4H is bonded to the second base portion 56, via the conductive bonding material 84.

The conductive bonding material 84 may be any material that is capable of bonding, and electrically connecting, the control chip 4G to the first base portion 55, and the control chip 4H to the second base portion 56. For example, silver paste, copper paste, or solder may be employed as the conductive bonding material 84. The conductive bonding material 84 corresponds to the third conductive material in the present disclosure. In this embodiment, the conductive bonding material 84 extends outwardly from the outer periphery of the control chips 4G and 4H, in a plan view. A reason of such a configuration is that, for example, when the conductive bonding material 84 performs the bonding function by curing after the fused state, the conductive bonding material 84 in the fused state spreads around the control chip 4G (control chip 4H) as viewed in the z-direction, as shown in FIG. 7. Therefore, in the illustrated example, the conductive bonding material 84 protrudes from the respective outer edges of the control chips 4G and 4H, as viewed in the z-direction. However, the specific shape of the conductive bonding material 84 is by no means limited. Here, the control chips 4G and 4H may be bonded to the first base portion 55 via an insulative bonding material, instead of the conductive bonding material 84.

As shown in FIG. 4, the control chip 4G is located between the leads 2B to 2O and the leads 1A to 1G, as viewed in the x-direction. The control chip 4H is located between the leads 2B to 2O and the leads 1A to 1G, as viewed in the x-direction. The control chip 4G overlaps with the semiconductor chip 4B, as viewed in the y-direction. In the illustrated example, the control chip 4G also overlaps with the semiconductor chip 4A, as viewed in the y-direction. The control chip 4H overlaps with the semiconductor chip 4E, as viewed in the y-direction. The control chip 4G may overlap with the semiconductor chip 4C, as viewed in the y-direction. The control chip 4H may overlap with either or both of the semiconductor chips 4D and 4F, as viewed in the y-direction.

As shown in FIG. 15 and FIG. 16, in the illustrated example, the control chip 4G overlaps with the wiring 50B (first portion 51B) and the wiring 50C (first portion 51C), as viewed in the y-direction. In addition, the control chip 4G overlaps with the second base portion 56 and the control chip 4H, as viewed in the x-direction. The control chip 4H overlaps with the wiring 50I (first portion 51I), the wiring 50J (first portion 51J), wiring 50K (first portion 51K), and the wiring 50L (first portion 51L), as viewed in the y-direction. In addition, the control chip 4H overlaps with the wiring 50O (first portion 51O) and the wiring 50P (first portion 51P), as viewed in the x-direction.

As shown in FIG. 5, the control chip 4G is located on the side of the substrate 3, with respect to the upper end of the fourth portion 24C in the z-direction. Further, the control chip 4G is located on the side of the substrate 3, in other words on the lower side, with respect to the upper end of the first portion 21C in the z-direction. The control chip 4H is located on the side of the substrate 3, with respect to the upper end of the fourth portion 24C in the z-direction. Further, the control chip 4H is located on the side of the substrate 3, in other words on the lower side, with respect to the upper end of the first portion 21C in the z-direction.

### <Diodes 49U, 49V, 49W>

The diodes 49U, 49V, and 49W are electrically connected to the control chip 4G. In this embodiment, the diodes 49U, 49V, and 49W each serve as what is known as a boot diode, to apply a higher voltage to the control chip 4G. As shown in FIG. 4, FIG. 15, and FIG. 16, the diode 49U is bonded to the first portion 51A of the wiring 50A of the conductive section 5, via a conductive bonding material 85. The conductive bonding material 85 is formed of, for example, a similar material to that of the conductive bonding material 84. The conductive bonding material 85 extends outwardly from the outer periphery of the diodes 49U, 49V, and 49W, in a plan view. A reason of such a configuration is that, for example, when the conductive bonding material 85 performs the bonding function by curing after the fused state, the conductive bonding material 85 of the fused phase spreads around the diode 49W (also diode 49U and diode 49V) as viewed in the z-direction, as shown in FIG. 8. Therefore, in the illustrated example, the conductive bonding material 85 protrudes from the outer edge of the diode 49U, as viewed in the z-direction. However, the specific shape of the conductive bonding material 85 is by no means limited.

As shown in FIG. 4, FIG. 15, and FIG. 16, the diode 49V is bonded to the first portion 51B of the wiring 50B of the conductive section 5, via the conductive bonding material 85. The diode 49W is bonded to the first portion 51C of the wiring 50C of the conductive section 5, via the conductive bonding material 85.

The actual positional arrangement of the diodes 49U, 49V, and 49W is not specifically limited. As shown in FIG. 15 and FIG. 16, in the illustrated example, the center of the diode 49U in the x-direction is shifted to the side of the wiring 50B (first portion 51B), with respect to the center of the first portion 51A in the x-direction. The center of the diode 490 in the y-direction is shifted to the opposite side of the lead 2A, with respect to the center of the first portion 51A in the y-direction. The center of the diode 49V in the x-direction is shifted to the side of the wiring 50A (first portion 51A), with respect to the center of the first portion 51B in the x-direction. In addition, the center of the diode 49V in the y-direction is shifted to the side of the lead 2B, with respect to the center of the first portion 51B in the y-direction. Further, the center of the diode 49W in the x-direction is shifted to the side of the wiring 50D (first portion 51D), with respect to the center of the first portion 51C in the x-direction. The center of the diode 49W in the y-direction is shifted to the side of the lead 2C, with respect to the center of the first portion 51C in the y-direction.

As shown in FIG. 5, the diode 49W is located on the side of the substrate 3, in other words on the lower side, with respect to the upper end of the fourth portion 24C in the z-direction. In addition, the diode 49W is located on the side of the substrate 3, in other words on the lower side, with respect to the upper end of the first portion 21C in the z-direction. The mentioned positional relations also apply to the diodes 49U and 49V.

### <First Wires 91A to 91F>

The first wires 91A to 91F are each connected to one of the semiconductor chips 4A to 4F and one of the plurality of leads 1. The material of the first wires 91A to 91F is not specifically limited and, for example, aluminum (Al) or copper (Cu) may be employed. The wire diameter of the first wires 91A to 91F is not specifically limited and, for example, may be approximately 250 to 500 μm. The first wires 91A to 91F correspond to the first conductive material in the present disclosure. Here, for example leads formed of copper may be employed, in place of the first wires 91A to 91F.

As shown in FIG. 4, the first wire 91A has one end connected to the source electrode SP of the semiconductor chip 4A, and the other end connected to the fourth portion 14B of the lead 1B. The position on the source electrode SP and the fourth portion 14B to which the first wire 91A is to be connected is not specifically limited. As shown in FIG. 10, in the illustrated example, the one end of the first wire 91A is connected to a position spaced apart from the center of the source electrode SP of the semiconductor chip 4A in the y-direction, toward the opposite side of the gate electrode GP, as viewed in the z-direction. In addition, the first wire 91A overlaps with the center of the source electrode SP of the semiconductor chip 4A in the x-direction, as viewed in the y-direction. The first wire 91A is inclined with respect to the x-direction and the y-direction.

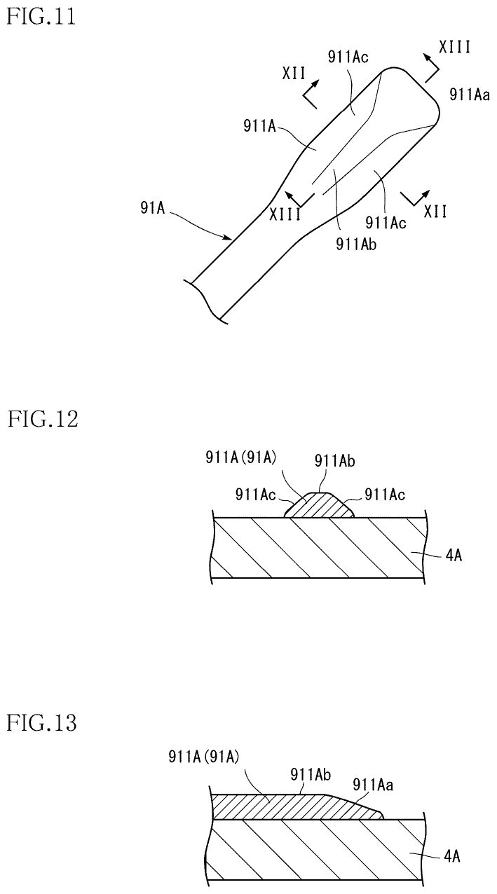

As shown in FIG. 10, the first wires 91A, 91B, and 91C respectively include end portions 911A, 911B, and 911C. The end portion 911A will be described hereunder, and the end portions 911B and 911C may be similarly formed to the end portion 911A. This also applies to the first wires 91D, 91E, and 91F. FIG. 11 is an enlarged partial plan view showing an end portion of the first wire 91A. FIG. 12 is an enlarged partial cross-sectional view taken along a line XII-XII in FIG. 11. FIG. 13 is an enlarged partial cross-sectional view taken along a line XIII-XIII in FIG. 11. The end portion 911A is connected, for example, to the source electrode SP of the semiconductor chip 4A. The end portion 911A includes a first face 911Aa, a second face 911Ab, and a pair of third faces 911Ac. The first face 911Aa is formed so as to come closer to the semiconductor chip 4A, toward the tip portion of the end portion 911Aa. The second face 911Ab is oriented upward in the z-direction. The pair of third faces 911Ac are formed on the respective sides of the second face 911Ab, so as to come closer to the semiconductor chip 4A, in the direction away from the second face 911Ab. The wires 91B to 91F also include the end portion similarly formed to the end portion 911A.

As shown in FIG. 4, the first wire 91B has one end connected to the source electrode SP of the semiconductor chip 4B, and the other end connected to the fourth portion 14C of the lead 1C. The position on the source electrode SP and the fourth portion 14C to which the first wire 91B is to be connected is not specifically limited. As shown in FIG. 10, in the illustrated example, the one end of the first wire 91B is connected to a position spaced apart from the center of the source electrode SP of the semiconductor chip 4B in the y-direction, toward the opposite side of the gate electrode GP, as viewed in the z-direction. In addition, the first wire 91B overlaps with the center of the source electrode SP of the semiconductor chip 4B in the x-direction, as viewed in the y-direction. The first wire 91B is inclined with respect to the x-direction and the y-direction.

As shown in FIG. 4, the first wire 91C has one end connected to the source electrode SP of the semiconductor chip 4C, and the other end connected to the fourth portion 14D of the lead 1D. The position on the source electrode SP and the fourth portion 14D to which the first wire 91C is to be connected is not specifically limited. As shown in FIG. 10, in the illustrated example, the one end of the first wire 91C is connected to a position spaced apart from the center of the source electrode SP of the semiconductor chip 4C in the y-direction, toward the opposite side of the gate electrode GP, as viewed in the z-direction. In addition, the first wire 91C overlaps with the center of the source electrode SP of the semiconductor chip 4C in the x-direction, as viewed in the y-direction. The first wire 91C is inclined with respect to the x-direction and the y-direction.

As shown in FIG. 4, the first wire 91D has one end connected to the source electrode SP of the semiconductor chip 4D, and the other end connected to the fourth portion 14E of the lead 1E. The position on the source electrode SP and the fourth portion 14E to which the first wire 91D is to be connected is not specifically limited. As shown in FIG. 10, in the illustrated example, the one end of the first wire 91D is connected to a position spaced apart from the center of the source electrode SP of the semiconductor chip 4D in the y-direction, toward the opposite side of the gate electrode GP, as viewed in the z-direction. In addition, the first wire 91D overlaps with the center of the source electrode SP of the semiconductor chip 4D in the x-direction, as viewed in the y-direction. The first wire 91D is inclined with respect to the x-direction and the y-direction.

As shown in FIG. 4, the first wire 91E has one end connected to the source electrode SP of the semiconductor chip 4E, and the other end connected to the fourth portion 14F of the lead 1F. The position on the source electrode SP and the fourth portion 14F to which the first wire 91E is to be connected is not specifically limited. As shown in FIG. 10, in the illustrated example, the one end of the first wire 91E is connected to a position spaced apart from the center of the source electrode SP of the semiconductor chip 4E in the y-direction, toward the opposite side of the gate electrode GP, as viewed in the z-direction. In addition, the first wire 91E overlaps with the center of the source electrode SP of the semiconductor chip 4E in the x-direction, as viewed in the y-direction. The first wire 91E is inclined with respect to the x-direction and the y-direction.

As shown in FIG. 4, the first wire 91F has one end connected to the source electrode SP of the semiconductor chip 4F, and the other end connected to the fourth portion 14G of the lead 1G. The position on the source electrode SP and the fourth portion 14G to which the first wire 91F is to be connected is not specifically limited. As shown in FIG. 10, in the illustrated example, the one end of the first wire 91F is connected to a position spaced apart from the center of the source electrode SP of the semiconductor chip 4F in the y-direction, toward the opposite side of the gate electrode GP, as viewed in the z-direction. In addition, the first wire 91F overlaps with the center of the source electrode SP of the semiconductor chip 4F in the x-direction, as viewed in the y-direction. The one end of the first wire 91F is, as viewed in the y-direction, shifted to the side of the semiconductor chip 4E, with respect to the center of the source electrode SP of the semiconductor chip 4F in the x-direction. The first wire 91F is inclined with respect to the x-direction and the y-direction.

### <Second Wires 92>

The plurality of second wires 92 are each connected to one of the control chips 4G and 4H, as shown in FIG. 4. The material of the second wires 92 is not specifically limited and, for example, gold (Au), silver (Ag), copper (Cu), or aluminum (Al) may be employed. The wire diameter of the second wires 92 is not specifically limited and, in this embodiment, finer than the first wires 91A to 91F. The wire diameter of the second wires 92 is, for example, approximately 10 μm to 50 μm. The second wires 92 correspond to the second conductive material in the present disclosure. In the subsequent description, the second wires 92 connected to the control chip 4G will be referred to as second wires 92G, and the second wires 92 connected to the control chip 4H will be referred to as second wires 92H.

As shown in FIG. 4, the second wire 92G is connected to the gate electrode GP of the semiconductor chip 4A, and to a position on the control chip 4G on the side of the first portion 11A, with respect to the center of the control chip 4G in the y-direction. Another second wire 92G is connected to the source electrode SP of the semiconductor chip 4A, and to a position on the control chip 4G on the side of the first portion 11A, with respect to the center of the control chip 4G in the y-direction. The latter second wire 92G is connected to a position on the source electrode SP of the semiconductor chip 4A on the side of the semiconductor chip 4B in the x-direction, with respect to the gate electrode GP.

As shown in FIG. 4, the second wire 92G is connected to the gate electrode GP of the semiconductor chip 4B, and to a position on the control chip 4G on the side of the first portion 11A, with respect to the center of the control chip 4G in the y-direction. Another second wire 92G is connected to the source electrode SP of the semiconductor chip 4B, and to a position on the control chip 4G on the side of the first portion 11A, with respect to the center of the control chip 4G in the y-direction. The latter second wire 92G is connected to a position on the source electrode SP of the semiconductor chip 4B on the side of the semiconductor chip 4C in the x-direction, with respect to the gate electrode GP.

As shown in FIG. 4, the second wire 92G is connected to the gate electrode GP of the semiconductor chip 4C, and to a position on the control chip 4G on the side of the first portion 11A, with respect to the center of the control chip 4G in the y-direction. Another second wire 92G is connected to the source electrode SP of the semiconductor chip 4C, and to a position on the control chip 4G on the side of the first portion 11A, with respect to the center of the control chip 4G in the y-direction. The latter second wire 92G is connected to a position on the source electrode SP of the semiconductor chip 4B on the side of the semiconductor chip 4B in the x-direction, with respect to the gate electrode GP.

As shown in FIG. 4, the second wire 92H is connected to the gate electrode GP of the semiconductor chip 4D, and to a position on the control chip 4H on the side of the first portion 11A, with respect to the center of the control chip 4H in the y-direction. Another second wire 92H is connected to the gate electrode GP of the semiconductor chip 4E, and to a position on the control chip 4H on the side of the first portion 11A, with respect to the center of the control chip 4H in the y-direction. Further, still another second wire 92H is connected to the gate electrode GP of the semiconductor chip 4F, and to a position on the control chip 4H on the side of the first portion 11A, with respect to the center of the control chip 4H in the y-direction.

As shown in FIG. 15 and FIG. 16, a pair of second wires 92G each have one end connected to the first portion 51A of the wiring 50A, and the other end connected to the control chip 4G. Another second wire 92G has one end connected to the diode 49U, and the other end connected to the control chip 4G.

As shown in FIG. 15 and FIG. 16, a pair of second wires 92G each have one end connected to the first portion 51B of the wiring 50B, and the other end connected to the control chip 4G. Another second wire 92G has one end connected to the diode 49V, and the other end connected to the control chip 4G.

As shown in FIG. 15 and FIG. 16, a pair of second wires 92G each have one end connected to the first portion 51C of the wiring 50C, and the other end connected to the control chip 4G. Another second wire 92G has one end connected to the diode 49W, and the other end connected to the control chip 4G.

As shown in FIG. 15 and FIG. 16, a pair of second wires 92G each have one end connected to the first portion 51D of the wiring 50D, and the other end connected to the control chip 4G. Another second wire 92G has one end connected to the first portion 51E of the wiring 50E, and the other end connected to the control chip 4G. Still another second wire 92G has one end connected to the first portion 51F of the wiring 50F, and the other end connected to the control chip 4G. Still another second wire 92G has one end connected to the first portion 51G of the wiring 50G, and the other end connected to the control chip 4G. Further, another pair of second wires 92G each have one end connected to the second portion 572 of the connecting portion 57, and the other end connected to the control chip 4G.

As shown in FIG. 15 and FIG. 16, the second wire 92H has one end connected to the first portion 51I of the wiring 50I, and the other end connected to the control chip 4H. Another second wire 92H has one end connected to the first portion 51J of the wiring 50J, and the other end connected to the control chip 4H. Still another second wire 92H has one end connected to the first portion 51K of the wiring 50K, and the other end connected to the control chip 4H. A pair of second wires 92H each have one end connected to the first portion 51L of the wiring 50L, and the other end connected to the control chip 4H. Still another second wire 92H has one end connected to the first portion 51M of the wiring 50M, and the other end connected to the control chip 4H. Still another second wire 92H has one end connected to the first portion 51N of the wiring 50N, and the other end connected to the control chip 4H. Further, another pair of second wires 92H each have one end connected to the first portion 51O of the wiring 50O, and the other end connected to the control chip 4H.

### <Resin 7>

The resin 7 covers at least the semiconductor chips 4A to 4F, the control chips 4G and 4H, a part of each of the plurality of leads 1, and a part of each of the plurality of leads 2. In this embodiment, in addition, the resin 7 covers the diodes 49U, 49V, and 49W, the plurality of first wires 91A to 91F, and the plurality of second wires 92. The material of the resin 7 is not specifically limited. Though not specifically limited, for example an insulative material such as an epoxy resin or silicone gel may be employed to form the resin 7.

It is preferable that the dimension DX in the x-direction of the resin 7 shown in FIG. 2 is equal to or smaller than 60 mm. It is preferable that the dimension DY of the resin 7 in the y-direction is equal to or smaller than 35 mm. It is preferable that the dimension DZ in the z-direction of the resin 7 shown in FIG. 1 is equal to or smaller than 6 mm. In this embodiment, the dimension DX of the resin 7 is approximately 57 mm, the dimension DY is approximately 30 mm, and the dimension DZ is approximately 5 mm.

In this embodiment, the resin 7 includes a first face 71, a second face 72, a third face 73, a fourth face 74, a fifth face 75, a sixth face 76, a recess 710, a recess 720, a recess 731, a recess 732, a recess 733, and a recess 734.

The first face 71 intersects with the z-direction and, in the illustrated example, is perpendicular to the z-direction. The first face 71 is oriented in the same direction as the first face 31 of the substrate 3. The second face 72 intersects with the z-direction and, in the illustrated example, is perpendicular to the z-direction. The second face 72 is oriented in the opposite direction to the first face 71, and in the same direction as the second face 32 of the substrate 3.

The third face 73 is located between the first face 71 and the second face 72 in the z-direction, and connected to the first face 71 and the second face 72, in the illustrated example. The third face 73 intersects with the x-direction, and is oriented in the same direction as the third face 33 of the substrate 3. The fourth face 74 is located between the first face 71 and the second face 72 in the z-direction, and connected to the first face 71 and the second face 72, in the illustrated example. The fourth face 74 intersects with the x-direction, and is oriented in the opposite direction to the third face 73, and in the same direction as the fourth face 34 of the substrate 3.

The fifth face 75 is located between the first face 71 and the second face 72 in the z-direction, and connected to the first face 71 and the second face 72, in the illustrated example. The fifth face 75 intersects with the y-direction, and is oriented in the same direction as the fifth face 35 of the substrate 3. The sixth face 76 is located between the first face 71 and the second face 72 in the z-direction, and connected to the first face 71 and the second face 72, in the illustrated example. The sixth face 76 intersects with the x-direction, and is oriented in the opposite direction to the fifth face 75, and in the same direction as the sixth face 36.

The recess 710 is a portion receding from the third face 73 in the x-direction. The recess 710 is formed so as to reach the first face 71 and the second face 72. The recess 720 is a portion receding from the fourth face 74 in the x-direction. The recess 720 is formed so as to reach the first face 71 and the second face 72.

As shown in FIG. 4, the recess 731, the recess 732, the recess 733, and the recess 734 are portions receding from the fifth face 75 in the y-direction. The recess 731 is located between the second portion 222 of the lead 22 and the second portion 22A of the lead 2A, as viewed in the y-direction. The recess 732 is located between the second portion 22A of the lead 2A and the second portion 22B of the lead 2B, as viewed in the y-direction. The recess 733 is located between the second portion 22B of the lead 2B and the second portion 22C of the lead 2C, as viewed in the y-direction. The recess 734 is located between the second portion 22C of the lead 2C and the second portion 22D of the lead 2D, as viewed in the y-direction.

### <Circuit Configuration of Semiconductor Device A1>

A circuit configuration of the semiconductor device A1 will now be described hereunder.

As shown in FIG. 18, the semiconductor device A1 includes three switching arms 40U, 40V, and 40W connected in parallel to each other. The switching arm 40U includes the semiconductor chips 4A and 4D, the switching arm 40V includes the semiconductor chips 4B and 4E, and the switching arm 40W includes the semiconductor chips 4C and 4F.

The respective drains of the semiconductor chips 4A to 4C are connected to each other, and connected to a P terminal (lead 1A). the source of the semiconductor chip 4A is connected to the drain of the semiconductor chip 4D, the source of the semiconductor chip 4B is connected to the drain of the semiconductor chip 4E, and the source of the semiconductor chip 4C is connected to the drain of the semiconductor chip 4F. A node N1 between the source of the semiconductor chip 4A and the drain of the semiconductor chip 4D is connected to a U terminal (lead 1B). A node N2 between the source of the semiconductor chip 4B and the drain of the semiconductor chip 4E is connected to a V terminal (lead 1C). A node N3 between the source of the semiconductor chip 4C and the drain of the semiconductor chip 4F is connected to a W terminal (lead 1D). The source of the semiconductor chip 4D is connected to an NU terminal (lead 1E), the source of the semiconductor chip 4E is connected to an NV terminal (lead 1F), and the source of the semiconductor chip 4F is connected to an NW terminal (lead 1G).

A voltage level applied to the U terminal (lead 1B), the V terminal (lead 1C), and the W terminal (lead 1D) is, for example, approximately 0 V to 650 V. A voltage level applied to the NU terminal (lead 1E), the NV terminal (lead 1F), and the NW terminal (lead 1G) is, for example, approximately 0V, and lower than the voltage level applied to the terminal (lead 1B), the V terminal (lead 1C), and the W terminal (lead 1D). The semiconductor chips 4A to 4C each constitute a high-potential side transistor of a three-phase inverter circuit, and the semiconductor chips 4D to 4F each constitute a low-potential side transistor of the three-phase inverter circuit.

The respective gates of the semiconductor chip 4A to 4C are connected to the control chip 4G, and the respective sources of the semiconductor chips 4A to 4C are connected to the control chip 4G. The respective gates of the semiconductor chips 4D to 4F are connected to the control chip 4H.

The control chip 4G is electrically connected to a VBU terminal (lead 2A), a VBV terminal (lead 2B), a VBW terminal (lead 2C), a first VCC terminal (lead 2D), an HINU terminal (lead 2E), an HINV terminal (lead 2F), an HINW terminal (lead 2G), and a first GND terminal (lead 2H). The first VCC terminal supplies a source voltage VCC to the control chip 4G. A gate signal voltage is applied to the HINU terminal, the HINV terminal, and the HINW terminal, from an external gate driver circuit (not shown). The control chip 4G is a circuit for applying the gate signal voltages to the respective gates of the semiconductor chips 4A to 4C. The first GND terminal and the second GND terminal (lead 2O) are connected to each other inside the semiconductor device A1, more specifically in the conductive section 5 on the substrate 3.

The control chip 4H is electrically connected to an LINU terminal (lead 2I), an LINV terminal (lead 2J), an LINW terminal (lead 2K), a second VCC terminal (lead 2L), an FO terminal (lead 2M), a CIN terminal (lead 2N), and a second GND terminal (lead 2O). The second VCC terminal supplies the source voltage VCC to the control chip 4H. The gate signal voltage is applied to the LINU terminal, the LINV terminal, and the LINW terminal, from the external gate driver circuit. The control chip 4H is a circuit for applying the gate signal voltages to the respective gates of the semiconductor chips 4D to 4F.

A first voltage of the electrical signal provided to the HINU terminal (lead 2E), the HINV terminal (lead 2F), and the HINW terminal (lead 2G) is lower than a second voltage (source voltage VCC) applied by the first VCC terminal (lead 2D) to drive the control chip 4G. A first voltage of the electrical signal provided to the LINU terminal (lead 2I), the LINV terminal (lead 2J), and the LINW terminal (lead 2K) is lower than a second voltage (source voltage VCC) applied by the second VCC terminal (lead 2L) to drive the control chip 4H.

FIG. 19 illustrates an example of the configuration of the control chips 4G and 4H, for example for driving the switching arm 40U, in other words an example of the circuit in the control chips 4G and 4H (hereinafter, control circuit GDC) for controlling the switching arm 40U.

As shown in FIG. 19, the circuit in the control circuit GDC corresponding to the control chip 4G includes a resistance 461, a Schmitt trigger 462, a level shifter 463, a controller 464, a pulse generator 465, a level shifter 466, a filter circuit 467, an RS flip-flop circuit 468, and a driver 469, in this order from the input side (HINU terminal side) to the output side (U terminal side).

The resistance 461 pulls down the HINU terminal to the ground terminal. Accordingly, when the HINU terminal is open, an upper input signal HINU, representing the gate signal voltage inputted from the gate driver circuit to the HINU terminal, falls to a low level (logic level to turn off the semiconductor chip 4A), and therefore the semiconductor chip 4A is prevented from being unintentionally turned on.

The Schmitt trigger 462 transmits the upper input signal HINU inputted to the HINU terminal, to the level shifter 463. Here, a predetermined hysteresis is given to the threshold voltage of the Schmitt trigger 462. Such a configuration improves noise resistance.

The level shifter 463 shifts the level of the output signal of the Schmitt trigger 462 to an appropriate voltage level (VCC-GND) to be inputted to the controller 464, and outputs the shifted voltage. The controller 464 controls whether to transmit the output signal of the level shifter 463 to the pulse generator 465 (consequently, whether to drive the semiconductor chip 4A), on the basis of a fault signal inputted from a fault protection unit 480, or an external fault signal inputted from the FO terminal.

The pulse generator 465 generates pulse signals, such as an on-signal S_{ON} and an off-signal S_{OFF}, on the basis of the output signal of the controller 464. More specifically, the pulse generator 465 sets the on-signal S_{ON} to a high level for a predetermined on-period T_{ON1}, using the rising edge of the output signal of the controller 464 as the trigger, and sets the off-signal S_{OFF} to a high level for a predetermined on-period T_{ON2}, using the falling edge of the output signal of the controller 464 as the trigger. Here, the output signal of the controller 464 (based on the upper input signal HINU), the on-period T_{ON1}, and the on-period T_{ON2} are set such that both of the on-signal S_{ON} and the off-signal S_{OFF} do not rise to the high level at the same time. Therefore, provided that the semiconductor device A1 is normally operating, when at least one of the on-signal S_{ON} and the off-signal S_{OFF} is at the high level, the other is at the low level.

The level shifter 466 is located between a high-potential block including the filter circuit 467, the RS flip-flop circuit 468, and the driver 469, and a low-potential block including the pulse generator 465, to shift the signal level and transmit the shifted signal from the low-potential block to the high-potential block. More specifically, the level shifter 466 receives the pulse signals, namely the on-signal S_{ON} and the off-signal S_{OFF}, from the pulse generator 465 included in the low-potential block. The level shifter 466 shifts the level of these signals, and outputs the shifted signals to the filter circuit 467, as a first shifted signal and a second shifted signal. Here, the high-potential block operates between a boost voltage VBU applied to the VBU terminal, and a switch voltage VS applied to the U terminal.

The filter circuit 467 filtrates the first shifted signal and the second shifted signal inputted from the level shifter 466, and outputs the filtrated signals to the RS flip-flop circuit 468.

The RS flip-flop circuit 468 includes a set terminal (S terminal) to which the first shifted signal filtrated by the filter circuit 467 is inputted as a set signal S_{SET}, a reset terminal (R terminal) to which the second shifted signal filtrated by the filter circuit 467 is inputted as a reset signal S_{RESET}, and an output terminal (Q terminal) that outputs an output signal S_{Q}. The RS flip-flop circuit 468 sets the output signal S_{Q} to the high level, using the falling edge of the set signal S_{SET} as the trigger, and sets the output signal S_{Q} to the low level, using the falling edge of the reset signal S_{RESET} as the trigger. Here, the set signal S_{SET} and the reset signal S_{RESET} are both inputted from the level shifter 466.

The driver 469 generates an upper output signal HOU based on the output signal of the RS flip-flop circuit 468, and outputs the upper output signal HOU to the gate of the semiconductor chip 4A. Here, the high level of the upper output signal HOU corresponds to the boost voltage VBU, and the low level corresponds to the switch voltage VS.

The circuit in the control circuit GDC corresponding to the control chip 4H includes a resistance 471, a Schmitt trigger 472, a level shifter 473, a delay circuit 474, and a driver 475, in this order from the input side (LINU terminal side) to the output side (U terminal side). In this embodiment, the controller 464 of the control chip 4G is provided between the level shifter 473 and the delay circuit 474. Alternatively, the control chip 4H may include a controller, apart from the controller 464 of the control chip 4G. In this case, the controller of the control chip 4H may be provided between the delay circuit 474 and the driver 475 because, when a fault occurs, the semiconductor chip 4D can be more quickly turned off without the need to involve the delay circuit 474.

The resistance 471 pulls down the LINU terminal to the ground terminal. Accordingly, when the LINU terminal is open, a lower input signal LINU, representing the gate signal voltage inputted from the gate driver circuit, falls to the low level (logic level to turn off the semiconductor chip 4D), and therefore the semiconductor chip 4D is prevented from being unintentionally turned on.

The Schmitt trigger 472 transmits the lower input signal LINU inputted to the LINU terminal, to the level shifter 473. Here, a predetermined hysteresis is given to the threshold voltage of the Schmitt trigger 472. Such a configuration improves noise resistance.

The level shifter 473 shifts the level of the output signal of the Schmitt trigger 472 to an appropriate voltage level (VCC-GND) to be inputted to the controller 464, and outputs the shifted voltage.

The controller 464 controls whether to transmit the output signal of the delay circuit 474 to the driver 475 (consequently, whether to drive the semiconductor chip 4D), on the basis of a fault signal inputted from the fault protection unit 480, or an external fault signal inputted from the FO terminal.

The delay circuit 474 transmits the output signal of the controller 464 to the driver 475, giving a predetermined delay (corresponding to the circuit delay in the pulse generator 465, the level shifter 466, and the RS flip-flop circuit 468 of the control chip 4G) to the output signal.

The driver 475 outputs the lower output signal LOU to the gate of the semiconductor chip 4D, on the basis of the output signal of the controller 464, delayed by the delay circuit 474. Here, the high level of the lower output signal LOU corresponds to the source voltage VCC, and the low level corresponds to the ground voltage VGND.

The fault protection unit 480 includes a thermal shut down circuit (TSD circuit) 481, an under voltage lock out circuit (UVLO circuit) 482, a low-pass filter circuit 483, a current limiting circuit 484, a power fault protection circuit 485, a fault signal generation circuit 486, a transistor 487, a Schmitt trigger 488, and a level shifter 489.

The thermal shut down circuit 481 switches a thermal shut down signal from the logic level in the normal condition (e.g., low level) to the logic level in an abnormal condition (e.g., high level), when the junction temperature of the semiconductor device A1 exceeds a predetermined threshold.

The under voltage lock out circuit 482 switches a lock out signal from the logic level in the normal condition (e.g., low level) to the logic level in an abnormal condition (e.g., high level), when the source voltage VCC falls below a predetermined threshold voltage.

The low-pass filter circuit 483 is electrically connected to a detection terminal CIN. The low-pass filter circuit 483 outputs a detected voltage CIN to each of the current limiting circuit 484 and the power fault protection circuit 485.

The current limiting circuit 484 switches a current limiting signal from the logic level in the normal condition (e.g., low level) to the logic level in an abnormal condition (e.g., high level), when the detected voltage CIN exceeds a first threshold.

The power fault protection circuit 485 switches a power fault protection signal from the logic level in the normal condition (e.g., low level) to the logic level in an abnormal condition (e.g., high level), when the detected voltage CIN exceeds a second threshold. Here, an example of the second threshold is a higher voltage than the first threshold.

The fault signal generation circuit 486 monitors the thermal shut down signal inputted from the thermal shut down circuit 481, the lock out signal inputted from the under voltage lock out circuit 482, the current limiting signal inputted from the current limiting circuit 484, the power fault protection signal inputted from the power fault protection circuit 485, and the external fault signal inputted from the FO terminal. The fault signal generation circuit 486 switches a first fault signal from the logic level in the normal condition (e.g., low level) to the logic level in an abnormal condition (e.g., high level), when a fault occurs in the current limiting circuit 484. The fault signal generation circuit 486 switches a second fault signal from the logic level in the normal condition (e.g., low level) to the logic level in an abnormal condition (e.g., high level), when a fault occurs in at least one of thermal shut down circuit 481, the under voltage lock out circuit 482, and the power fault protection circuit 485, or when the external fault signal is inputted. The fault signal generation circuit 486 outputs the first fault signal and the second fault signal to the controller 464.

Upon receipt of the first fault signal, the controller 464 limits, for example, the current flowing to at least one of the semiconductor chip 4A and the semiconductor chip 4D. Upon receipt of the second fault signal, the controller 464 turns off both of the semiconductor chips 4A and 4D. The fault signal generation circuit 486 switches the first fault signal to the logic level in the abnormal condition, when the current limiting signal is inputted, and switches the second fault signal to the logic level in the abnormal condition, when one of the thermal shut down signal, the lock out signal, the power fault protection signal, and the external fault signal is inputted.

The transistor 487 forms an open drain output stage for outputting the external fault signal from the FO terminal. While the semiconductor device A1 is without a fault, the transistor 487 is turned off by the fault signal generation circuit 486, and the external fault signal is set to the high level. In contrast, when a fault occurs in the semiconductor device A1, the transistor 487 is turned on by the fault signal generation circuit 486, and the external fault signal is set to the low level.

The Schmitt trigger 488 transmits the external fault signal inputted to the FO terminal (e.g., external fault signal outputted from the FO terminal of another semiconductor device), to the level shifter 489. Here, a predetermined hysteresis is given to the threshold voltage of the Schmitt trigger 488. Such a configuration improves noise resistance.

The level shifter 489 shifts the level of the output signal of the Schmitt trigger 488 to an appropriate voltage level (VCC-GND) to be inputted to the controller 464, and outputs the shifted voltage.

A boot strap circuit 490U includes the diode 49U having the anode connected to the application terminal of the source voltage VCC via a resistance 491U, and a bootstrap capacitor 492U located between the cathode of the diode 49U and the source of the semiconductor chip 4A. The bootstrap capacitor 492U is electrically connected to the VBU terminal and the U terminal.

The boot strap circuit 490U generates a boost voltage VB (drive voltage for the high-potential block including the driver 469), at a connection node (U terminal) between the diode 49U and the bootstrap capacitor 492U. The resistance 491U limits the current supplied from an external power source to the diode 49U through the first VCC terminal. Thus, the charging current to the bootstrap capacitor 492U is limited.

When the semiconductor chip 4A is turned on and the semiconductor chip 4D is turned off, the current runs from the application terminal of the source voltage VCC, through the diode 49U, the bootstrap capacitor 4920, and the semiconductor chip 4D, when the switch voltage VS seen at the U terminal is set to the low level (GND). Accordingly, the bootstrap capacitor 492U provided between the VBU terminal and the U terminal is charged. At this point, the boost voltage VB (i.e., charging voltage for the bootstrap capacitor 492U) seen at the VBU terminal has a value obtained by subtracting a forward dropping voltage Vf of the diode 49U from the source voltage VCC (VCC−Vf).

In contrast, when the semiconductor chip 4A is turned on and the semiconductor chip 4D is turned off, with the bootstrap capacitor 492U being charged, the switch voltage VS is raised from the low level (GND) to the high level (HV). The boost voltage VB is raised to a value higher than the high level (HV) of the switch voltage VS, by an amount corresponding to the charging voltage (VCC−Vf) for the bootstrap capacitor 493U (i.e., HV+VCC−Vf). Employing thus the boost voltage VB as the drive voltage for the high-potential block (RS flip-flop circuit 468 and driver 469) and the level shifter 466 enables the on/off control (in particular, on control), in other words the switching control of the semiconductor chip 4A, to be performed.

### <Manufacturing Method of Semiconductor Device A1>

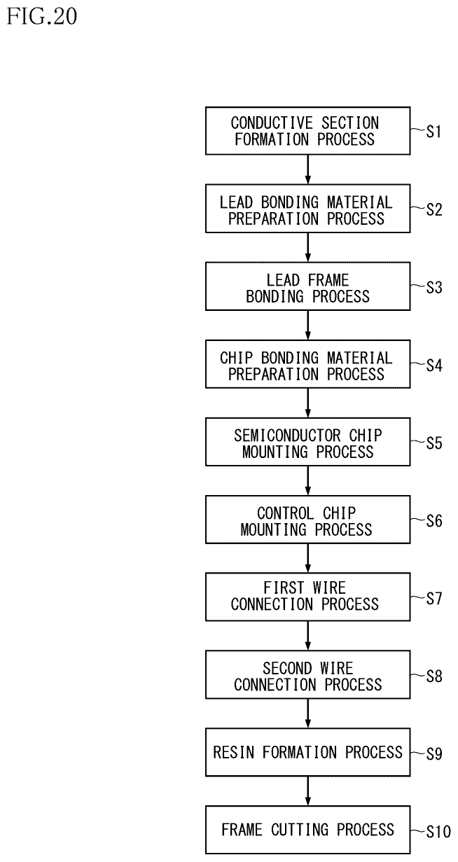

An example of the manufacturing method of the semiconductor device A1 will be described hereunder, with reference to FIG. 20 to FIG. 30. The manufacturing method described hereunder is merely an exemplary method to obtain the semiconductor device A1, and in no way intended to limit the present disclosure.

As shown in FIG. 20, the manufacturing method according to this embodiment includes a conductive section formation process (step S1), a lead bonding material preparation process (step S2), a lead frame bonding process (step S3), a chip bonding material preparation process (step S4), a semiconductor chip mounting process (step S5), a control chip mounting process (step S6), a first wire connection process (step S7), a second wire connection process (step S8), a resin formation process (step S9), and a frame cutting process (step S10).

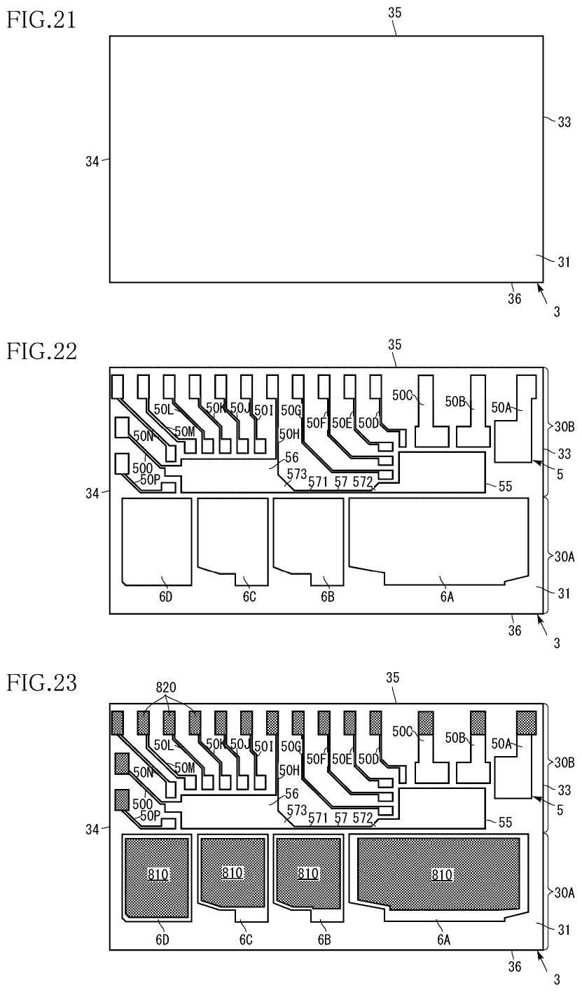

In the conductive section formation process (step S1), the substrate 3 is prepared as shown in FIG. 21. For example, a ceramic is employed to form the substrate 3. Then the conductive section 5 and the plurality of bonding sections 6 are formed on the first face 31 of the substrate 3, as shown in FIG. 22. In this embodiment, the conductive section 5 and the plurality of bonding sections 6 are collectively formed. For example, the conductive section 5 and the plurality of bonding sections 6, containing a conductive material, for example a metal such as silver (Ag), can be obtained by printing a metal paste and then sintering the metal paste.

In the lead bonding material preparation process (step S2), a bonding paste 810 and a conductive bonding paste 820 are printed on the conductive section 5 and the plurality of bonding sections 6, as shown in FIG. 23. The bonding paste 810 and the conductive bonding paste 820 are, for example, Ag paste or solder paste.

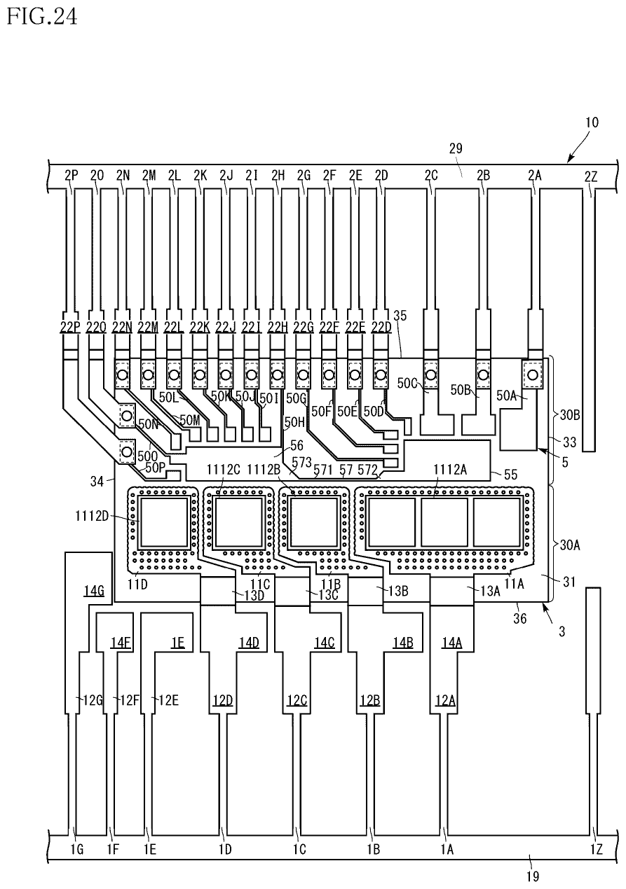

In the lead frame bonding process (step S3), the lead frame 10 is prepared as shown in FIG. 24. The lead frame 10 includes the plurality of leads 1 and the plurality of leads 2, and also a frame 19 and a frame 29. The frame 19 is connected to the plurality of leads 1, to support the leads 1. The frame 29 is connected to the plurality of leads 2, to support the leads 2. The shape of the lead frame 10 is by no means limited. Then the plurality of leads 1 are made to oppose the plurality of bonding regions 6, via the bonding paste 810. In addition, the plurality of leads 2 are made to oppose the conductive section 5, via the conductive bonding paste 820. For example, by heating the bonding paste 810 and the conductive bonding paste 820 and then cooling these pastes, the bonding material 81 is formed from the bonding paste 810, and the conductive bonding material 82 is formed from the conductive bonding paste 820. Thus, the plurality of leads 1 are bonded to the plurality of bonding sections 6 via the bonding material 81, and the plurality of leads 2 are bonded to the conductive section 5 via the conductive bonding material 82.

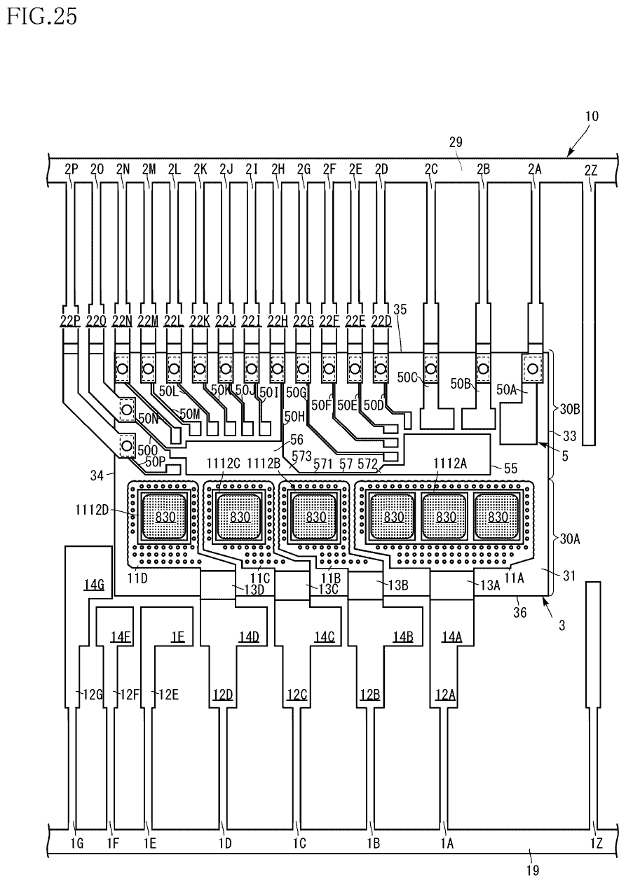

In the chip bonding material preparation process (step S4), a conductive bonding paste 830 is printed on the main surface 111A of the first portion 11A, the main surface 111B of the first portion 11B, the main surface 111C of the first portion 11C, and the main surface 111D of the first portion 11D, for example as shown in FIG. 25. The conductive bonding paste 830 is, for example, Ag paste or solder paste.

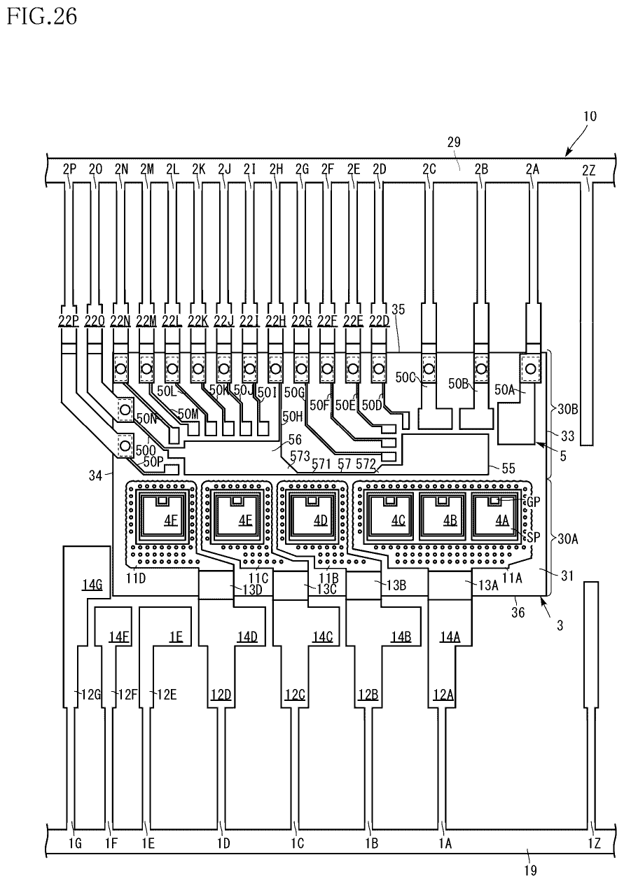

In the semiconductor chip mounting process (step S5), the semiconductor chips 4A to 4F are each stuck to the conductive bonding paste 830, as shown in FIG. 26. Then the conductive bonding material 83 is formed from the conductive bonding paste 830, for example by heating the conductive bonding paste 830 and then cooling the same. Thus, the semiconductor chips 4A to 4F are each bonded to the corresponding one of the first portions 11A to 11D, via the conductive bonding material 83.

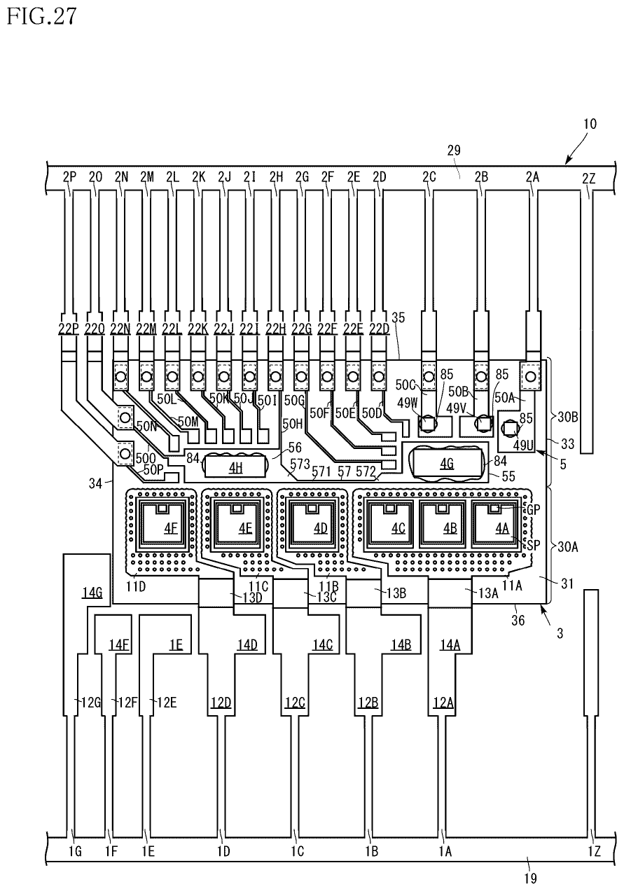

In the control chip mounting process (step S6), a paste containing a metal is printed on the first base portion 55 and the second base portion 56 of the conductive section 5, as shown in FIG. 27. The mentioned paste may be, for example, Ag paste or solder paste. Then the control chip 4G and the control chip 4H are each stuck to the paste. Then the control chip 4G and the control chip 4H are respectively bonded to the first base portion 55 and the second base portion 56 via the conductive bonding material 84, for example by heating the paste and then cooling the same. In addition, through a similar process, the diodes 49U, 49V, and 49W are respectively bonded to the wirings 50A, 50B, and 50C, via the conductive bonding material 85.

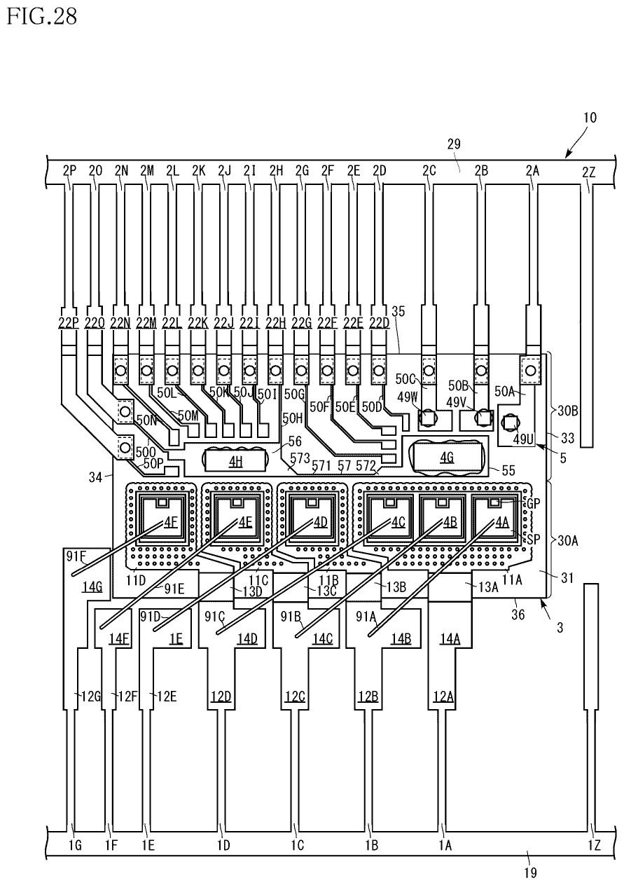

In the first wire connection process (step S7), the first wires 91A to 91F are attached as shown in FIG. 28. In the illustrated example, wires formed of aluminum (Al) are sequentially attached, for example by a wedge bonding method. Thus, the first wires 91A to 91F can be obtained.

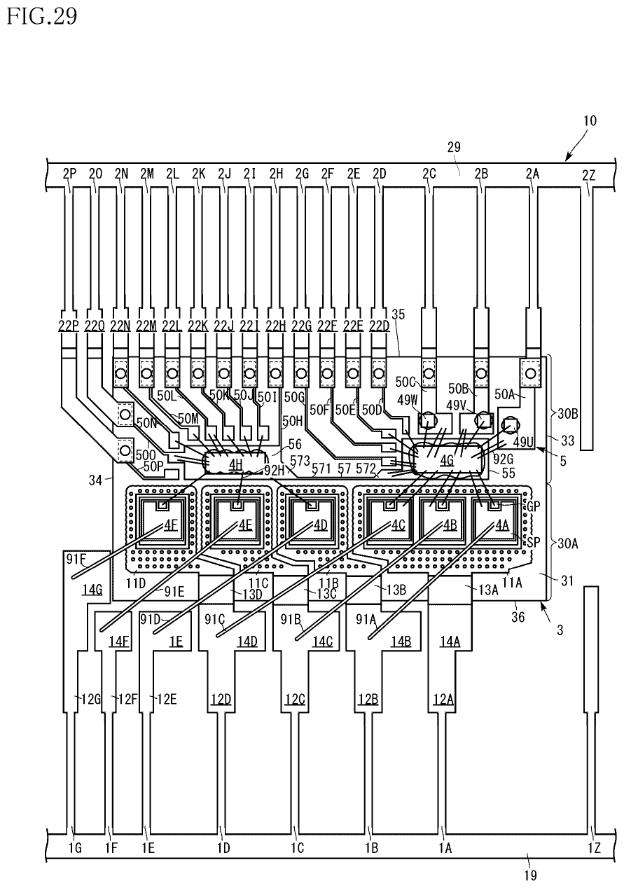

In the second wire connection process (step S8), the plurality of second wires 92 are attached as shown in FIG. 29. In the illustrated example, wires formed of gold (Au) are sequentially attached, for example by a capillary bonding method. Thus, the plurality of second wires 92 can be obtained.

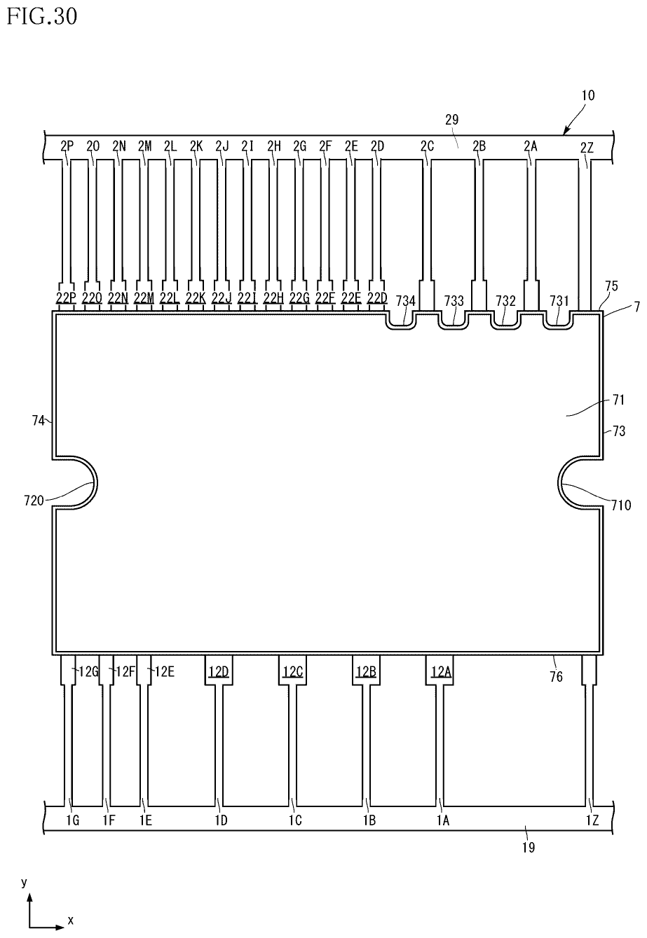

In the resin formation process (step S9), for example a part of the lead frame 10, a part of the substrate 3, the semiconductor chips 4A to 4F, the control chips 4G and 4H, the diodes 49U, 49V, and 49W, the first wires 91A to 91F, and the plurality of second wires 92 are enclosed by a mold, as shown in FIG. 30. Then a resin material of a liquid phase is loaded in the space defined by the mold. Upon curing the resin material, the resin 7 can be obtained.

In the frame cutting process (step S10), portions of the lead frame 10 exposed from the resin 7 are cut, at predetermined positions. Therefore, the plurality of leads 1 and the plurality of leads 2 separated from each other. Then upon bending the plurality of leads 1 and the plurality of leads 2 if need be, the semiconductor device A1 can be obtained.

Advantageous effects of the semiconductor device A1 will now be described hereunder.

According to this embodiment, the control chips 4G and 4H are located on the conductive section 5 formed on the substrate 3. Utilizing the conductive section 5 as the conduction path to the control chips 4G and 4H allows the conduction path to be formed in a finer size and in higher density, compared with the case of employing a metal lead to form the conduction path. Therefore, the level of integration of the semiconductor device A1 can be upgraded. In addition, employing the leads 1A to 1D, which exhibit higher heat dissipation performance than the substrate 3, prevents degradation in heat dissipation performance of the semiconductor chips 4A to 4F, which may be incurred in the case of employing the substrate 3.

The bonding sections 6A to 6D are formed on the substrate 3, and the leads 1A to 1D are bonded to the substrate 3 via the bonding sections 6A to 6D. The surface of the bonding sections 6A to 6D can be finished to be smoother, compared with the surface roughness of the main surface 31 of the substrate 3, for example formed of a ceramic. Such a configuration prevents undesired appearance of a minute void in the heat conduction path from the leads 1A to 1D to the substrate 3, thereby further improving the heat dissipation performance of the semiconductor chips 4A to 4F.

Since the leads 1A to 1D are exposed from the resin 7, conduction paths from outside to the semiconductor chips 4A to 4F can be provided, and the semiconductor chips 4A to 4F can attain a higher level of heat dissipation characteristics.

The second face 32 of the substrate 3 is exposed from the resin 7. Therefore, the heat transmitted from the semiconductor chips 4A to 4F to the substrate 3 can be more efficiently released to outside.

Since the conductive section 5 and the bonding sections 6A to 6D contain the same conductive material, the conductive section 5 and the bonding sections 6A to 6D can be collectively formed on the substrate 3. Such a configuration contributes to improving the manufacturing efficiency of the semiconductor device A1.

The plurality of leads 2 are bonded to the conductive section 5 via the conductive bonding material 82. Accordingly, the plurality of leads 2 can be more firmly fixed to the substrate 3. Further, the resistance between the plurality of leads 2 and the conductive section 5 can be reduced.

As shown in FIG. 15 and FIG. 16, the clearances G23 between the adjacent ones of the leads 2D to 2N are narrower than the clearance G54 between the adjacent ones of the second portions 52D to 52N shown in FIG. 16. Therefore, the leads 2D to 2N can be located closer to each other.

The first portion 21A to the first portion 21N of the lead 2A to 2N have a rectangular shape, with the longer sides extending along the y-direction. Therefore, the clearances G21, G22, and G23 between the adjacent ones of the leads 2A to 2N can be narrowed, while an increased bonding area of the leads 2A to 2N can be secured.

The first portions 21O and 21P of the leads 2O, 2P are aligned in the y-direction, so as to overlap with the first portion 21N as viewed in the y-direction. Such a configuration allows a sufficient number of leads 2 to be secured, and yet prevents an increase in size of the substrate 3.

The control chips 4G and 4H are located between the semiconductor chips 4A to 4F and the plurality of leads 2, as viewed in the x-direction. Accordingly, the plurality of leads 2, electrically connected to the control chips 4G and 4H via the conductive section 5, can be spaced apart from the semiconductor chips 4A to 4F, to insulate the plurality of leads 2 from the semiconductor chips 4A to 4F.

The semiconductor chips 4A to 4C are directly bonded to the lead 1A via the conductive bonding material 83, the semiconductor chip 4D is directly bonded to the lead 1B via the conductive bonding material 83, the semiconductor chip 4E is directly bonded to the lead 1C via the conductive bonding material 83, and the semiconductor chip 4F is directly bonded to the lead 1D via the conductive bonding material 83. Therefore, the semiconductor chips 4A to 4F can each be electrically connected to the corresponding one of the leads 1A to 1D, and the heat of the semiconductor chips 4A to 4F can be more efficiently conducted to the leads 1A to 1D.

The semiconductor chip 4A is connected to the lead 1B via the first wire 91A. The semiconductor chip 4B is connected to the lead 1C via the first wire 91B. The semiconductor chip 4C is connected to the lead 1D via the first wire 91C. The semiconductor chip 4D is connected to the lead 1E via the first wire 91D. The semiconductor chip 4E is connected to the lead 1F via the first wire 91A. The semiconductor chip 4F is connected to the lead 1G via the first wire 91A. Such a configuration suppresses an increase in resistance, in each of the conduction paths between the leads 1B to 1G and the semiconductor chips 4A to 4F spaced therefrom.

The control chips 4G and 4H are bonded to the conductive section 5 formed on the substrate 3, via the conductive bonding material 84. Therefore, the control chips 4G and 4H can be electrically connected to the conductive section 5.

The control chip 4G is connected to the conductive section 5 via the second wire 92G, and the control chip 4H is connected to the conductive section 5 via the second wire 92H. Such a configuration allows the control chips 4G and 4H to be electrically connected to the respective portions of the conductive section 5 spaced apart from the control chips 4G and 4H.

In the case of selecting a ceramic such as alumina (A₂O₃), silicon nitride (SiN), aluminum nitride (AlN), or alumina containing zirconia, to form the substrate 3, and forming the substrate 3 in a thickness of, for example, approximately 0.1 mm to 1.0 mm, the conductive section 5 and the bonding section 6 can be seen through the substrate 3, from the side of the second face 32 of the substrate 3. Therefore, after the manufacturing of the semiconductor device A1, whether the conductive section 5 or the bonding sections 6 have been unintentionally formed in an irregular shape can be visually checked from outside, without the need to disassemble the semiconductor device. Here, the material and the thickness of the substrate 3 may be selected as desired without limitation to the above, provided that the shape of at least a part of the conductive section 5 can be visually checked from outside.

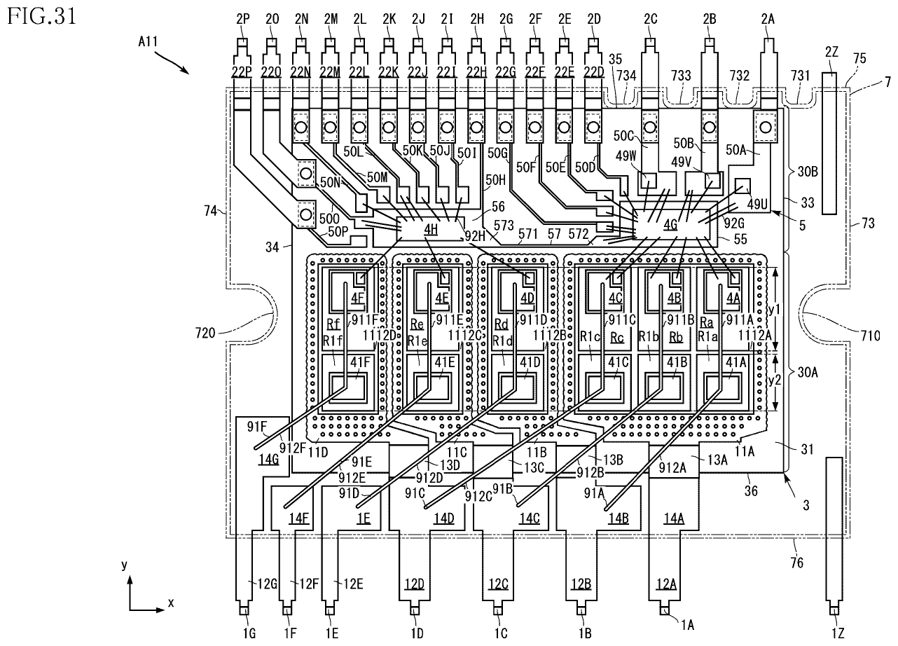

FIG. 31 and the subsequent drawings illustrate variations and other embodiments of the present disclosure. In these drawings, elements that are the same as or similar to those of the foregoing embodiment are given the same numeral as in the mentioned embodiment.

### <First Variation of First Embodiment>

FIG. 31 illustrates a first variation of the semiconductor device A1. A semiconductor device A11 according to this variation is different from the foregoing embodiment, in the configuration of the semiconductor chips 4A to 4F. In addition, the semiconductor device A11 includes diodes 41A to 41F.

### <Semiconductor Chips 4A to 4F>

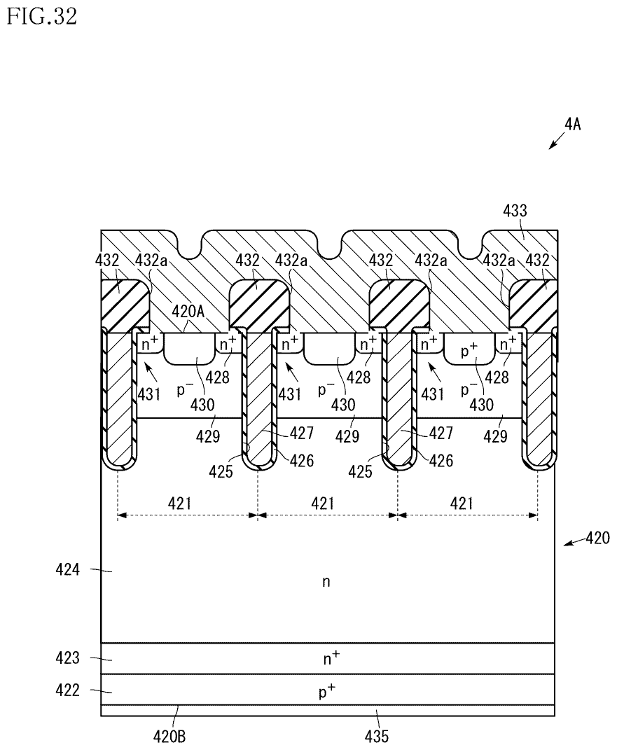

In this variation, the semiconductor chips 4A to 4F are a transistor configured as an IGBT. FIG. 32 illustrates an example of the detailed configuration of the semiconductor chip 4A. The semiconductor chips 4A to 4F have the same configuration as each other. Therefore, the configuration of the semiconductor chip 4A will be described hereunder, and the description of the remaining semiconductor chips 4B to 4F will be omitted. The configuration of the semiconductor chips 4A to 4F is not limited to the example shown in FIG. 32, but may be modified in various manners.

The semiconductor chip 4A according to this variation is a trench gate-type IGBT. The semiconductor chip 4A includes an n-type semiconductor substrate 420. The semiconductor substrate 420 is for example a silicon substrate, and includes a front surface 420A and a back surface 420B on the opposite side of the front surface 420A. A unit cell 421, constituting a part of the semiconductor chip 4A, is fabricated on the front surface region of the semiconductor substrate 420.

The semiconductor substrate 420 includes a P⁺-type collector region 422, an n⁺-type buffer region 423, and an n-type drift region 424, in this order from the side of the back surface 420B. The collector region 422 and the buffer region 423 are formed in the back surface region of the semiconductor substrate 420. The collector region 422 is exposed from the back surface 420B of the semiconductor substrate 420. The collector region 422 contains boron (B) as the p-type impurity. The buffer region 423 is formed on the collector region 422, in contact therewith. The drift region 424 is formed from a part of the semiconductor substrate 420. A part of the drift region 424 is exposed from the front surface 420A of the semiconductor substrate 420 (not shown). The buffer region 423 and the drift region 424 each contain one of phosphor (P), arsenic (As), and antimony (Sb), as the n-type impurity.

A plurality of gate trenches 425 are formed in the front surface region of the semiconductor substrate 420, at predetermined intervals between each other. The gate trenches 425 are each formed so as to penetrate through a base region 429, and include a bottom portion located in the drift region 424. A gate electrode 427 is filled in each of the gate trenches 425, via a gate insulation film 426. On the lateral faces of the plurality of gate trenches 425, an n⁺-type emitter region 428, the p⁻-type base region 429, and the drift region 424 are formed in this order, from the side of the front surface 420A toward the back surface 420B of the semiconductor substrate 420.

The base region 429 is shared by one of the gate trenches 425 and another gate trench 425. The emitter region 428 is formed along the lateral face on one side and the opposite side of each gate trench 425, so as to be exposed from the front surface 420A of the semiconductor substrate 420. The emitter region 428 contains one of phosphor (P), arsenic (As), and antimony (Sb), as the n-type impurity. A p⁺-type contact region 430 is formed in the front surface region of the base region 429, so as to be interposed between the emitter regions 428. The base region 429 and the contact region 430 contain boron (B), as the p-type impurity.

A region in the base region 429 between the emitter region 428 and the drift region 424 serves as a channel region 431, so that a plurality of unit cells 421, constituting a part of the semiconductor chip 4A, are formed. The unit cell 421 is defined as a region between the center line of one gate trench 425 and the center line of another gate trench 425.

An insulation film 432, for example formed of silicon dioxide (SiO₂), is provided on the front surface 420A of the semiconductor substrate 420, so as to cover the gate trench 425. The insulation film 432 includes a contact hole 432a for exposing a part of the emitter region 428, and the contact region 430. An emitter electrode 433, for example formed of Ti/TiN, is provided on the insulation film 432. The emitter electrode 433 enters into the contact hole 432a from the insulation film 432, to be electrically connected to the emitter region 428 and the contact region 430, inside the contact hole 432a.

A collector electrode 435, for example formed of aluminum (AlSiCu, AlCu, or the like), is provided on the side of the back surface 420B of the semiconductor substrate 420. The collector electrode 435 is electrically connected to the collector region 422.

### <Diodes 41A to 41F>

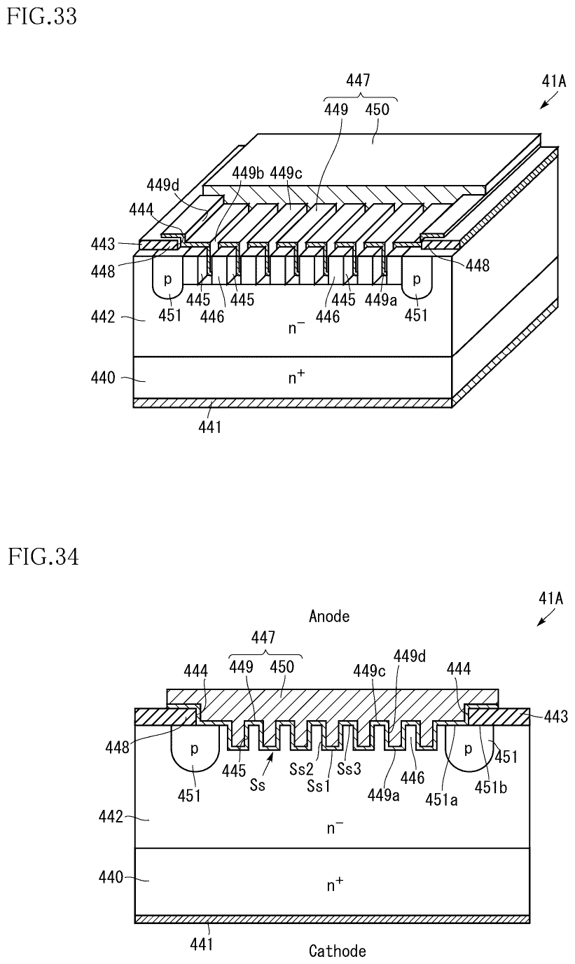

Referring to FIG. 33 and FIG. 34, an example of the detailed configuration of the diodes 41A to 41F will be described. The diodes 41A to 46F have the same configuration as each other. Therefore, the configuration of the diode 46A will be described hereunder, and the description of the remaining diodes 46B to 46F will be omitted. The configuration of the diodes 41A to 46F is not limited to the example shown in FIG. 33 and FIG. 34, but may be modified in various manners.

The diode 41A includes an n⁺-type silicon substrate 440 (with n-type impurity concentration of, for example, 1e18 to 1e21 cm⁻³). A cathode electrode 441 is formed so as to cover the entirety of the back surface of the silicon substrate 440. The cathode electrode 441 is formed of a metal that makes an ohmic contact with n-type silicon (e.g., gold (Au), nickel (Ni), silicide, or cobalt (Co) silicide).

An n⁻-type epitaxial layer 442 (semiconductor layer), lower in concentration than the silicon substrate 440 (with n-type impurity concentration of, for example, 1e15 to 1e17 cm⁻³), is stacked on the surface of the silicon substrate 440. The thickness of the epitaxial layer 442 is, for example, 2 μm to 20 μm.

A field insulation film 443, for example formed of silicon dioxide (SiO₂), is stacked on the surface of the epitaxial layer 442. The thickness of the field insulation film 443 is, for example, equal to or thicker than 1000 Å, preferably 7000 Å to 40000 Å. Here the, field insulation film 443 may be formed of other insulative materials, such as silicon nitride (SiN).

The field insulation film 443 includes an opening 444, in which the central region of the epitaxial layer 442 is exposed. A plurality of trenches 445 are formed in the superficial portion of the central region of the epitaxial layer 442, so as to recede from the surface of the epitaxial layer 442. Each of the trenches 445 is a vertical groove extending in a predetermined direction. The bottom face of the trench 445 is planar, along the surface of the epitaxial layer 442. Accordingly, the cross-section of the trench 445 has a generally rectangular shape. In this embodiment, seven trenches 445 extend in parallel, at predetermined intervals. In other words, the seven trenches 445 are formed in a stripe pattern, in a plan view.

In the superficial portion of the epitaxial layer 442, a mesa portion 446 is formed in a region between the trenches 445 adjacent to each other. When the trench 445 has a cross-section of a generally rectangular shape, accordingly the mesa portion 446 also has a cross-section of a generally rectangular shape. The mesa portions 446 each include a pair of side walls (side walls of the trench 445) erected generally vertically from the end of the respective bottom faces of two trenches 445 adjacent to each other, and a top face (surface of the epitaxial layer 442) connecting the pair of side walls.

An anode electrode 447 is formed on the epitaxial layer 442. The anode electrode 447 is completely filled in the opening 444 of the field insulation film 443, and protrudes outwardly from the opening 444, so as to cover the peripheral edge 448 of the opening 444 in the field insulation film 443. In other words, the peripheral edge 448 of the field insulation film 443 is interposed between the epitaxial layer 442 and the anode electrode 447 from the upper and lower sides, along the entire circumference. The protruding range of the anode electrode 447, covering the peripheral edge 448 of the field insulation film 443, from the end portion of the opening 444 of the field insulation film 443 is, for example, equal to or wider than 10 μm, preferably 10 μm to 100 μm.

The anode electrode 447 has a multilayer structure (in this embodiment, two-layer structure), including a Schottky metal 449 bonded to the epitaxial layer 442 in the opening 444 of the field insulation film 443, and a contact metal 450 stacked on the Schottky metal 449.

The Schottky metal 449 is formed of a metal that forms a Schottky junction upon being bonded to an N-type silicon (e.g., titanium (Ti), molybdenum (Mo), palladium (Pd), and so forth). The Schottky metal 449 according to this embodiment is formed of titanium. The Schottky metal 449 is formed in contact with the surface of the epitaxial layer 442, including the inner wall (bottom face and a pair of side walls) of the trench 445. Accordingly, the Schottky metal 449 is in contact with the surface of the epitaxial layer 442, along the inner wall of all the trenches 445, and outside the trenches 445. In addition, the Schottky metal 449 covers the entirety of the inner wall of each of the trenches 445, and continuously extends outwardly of the trench 445. Thus, the Schottky metal 449 is bonded to the surface of the epitaxial layer 442 exposed in the opening 444 of the field insulation film 443, so as to cover the entirety of the mentioned surface. The Schottky metal 449 according to this embodiment includes bottom faces 449a each formed in contact with the bottom face of the trench 445, side faces 449b each formed in contact with the side wall of the trench 445 (side wall of the mesa portion 446), and top faces 449c each formed in contact with the top face of the mesa portion 446.

In this case, as indicated by bold lines in FIG. 34, the interface S between the Schottky metal 449 and the surface of the epitaxial layer 442 (Schottky interface) has an uneven cross-section, inside the opening 444 of the field insulation film 443. Accordingly, the area of the Schottky interface Ss is larger than the apparent area of the epitaxial layer 442, in a plan view of the surface of the epitaxial layer 442 (horizontal portion in FIG. 34) along the normal direction thereof. More specifically, the Schottky interface Ss includes bottom faces Ss1 each formed in contact with the bottom face of the trench 445, side faces Ss2 each formed in contact with the side wall of the trench 445 (side wall of the mesa portion 446), and top faces Ss3 each formed in contact with the top face of the mesa portion 446. When the trenches 445 each have a generally rectangular shape, the area of the Schottky interface Ss can be increased by an amount corresponding to the side faces Ss2, compared with the case where the trenches 445 are not provided.

The Schottky metal 449 bonded to the epitaxial layer 442 forms a Schottky barrier (potential barrier) of 0.52 eV to 0.9 eV for example, against the silicon semiconductor constituting the epitaxial layer 442. The thickness of the Schottky metal 449 according to this embodiment is 0.02 μm to 0.2 μm.

The contact metal 450 is a portion of the anode electrode 447 exposed on the outermost surface of the diode 41A, to which the first wire 91A is connected. In other words, the contact metal 450 serves as the anode electrode pad of the diode 41A. The contact metal 450 is, for example, formed of aluminum (Al). In this embodiment, the thickness of the contact metal 450 is, for example, 0.5 μm to 5 μm. The contact metal 450 is filled in each of the trenches 445, in contact with the Schottky metal 449 covering the inner wall of the trenches 445. Thus, the contact metal 450 is in contact with the bottom face 449a, the pair of side faces 449b, and the top face 449c of the Schottky metal 449. Accordingly, the contact metal 450 is formed so as to have an uneven cross-section, on the side in contact with the Schottky metal 449 in the trenches 445. The surface of the contact metal 450 on the opposite side of the Schottky metal 449 is formed in a planar shape, along the surface of the epitaxial layer 442 (except the inner wall of the trenches 445).

When the Schottky metal 449 is formed of titanium, it is preferable that a titanium nitride (TiN) layer is interposed between the Schottky metal 449 and the contact metal 450, which is formed of aluminum. The titanium nitride layer serves as a barrier layer that bonds the titanium of the Schottky metal 449 and the aluminum of the contact metal 450 together, and secures conduction between the titanium and the aluminum, and further suppresses mutual diffusion of the titanium and the aluminum. The barrier layer suppresses or prevents the diffusion of the material of the contact metal 450 to the Schottky metal 449, to thereby protect the Schottky interface Ss.

A surface cover film (not shown) may be formed on the outermost surface of the diode 41A. In this case, it is preferable to form an opening for exposing the contact metal 450, at a central region of the surface cover film. The first wire 91A is connected to the contact metal 450, through this opening.

A guard ring 451, formed of a p-type diffusion layer, is provided in the superficial portion of the epitaxial layer 442, in contact with the Schottky metal 449. The guard ring 451 is formed along the contour of the opening 444 of f the field insulation film 443, so as to cover both the outer and inner sides of the opening 444, in a plan view. Accordingly, the guard ring 451 includes an inner portion 451a extending inwardly of the opening 444 of the field insulation film 443, and contacting an outer edge 449d, corresponding to the extremity of the portion of the Schottky metal 449 located inside the opening 444, and an outer portion 451b extending outwardly of the opening 444, and opposed to the anode electrode 447 (Schottky metal 449 on the peripheral edge 448), via the peripheral edge 448 of the field insulation film 443. The depth of the guard ring 451 from the surface of the epitaxial layer 442 is, for example, 0.5 μm to 8 μm.

The guard ring 451, formed over the outer and inner sides of the opening 444 of the field insulation film 443, covers the boundary between the peripheral edge 448 of the field insulation film 443 and the Schottky metal 449, from the side of the epitaxial layer 442. Without the guard ring 451, the electric field concentrates at the boundary when a reverse bias is applied to the diode 41A, and therefore leakage is prone to be incurred. Because of the presence of the guard ring 451 covering the mentioned boundary in the diode 41A, the depletion layer spreading from the guard ring 451 when the reverse bias is applied mitigates the concentration of the electric field, to thereby suppress the leakage. Consequently, the withstand voltage of the diode 41A is improved.

In this variation, as shown in FIG. 31, the main surface 111A includes three first regions Ra, Rb, and Rc, and three second regions R1a, R1b, and R1c, defined by the groove 1112A. The three first regions Ra, Rb, and Rc are located on the side of the lead 2, in the y-direction. The shape of the three first regions Ra, Rb, and Rc is not specifically limited. In the illustrated example, the mentioned regions have an elongate rectangular shape having the long sides extending along the y-direction, as viewed in the z-direction. The three first regions Ra, Rb, and Rc overlap with each other as viewed in the x-direction. In the illustrated example, further, the three first regions Ra, Rb, and Rc generally coincide with each other, as viewed in the x-direction. Here, the expression “generally coincide” as viewed in the x-direction refers to, for example, exactly coinciding with each other, or being deviated by within ±5% of the characteristic size (size of the first region Ra, Rb, or Rc in the y-direction).

The second regions R1a, R1b, and R1c are located on the opposite side of the lead 2 with respect to the first regions Ra, Rb, and Rc, in the y-direction. The shape of the three second regions R1a, R1b, and R1c is not specifically limited. In the illustrated example, the mentioned regions have a rectangular shape, as viewed in the z-direction. The three second regions R1a, R1b, and R1c overlap with each other, as viewed in the x-direction. In the illustrated example, further, the three second regions R1a, R1b, and R1c generally coincide with each other, as viewed in the x-direction. Here, the expression “generally coincide” as viewed in the x-direction refers to, for example, exactly coinciding with each other, or being deviated by within ±5% of the characteristic size (size of the second region R1a, R1b, or R1c in the y-direction).

The sizes of the three first regions Ra, Rb, and Rc, and the three second regions R1a, R1b, and R1c, are not specifically limited. In the illustrated example, a size y1 of the first regions Ra, Rb, and Rc in the y-direction is larger than a size y2 of the second regions R1a, R1b, and R1c in the y-direction.

The main surface 111B includes a first region Rd and a second region R1d, defined by the groove 1112B. The first region Rd is located on the side of the lead 2, in the y-direction. The shape of the first region Rd is not specifically limited. In the illustrated example, the first region Rd has an elongate rectangular shape having the long sides extending along the y-direction, as viewed in the z-direction. The second region R1d is located on the opposite side of the lead 2 with respect to the first region Rd, in the y-direction. The shape of the second region R1d is not specifically limited. In the illustrated example, the second region R1d has a rectangular shape, as viewed in the z-direction.

The main surface 111C includes a first region Re and a second region R1e, defined by the groove 1112C. The first region Re is located on the side of the lead 2, in the y-direction. The shape of the first region Re is not specifically limited. In the illustrated example, the first region Re has an elongate rectangular shape having the long sides extending along the y-direction, as viewed in the z-direction. The second region R1e is located on the opposite side of the lead 2 with respect to the first region Re, in the y-direction. The shape of the second region R1e is not specifically limited. In the illustrated example, the second region R1e has a rectangular shape, as viewed in the z-direction.

The main surface 111D includes a first region Rf and a second region R1f, defined by the groove 1112D. The first region Rf is located on the side of the lead 2, in the y-direction. The shape of the first region Rf is not specifically limited. In the illustrated example, the first region Rf has an elongate rectangular shape having the long sides extending along the y-direction, as viewed in the z-direction. The second region R1f is located on the opposite side of the lead 2 with respect to the first region Rf, in the y-direction. The shape of the second region R1f is not specifically limited. In the illustrated example, the second region Rif has a rectangular shape, as viewed in the z-direction.

The three first regions Rd, Re, and Rf overlap with each other, as viewed in the x-direction. In addition, in the illustrated example, the three first regions Rd, Re, and Rf generally coincide with each other, as viewed in the x-direction. Here, the expression “generally coincide” as viewed in the x-direction refers to, for example, exactly coinciding with each other, or being deviated by within ±5% of the characteristic size (size of the first region Rd, Re, or Rf in the y-direction). The three second regions R1d, R1e, and Rif overlap with each other, as viewed in the x-direction. In the illustrated example, further, the three second regions R1d, R1e, and Rif generally coincide with each other, as viewed in the x-direction. Here, the expression “generally coincide” as viewed in the x-direction refers to, for example, exactly coinciding with each other, or being deviated by within ±5% of the characteristic size (size of the second region R1d, R1e, or Rif in the y-direction).

The sizes of the three first regions Rd, Re, and Rf and the three second regions R1d, R1e, and R1f are not specifically limited. In the illustrated example, the size y1 of the first regions Rd, Re, and Rf in the y-direction is larger than the size y2 of the second regions R1d, R1e, and Rif in the y-direction.

In this variation, the semiconductor chip 4A is located on the first region Ra. The semiconductor chip 4B is located on the first region Rb. The semiconductor chip 4C is located on the first region Rc. The diode 41A is mounted on the second region R1a. The diode 41B is mounted on the second region Rib. The diode 41C is mounted on the second region R1c. In the illustrated example, the semiconductor chip 4A is mounted at a position on the side of the lead 2, with respect to the center of the first region Ra in the y-direction. The semiconductor chip 4B is mounted at a position on the side of the lead 2, with respect to the center of the first region Rb in the y-direction. The semiconductor chip 4C is mounted at a position on the side of the lead 2, with respect to the center of the first region Rc in the y-direction. The diode 41A is mounted at a position on the opposite side of the lead 2, with respect to the center of the second region R1a in the y-direction. The diode 41B is mounted at a position on the opposite side of the lead 2, with respect to the center of the second region Rib in the y-direction. The diode 41C is mounted at a position on the opposite side of the lead 2, with respect to the center of the second region R1c in the y-direction.

The collector electrode of the semiconductor chip 4A and the cathode electrode of the diode 41A are connected to each other, via the first portion 11A and the conductive bonding material 83. The collector electrode of the semiconductor chip 4B and the cathode electrode of the diode 41B are connected to each other, via the first portion 11A and the conductive bonding material 83. The collector electrode of the semiconductor chip 4C and the cathode electrode of the diode 41C are connected to each other, via the first portion 11A and the conductive bonding material 83.

In this variation, the first wire 91A includes a first portion 911A and a second portion 912A, each of which will be described hereunder. An end of the first portion 911A is connected to the emitter electrode of the semiconductor chip 4A, and the other end is connected to the anode electrode of the diode 41A. In the illustrated example, the first portion 911A extends along the y-direction. An end of the second portion 912A is connected to the anode electrode of the diode 41A, and the other end is connected to the fourth portion 14B of the lead 1B. In the illustrated example, the second portion 912A is inclined with respect to the x-direction and the y-direction.

In this variation, the first wire 91B includes a first portion 911B and a second portion 912B, each of which will be described hereunder. An end of the first f portion 911B is connected to the emitter electrode of the semiconductor chip 4B, and the other end is connected to the anode electrode of the diode 41B. In the illustrated example, the first portion 911B extends along the y-direction. An end of the second portion 912B is connected to the anode electrode of the diode 41B, and the other end is connected to the fourth portion 14C of the lead 1C. In the illustrated example, the second portion 912B is inclined with respect to the x-direction and the y-direction.

In this variation, the first wire 91C includes a first portion 911C and a second portion 912C, each of which will be described hereunder. An end of the first portion 911C is connected to the emitter electrode of the semiconductor chip 4C, and the other end is connected to the anode electrode of the diode 41C. In the illustrated example, the first portion 911C extends along the y-direction. An end of the second portion 912C is connected to the anode electrode of the diode 41C, and the other end is connected to the fourth portion 14D of the lead 1D. In the illustrated example, the second portion 912C is inclined with respect to the x-direction and the y-direction.

In this variation, the gate electrode of the semiconductor chip 4A and the control chip 4G are connected via the second wire 92G, and the emitter electrode of the semiconductor chip 4A and the control chip 4G are connected via the second wire 92G.

In this variation, the gate electrode of the semiconductor chip 4B and the control chip 4G are connected via the second wire 92G, and the emitter electrode of the semiconductor chip 4B and the control chip 4G are connected via the second wire 92G.

In this variation, the gate electrode of the semiconductor chip 4C and the control chip 4G are connected via the second wire 92GG, and the emitter electrode of the semiconductor chip 4C and the control chip 4G are connected via the second wire 92.

In this variation, the gate electrode of the semiconductor chip 4D and the control chip 4H are connected via the second wire 92H. The gate electrode of the semiconductor chip 4E and the control chip 4H are connected via the second wire 92H. The gate electrode of the semiconductor chip 4F and the control chip 4H are connected via the second wire 92H.

The collector electrode of the semiconductor chip 4D and the cathode electrode of the diode 41D are connected to each other, via the first portion 11B and the conductive bonding material 83. The collector electrode of the semiconductor chip 4E and the cathode electrode of the diode 41E are connected to each other, via the first portion 11C and the conductive bonding material 83. The collector electrode of the semiconductor chip 4F and the cathode electrode of the diode 41F are connected to each other, via the first portion 11D and the conductive bonding material 83.

In this variation, the first wire 91D includes a first portion 911D and a second portion 912D, each of which will be described hereunder. An end of the first portion 911D is connected to the emitter electrode of the semiconductor chip 4D, and the other end is connected to the anode electrode of the diode 41D. In the illustrated example, the first portion 911D extends along the y-direction. An end of the second portion 912D is connected to the anode electrode of the diode 41D, and the other end is connected to the fourth portion 14E of the lead 1E. In the illustrated example, the second portion 912D is inclined with respect to the x-direction and the y-direction.

In this variation, the first wire 91E includes a first portion 911E and a second portion 912E, each of which will be described hereunder. An end of the first portion 911E is connected to the emitter electrode of the semiconductor chip 4E, and the other end is connected to the anode electrode of the diode 41E. In the illustrated example, the first portion 911E extends along the y-direction. An end of the second portion 912E is connected to the anode electrode of the diode 41E, and the other end is connected to the fourth portion 14F of the lead 1F. In the illustrated example, the second portion 912E is inclined with respect to the x-direction and the y-direction.

In this variation, the first wire 91F includes a first portion 911F and a second portion 912F, each of which will be described hereunder. An end of the first portion 911F is connected to the emitter electrode of the semiconductor chip 4F, and the other end is connected to the anode electrode of the diode 41F. In the illustrated example, the first portion 911F extends along the y-direction. An end of the second portion 912F is connected to the anode electrode of the diode 41F, and the other end is connected to the fourth portion 14G of the lead 1G. In the illustrated example, the second portion 912F is inclined with respect to the x-direction and the y-direction.

### Second Embodiment

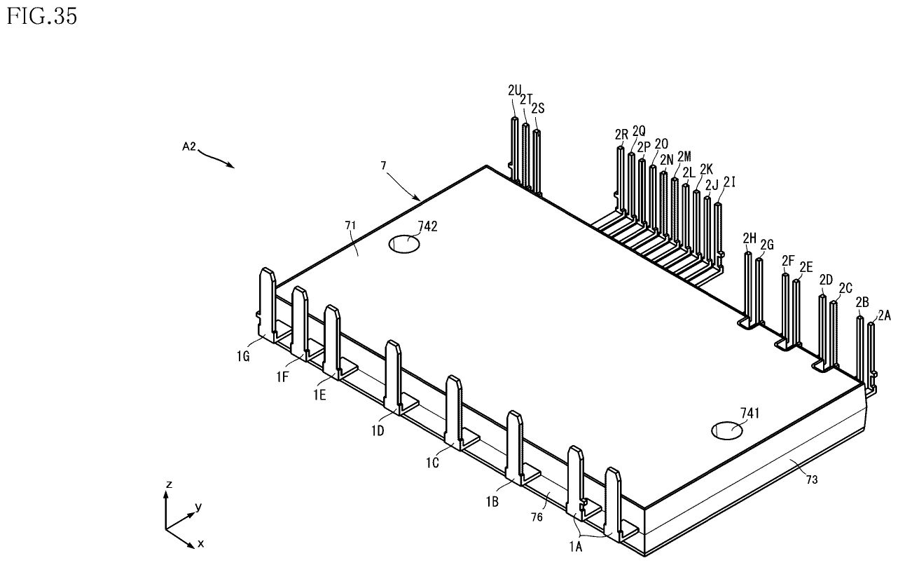

Referring to FIG. 35 to FIG. 57, a semiconductor device according to a second embodiment of the present disclosure will be described. The semiconductor device A2 according to this embodiment includes a plurality of leads 1, a plurality of leads 2, a substrate 3, a plurality of semiconductor chips 4, a diode 41, a plurality of control chips 4, a transmission circuit chip 4I, a primary-side circuit chip 4J, a plurality of diodes 49, a conductive section 5, a plurality of bonding sections 6, a plurality of first wires 91, a plurality of second wires 92, a plurality of third wires 93, a plurality of fourth wires 94, a plurality of fifth wires 95, a plurality of sixth wires 96, a plurality of seventh wires 97, and an encapsulating resin 7.

The semiconductor device A2 according to this embodiment is different from the semiconductor device A1 according to the first embodiment, in further including a transformer 690, in the locations of the plurality of leads 1 and the plurality of leads 2, and in the configuration of the conductive section 5. In the description of this embodiment, the similar elements to those of the first embodiment will be given the same numeral, and a part or the whole of the description thereof may be omitted.

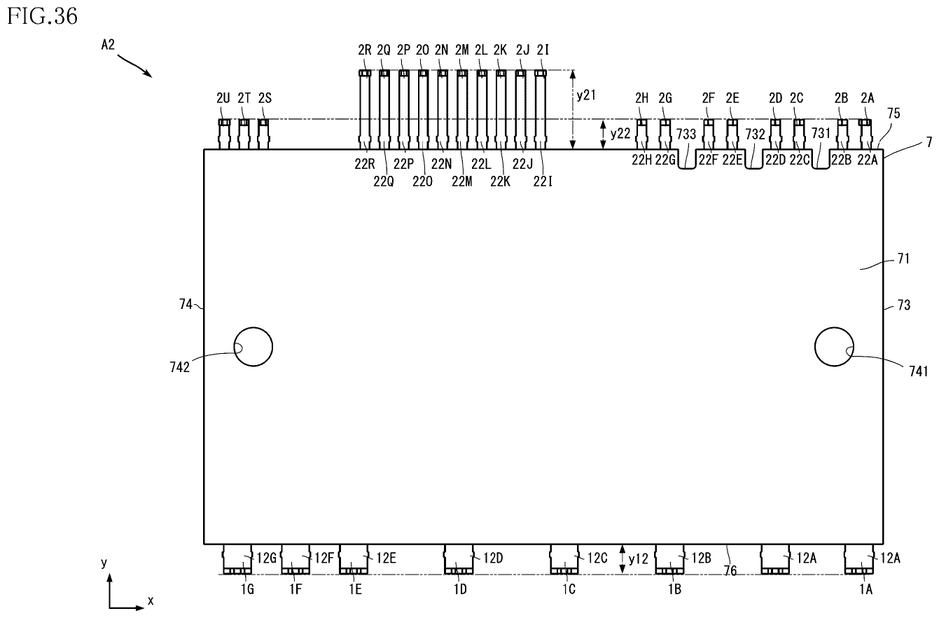

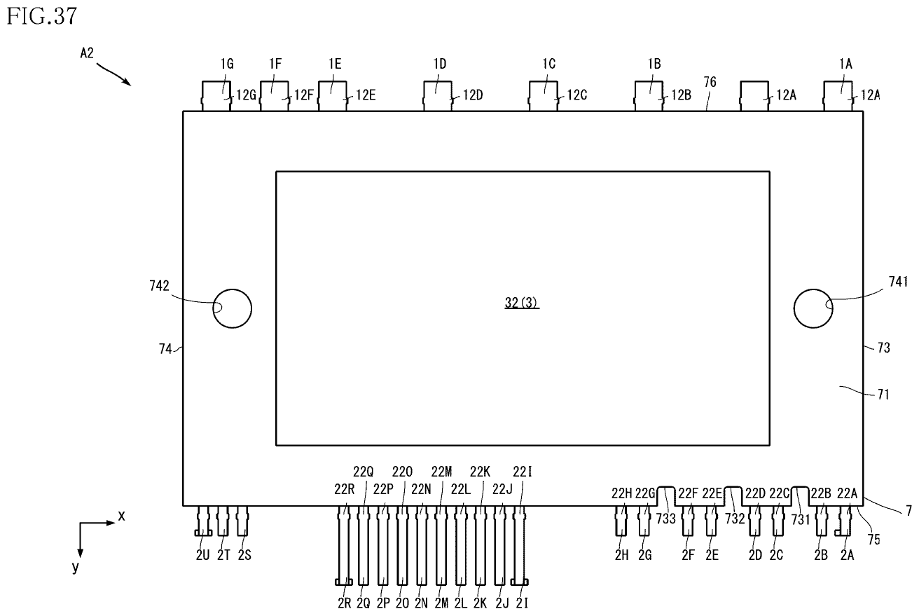

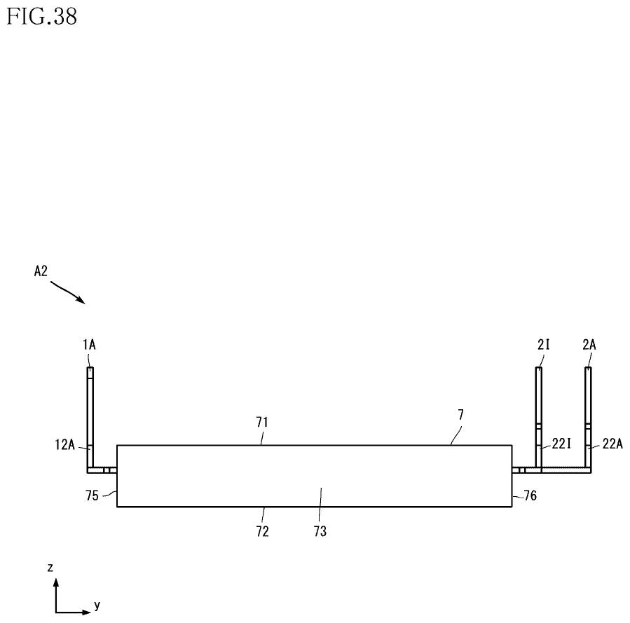

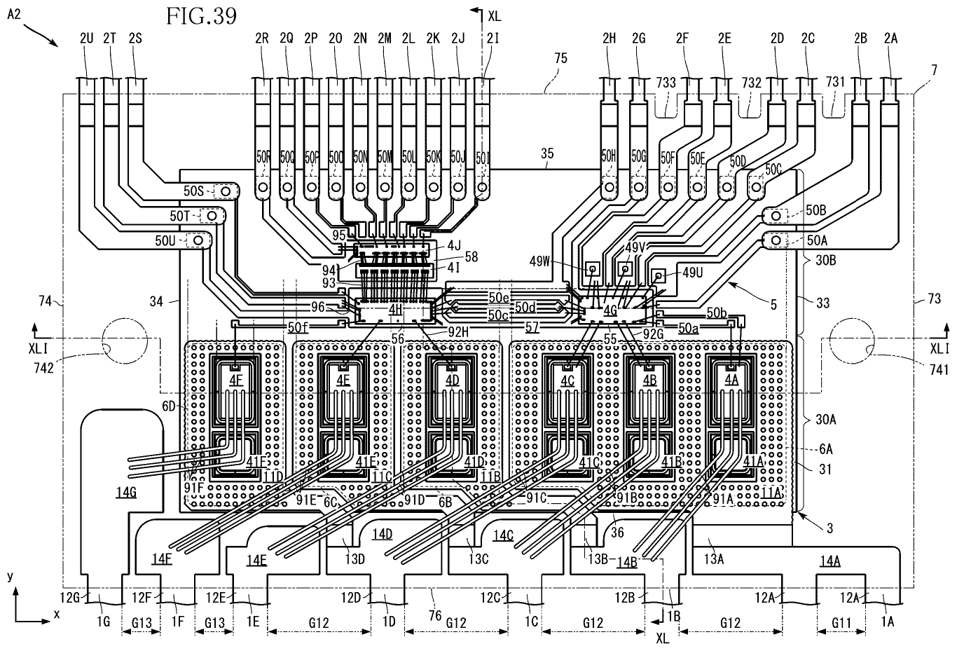

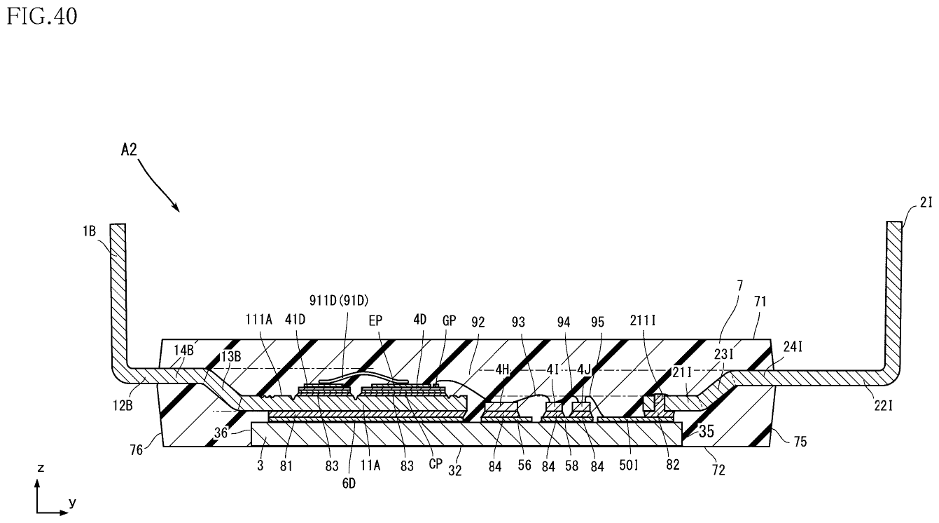

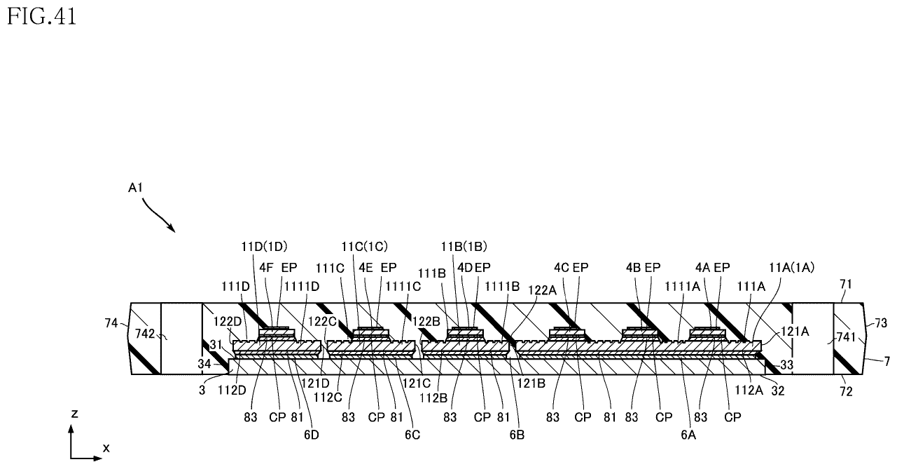

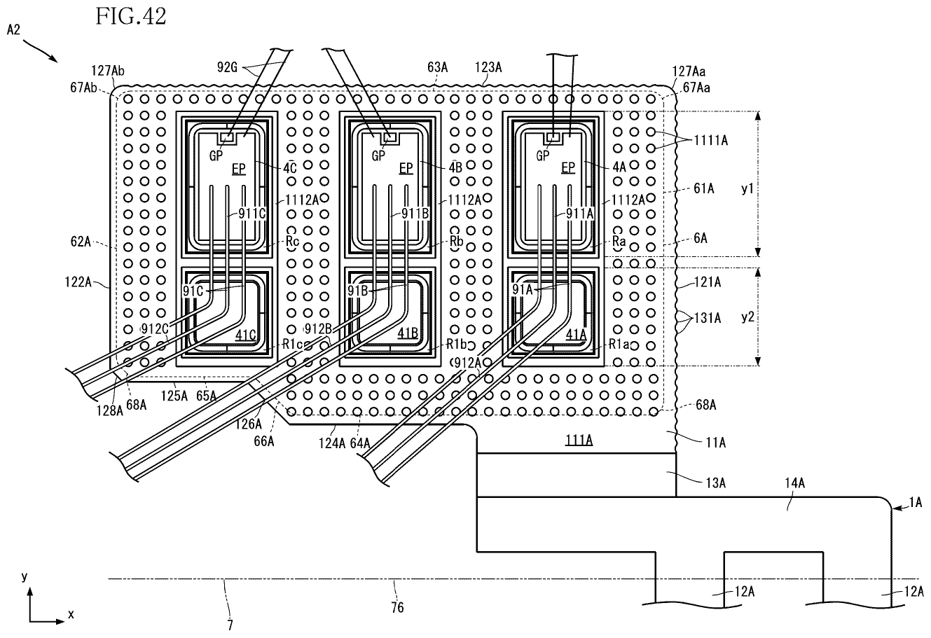

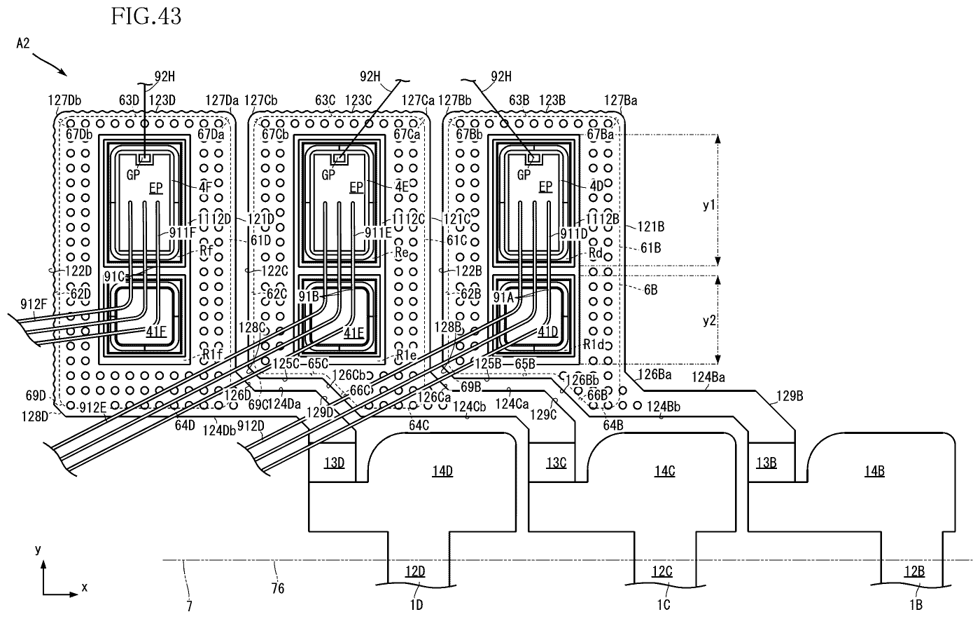

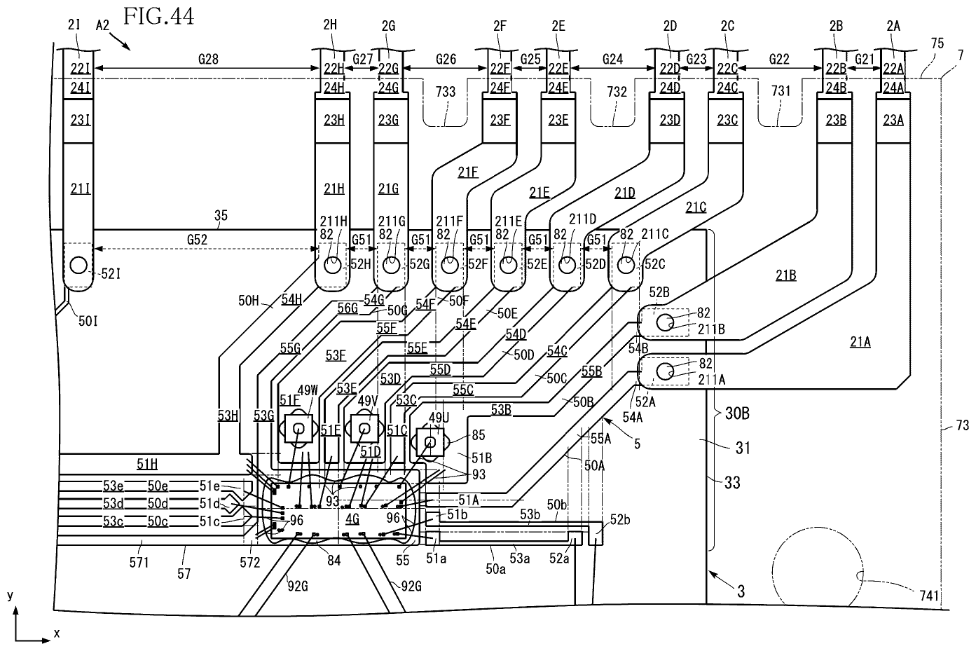

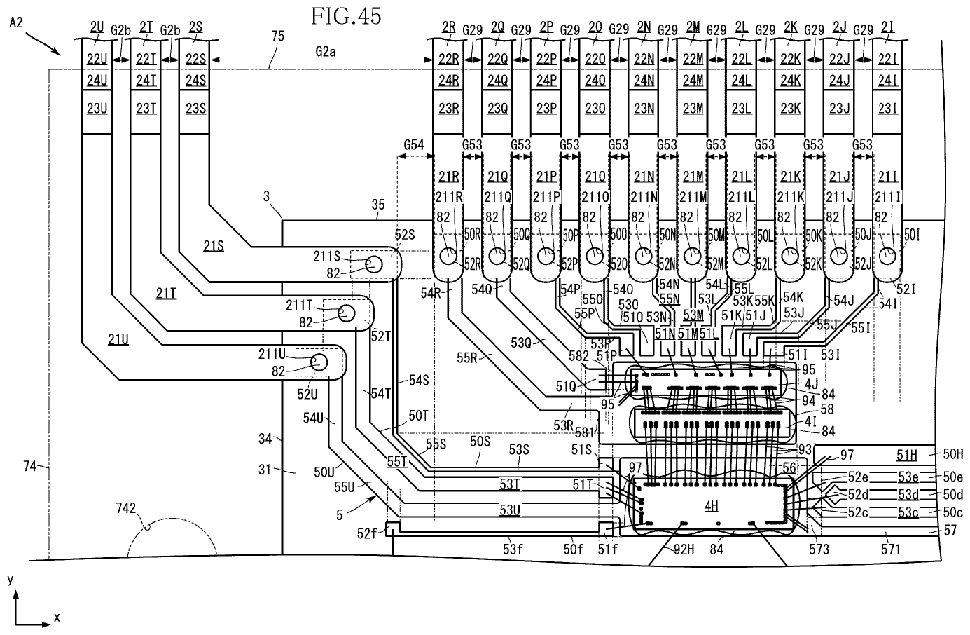

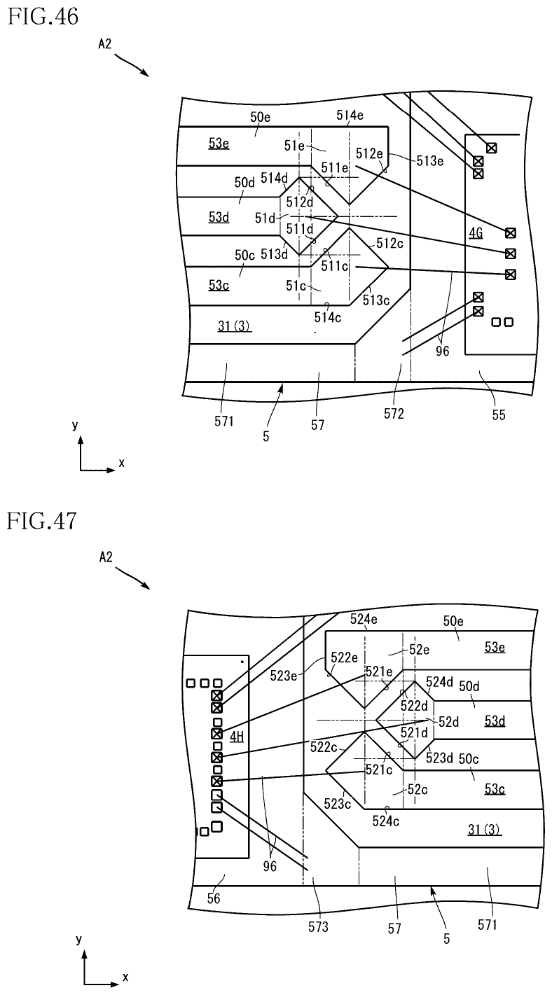

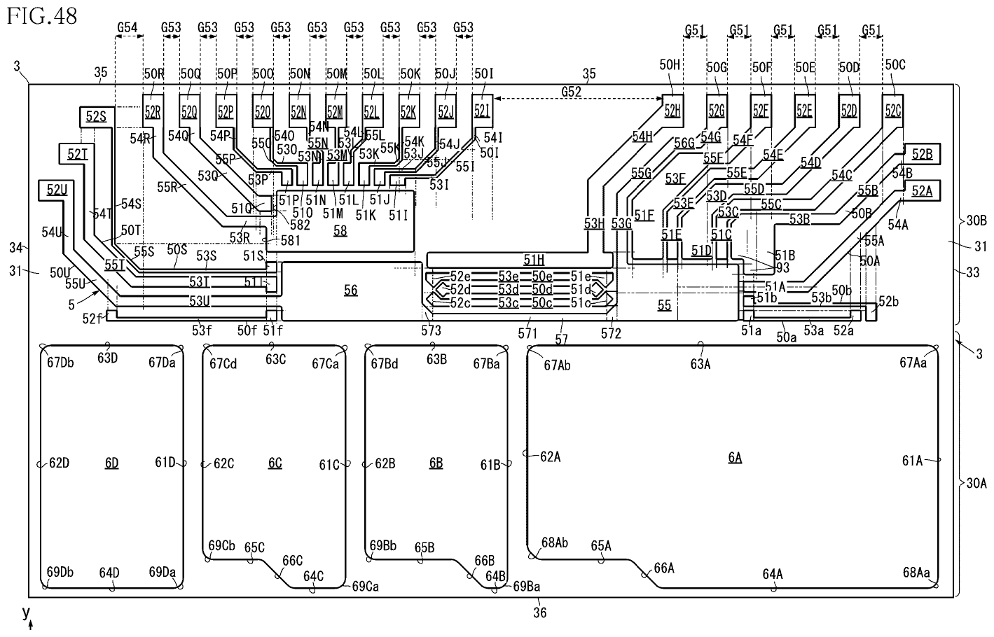

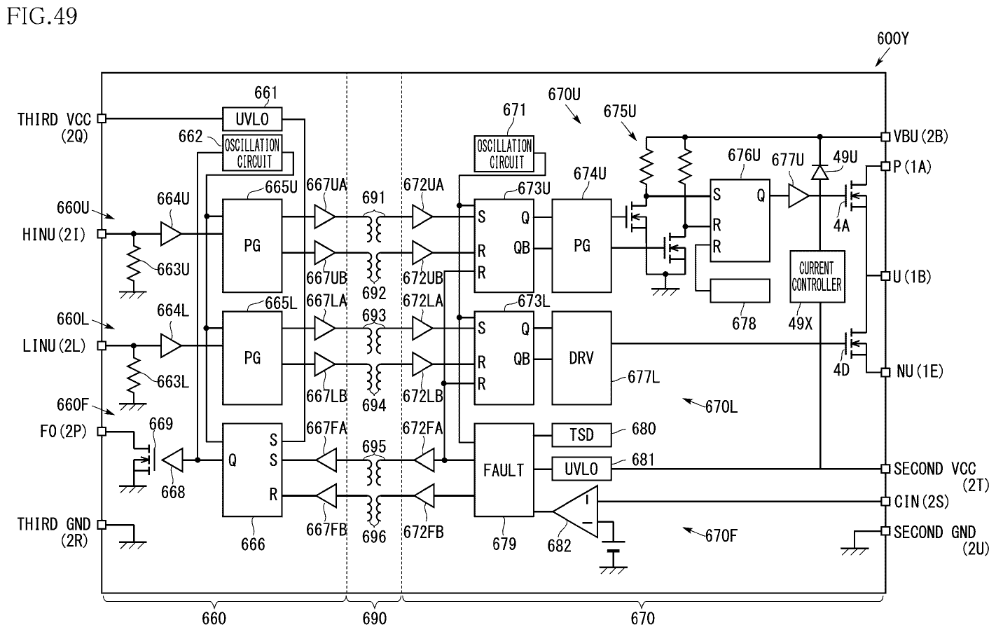

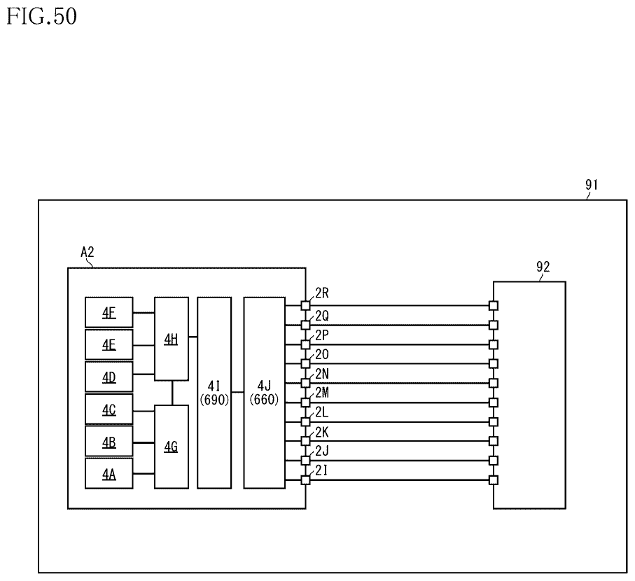

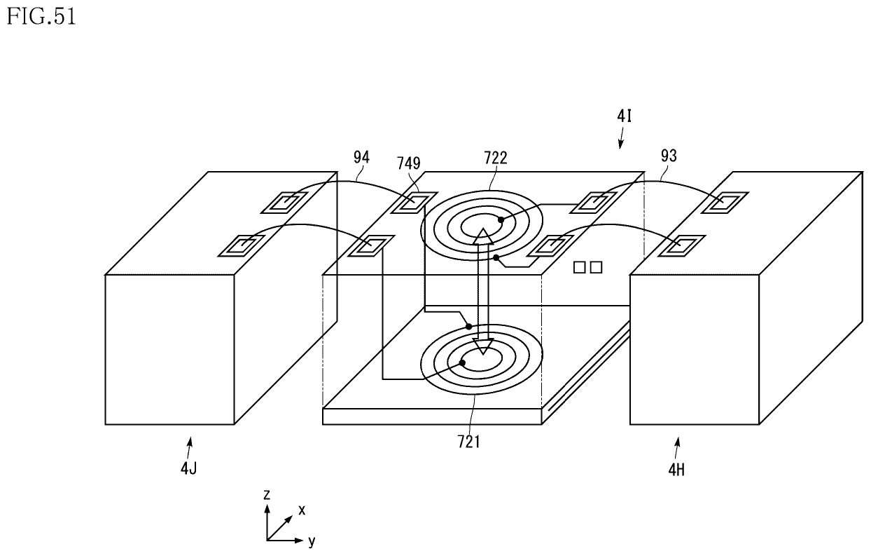

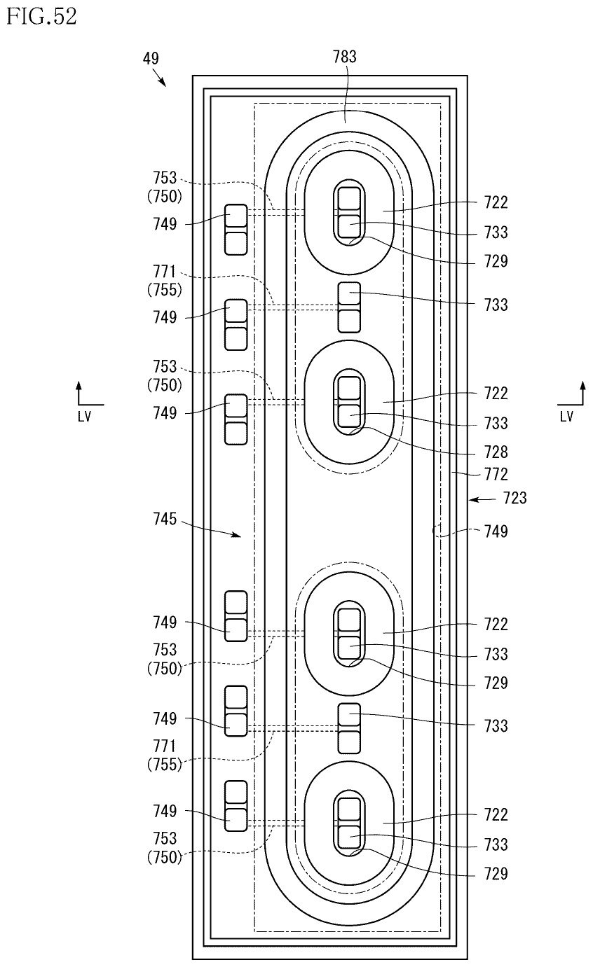

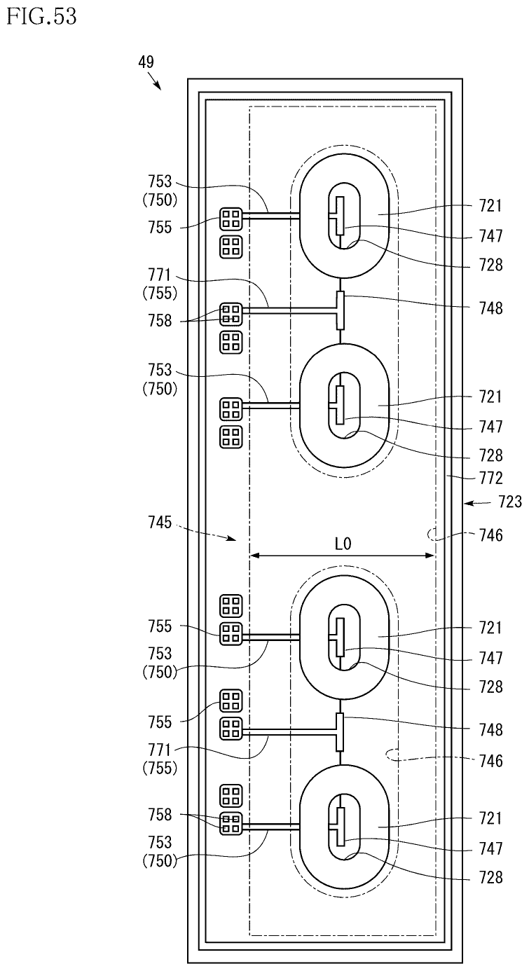

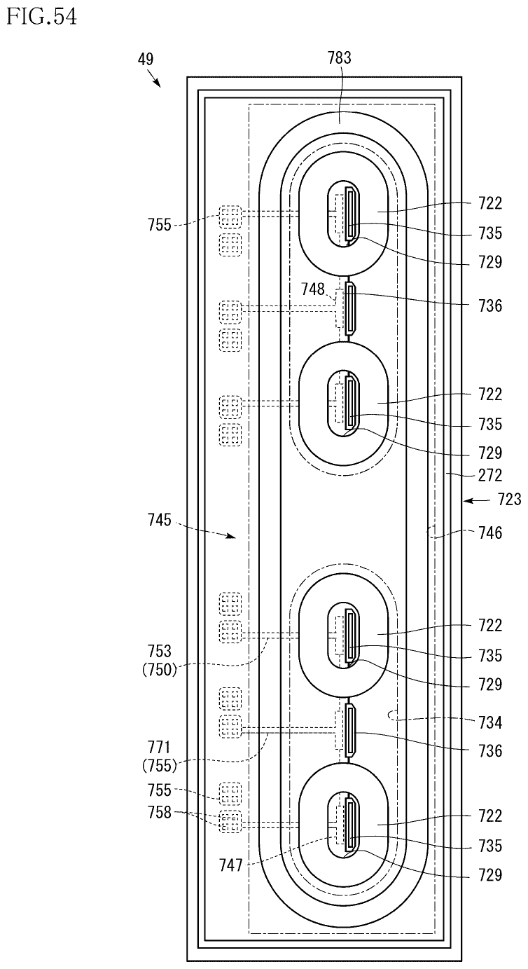

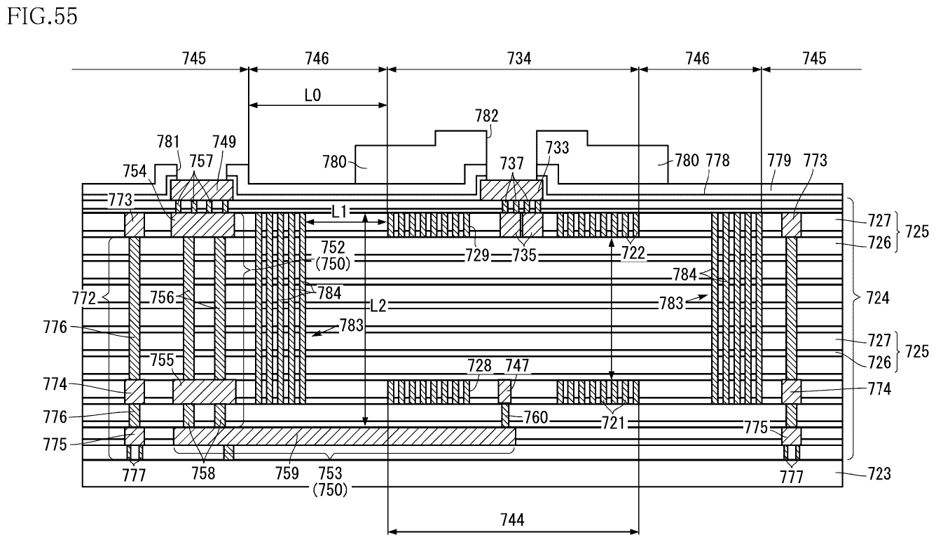

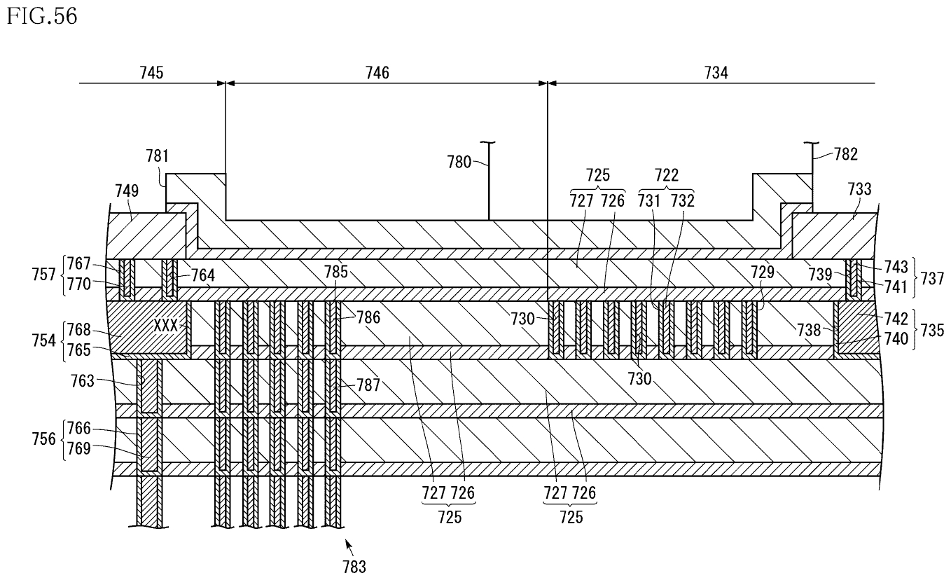

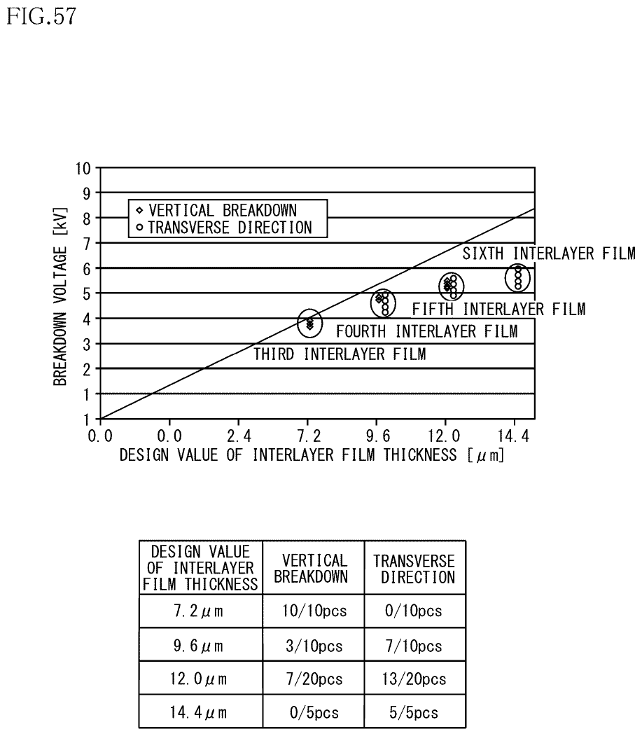

FIG. 35 is a perspective view showing the semiconductor device A2. FIG. 36 is a plan view showing the semiconductor device A2. FIG. 37 is a bottom view showing the semiconductor device A2. FIG. 38 is a side view showing the semiconductor device A2. FIG. 39 is a partial plan view of the semiconductor device A2. FIG. 40 is a cross-sectional view taken along a line XL-XL in FIG. 39. FIG. 41 is a cross-sectional view taken along a line XLI-XLI in FIG. 39. FIG. 42 is a partial plan view of the semiconductor device A2. FIG. 43 is a partial plan view of the semiconductor device A2. FIG. 44 is a schematic circuit diagram showing an electrical configuration of the semiconductor device A2. FIG. 45 is a partial plan view of the semiconductor device A2. FIG. 46 is an enlarged partial plan view of the semiconductor device A2. FIG. 47 is an enlarged partial plan view of the semiconductor device A2. FIG. 48 is an enlarged partial plan view of a substrate of the semiconductor device A2. FIG. 49 is a schematic circuit diagram showing an electrical configuration of the semiconductor device A2. FIG. 50 is a schematic circuit diagram showing an electrical configuration of a circuit board, on which the semiconductor device A2 is mounted. FIG. 51 is a schematic perspective view showing a first transmission circuit chip, a primary-side circuit chip, and a control chip of the semiconductor device A2. FIG. 52 is a partial plan view of the first transmission circuit chip. FIG. 53 is a partial bottom view of the first transmission circuit chip. FIG. 54 is a partial plan view of the first transmission circuit chip. FIG. 55 is a cross-sectional view taken along a line LV-LV in FIG. 52. FIG. 56 is an enlarged partial cross-sectional view of the first transmission circuit chip. FIG. 57 includes graphs indicating a relation between a thickness of an interlayer film and a breakdown voltage of the first transmission circuit chip.

### <Substrate 3>

The shape, size, and material of the substrate 3 are not specifically limited, but may be, for example, similar to those of the substrate 3 in the semiconductor device A1.

### <Conductive Section 5>

Regarding the conductive section 5 according to this embodiment, although any of the elements is apparently given, for the sake of convenience of description, the same numeral as that of the conductive section 5 according to the first embodiment, it does not necessarily mean that the mentioned element has the same or similar configuration. The configuration of an element with a numeral is defined by the description relevant to this embodiment.

The conductive section 5 is formed on the substrate 3. In this embodiment, the conductive section 5 is formed on the first face 31 of the substrate 3. The conductive section 5 is formed of a conductive material. The conductive material to form the conductive section 5 is not specifically limited. Examples of the conductive material to form the conductive section 5 include materials containing silver (Ag), copper (Cu), or gold (Au). In the subsequent description, it will be assumed that the conductive section 5 contains silver. However, the conductive section 5 may contain copper instead of silver, or gold instead of silver or copper. Alternatively, the conductive section 5 may contain Ag—Pt or Ag—Pd. The forming method of the conductive section 5 is not limited. For example, the conductive section 5 may be formed by sintering a paste containing the mentioned metal. The thickness of the conductive section 5 is not specifically limited, but may be, for example, approximately 5 μm to 30 μm.

In this embodiment, as shown in FIG. 39, FIG. 44 to FIG. 47, and FIG. 48, the conductive section 5 includes wirings 50A to 50U, wirings 50a to 50f, a first base portion 55, a second base portion 56, and a third base portion 58, each of which will be described hereunder.

The shape of the first base portion 55 is not specifically limited, and a desired shape may be selected from a rectangular shape, a polygonal shape, a circular shape, an elliptical shape, and so forth. In the illustrated example, the first base portion 55 has a rectangular shape. In the illustrated example, the first base portion 55 has an elongate rectangular shape, having the long sides extending along the x-direction.

The shape of the second base portion 56 is not specifically limited, and a desired shape may be selected from a rectangular shape, a polygonal shape, a circular shape, an elliptical shape, and so forth. In the illustrated example, the second base portion 56 has a rectangular shape. In the illustrated example, the second base portion 56 has an elongate rectangular shape, having the long sides extending along the x-direction.

The second base portion 56 is located on the side of the fourth face 34 with respect to the first base portion 55, in the x-direction. In the illustrated example, the edge of the second base portion 56 on the side of the sixth face 36 in the y-direction is located generally at the same position as the edge of the first base portion 55 on the side of the sixth face 36, in the y-direction. Here, the expression “located generally at the same position” in the y-direction refers to, for example, being located exactly at the same position, or being deviated by within ±5% of the characteristic size (size of the first base portion 55 or second base portion 56 in the y-direction). In the illustrated example, the edge of the second base portion 56 on the side of the fifth face 35 in the y-direction is located generally at the same position as the edge of the first base portion 55 on the side of the fifth face 35, in the y-direction. Here, the expression “located generally at the same position” in the y-direction refers to, for example, being located exactly at the same position, or being deviated by within ±5% of the characteristic size (size of the first base portion 55 or second base portion 56 in the y-direction). In the illustrated example, the center of the second base portion 56 in the y-direction is located generally at the same position in the y-direction, as the center of the first base portion 55 in the y-direction. Here, the expression “located generally at the same position” in the y-direction refers to, for example, being located exactly at the same position, or being deviated by within ±5% of the characteristic size (size of the first base portion 55 or second base portion 56 in the y-direction).

The connecting portion 57 is interposed between the first base portion 55 and the second base portion 56 and, in the illustrated example, connecting the first base portion 55 and the second base portion 56. In the illustrated example, the connecting portion 57 is located between the first base portion 55 and the second base portion 56, as viewed in the y-direction. The shape of the connecting portion 57 is not specifically limited. In the illustrated example, the connecting portion 57 includes a first portion 571, a second portion 572, and a third portion 573, each of which will be described hereunder.

The first portion 571 is located between the first base portion 55 and the second base portion 56, as viewed in the y-direction. The shape of the first portion 571 is not specifically limited. In the illustrated example, the first portion 571 has a strip shape extending along the x-direction. In the illustrated example, the size of the first portion 571 in the y-direction is constant.

The second portion 572 is interposed between the first portion 571 and the first base portion 55 and, in the illustrated example, connected to the first portion 571 and the first base portion 55. The second portion 572 is larger in size in the y-direction, than the first portion 571. The shape of the second portion 572 is not specifically limited. In the illustrated example, the size of the second portion 572 in the y-direction increases in the direction from the first portion 571 toward the first base portion 55.

The third portion 573 is interposed between the first portion 571 and the second base portion 56 and, in the illustrated example, connected to the first portion 571 and the second base portion 56. The third portion 573 is larger in size in the y-direction, than the first portion 571. The shape of the third portion 573 is not specifically limited. In the illustrated example, the size of the third portion 573 in the y-direction increases in the direction from the first portion 571 toward the second base portion 56.

In the illustrated example, the respective edges of the first base portion 55, the second base portion 56, and the connecting portion 57 on the side of the sixth face 36 in the y-direction are located generally at the same position in the y-direction. Here, the expression “located generally at the same position” in the y-direction refers to, for example, being located exactly at the same position, or being deviated by within ±5% of the characteristic size (size of the first base portion 55 or second base portion 56 in the y-direction).

The shape of the third base portion 58 is not specifically limited, and a desired shape may be selected from a rectangular shape, a polygonal shape, a circular shape, an elliptical shape, and so forth. In the illustrated example, the third base portion 58 includes two edges extending along the x-direction and two edges extending along the y-direction, the edges along the x-direction constituting the long sides. In addition, the illustrated third base portion 58 includes edges 581 and 582. One of the edges 581 and 582 corresponds to one of the two edges extending along the y-direction. The edge 582 is located on the side of the fifth face 35 in the y-direction, with respect to the edge 581. Further, the edge 582 is located on the side of the third face 33 in the x-direction, with respect to the edge 581.

The edge of the third base portion 58 on the side of the third face 33 in the x-direction is located on the side of the fourth face 34 in the x-direction, with respect to the edge of the second base portion 56 on the side of the third face 33 in the x-direction. In addition, the edge of the third base portion 58 on the side of the fourth face 34 in the x-direction is located on the side of the fourth face 34 in the x-direction, with respect to the edge of the second base portion 56 on the side of the fourth face 34 in the x-direction. The third base portion 58 is spaced apart from the first base portion 55, as viewed in the x-direction.

The wiring 50A includes a first portion 51A, a second portion 52A, and a third portion 53A, each of which will be described hereunder.

The first portion 51A is located on the side of the third face 33 in the x-direction with respect to the first base portion 55, and spaced therefrom. The shape of the first portion 51A is not specifically limited, and a desired shape may be selected from a rectangular shape, a polygonal shape, a circular shape, an elliptical shape, and so forth. In the illustrated example, the first portion 51A has an elongate strip shape extending along the x-direction. In the illustrated example, in addition, the first portion 51A overlaps with the first base portion 55, as viewed in the x-direction. The center of the first portion 51A in the y-direction is located on the side of the fifth face 35, with respect to the center of the first base portion 55 in the y-direction.

The second portion 52A is located on the side of the fifth face 35 in the y-direction, and on the side of the third face 33 in the x-direction, with respect to the first portion 51A. The shape of the second portion 52A is not specifically limited, and a desired shape may be selected from a rectangular shape, a polygonal shape, a circular shape, an elliptical shape, and so forth. In the illustrated example, the first portion 51A has a rectangular shape.

The fourth portion 54A is interposed between the first portion 51A and the second portion 52A and, in the illustrated example, connected to the edge of the second portion 52A on the side of the fourth face 34 in the x-direction. The shape of the fourth portion 54A is not specifically limited. The fourth portion 54A is spaced apart from the first portion 51A, as viewed in the x-direction.

The fifth portion 55A is interposed between the first portion 51A and the fourth portion 54A and, in the illustrated example, connected to the first portion 51A and the fourth portion 54A. The shape of the fifth portion 55A is not specifically limited. In the illustrated example, the fifth portion 55A has a strip shape inclined with respect to the x-direction and the y-direction.

The wiring 50B includes a first portion 51B, a second portion 52B, a third portion 53B, a fourth portion 54B, and a fifth portion 55B, each of which will be described hereunder.

The shape of the first portion 51B is not specifically limited, and a desired shape may be selected from a rectangular shape, a polygonal shape, a circular shape, an elliptical shape, and so forth. The first portion 51B is located on the side of the third face 33 in the x-direction, and on the side of the fifth face 35 in the y-direction, with respect to the first base portion 55, and spaced therefrom. In the illustrated example, a part of the first portion 51B overlaps with the first base portion 55 as viewed in the x-direction, and also as viewed in the y-direction. The first portion 51B includes portions respectively opposed to the edge of the first base portion 55 on the side of the third face 33 in a view in the x-direction, and the edge on the side of the fifth face 35 in the y-direction.

The second portion 52B is located on the side of the fifth face 35 with respect to the first portion 51B, in the y-direction. The second portion 52B overlaps with the first portion 51B, as viewed in the y-direction. The shape of the second portion 52B is not specifically limited, and a desired shape may be selected from a rectangular shape, a polygonal shape, a circular shape, an elliptical shape, and so forth. In the illustrated example, the second portion 52B has a rectangular shape.

The third portion 53B is interposed between the first portion 51B and the second portion 52B and, in the illustrated example, connected to the edge of the first portion 51B on the side of the third face 33 in the x-direction. The shape of the third portion 53B is not specifically limited. In the illustrated example, the third portion 53B has a strip shape extending along the x-direction. The third portion 53B is spaced apart from the second portion 52B, as viewed in the x-direction.

The fourth portion 54B is interposed between the first portion 51B and the second portion 52B and, in the illustrated example, connected to the edge of the second portion 52B on the side of the fourth face 34 in the x-direction. The shape of the fourth portion 54B is not specifically limited. The fourth portion 54B is spaced apart from the first portion 51B, as viewed in the x-direction.

The fifth portion 55B is interposed between the first portion 51B and the fourth portion 54B and, in the illustrated example, connected to the third portion 53B and the fourth portion 54B. The shape of the fifth portion 55A is not specifically limited. In the illustrated example, the fifth portion 55A has a strip shape inclined with respect to the x-direction and the y-direction. In the illustrated example, the fifth portion 55A and the fifth portion 55B are generally parallel to each other. Here, the expression “generally parallel” refers to, for example, being exactly parallel to each other, or a situation where the angles with respect to the x-direction or y-direction are different by within ±5%.

The wiring 50C includes a first portion 51C, a second portion 52C, a third portion 53C, a fourth portion 54C, and a fifth portion 55C, each of which will be described hereunder.

The first portion 51C is located on the side of the fifth face 35 in the y-direction, with respect to the first base portion 55 with a spacing therefrom, and on the side of the fourth face 34 in the x-direction, with respect to the first portion 51B with a spacing therefrom. In the illustrated example, the first portion 51C overlaps with the first base portion 55, as viewed in the y-direction. The shape of the first portion 51C is not specifically limited. In the illustrated example, the first portion 51C has a strip shape extending along the y-direction.

The second portion 52C is located on the side of the fifth face 35 with respect to the first portion 51C, in the y-direction. The second portion 52C is located between the second portions 52A and 52B, and the first portion 51C, as viewed in the y-direction. The second portion 52C is spaced apart from the second portion 52B toward the fifth face 35, as viewed in the x-direction. The shape of the second portion 52C is not specifically limited, and a desired shape may be selected from a rectangular shape, a polygonal shape, a circular shape, an elliptical shape, and so forth. In the illustrated example, the second portion 52C has a rectangular shape.

The third portion 53C is interposed between the first portion 51C and the second portion 52C and, in the illustrated example, connected to the end portion of the first portion 51C on the side of the fifth face 35 in the y-direction. The shape of the third portion 53C is not specifically limited. In the illustrated example, the third portion 53C is inclined with respect to the x-direction and the y-direction. The third portion 53C is spaced apart from the second portion 52C, as viewed in the x-direction.

The fourth portion 54C is interposed between the first portion 51C and the second portion 52C and, in the illustrated example, connected to the edge of the second portion 52C on the side of the sixth face 36 in the y-direction. The shape of the fourth portion 54C is not specifically limited. In the illustrated example, the fourth portion 54C has a strip shape inclined with respect to the x-direction and the y-direction. The fourth portion 54C is spaced apart from the first portion 51C, as viewed in the x-direction.

The fifth portion 55C is interposed between the first portion 51C and the fourth portion 54C and, in the illustrated example, connected to the third portion 53C and the fourth portion 54C. The shape of the fifth portion 55C is not specifically limited. In the illustrated example, the fifth portion 55C has a strip shape extending along the x-direction.

The wiring 50D includes a first portion 51D, a second portion 52D, a third portion 53D, a fourth portion 54D, and a fifth portion 55D, each of which will be described hereunder.

The shape of the first portion 51D is not specifically limited, and a desired shape may be selected from a rectangular shape, a polygonal shape, a circular shape, an elliptical shape, and so forth. In the illustrated example, the first portion 51D has a rectangular shape. The first portion 51D is located on the side of the fifth face 35 in the y-direction, with respect to the first base portion 55, and spaced therefrom. The first portion 51D is located on the side of the fourth face 34 in the x-direction with respect to the first portion 51C, and spaced therefrom. In addition, in the illustrated example, the first portion 51D overlaps with the first portion 51C as viewed in the x-direction, and with the first base portion 55 as viewed in the y-direction.

The second portion 52D is located on the side of the fifth face 35 with respect to the first portion 51D, in the y-direction. The second portion 52D is located on the side of the fourth face 34 in the x-direction with respect to the second portion 52C, and spaced therefrom. The second portion 52D overlaps with the second portion 52C, as viewed in the x-direction. The second portion 52D is located between the second portions 52A, 52B, and the first portion 51B, as viewed in the y-direction. The shape of the second portion 52D is not specifically limited, and a desired shape may be selected from a rectangular shape, a polygonal shape, a circular shape, an elliptical shape, and so forth. In the illustrated example, the second portion 52E has a rectangular shape.

The third portion 53D is interposed between the first portion 51D and the second portion 52D and, in the illustrated example, connected to the end portion of the first portion 51D on the side of the fifth face 35 in the y-direction. The shape of the third portion 53D is not specifically limited. In the illustrated example, the third portion 53D is inclined with respect to the x-direction and the y-direction. The third portion 53D is spaced apart from the second portion 52D, as viewed in the x-direction. In addition, the third portion 53D is generally parallel to the third portion 53C. Here, the expression “generally parallel” refers to, for example, being exactly parallel to each other, or a situation where the angles with respect to the x-direction or y-direction are different by within ±5%.

The fourth portion 54D is interposed between the first portion 51D and the second portion 52D and, in the illustrated example, connected to the edge of the second portion 52D on the side of the sixth face 36 in the y-direction. The shape of the fourth portion 54D is not specifically limited. In the illustrated example, the fourth portion 54D has a strip shape inclined with respect to the x-direction and the y-direction. The fourth portion 54D is spaced apart from the first portion 51D, as viewed in the x-direction. In addition, the fourth portion 54D is generally parallel to the fourth portion 54C. Here, the expression “generally parallel” refers to, for example, being exactly parallel to each other, or a situation where the angles with respect to the x-direction or y-direction are different by within ±5%.

The fifth portion 55D is interposed between the third portion 53D and the fourth portion 54D and, in the illustrated example, connected to the third portion 53D and the fourth portion 54D. The shape of the fifth portion 55D is not specifically limited. In the illustrated example, the fifth portion 55D has a strip shape extending along the x-direction.

The wiring 50E includes a first portion 51E, a second portion 52E, a third portion 53E, a fourth portion 54E, and a fifth portion 55E, each of which will be described hereunder.

The first portion 51E is located on the side of the fifth face 35 in the y-direction, with respect to the first base portion 55 with a spacing therefrom, and on the side of the fourth face 34 in the x-direction, with respect to the first portion 51D with a spacing therefrom. In the illustrated example, the first portion 51E overlaps with the first base portion 55, as viewed in the y-direction. The shape of the first portion 51E is not specifically limited. In the illustrated example, the first portion 51E has a strip shape extending along the y-direction.

The second portion 52E is located on the side of the fifth face 35 with respect to the first portion 51E, in the y-direction. The second portion 52E is located on the side of the fifth face 35 with respect to the second portion 52C and spaced therefrom, as viewed in the x-direction. The shape of the second portion 52E is not specifically limited, and a desired shape may be selected from a rectangular shape, a polygonal shape, a circular shape, an elliptical shape, and so forth. In the illustrated example, the second portion 52B has a rectangular shape.

The third portion 53E is interposed between the first portion 51E and the second portion 52E and, in the illustrated example, connected to the end portion of the first portion 51E on the side of the fifth face 35 in the y-direction. The shape of the third portion 53E is not specifically limited. In addition, the third portion 53E is generally parallel to the third portion 53D. Here, the expression “generally parallel” refers to, for example, being exactly parallel to each other, or a situation where the angles with respect to the x-direction or y-direction are different by within ±5%.

The fourth portion 54E is interposed between the first portion 51E and the second portion 52E and, in the illustrated example, connected to the edge of the second portion 52E on the side of the sixth face 36 in the y-direction. The shape of the fourth portion 54E is not specifically limited. In the illustrated example, the fourth portion 54E has a strip shape inclined with respect to the x-direction and the y-direction. In addition, the fourth portion 54E is generally parallel to the fourth portion 54D. Here, the expression “generally parallel” refers to, for example, being exactly parallel to each other, or a situation where the angles with respect to the x-direction or y-direction are different by within ±5%.

The fifth portion 55E is interposed between the first portion 51E and the fourth portion 54E and, in the illustrated example, connected to the third portion 53E and the fourth portion 54E. The shape of the fifth portion 55E is not specifically limited. In the illustrated example, the fifth portion 55E has a strip shape extending along the x-direction.

The wiring 50F includes a first portion 51F, a second portion 52F, a third portion 53F, a fourth portion 54F, and a fifth portion 55F, each of which will be described hereunder.

The shape of the first portion 51F is not specifically limited, and a desired shape may be selected from a rectangular shape, a polygonal shape, a circular shape, an elliptical shape, and so forth. The first portion 51F is located on the side of the fifth face 35 in the y-direction, with respect to the first base portion 55, and spaced therefrom. The first portion 51F is located on the side of the fourth face 34 in the x-direction with respect to the first portion 51E, and spaced therefrom. In addition, in the illustrated example, the first portion 51F overlaps with the first portion 51E as viewed in the x-direction, and with the first base portion 55 as viewed in the y-direction.

The second portion 52F is located on the side of the fifth face 35 with respect to the first portion 51F, in the y-direction. The second portion 52F is located on the side of the fourth face 34 in the x-direction with respect to the second portion 52E, and spaced therefrom. The second portion 52F overlaps with the second portion 52E, as viewed in the x-direction. The second portion 52F overlaps with the first portion 51B, as viewed in the y-direction. The shape of the second portion 52F is not specifically limited, and a desired shape may be selected from a rectangular shape, a polygonal shape, a circular shape, an elliptical shape, and so forth. In the illustrated example, the second portion 52F has a rectangular shape.

The third portion 53F is interposed between the first portion 51F and the second portion 52F and, in the illustrated example, connected to the end portion of the first portion 51F on the side of the fifth face 35 in the y-direction. The shape of the third portion 53F is not specifically limited. In the illustrated example, the third portion 53F is inclined with respect to the x-direction and the y-direction. The third portion 53F is spaced apart from the second portion 52F, as viewed in the x-direction. In addition, the third portion 53F is generally parallel to the third portion 53E. Here, the expression “generally parallel” refers to, for example, being exactly parallel to each other, or a situation where the angles with respect to the x-direction or y-direction are different by within ±5%.

The fourth portion 54F is interposed between the first portion 51F and the second portion 52F and, in the illustrated example, connected to the edge of the second portion 52F on the side of the sixth face 36 in the y-direction. The shape of the fourth portion 54F is not specifically limited. In the illustrated example, the fourth portion 54F has a strip shape inclined with respect to the x-direction and the y-direction. The fourth portion 54F is spaced apart from the first portion 51F, as viewed in the x-direction. In addition, the fourth portion 54F is generally parallel to the fourth portion 54E. Here, the expression “generally parallel” refers to, for example, being exactly parallel to each other, or a situation where the angles with respect to the x-direction or y-direction are different by within ±5%.

The fifth portion 55F is interposed between the third portion 53F and the fourth portion 54F and, in the illustrated example, connected to the third portion 53F and the fourth portion 54F. The shape of the fifth portion 55F is not specifically limited. In the illustrated example, the fifth portion 55F has a strip shape extending along the x-direction.

The wiring 50G includes a second portion 52G, a third portion 53G, a fourth portion 54G, a fifth portion 55G, and a sixth portion 56G, each of which will be described hereunder.

The second portion 52G is located on the side of the fifth face 35 with respect to the first base portion 55, in the y-direction. The second portion 52G is located on the side of the fourth face 34 in the x-direction with respect to the second portion 52F, and spaced therefrom. The second portion 52G overlaps with the second portion 52F, as viewed in the x-direction. The second portion 52G overlaps with the first base portion 55, as viewed in the y-direction. The shape of the second portion 52G is not specifically limited, and a desired shape may be selected from a rectangular shape, a polygonal shape, a circular shape, an elliptical shape, and so forth. In the illustrated example, the second portion 52G has a rectangular shape.

The third portion 53G is interposed between the first base portion 55 and the second portion 52G and, in the illustrated example, connected to the edge of the first base portion 55 on the side of the fifth face 35 in the y-direction. The shape of the third portion 53G is not specifically limited. In the illustrated example, the third portion 53G has a strip shape extending along the y-direction. The edge of the third portion 53G on the side of the fourth face 34 in the x-direction generally coincides with the edge of the first base portion 55 on the side of the fourth face 34 in the x-direction, as viewed in the y-direction. Here, the expression “generally coincides” as viewed in the y-direction refers to, for example, exactly coinciding with each other, or being deviated by within ±5% of the characteristic size (size of the third portion 53G or first base portion 55 in the x-direction). The third portion 53G is spaced apart from the second portion 52G, as viewed in the x-direction.

The fourth portion 54G is interposed between the third portion 53G and the second portion 52G and, in the illustrated example, connected to the edge of the second portion 52G on the side of the sixth face 36 in the y-direction. The shape of the fourth portion 54G is not specifically limited. In the illustrated example, the fourth portion 54G has a strip shape inclined with respect to the x-direction and the y-direction. The fourth portion 54G is spaced apart from the first base portion 55, as viewed in the x-direction. In addition, the fourth portion 54G is generally parallel to the third portion 54F. Here, the expression “generally parallel” refers to, for example, being exactly parallel to each other, or a situation where the angles with respect to the x-direction or y-direction are different by within ±5%.

The fifth portion 55G is interposed between the third portion 53G and the fourth portion 54G and, in the illustrated example, connected to the third portion 53G. The shape of the fifth portion 55G is not specifically limited. In the illustrated example, the fifth portion 55G has a strip shape inclined with respect to the x-direction and the y-direction. The fifth portion 55G is generally parallel to the third portion 53F. Here, the expression “generally parallel” refers to, for example, being exactly parallel to each other, or a situation where the angles with respect to the x-direction or y-direction are different by within ±5%.

The sixth portion 56G is interposed between the fifth portion 55G and the fourth portion 54G and, in the illustrated example, connected to the fifth portion 55G and the fourth portion 54G. The shape of the sixth portion 56G is not specifically limited. In the illustrated example, the sixth portion 56G has a strip shape extending along the x-direction.

The wiring 50H includes a first portion 51H, a second portion 52H, a third portion 53H, and a fourth portion 54H, each of which will be described hereunder.

The first portion 51H is located between the first base portion 55 and the second base portion 56, as viewed in the y-direction. In the illustrated example, a part of the first portion 51H overlaps with the first base portion 55 and the second base portion 56, as viewed in the x-direction. The shape of the first portion 51H is not specifically limited. In the illustrated example, the first portion 51H has a strip shape extending in the x-direction.

The second portion 52H is located on the side of the fifth face 35 in the y-direction, and on the side of the third face 33 in the x-direction, with respect to the first portion 51H. The second portion 52H is located on the side of the fourth face 34 in the x-direction with respect to the second portion 52G. The second portion 52H overlaps with the second portion 52G, as viewed in the x-direction. The shape of the second portion 52H is not specifically limited, and a desired shape may be selected from a rectangular shape, a polygonal shape, a circular shape, an elliptical shape, and so forth. In the illustrated example, the second portion 52H has a rectangular shape.

The third portion 53H is interposed between the first portion 51H and the second portion 52H and, in the illustrated example, connected to the edge of the first portion 51H on the side of the fifth face 35 in the y-direction, at a position on the side of the third face 33, in the x-direction. The shape of the third portion 53H is not specifically limited. In the illustrated example, the third portion 53H has a strip shape extending along the y-direction.

The fourth portion 54H is interposed between the first portion 51H and the second portion 52H and, in the illustrated example, connected to the third portion 53H and the second portion 52H. The shape of the fourth portion 54H is not specifically limited. In the illustrated example, the fourth portion 54H has a strip shape inclined with respect to the x-direction and the y-direction. The fourth portion 54H is generally parallel to the fifth portion 55G. Here, the expression “generally parallel” refers to, for example, being exactly parallel to each other, or a situation where the angles with respect to the x-direction or y-direction are different by within ±5%.

The wiring 50I includes a first portion 51I, a second portion 52I, a third portion 53I, a fourth portion 54I, and a fifth portion 55I, each of which will be described hereunder.

The first portion 51I is located on the side of the fifth face 35 in the y-direction with respect to the third base portion 58, and spaced therefrom. In the illustrated example, the first portion 51I overlaps with the third base portion 58, as viewed in the y-direction. The shape of the first portion 51I is not specifically limited. In the illustrated example, the first portion 51I has a rectangular shape.

The second portion 52I is located on the side of the fifth face 35 with respect to the first portion 51I, in the y-direction. The second portion 52I is located on the side of the fourth face 34 in the x-direction with respect to the second portion 52H, and spaced therefrom. The second portion 52I is spaced apart from the third base portion 58, as viewed in the y-direction. The second portion 52I overlaps with the second portion 52H, as viewed in the x-direction. The shape of the second portion 52I is not specifically limited, and a desired shape may be selected from a rectangular shape, a polygonal shape, a circular shape, an elliptical shape, and so forth. In the illustrated example, the second portion 52I has a rectangular shape.

The third portion 53I is interposed between the first portion 51I and the second portion 52I and, in the illustrated example, connected to the edge of the first portion 51I on the side of the third face 33 in the x-direction. The shape of the third portion 53I is not specifically limited. In the illustrated example, the third portion 53I has a strip shape extending along the x-direction. An end portion of the third portion 53I includes a portion extending from the third base portion 58 toward the third face 33, as viewed in the y-direction.

The fourth portion 54I is interposed between the first portion 51I and the second portion 52I and, in the illustrated example, connected to the edge of the second portion 52I on the side of the sixth face 36 in the y-direction. The shape of the fourth portion 54I is not specifically limited. In the illustrated example, the fourth portion 54I has a strip shape extending along the y-direction. The fourth portion 54I is spaced apart from the first portion 51I, as viewed in the x-direction.

The fifth portion 55I is interposed between the third portion 53I and the fourth portion 54I and, in the illustrated example, connected to the third portion 53I and the fourth portion 54I. The shape of the fifth portion 55I is not specifically limited. In the illustrated example, the fifth portion 55I has a strip shape inclined with respect to the x-direction and the y-direction.

The wiring 50J includes a first portion 51J, a second portion 52J, a third portion 53J, a fourth portion 54J, and a fifth portion 55J, each of which will be described hereunder.

The first portion 51J is located on the side of the fifth face 35 in the y-direction with respect to the third base portion 58, and spaced therefrom. In the illustrated example, the first portion 51J overlaps with the third base portion 58, as viewed in the y-direction. The first portion 51J is located on the side of the fourth face 34 in the x-direction with respect to the first portion 51I, and spaced therefrom. The first portion 51J overlaps with the first portion 51I, as viewed in the x-direction. The shape of the first portion 51J is not specifically limited. In the illustrated example, the first portion 51J has a rectangular shape.

The second portion 52J is located on the side of the fifth face 35 with respect to the first portion 51J, in the y-direction. The second portion 52J is located on the side of the fourth face 34 in the x-direction with respect to the second portion 52I, and spaced therefrom. The second portion 52J is spaced apart from the third base portion 58, as viewed in the y-direction. The second portion 52J overlaps with the second portion 52I, as viewed in the x-direction. The shape of the second portion 52J is not specifically limited, and a desired shape may be selected from a rectangular shape, a polygonal shape, a circular shape, an elliptical shape, and so forth. In the illustrated example, the second portion 52J has a rectangular shape.

The third portion 53J is interposed between the first portion 51J and the second portion 52J and, in the illustrated example, connected to the edge of the first portion 51J on the side of the third face 33 in the x-direction. The shape of the third portion 53J is not specifically limited. In the illustrated example, the third portion 53J has a strip shape extending along the x-direction. An end portion of the third portion 53J includes a portion extending from the third base portion 58 toward the third face 33, as viewed in the y-direction. The third portion 53J is located on the side of the fifth face 35 in the y-direction with respect to the third portion 53I, and spaced therefrom.

The fourth portion 54J is interposed between the first portion 51J and the second portion 52J and, in the illustrated example, connected to the edge of the second portion 52J on the side of the sixth face 36 in the y-direction. The shape of the fourth portion 54J is not specifically limited. In the illustrated example, the fourth portion 54J has a strip shape extending along the y-direction. The fourth portion 54J is spaced apart from the first portion 51J, as viewed in the x-direction. The fourth portion 54J is longer than the fourth portion 54I.

The fifth portion 55J is interposed between the third portion 53J and the fourth portion 54J and, in the illustrated example, connected to the third portion 53J and the fourth portion 54J. The shape of the fifth portion 55J is not specifically limited. In the illustrated example, the fifth portion 55J has a strip shape inclined with respect to the x-direction and the y-direction. The fifth portion 55J is generally parallel to the fifth portion 55I. Here, the expression “generally parallel” refers to, for example, being exactly parallel to each other, or a situation where the angles with respect to the x-direction or y-direction are different by within ±5%. The fifth portion 55J is shorter than the fifth portion 55I.

The wiring 50K includes a first portion 51K, a second portion 52K, a third portion 53K, a fourth portion 54K, and a fifth portion 55K, each of which will be described hereunder.

The first portion 51K is located on the side of the fifth face 35 in the y-direction with respect to the third base portion 58, and spaced therefrom. In the illustrated example, the first portion 51K overlaps with the third base portion 58, as viewed in the y-direction. The first portion 51K is located on the side of the fourth face 34 in the x-direction with respect to the first portion 51J, and spaced therefrom. The first portion 51K overlaps with the first portion 51J, as viewed in the x-direction. The shape of the first portion 51K is not specifically limited. In the illustrated example, the first portion 51K has a rectangular shape.

The second portion 52K is located on the side of the fifth face 35 with respect to the first portion 51K, in the y-direction. The second portion 52K is located on the side of the fourth face 34 in the x-direction with respect to the second portion 52J, and spaced therefrom. The second portion 52K overlaps with the third base portion 58, as viewed in the y-direction. The second portion 52K overlaps with the second portion 52J, as viewed in the x-direction. The shape of the second portion 52K is not specifically limited, and a desired shape may be selected from a rectangular shape, a polygonal shape, a circular shape, an elliptical shape, and so forth. In the illustrated example, the second portion 52K has a rectangular shape.

The third portion 53K is interposed between the first portion 51K and the second portion 52K and, in the illustrated example, connected to the edge of the first portion 51K on the side of the third face 33 in the x-direction. The shape of the third portion 53K is not specifically limited. In the illustrated example, the third portion 53K has a strip shape extending along the x-direction. The third portion 53K overlaps with the third base portion 58, as viewed in the y-direction. The third portion 53K is located on the side of the fifth face 35 in the y-direction with respect to the third portion 53J, and spaced therefrom.

The fourth portion 54K is interposed between the first portion 51K and the second portion 52K and, in the illustrated example, connected to the edge of the second portion 52K on the side of the sixth face 36 in the y-direction. The shape of the fourth portion 54K is not specifically limited. In the illustrated example, the fourth portion 54K has a strip shape extending along the y-direction. The fourth portion 54K is spaced apart from the first portion 51K, as viewed in the x-direction. The fourth portion 54K is longer than the fourth portion 54J.

The fifth portion 55K is interposed between the third portion 53K and the fourth portion 54K and, in the illustrated example, connected to the third portion 53K and the fourth portion 54K. The shape of the fifth portion 55K is not specifically limited. In the illustrated example, the fifth portion 55K has a strip shape inclined with respect to the x-direction and the y-direction. The fifth portion 55K is generally parallel to the fifth portion 55J. Here, the expression “generally parallel” refers to, for example, being exactly parallel to each other, or a situation where the angles with respect to the x-direction or y-direction are different by within ±5%. The fifth portion 55K is shorter than the fifth portion 55J.

The wiring 50L includes a first portion 51L, a second portion 52L, a third portion 53L, a fourth portion 54L, and a fifth portion 55L, each of which will be described hereunder.

The first portion 51L is located on the side of the fifth face 35 in the y-direction with respect to the third base portion 58, and spaced therefrom. In the illustrated example, the first portion 51L overlaps with the third base portion 58, as viewed in the y-direction. The first portion 51L is located on the side of the fourth face 34 in the x-direction with respect to the first portion 51K, and spaced therefrom. The first portion 51L overlaps with the first portion 51K, as viewed in the x-direction. The shape of the first portion 51L is not specifically limited. In the illustrated example, the first portion 51L has a rectangular shape.

The second portion 52L is located on the side of the fifth face 35 with respect to the first portion 51L, in the y-direction. The second portion 52L is located on the side of the fourth face 34 in the x-direction with respect to the second portion 52K, and spaced therefrom. The second portion 52L overlaps with the third base portion 58, as viewed in the y-direction. The second portion 52L overlaps with the second portion 52K, as viewed in the x-direction. The shape of the second portion 52L is not specifically limited, and a desired shape may be selected from a rectangular shape, a polygonal shape, a circular shape, an elliptical shape, and so forth. In the illustrated example, the second portion 52L has a rectangular shape.

The third portion 53L is interposed between the first portion 51L and the second portion 52L and, in the illustrated example, connected to the edge of the first portion 51L on the side of the fifth face 35 in the y-direction. The shape of the third portion 53L is not specifically limited. In the illustrated example, the third portion 53L has a strip shape extending along the y-direction. The third portion 53L overlaps with the third base portion 58, as viewed in the y-direction.

The fourth portion 54L is interposed between the first portion 51L and the second portion 52L and, in the illustrated example, connected to the edge of the second portion 52L on the side of the sixth face 36 in the y-direction. The shape of the fourth portion 54L is not specifically limited. In the illustrated example, the fourth portion 54L has a strip shape extending along the y-direction. The fourth portion 54L is spaced apart from the first portion 51L, as viewed in the x-direction.

The fifth portion 55L is interposed between the third portion 53L and the fourth portion 54L and, in the illustrated example, connected to the third portion 53L and the fourth portion 54L. The shape of the fifth portion 55L is not specifically limited. In the illustrated example, the fifth portion 55L has a strip shape inclined with respect to the x-direction and the y-direction. The fifth portion 55L is generally parallel to the fifth portion 55K. Here, the expression “generally parallel” refers to, for example, being exactly parallel to each other, or a situation where the angles with respect to the x-direction or y-direction are different by within ±5%. The fifth portion 55L is longer than the fifth portion 55K.

The wiring 50M includes a first portion 51M, a second portion 52M, and a third portion 53M, each of which will be described hereunder.

The first portion 51M is located on the side of the fifth face 35 in the y-direction with respect to the third base portion 58, and spaced therefrom. In the illustrated example, the first portion 51M overlaps with the third base portion 58, as viewed in the y-direction. The first portion 51M is located on the side of the fourth face 34 in the x-direction with respect to the first portion 51L, and spaced therefrom. The first portion 51M overlaps with the first portion 51L, as viewed in the x-direction. The shape of the first portion 51M is not specifically limited. In the illustrated example, the first portion 51M has a rectangular shape.

The second portion 52M is located on the side of the fifth face 35 with respect to the first portion 51M, in the y-direction. The second portion 52M is located on the side of the fourth face 34 in the x-direction with respect to the second portion 52L, and spaced therefrom. The second portion 52M overlaps with the third base portion 58, as viewed in the y-direction. The second portion 52M overlaps with the second portion 52L, as viewed in the x-direction. The shape of the e second portion 52M is not specifically limited, and a desired shape may be selected from a rectangular shape, a polygonal shape, a circular shape, an elliptical shape, and so forth. In the illustrated example, the second portion 52M has a rectangular shape.

The third portion 53M is interposed between the first portion 51M and the second portion 52M and, in the illustrated example, connected to the first portion 51M and the second portion 52M. The shape of the third portion 53M is not specifically limited. In the illustrated example, the third portion 53M has a strip shape extending along the y-direction. The third portion 53M overlaps with the third base portion 58, as viewed in the y-direction.

The wiring 50N includes a first portion 51N, a second portion 52N, a third portion 53N, a fourth portion 54N, and a fifth portion 55N, each of which will be described hereunder.

The first portion 51N is located on the side of the fifth face 35 in the y-direction with respect to the third base portion 58, and spaced therefrom. In the illustrated example, the first portion 51N overlaps with the third base portion 58, as viewed in the y-direction. The first portion 51N is located on the side of the fourth face 34 in the x-direction with respect to the first portion 51M, and spaced therefrom. The first portion 51N overlaps with the first portion 51M, as viewed in the x-direction. The shape of the first portion 51N is not specifically limited. In the illustrated example, the first portion 51N has a rectangular shape.

The second portion 52N is located on the side of the fifth face 35 with respect to the first portion 51N, in the y-direction. The second portion 52N is located on the side of the fourth face 34 in the x-direction with respect to the second portion 52M, and spaced therefrom. The second portion 52N overlaps with the third base portion 58, as viewed in the y-direction. The second portion 52N overlaps with the second portion 52M, as viewed in the x-direction. The shape of the second portion 52N is not specifically limited, and a desired shape may be selected from a rectangular shape, a polygonal shape, a circular shape, an elliptical shape, and so forth. In the illustrated example, the second portion 52N has a rectangular shape.

The third portion 53N is interposed between the first portion 51N and the second portion 52N and, in the illustrated example, connected to the edge of the first portion 51N on the side of the fifth face 35 in the y-direction. The shape of the third portion 53N is not specifically limited. In the illustrated example, the third portion 53N has a strip shape extending along the y-direction. The third portion 53N overlaps with the third base portion 58, as viewed in the y-direction.

The fourth portion 54N is interposed between the first portion 51N and the second portion 52N and, in the illustrated example, connected to the edge of the second portion 52N on the side of the sixth face 36 in the y-direction. The shape of the fourth portion 54N is not specifically limited. In the illustrated example, the fourth portion 54N has a strip shape extending along the y-direction. The fourth portion 54N is spaced apart from the first portion 51N, as viewed in the x-direction.

The fifth portion 55N is interposed between the third portion 53N and the fourth portion 54N and, in the illustrated example, connected to the third portion 53N and the fourth portion 54N. The shape of the fifth portion 55N is not specifically limited. In the illustrated example, the fifth portion 55N has a strip shape inclined with respect to the x-direction and the y-direction.

The wiring 50O includes a first portion 51O, a second portion 52O, a third portion 53O, a fourth portion 54O, and a fifth portion 55O, each of which will be described hereunder.

The first portion 51O is located on the side of the fifth face 35 in the y-direction with respect to the third base portion 58, and spaced therefrom. In the illustrated example, the first portion 51O overlaps with the third base portion 58, as viewed in the y-direction. The first portion 51O is located on the side of the fourth face 34 in the x-direction with respect to the first portion 51N, and spaced therefrom. The first portion 51O overlaps with the first portion 51N, as viewed in the x-direction. The shape of the first portion 51O is not specifically limited. In the illustrated example, the first portion 51O has a rectangular shape.

The second portion 52O is located on the side of the fifth face 35 with respect to the first portion 51O, in the y-direction. The second portion 52O is located on the side of the fourth face 34 in the x-direction with respect to the second portion 52N, and spaced therefrom. The second portion 52O overlaps with the third base portion 58, as viewed in the y-direction. The second portion 52O overlaps with the second portion 52N, as viewed in the x-direction. The shape of the second portion 52O is not specifically limited, and a desired shape may be selected from a rectangular shape, a polygonal shape, a circular shape, an elliptical shape, and so forth. In the illustrated example, the second portion 52O has a rectangular shape.

The third portion 53O is interposed between the first portion 51O and the second portion 52O and, in the illustrated example, connected to the edge of the first portion 51O on the side of the fourth face 34 in the x-direction. The shape of the third portion 53O is not specifically limited. In the illustrated example, the third portion 53O has a strip shape extending along the x-direction. The third portion 53O overlaps with the third base portion 58, as viewed in the y-direction.

The fourth portion 54O is interposed between the first portion 51O and the second portion 52O and, in the illustrated example, connected to the edge of the second portion 52O on the side of the sixth face 36 in the y-direction. The shape of the fourth portion 54O is not specifically limited. In the illustrated example, the fourth portion 54O has a strip shape extending along the y-direction. The fourth portion 54O is spaced apart from the first portion 51O, as viewed in the x-direction.

The fifth portion 55O is interposed between the third portion 53O and the fourth portion 54O and, in the illustrated example, connected to the third portion 53O and the fourth portion 54O. The shape of the fifth portion 55O is not specifically limited. In the illustrated example, the fifth portion 55O has a strip shape inclined with respect to the x-direction and the y-direction. The fifth portion 55O is generally parallel to the fifth portion 55N. Here, the expression “generally parallel” refers to, for example, being exactly parallel to each other, or a situation where the angles with respect to the x-direction or y-direction are different by within ±5%.

The wiring 50P includes a first portion 51P, a second portion 52P, a third portion 53P, a fourth portion 54P, and a fifth portion 55P, each of which will be described hereunder.

The first portion 51P is located on the side of the fifth face 35 in the y-direction with respect to the third base portion 58, and spaced therefrom. In the illustrated example, the first portion 51P overlaps with the third base portion 58, as viewed in the y-direction. The first portion 51P is located on the side of the fourth face 34 in the x-direction with respect to the first portion 51O, and spaced therefrom. The first portion 51P overlaps with the first portion 51O, as viewed in the x-direction. The shape of the first portion 51P is not specifically limited. In the illustrated example, the first portion 51P has a rectangular shape.

The second portion 52P is located on the side of the fifth face 35 with respect to the first portion 51P, in the y-direction. The second portion 52P is located on the side of the fourth face 34 in the x-direction with respect to the second portion 52O, and spaced therefrom. The second portion 52P is spaced apart from the third base portion 58, as viewed in the y-direction. The second portion 52P overlaps with the second portion 52O, as viewed in the x-direction. The shape of the second portion 52P is not specifically limited, and a desired shape may be selected from a rectangular shape, a polygonal shape, a circular shape, an elliptical shape, and so forth. In the illustrated example, the second portion 52P has a rectangular shape.

The third portion 53P is interposed between the first portion 51P and the second portion 52P and, in the illustrated example, connected to the edge of the first portion 51P on the side of the fourth face 34 in the x-direction. The shape of the third portion 53P is not specifically limited. In the illustrated example, the third portion 53P has a strip shape extending along the x-direction. An end portion of the third portion 53P includes a portion extending from the third base portion 58 toward the fourth face 34, as viewed in the y-direction.

The fourth portion 54P is interposed between the first portion 51P and the second portion 52P and, in the illustrated example, connected to the edge of the second portion 52P on the side of the sixth face 36 in the y-direction. The shape of the fourth portion 54P is not specifically limited. In the illustrated example, the fourth portion 54P has a strip shape extending along the y-direction. The fourth portion 54P is spaced apart from the first portion 51P, as viewed in the x-direction.

The fifth portion 55P is interposed between the third portion 53P and the fourth portion 54P and, in the illustrated example, connected to the third portion 53P and the fourth portion 54P. The shape of the fifth portion 55P is not specifically limited. In the illustrated example, the fifth portion 55P has a strip shape inclined with respect to the x-direction and the y-direction. The fifth portion 55P is generally parallel to the fifth portion 55O. Here, the expression “generally parallel” refers to, for example, being exactly parallel to each other, or a situation where the angles with respect to the x-direction or y-direction are different by within ±5%. The fifth portion 55P is longer than the fifth portion 55O.

The wiring 50O includes a first portion 51O, a second portion 52O, a third portion 53O, and a fourth portion 54O, each of which will be described hereunder.

The first portion 51O is located on the side of the fourth face 34 in the x-direction, with respect to the third base portion 58. The first portion 51O overlaps with the edge 582 of the third base portion 58, as viewed in the x-direction. The first portion 51Q overlaps with the edge 581 of the third base portion 58, as viewed in the y-direction. The shape of the first portion 51O is not specifically limited. In the illustrated example, the first portion 51Q has a rectangular shape.

The second portion 52Q is located on the side of the fifth face 35 with respect to the first portion 51Q, in the y-direction. The second portion 52Q is located on the side of the fourth face 34 in the x-direction with respect to the second portion 52P, and spaced therefrom. The second portion 52Q is spaced apart from the third base portion 58, as viewed in the y-direction. The second portion 52Q overlaps with the second portion 52P, as viewed in the x-direction. The shape of the second portion 52Q is not specifically limited, and a desired shape may be selected from a rectangular shape, a polygonal shape, a circular shape, an elliptical shape, and so forth. In the illustrated example, the second portion 52Q has a rectangular shape.

The third portion 53Q is interposed between the first portion 51Q and the second portion 52Q and, in the illustrated example, connected to the edge of the first portion 51Q on the side of the fourth face 34 in the x-direction. The shape of the third portion 53Q is not specifically limited. In the illustrated example, the third portion 53Q has a strip shape inclined with respect to the x-direction and the y-direction. The third portion 53Q is spaced apart from the third base portion 58 toward the fourth face 34, as viewed in the y-direction. The third portion 53Q is generally parallel to the fifth portion 55P. Here, the expression “generally parallel” refers to, for example, being exactly parallel to each other, or a situation where the angles with respect to the x-direction or y-direction are different by within ±5%. The third portion 53O is longer and wider than the fifth portion 55P.

The fourth portion 54O is interposed between the first portion 51Q and the second portion 52O and, in the illustrated example, connected to the edge of the second portion 52O on the side of the sixth face 36 in the y-direction, and the third portion 53Q. The shape of the fourth portion 54O is not specifically limited. In the illustrated example, the fourth portion 54O extends along the y-direction. The fourth portion 54Q is spaced apart from the first portion 51Q, as viewed in the x-direction. The fourth portion 54O is shorter and wider than the fourth portion 54P.

The wiring 50R includes a second portion 52R, a third portion 53R, a fourth portion 54R, and a fifth portion 55R, each of which will be described hereunder.

The second portion 52R is located on the side of the fifth face 35 with respect to the first portion 51R, in the y-direction. The second portion 52R is located on the side of the fourth face 34 in the x-direction with respect to the second portion 52O, and spaced therefrom. The second portion 52R is spaced apart from the third base portion 58, as viewed in the y-direction. The second portion 52R overlaps with the second portion 52O, as viewed in the x-direction. The shape of the second portion 52R is not specifically limited, and a desired shape may be selected from a rectangular shape, a polygonal shape, a circular shape, an elliptical shape, and so forth. In the illustrated example, the second portion 52R has a rectangular shape.

The third portion 53R is connected to the end portion of the third base portion 58 on the side of the fourth face 34 in the x-direction. The third portion 53R is located between the edge 581 and the edge 582, as viewed in the x-direction, and connected to the edge 581 and the edge 582. The shape of the third portion 53R is not specifically limited. In the illustrated example, the third portion 53R has a strip shape extending along the x-direction. The third portion 53R is wider than the third portion 53P.

The fourth portion 54R is interposed between the second portion 52R and the third portion 53R and, in the illustrated example, connected to the edge of the second portion 52R on the side of the sixth face 36 in the y-direction. The shape of the fourth portion 54R is not specifically limited. In the illustrated example, the fourth portion 54R extends along the y-direction. The fourth portion 54R is spaced apart from the first portion 51R, as viewed in the x-direction. The fourth portion 54R is shorter than the fourth portion 54Q. The fourth portion 54R has generally the same width as the fourth portion 54Q. Here, the expression “generally the same width” refers to, for example, being exactly the same, or different by within ±5% from each other's width.

The fifth portion 55R is interposed between the third portion 53R and the fourth portion 54R and, in the illustrated example, connected to the third portion 53R and the fourth portion 54R. The shape of the fifth portion 55R is not specifically limited. In the illustrated example, the fifth portion 55R has a strip shape inclined with respect to the x-direction and the y-direction. The fifth portion 55R is generally parallel to the third portion 53Q. Here, the expression “generally parallel” refers to, for example, being exactly parallel to each other, or a situation where the angles with respect to the x-direction or y-direction are different by within ±5%. The fifth portion 55R has generally the same width as the third portion 53O. Here, the expression “generally the same width” refers to, for example, being exactly the same, or different by within ±5% from each other's width.

The wiring 50S includes a first portion 51S, a second portion 52S, a third portion 53S, a fourth portion 54S, and a fifth portion 55S, each of which will be described hereunder.

The first portion 51S is located on the side of the fourth face 34 in the x-direction, with respect to the third base portion 58, and spaced therefrom. The first portion 51S is located on the side of the sixth face 36 in the y-direction, with respect to the third base portion 58, and spaced therefrom. In the illustrated example, the first portion 51S overlaps with the third base portion 58, as viewed in the y-direction. The first portion 51S overlaps with the second base portion 56, as viewed in the x-direction. The shape of the first portion 51S is not specifically limited. In the illustrated example, the first portion 51S has a rectangular shape.

The second portion 52S is located on the side of the fifth face 35 with respect to the first portion 51S, in the y-direction. The second portion 52S is located on the side of the fourth face 34 in the x-direction with respect to the second portion 52R, and spaced therefrom. The second portion 52S is spaced apart from the third base portion 58, as viewed in the y-direction. The second portion 52S overlaps with the second portion 52R, as viewed in the x-direction. The shape of the second portion 52S is not specifically limited, and a desired shape may be selected from a rectangular shape, a polygonal shape, a circular shape, an elliptical shape, and so forth. In the illustrated example, the second portion 52S has a rectangular shape.

The third portion 53S is interposed between the first portion 51S and the second portion 52S and, in the illustrated example, connected to the edge of the first portion 51S on the side of the fourth face 34 in the x-direction. The shape of the third portion 53S is not specifically limited. In the illustrated example, the third portion 53S has a strip shape extending along the x-direction. The third portion 53S overlaps with the third portion 53R, the fourth portion 54R, and the fifth portion 55R, as viewed in the y-direction.

The fourth portion 54S is interposed between the first portion 51S and the second portion 52S and, in the illustrated example, connected to the edge of the second portion 52S on the side of the sixth face 36 in the y-direction. The shape of the fourth portion 54S is not specifically limited. In the illustrated example, the fourth portion 54S has a strip shape extending along the y-direction. The fourth portion 54S overlaps with the third base portion 58, the third portion 53R, the fourth portion 54R, and the fifth portion 55R, as viewed in the x-direction.

The fifth portion 55S is interposed between the third portion 53S and the fourth portion 54S and, in the illustrated example, connected to the third portion 53S and the fourth portion 54S. The shape of the fifth portion 55S is not specifically limited. In the illustrated example, the fifth portion 55S has a strip shape inclined with respect to the x-direction and the y-direction. The fifth portion 55S is generally parallel to the fifth portion 55R. Here, the expression “generally parallel” refers to, for example, being exactly parallel to each other, or a situation where the angles with respect to the x-direction or y-direction are different by within ±5%. The fifth portion 55S is shorter than the fifth portion 55R.

The wiring 50T includes a first portion 51T, a second portion 52T, a third portion 53I, a fourth portion 54T, and a fifth portion 55T, each of which will be described hereunder.

The first portion 51T is located on the side of the fourth face 34 in the x-direction, with respect to the third base portion 58, and spaced therefrom. The first portion 51T is located on the side of the sixth face 36 in the y-direction, with respect to the first portion 51S, and spaced therefrom. In the illustrated example, the first portion 51T overlaps with the first portion 51S, as viewed in the y-direction. The first portion 51T overlaps with the second base portion 56, as viewed in the x-direction. The shape of the first portion 51T is not specifically limited. In the illustrated example, the first portion 51T has a rectangular shape.

The second portion 52T is located on the side of the fifth face 35 with respect to the first portion 51T, in the y-direction. The second portion 52T is located on the side of the sixth face 36 in the y-direction with respect to the second portion 52S, and spaced therefrom. The second portion 52T is spaced apart from the third base portion 58, as viewed in the y-direction. The second portion 52T overlaps with the second portion 52S, and includes a portion extending toward the fourth face 34, as viewed in the y-direction. The second portion 52T is spaced apart from the second portion 52R toward the sixth face 36, as viewed in the x-direction. The shape of the second portion 52T is not specifically limited, and a desired shape may be selected from a rectangular shape, a polygonal shape, a circular shape, an elliptical shape, and so forth. In the illustrated example, the second portion 52T has a rectangular shape.

The third portion 53T is interposed between the first portion 51T and the second portion 52T and, in the illustrated example, connected to the edge of the first portion 51T on the side of the fourth face 34 in the x-direction. The shape of the third portion 53T is not specifically limited. In the illustrated example, the third portion 53T has a strip shape extending along the x-direction. The third portion 53T overlaps with the third portion 53S, as viewed in the y-direction. In the illustrated example, the third portion 53T is longer and wider than the third portion 53S.

The fourth portion 54T is interposed between the first portion 51T and the second portion 52T and, in the illustrated example, connected to the edge of the second portion 52T on the side of the sixth face 36 in the y-direction. The shape of the fourth portion 54T is not specifically limited. In the illustrated example, the fourth portion 54T has a strip shape extending along the y-direction. The fourth portion 54T overlaps with the third base portion 58 and the fourth portion 54S, as viewed in the x-direction. The fourth portion 54T is wider than the fourth portion 54S.

The fifth portion 55T is interposed between the third portion 53T and the fourth portion 54T and, in the illustrated example, connected to the third portion 53T and the fourth portion 54T. The shape of the fifth portion 55T is not specifically limited. In the illustrated example, the fifth portion 55T has a strip shape inclined with respect to the x-direction and the y-direction. The fifth portion 55T is generally parallel to the fifth portion 55S. Here, the expression “generally parallel” refers to, for example, being exactly parallel to each other, or a situation where the angles with respect to the x-direction or y-direction are different by within ±5%. The fifth portion 55T is longer and wider than the fifth portion 55S.

The wiring 50U includes a second portion 52U, a third portion 53U, a fourth portion 54U, and a fifth portion 55U, each of which will be described hereunder.

The second portion 52U is located on the side of the fifth face 35 with respect to the second base portion 56, in the y-direction. The second portion 52O is located on the side of the sixth face 36 in the y-direction with respect to the second portion 52I, and spaced therefrom. The second portion 52U is spaced apart from the third base portion 58, as viewed in the y-direction. The second portion 52O overlaps with the second portion 52T, and includes a portion extending from the second portion 52T toward the fourth face 34, as viewed in the y-direction. The second portion 52O is spaced apart from the second portion 52R toward the sixth face 36, as viewed in the x-direction. The shape of the second portion 52U is not specifically limited, and a desired shape may be selected from a rectangular shape, a polygonal shape, a circular shape, an elliptical shape, and so forth. In the illustrated example, the second portion 52U has a rectangular shape.

The third portion 53U is located on the side of the sixth face 36 in the y-direction, with respect to the first portion 51T and the third portion 53T. The third portion 53U is connected to the edge of the second base portion 56 on the side of the fourth face 34 in the x-direction. The shape of the third portion 53U is not specifically limited. In the illustrated example, the third portion 53U has a strip shape extending along the x-direction. The third portion 53U overlaps with the third portion 53S, the third portion 53T, and the first portion 51T, as viewed in the y-direction. In the illustrated example, the third portion 53U is longer than the third portion 53T. Further, the third portion 53U has generally the same width as the third portion 53T. Here, the expression “generally the same width” refers to, for example, being exactly the same, or different by within ±5% from each other's width.

The fourth portion 54U is interposed between the first portion 51U and the second portion 52O and, in the illustrated example, connected to the edge of the second portion 52O on the side of the sixth face 36 in the y-direction. The shape of the fourth portion 54U is not specifically limited. In the illustrated example, the fourth portion 54U has a strip shape extending along the y-direction. The fourth portion 54U overlaps with the third base portion 58, the fourth portion 54S, and the fourth portion 54T, as viewed in the x-direction. The fourth portion 54U has generally the same width as the fourth portion 54T. Here, the expression “generally the same width” refers to, for example, being exactly the same, or different by within ±5% from each other's width.

The fifth portion 55U is interposed between the third portion 53U and the fourth portion 54U and, in the illustrated example, connected to the third portion 53U and the fourth portion 54U. The shape of the fifth portion 55U is not specifically limited. In the illustrated example, the fifth portion 55U has a strip shape inclined with respect to the x-direction and the y-direction. The fifth portion 55U is generally parallel to the fifth portion 55T. Here, the expression “generally parallel” refers to, for example, being exactly parallel to each other, or a situation where the angles with respect to the x-direction or y-direction are different by within 5%. The fifth portion 55U has generally the same width as the fifth portion 55T. Here, the expression “generally the same width” refers to, for example, being exactly the same, or different by within ±5% from each other's width.

The wiring 50a includes a first portion 51a, a second portion 52a, and a third portion 53a, each of which will be described hereunder.

The first portion 51a is located on the side of the third face 33 in the x-direction with respect to the first base portion 55, and spaced therefrom. The first portion 51a is located on the side of the sixth face 36 in the y-direction with respect to the first portion 51A, and spaced therefrom. In the illustrated example, the first portion 51a overlaps with the first portion 51A and the first portion 51B, as viewed in the y-direction. The first portion 51a overlaps with the first base portion 55, as viewed in the x-direction. The shape of the first portion 51a is not specifically limited. In the illustrated example, the first portion 51a has a rectangular shape.

The second portion 52a is located on the side of the third face 33 in the x-direction with respect to the first portion 51a, and spaced therefrom. The second portion 52a overlaps with the first portion 51a and the first base portion 55, as viewed in the x-direction. The second portion 52a overlaps with the fifth portion 55A, as viewed in the y-direction. The shape of the second portion 52a is not specifically limited, and a desired shape may be selected from a rectangular shape, a polygonal shape, a circular shape, an elliptical shape, and so forth. In the illustrated example, the second portion 52a has a rectangular shape.

The third portion 53a is interposed between the first portion 51a and the second portion 52a and, in the illustrated example, connected to the first portion 51a and the second portion 52a. The shape of the third portion 53a is not specifically limited. In the illustrated example, the third portion 53a has a strip shape extending along the x-direction. The third portion 53a overlaps with the first portion 51a, the second portion 52a, and the first base portion 55, as viewed in the x-direction. The third portion 53a overlaps with the first portion 51A and the fifth portion 55A, as viewed in the y-direction.

The wiring 50b includes a first portion 51b, a second portion 52b, and a third portion 53b, each of which will be described hereunder.

The first portion 51b is located on the side of the third face 33 in the x-direction with respect to the first base portion 55, and spaced therefrom. The first portion 51b is located between the first portion 51a and the first portion 51A, in the y-direction. In the illustrated example, the first portion 51b overlaps with the first portion 51a and the first portion 51A, as viewed in the y-direction. The first portion 51b overlaps with the first base portion 55, as viewed in the x-direction. The shape of the first portion 51b is not specifically limited. In the illustrated example, the first portion 51b has a rectangular shape.

The second portion 52b is located on the side of the third face 33 in the x-direction with respect to the first portion 51b, and spaced therefrom. In addition, the second portion 52b is located on the side of the third face 33 in the x-direction with respect to the second portion 52b, and spaced therefrom. The second portion 52b overlaps with the first portion 51b, the first portion 51a, and the second portion 52a, as viewed in the x-direction. An end portion of the second portion 52b includes a portion extending from the second portion 52a toward the fifth face 35, as viewed in the x-direction. The second portion 52b overlaps with the fifth portion 55A, as viewed in the y-direction. The shape of the second portion 52b is not specifically limited, and a desired shape may be selected from a rectangular shape, a polygonal shape, a circular shape, an elliptical shape, and so forth. In the illustrated example, the second portion 52b has a rectangular shape.

The third portion 53b is interposed between the first portion 51b and the second portion 52b and, in the illustrated example, connected to the first portion 51b and the second portion 52b. The shape of the third portion 53b is not specifically limited. In the illustrated example, the third portion 53b has a strip shape extending along the x-direction. The third portion 53b overlaps with the first portion 51b, the second portion 52b, and the first base portion 55, as viewed in the x-direction. The third portion 53b overlaps with the first portion 51A and the fifth portion 55A, as viewed in the y-direction. In the illustrated example, the third portion 53b is longer than the third portion 53a, and has generally the same width as the third portion 53a. Here, the expression “generally the same width” refers to, for example, being exactly the same, or different by within ±5% from each other's width.

The wiring 50c includes a first portion 51c, a second portion 52c, and a third portion 53c, each of which will be described hereunder.

The first portion 51c is located on the side of the fourth face 34 in the x-direction with respect to the first base portion 55, and spaced therefrom. The first portion 51c is located between the connecting portion 57 and the first portion 51H, in the y-direction. In the illustrated example, the first portion 51c overlaps with the first portion 571 and the second portion 572 of the connecting portion 57, as viewed in the y-direction. The first portion 51c overlaps with the first base portion 55, as viewed in the x-direction. The shape of the first portion 51c is not specifically limited. In the illustrated example, the first portion 51c has a polygonal shape including three sides inclined with respect to the x-direction and the y-direction.

The second portion 52c is located on the side of the fourth face 34 in the x-direction with respect to the first portion 51c, with a spacing therefrom, and on the side of the third face 33 in the x-direction with respect to the second base portion 56, with a spacing therefrom. The second portion 52c overlaps with the second base portion 56, as viewed in the x-direction. The second portion 52c overlaps with the first portion 571 and the third portion 573 of the connecting portion 57, as viewed in the y-direction. The shape of the second portion 52c is not specifically limited, and a desired shape may be selected from a rectangular shape, a polygonal shape, a circular shape, an elliptical shape, and so forth. In the illustrated example, the second portion 52c has a polygonal shape including three sides inclined with respect to the x-direction and the y-direction.

The third portion 53c is interposed between the first portion 51c and the second portion 52c and, in the illustrated example, connected to the first portion 51c and the second portion 52c. The shape of the third portion 53c is not specifically limited. In the illustrated example, the third portion 53c has a strip shape extending along the x-direction. The third portion 53c overlaps with the first portion 51c, the second portion 52c, the first base portion 55, and the second base portion 56, as viewed in the x-direction. The third portion 53c overlaps with the first portion 571 of the connecting portion 57, as viewed in the y-direction. In the illustrated example, the third portion 53c has generally the same width as the first portion 571. Here, the expression “generally the same width” refers to, for example, being exactly the same, or different by within ±5% from each other's width.

The wiring 50d includes a first portion 51d, a second portion 52d, and a third portion 53d, each of which will be described hereunder.

The first portion 51d is located on the side of the fourth face 34 in the x-direction with respect to the first base portion 55, with a spacing therefrom, and on the side of the fourth face 34 with respect to the first portion 51c, with a spacing therefrom. The first portion 51d is located between the connecting portion 57 and the first portion 51H in the y-direction, at a position shifted toward the fifth face 35 from the first portion 51c. In the illustrated example, the first portion 51d overlaps with the first portion 571 of the connecting portion 57, as viewed in the y-direction. The first portion 51d overlaps with the first base portion 55 and the first portion 51c, as viewed in the x-direction. The shape of the first portion 51d is not specifically limited. In the illustrated example, the first portion 51d has a polygonal shape including three sides inclined with respect to the x-direction and the y-direction.

The second portion 52d is located on the side of the fourth face 34 in the x-direction with respect to the first portion 51d, with a spacing therefrom, and on the side of the third face 33 in the x-direction with respect to the second base portion 56, with a spacing therefrom. The second portion 52d is located at a position shifted toward the third face 33 in the x-direction, from the second portion 52c. The second portion 52d overlaps with the second base portion 56, as viewed in the x-direction. The second portion 52d overlaps with the first portion 571 of the connecting portion 57, as viewed in the y-direction. The shape of the second portion 52d is not specifically limited, and a desired shape may be selected from a rectangular shape, a polygonal shape, a circular shape, an elliptical shape, and so forth. In the illustrated example, the second portion 52d has a polygonal shape including three sides inclined with respect to the x-direction and the y-direction.

The third portion 53d is interposed between the first portion 51d and the second portion 52d and, in the illustrated example, connected to the first portion 51d and the second portion 52d. The shape of the third portion 53d is not specifically limited. In the illustrated example, the third portion 53d has a strip shape extending along the x-direction. The third portion 53d overlaps with the first portion 51d, the second portion 52d, the first base portion 55, and the second base portion 56, as viewed in the x-direction. The third portion 53d overlaps with the first portion 571 of the connecting portion 57, as viewed in the y-direction. In the illustrated example, the third portion 53d is shorter than the third portion 53c, and has generally the same width as the third portion 53c. Here, the expression “generally the same width” refers to, for example, being exactly the same, or different by within ±5% from each other's width.

The wiring 50e includes a first portion 51e, a second portion 52e, and a third portion 53e, each of which will be described hereunder.

The first portion 51e is located on the side of the fourth face 34 in the x-direction with respect to the first base portion 55, and spaced therefrom. The first portion 51e is located between the connecting portion 57 and the first portion 51H in the y-direction, at a position shifted toward the fifth face 35 from the first portion 51d. In the illustrated example, the first portion 51e overlaps with the first portion 571 and the second portion 572 of the connecting portion 57, as viewed in the y-direction. The first portion 51e overlaps with the first base portion 55 and the first portion 51d, as viewed in the x-direction. The shape of the first portion 51e is not specifically limited. In the illustrated example, the first portion 51e has a polygonal shape including two sides inclined with respect to the x-direction and the y-direction.

The second portion 52e is located on the side of the fourth face 34 in the x-direction with respect to the first portion 51e, with a spacing therefrom, and on the side of the third face 33 in the x-direction with respect to the second base portion 56, with a spacing therefrom. The second portion 52e is located at a position shifted toward the fourth face 34 in the x-direction, from the second portion 52d. The second portion 52e overlaps with the second base portion 56, as viewed in the x-direction. The second portion 52e overlaps with the second portion 52c, the second portion 52d, and the first portion 571 and the third portion 573 of the connecting portion 57, as viewed in the y-direction. The shape of the second portion 52e is not specifically limited, and a desired shape may be selected from a rectangular shape, a polygonal shape, a circular shape, an elliptical shape, and so forth. In the illustrated example, the second portion 52e has a polygonal shape including two sides inclined with respect to the x-direction and the y-direction.

The third portion 53e is interposed between the first portion 51e and the second portion 52e and, in the illustrated example, connected to the first portion 51e and the second portion 52e. The shape of the third portion 53e is not specifically limited. In the illustrated example, the third portion 53e has a strip shape extending along the x-direction. The third portion 53e overlaps with the first portion 51e, the second portion 52e, the first base portion 55, and the second base portion 56, as viewed in the x-direction. The third portion 53e overlaps with the first portion 571 of the connecting portion 57, as viewed in the y-direction. In the illustrated example, the third portion 53e is longer than the third portion 53d, and has generally the same length as the third portion 53c. Here, the expression “generally the same length” refers to, for example, being exactly the same, or different by within ±5% from each other's length. Further, the third portion 53e has generally the same width as the third portion 53d. Here, the expression “generally the same width” refers to, for example, being exactly the same, or different by within ±5% from each other's width.

Referring to FIG. 46, in the illustrated example, the first portion 51c includes a first edge 511c, a second edge 512c, a third edge 513c, and a fourth edge 514c. The first edge 511c is connected to the third portion 53c, and inclined so as to be closer to the fifth face 35 in the y-direction, toward the third face 33 in the x-direction. The second edge 512c is connected to the first edge 511c, and inclined so as to be closer to the sixth face 36 in the y-direction, toward the third face 33 in the x-direction. The third edge 513c is connected to the second edge 512c, and inclined so as to be closer to the fifth face 35 in the y-direction, toward the third face 33 in the x-direction. The fourth edge 514c is connected to the third edge 513c and the third portion 53c, and extends along the x-direction.

In the illustrated example, the first portion 51d includes a first edge 511d, a second edge 512d, a third edge 513d, and a fourth edge 514d. The third edge 513d is connected to the third portion 53d, and inclined so as to be closer to the sixth face 36 in the y-direction, toward the third face 33 in the x-direction. The first edge 511d is connected to the third edge 513d, and inclined so as to be closer to the fifth face 35 in the y-direction, toward the third face 33 in the x-direction. The first edge 511d is opposed to the first edge 511c. The second edge 512d is connected to the first edge 511d, and inclined so as to be closer to the sixth face 36 in the y-direction, toward the third face 33 in the x-direction. The fourth edge 514d is connected to the second edge 512d and the third portion 53d, and inclined so as to be closer to the fifth face 35 in the y-direction, toward the third face 33 in the x-direction.

In the illustrated example, the first portion 51e includes a first edge 511e, a second edge 512e, a third edge 513e, and a fourth edge 514e. The first edge 511e is connected to the third portion 53e, and inclined so as to be closer to the sixth face 36 in the y-direction, toward the third face 33 in the x-direction. The first edge 511e is opposed to the second edge 512d. The second edge 512e is connected to the first edge 511e, and inclined so as to be closer to the fifth face 35 in the y-direction, toward the third face 33 in the x-direction. The third edge 513e is connected to the second edge 512e, and extends along the y-direction. The third edge 513e is opposed to the first base portion 55. The fourth edge 514e is connected to the third edge 513e and the third portion 53e, and extends along the x-direction.

Referring to FIG. 47, in the illustrated example, the second portion 52c includes a first edge 521c, a second edge 522c, a third edge 523c, and a fourth edge 524c. The first edge 521c is connected to the third portion 53c, and inclined so as to be closer to the fifth face 35 in the y-direction, toward the fourth face 34 in the x-direction. The second edge 522c is connected to the first edge 521c, and inclined so as to be closer to the sixth face 36 in the y-direction, toward the fourth face 34 in the x-direction. The third edge 523c is connected to the second edge 522c, and inclined so as to be closer to the fifth face 35 in the y-direction, toward the fourth face 34 in the x-direction. The fourth edge 524c is connected to the third edge 523c and the third portion 53c, and extends along the x-direction.

In the illustrated example, the second portion 52d includes a first edge 521d, a second edge 522d, a third edge 523d, and a fourth edge 524d. The third edge 523d is connected to the third portion 53d, and inclined so as to be closer to the sixth face 36 in the y-direction, toward the fourth face 34 in the x-direction. The first edge 521d is connected to the third edge 523d, and inclined so as to be closer to the fifth face 35 in the y-direction, toward the fourth face 34 in the x-direction. The first edge 521d is opposed to the first edge 521c. The second edge 522d is connected to the first edge 521d, and inclined so as to be closer to the sixth face 36 in the y-direction, toward the fourth face 34 in the x-direction. The fourth edge 524d is connected to the second edge 522d and the third portion 53d, and inclined so as to be closer to the fifth face 35 in the y-direction, toward the fourth face 34 in the x-direction.

In the illustrated example, the second portion 52e includes a first edge 521e, a second edge 522e, a third edge 523e, and a fourth edge 524e. The first edge 521e is connected to the third portion 53e, and inclined so as to be closer to the sixth face 36 in the y-direction, toward the fourth face 34 in the x-direction. The first edge 521e is opposed to the second edge 522d. The second edge 522e is connected to the first edge 521e, and inclined so as to be closer to the fifth face 35 in the y-direction, toward the fourth face 34 in the x-direction. The third edge 523e is connected to the second edge 522e, and extends along the y-direction. The third edge 523e is opposed to the second base portion 56. The fourth edge 524e is connected to the third edge 523e and the third portion 53e, and extends along the x-direction.

As shown in FIG. 45, the wiring 50f includes a first portion 51f, a second portion 52f, and a third portion 53f, each of which will be described hereunder.

The first portion 51f is located on the side of the fourth face 34 in the x-direction with respect to the second base portion 56, and spaced therefrom. The first portion 51f is located on the side of the sixth face 36 in the y-direction with respect to the third portion 53O, and spaced therefrom. In the illustrated example, the first portion 51f overlaps with the second base portion 56, as viewed in the x-direction. The first portion 51f overlaps with the third portion 53U, the first portion 51T, and the first portion 51S, as viewed in the y-direction. The shape of the first portion 51f is not specifically limited, and a desired shape may be selected from a rectangular shape, a polygonal shape, a circular shape, an elliptical shape, and so forth. In the illustrated example, the first portion 51f has a rectangular shape.

The second portion 52f is located on the side of the fourth face 34 in the x-direction with respect to the first portion 51f. The second portion 52f is located on the side of the sixth face 36 in the y-direction with respect to the third portion 53U, and spaced therefrom. In the illustrated example, the second portion 52f overlaps with the first portion 51f and the second base portion 56, as viewed in the x-direction. The second portion 52f also overlaps with the fifth portion 55U, as viewed in the y-direction. The shape of the second portion 52f is not specifically limited, and a desired shape may be selected from a rectangular shape, a polygonal shape, a circular shape, an elliptical shape, and so forth. In the illustrated example, the second portion 52f has a rectangular shape.

The third portion 53f is interposed between the first portion 51f and the second portion 52f and, in the illustrated example, connected to the first portion 51f and the second portion 52f. The shape of the third portion 53f is not specifically limited. In the illustrated example, the third portion 53f has a strip shape extending along the x-direction. The third portion 53f overlaps with the first portion 51f, the second portion 52f, and the second base portion 56, as viewed in the x-direction. The third portion 53f overlaps with the third portion 53U and the third portion 53T, as viewed in the y-direction. In the illustrated example, the third portion 53f is longer than the third portion 53Td, and narrower than the third portion 53T and the third portion 53U.

As shown in FIG. 44 and FIG. 45, the second portion 52C to the second portion 52H are aligned in the x-direction, with clearances G51 between each other. A difference in size among the clearances G51 is within ±5%. The second portion 52H and the second portion 52I are aligned in the x-direction, with a clearance G52 therebetween. The clearance G52 is wider than the clearance G51. The second portion 52I to the second portion 52R are aligned in the x-direction, with clearances G53 between each other. The clearances G53 are narrower than the clearance G51 and the clearance G52, and a difference among the clearances G53 is within ±5%. The second portion 52R and the second portion 52S are aligned in the x-direction, with a clearance G54 therebetween. The clearance G54 is wider than the clearance G53 and the clearance G51, and narrower than the clearance G52.

### <Bonding Section 6>

Regarding the bonding section 6 according to this embodiment, although any of the elements is apparently given, for the sake of convenience of description, the same numeral as that of the bonding section 6 according to the first embodiment, it does not necessarily mean that the mentioned element has the same or similar configuration. The configuration of an element with a numeral is defined by the description relevant to this embodiment.

The plurality of bonding sections 6 are formed on the substrate 3. In this embodiment, the plurality of bonding sections 6 are formed on the first face 31 of the substrate 3. The bonding section 6 is formed of, for example, a conductive material. The conductive material to form the bonding section 6 is not specifically limited. Examples of the conductive material to form the bonding section 6 include materials containing silver (Ag), copper (Cu), or gold (Au). In the subsequent description, it will be assumed that the bonding section 6 contains silver. The bonding section 6 according to this embodiment contains the same conductive material as that employed to form the conductive section 5. However, the bonding section 6 may contain copper instead of silver, or gold instead of silver or copper. Alternatively, the bonding section 6 may contain Ag—Pt or Ag—Pd. The forming method of the bonding section 6 is not limited. For example, the bonding section 6 may be formed, like the conductive section 5, by sintering a paste containing the mentioned metal. The thickness of the bonding section 6 is not specifically limited, but may be, for example, approximately 5 μm to 30 μm.

In this embodiment, as shown in FIG. 39 to FIG. 43 and FIG. 48, the plurality of bonding sections 6 include a bonding section 6A to a bonding section 6D.

As shown in FIG. 39, FIG. 41, FIG. 42, and FIG. 48, the bonding section 6A is located on the side of the sixth face 36 with respect to the conductive section 5, in the y-direction. The bonding section 6A overlaps with the entirety of the first base portion 55, as viewed in the y-direction. The shape of the bonding section 6A is not specifically limited. In the illustrated example, the bonding section 6A includes a first edge 61A, a second edge 62A, a third edge 63A, a fourth edge 64A, a fifth edge 65A, a sixth edge 66A, a seventh edge 67Aa, an eighth edge 68Ab, and a ninth edge 67Ab.

The first edge 61A extends along the y-direction. In the illustrated example, the first edge 61A overlaps with the second portion 52A, as viewed in the y-direction.

The second edge 62A is located on the opposite side of the first edge 61A in the x-direction, across the center of the bonding section 6A in the x-direction, and extends along the y-direction. In the illustrated example, the second edge 62A overlaps with the first portion 571 of the connecting portion 57, the third portion 53c, the third portion 53d, the third portion 53e, and the first portion 51H, as viewed in the y-direction. The second edge 62A is smaller in size in the y-direction, than the first edge 61A.

The third edge 63A is located between the first edge 61A and the second edge 62A, as viewed in the y-direction. The third edge 63A extends along the x-direction. The third edge 63A is spaced apart from the first base portion 55, in the y-direction. In the illustrated example, the third edge 63A overlaps with the first portion 51A to the first portion 51H, and the wirings 50a to 50e, as viewed in the y-direction.

The fourth edge 64A is located on the opposite side of the third edge 63A in the y-direction, across the center of the bonding section 6A in the y-direction. The fourth edge 64A extends along the x-direction. The fourth edge 64A is smaller in size in the x-direction, than the third edge 63A. The entirety of the fourth edge 64A overlaps with the third edge 63A, as viewed in the y-direction.

The fifth edge 65A is located between the second edge 62A and the fourth edge 64A, in the y-direction. The fifth edge 65A, extending along the x-direction, overlaps with the first edge 61A, as viewed in the x-direction.

The sixth edge 66A is connected to the end of the fifth edge 65A on the side of the third face 33 in the x-direction, and the end of the fourth edge 64A on the side of the fourth face 34 in the x-direction. In the illustrated example, the sixth edge 66A is inclined with respect to the x-direction and the y-direction.

The seventh edge 67Aa is located between the first edge 61A and the third edge 63A in the x-direction, and between the first edge 61A and the third edge 63A in the y-direction. The seventh edge 67Aa is connected to the first edge 61A and the third edge 63A. In the illustrated example, the seventh edge 67Aa forms a convex curved surface, as viewed in the z-direction. The ninth edge 67Ab is located between the second edge 62A and the third edge 63A in the x-direction, and between the second edge 62A and the third edge 63A in the y-direction. The ninth edge 67Ab is connected to the second edge 62A and the third edge 63A. In the illustrated example, the ninth edge 67Ab forms a convex curved surface, as viewed in the z-direction.

The eighth edge 68Ab is located between the second edge 62A and the fifth edge 65A in the y-direction. In the illustrated example, the eighth edge 68A is connected to the end of the second edge 62A on the side of the sixth face 36 in the y-direction, and the end of the fifth edge 65A on the side of the fourth face 34 in the x-direction. In the illustrated example, the eighth edge 68A is inclined with respect to the x-direction and the y-direction.

As shown in FIG. 39, FIG. 41, and FIG. 43, the bonding section 6B is located on the side of the sixth face 36 with respect to the conductive section 5, in the y-direction. The bonding section 6B is located on the side of the fourth face 34 with respect to the bonding section 6A, in the x-direction. In the illustrated example, the bonding section 6B overlaps with the connecting portion 57, the wirings 50c to 50e, and the second base portion 56, as viewed in the y-direction. The shape of the bonding section 6B is not specifically limited. In the illustrated example, the bonding section 6B includes a first edge 61B, a second edge 62B, a third edge 63B, a fourth edge 64B, a fifth edge 65B, a sixth edge 66B, a seventh edge 67Ba, a ninth edge 69Ba, a tenth edge 67Bb, and an eleventh edge 69Bb.

The first edge 61B extends along the y-direction. The first edge 61B is opposed to the second edge 62A. In the illustrated example, the first edge 61B overlaps with the first portion 571 of the connecting portion 57, the third portion 53c, the third portion 53d, the third portion 53e, and the first portion 51H, as viewed in the y-direction.

The second edge 62B is located on the opposite side of the first edge 61B in the x-direction, across the center of the bonding section 6B in the x-direction, and extends along the y-direction. In the illustrated example, the second edge 62B overlaps with the second base portion 56, as viewed in the y-direction. The second edge 62B is smaller in size in the y-direction, than the first edge 61B. In addition, the second edge 62B is generally the same in size in the y-direction, as the second edge 62A (exactly the same, or different by within ±5%).

The third edge 63B is located between the first edge 61B and the second edge 62B, as viewed in the y-direction. The third edge 63B extends along the x-direction. The third edge 63B is spaced apart from the second base portion 56, in the y-direction. In the illustrated example, the third edge 63B overlaps with the second base portion 56, the connecting portion 57, and the wirings 50a to 50e, as viewed in the y-direction. In the illustrated example, in addition, the third edge 63B is located generally at the same position as the third edge 63A, in the y-direction. Here, the expression “located generally at the same position” in the y-direction refers to, for example, being located exactly at the same position, or being deviated by within ±5% of the characteristic size (size of the bonding section 6A or bonding section 6B in the y-direction).

The fourth edge 64B is located on the opposite side of the third edge 63B in the y-direction, across the center of the bonding section 6B in the y-direction. The fourth edge 64B extends along the x-direction. The fourth edge 64B is connected to the end of the first edge 61B on the side of the sixth face 36 in the y-direction. The fourth edge 64B is smaller in size in the x-direction, than the third edge 63B. The entirety of the fourth edge 64B overlaps with the third edge 63B, as viewed in the y-direction.

The fifth edge 65B is located between the second edge 62B and the fourth edge 64B, in the x-direction and the y-direction. In the illustrated example, the fifth edge 65B extends along the x-direction. The fifth edge 65B is smaller in size in the x-direction, than the third edge 63B.

The sixth edge 66B is connected to the fourth edge 64B and the fifth edge 65B. In the illustrated example, the sixth edge 66B is inclined with respect to the x-direction and the y-direction.

The seventh edge 67Ba is located between the first edge 61B and the third edge 63B in the x-direction, and between the first edge 61B and the third edge 63B in the y-direction. The seventh edge 67Ba is connected to the first edge 61B and the third edge 63B. In the illustrated example, the seventh edge 67Ba forms a convex curved surface, as viewed in the z-direction. The tenth edge 67Bb is located between the second edge 62B and the third edge 63B in the x-direction, and between the second edge 62B and the third edge 63B in the y-direction. The tenth edge 67Bb is connected to the second edge 62B and the third edge 63B. In the illustrated example, the tenth edge 67Bb forms a convex curved surface, as viewed in the z-direction.

The ninth edge 69Ba is located between the first edge 61B and the fourth edge 64B, in the y-direction. In the illustrated example, the ninth edge 69Ba is connected to the end of the first edge 61B on the side of the sixth face 36 in the y-direction, and the end of the fourth edge 64B on the side of the third face 33 in the x-direction. In the illustrated example, the ninth edge 69Ba is inclined with respect to the x-direction and the y-direction.

The eleventh edge 69Bb is located between the second edge 62B and the fifth edge 65B, in the y-direction. In the illustrated example, the eleventh edge 69Bb is connected to the end of the second edge 62B on the side of the sixth face 36 in the y-direction, and the end of the fifth edge 65B on the side of the fourth face 34 in the x-direction. In the illustrated example, the eleventh edge 69Bb is inclined with respect to the x-direction and the y-direction.

As shown in FIG. 39, FIG. 41, and FIG. 43, the bonding section 6C is located on the side of the sixth face 36 with respect to the conductive section 5, in the y-direction. The bonding section 6C is located on the side of the fourth face 34 with respect to the bonding section 6B, in the x-direction. In the illustrated example, the bonding section 6C overlaps with the wirings 50S to 50U, the wiring 50f, and the second base portion 56, as viewed in the y-direction. The shape of the bonding section 6C is not specifically limited. In the illustrated example, the bonding section 6C includes a first edge 61C, a second edge 62C, a third edge 63C, a fourth edge 64C, a fifth edge 65C, a sixth edge 66C, a seventh edge 67Ca, a ninth edge 69Ca, a tenth edge 67Cb, and an eleventh edge 69Cb.

The first edge 61C extends along the y-direction. The first edge 61C is opposed to the second edge 62B. In the illustrated example, the first edge 61C overlaps with the second base portion 56, as viewed in the y-direction.

The second edge 62C is located on the opposite side of the first edge 61C in the x-direction, across the center of the bonding section 6C in the x-direction, and extends along the y-direction. In the illustrated example, the second edge 62C overlaps with the wirings 50S to 50U and the wiring 50f, as viewed in the y-direction. The second edge 62C is smaller in size in the y-direction, than the first edge 61C. In addition, the second edge 62C is generally the same in size in the y-direction, as the second edge 62B (exactly the same, or different by within ±5%).

The third edge 63C is located between the first edge 61C and the second edge 62C, as viewed in the y-direction. The third edge 63C extends along the x-direction. The third edge 63C is spaced apart from the second base portion 56, in the y-direction. In the illustrated example, the third edge 63C overlaps with the wirings 50S to 50U, the wiring 50f, and the second base portion 56, as viewed in the y-direction. In the illustrated example, in addition, the third edge 63C is located generally at the same position as the third edge 63B, in the y-direction. Here, the expression “located generally at the same position” in the y-direction refers to, for example, being located exactly at the same position, or being deviated by within ±5% of the characteristic size (size of the bonding section 6B or bonding section 6C in the y-direction).

The fourth edge 64C is located on the opposite side of the third edge 63C in the y-direction, across the center of the bonding section 6C in the y-direction. The fourth edge 64C extends along the x-direction. The fourth edge 64C is connected to the end of the first edge 61C on the side of the sixth face 36 in the y-direction. The fourth edge 64C is smaller in size in the x-direction, than the third edge 63C. The entirety of the fourth edge 64C overlaps with the third edge 63C, as viewed in the y-direction.

The fifth edge 65C is located between the second edge 62C and the fourth edge 64C, in the x-direction and the y-direction. In the illustrated example, the fifth edge 65C extends along the x-direction. The fifth edge 65C is smaller in size in the x-direction, than the third edge 63C.

The sixth edge 66C is connected to the fourth edge 64C and the fifth edge 65C. In the illustrated example, the sixth edge 66C is inclined with respect to the x-direction and the y-direction.

The seventh edge 67Ca is located between the first edge 61C and the third edge 63C in the x-direction, and between the first edge 61C and the third edge 63C in the y-direction. The seventh edge 67Ca is connected to the first edge 61C and the third edge 63C. In the illustrated example, the seventh edge 67Ca forms a convex curved surface, as viewed in the z-direction. The tenth edge 67Cb is located between the second edge 62C and the third edge 63C in the x-direction, and between the second edge 62C and the third edge 63C in the y-direction. The tenth edge 67Cb is connected to the second edge 62C and the third edge 63C. In the illustrated example, the tenth edge 67Cb forms a convex curved surface, as viewed in the z-direction.

The ninth edge 69Ca is located between the first edge 61C and the fourth edge 64C, in the y-direction. In the illustrated example, the ninth edge 69Ca is connected to the end of the first edge 61C on the side of the sixth face 36 in the y-direction, and the end of the fourth edge 64C on the side of the third face 33 in the x-direction. In the illustrated example, the ninth edge 69Ca is inclined with respect to the x-direction and the y-direction.

The eleventh edge 69Cb is located between the second edge 62C and the fifth edge 65C, in the y-direction. In the illustrated example, the eleventh edge 69Cb is connected to the end of the second edge 62C on the side of the sixth face 36 in the y-direction, and the end of the fifth edge 65C on the side of the fourth face 34 in the x-direction. In the illustrated example, the ninth edge 69Cb is inclined with respect to the x-direction and the y-direction.

As shown in FIG. 39, FIG. 41, and FIG. 43, the bonding section 6D is located on the side of the sixth face 36 with respect to the conductive section 5, in the y-direction. The bonding section 6D is located on the side of the fourth face 34 with respect to the bonding section 6C, in the x-direction. In the illustrated example, the bonding section 6D overlaps with the wirings 50S to 50U and the wiring 50f, as viewed in the y-direction, and is spaced apart from the second base portion 56. The shape of the bonding section 6D is not specifically limited. In the illustrated example, the bonding section 6D includes a first edge 61D, a second edge 62D, a third edge 63D, a fourth edge 64D, a seventh edge 67Da, a ninth edge 69Da, a tenth edge 67Db, and an eleventh edge 69Db.

The first edge 61D extends along the y-direction. The first edge 61D is opposed to the second edge 62C. In the illustrated example, the first edge 61D overlaps with the wirings 50S to 50U and the wiring 50f, as viewed in the y-direction.

The second edge 62D is located on the opposite side of the first edge 61D in the x-direction, across the center of the bonding section 6D in the x-direction, and extends along the y-direction. In the illustrated example, the second edge 62D overlaps with the wirings 50S to 50U, as viewed in the y-direction. The second edge 62D is generally the same in size in the y-direction, as the first edge 61D (exactly the same, or different by within ±5%). Further, the second edge 62D is larger in size in the y-direction, than the second edge 62C.

The third edge 63D is located between the first edge 61D and the second edge 62D, as viewed in the y-direction. The third edge 63D extends along the x-direction. The third edge 63D is spaced apart from the second base portion 56, in the y-direction. In the illustrated example, the third edge 63D overlaps with the wirings 50S to 50U, the wiring 50f, and the second base portion 56, as viewed in the y-direction. In the illustrated example, in addition, the third edge 63D is located generally at the same position as the third edge 63C, in the y-direction. Here, the expression “located generally at the same position” in the y-direction refers to, for example, being located exactly at the same position, or being deviated by within ±5% of the characteristic size (size of the bonding section 6C or bonding section 6D in the y-direction).

The fourth edge 64D is located on the opposite side of the third edge 63D in the y-direction, across the center of the bonding section 6D in the y-direction. The fourth edge 64D extends along the x-direction. The fourth edge 64D is connected to the end of the first edge 61D on the side of the sixth face 36 in the y-direction. The fourth edge 64D is generally the same in size in the x-direction, as the third edge 63D (exactly the same, or different by within ±5%).

The seventh edge 67Da is located between the first edge 61D and the third edge 63D in the x-direction, and between the first edge 61D and the third edge 63D in the y-direction. The seventh edge 67Da is connected to the first edge 61D and the third edge 63D. In the illustrated example, the seventh edge 67Da forms a convex curved surface, as viewed in the z-direction. The tenth edge 67Db is located between the second edge 62D and the third edge 63D in the x-direction, and between the second edge 62D and the third edge 63D in the y-direction. The tenth edge 67Db is connected to the second edge 62D and the third edge 63D. In the illustrated example, the tenth edge 67Db forms a convex curved surface, as viewed in the z-direction.

The ninth edge 69Da is located between the first edge 61D and the fourth edge 64D, in the y-direction. In the illustrated example, the ninth edge 69Da is connected to the end of the first edge 61D on the side of the sixth face 36 in the y-direction, and the end of the fourth edge 64D on the side of the third face 33 in the x-direction. In the illustrated example, the ninth edge 69Da is inclined with respect to the x-direction and the y-direction.

The eleventh edge 69Db is located between the second edge 62D and the fourth edge 64D, in the y-direction. In the illustrated example, the eleventh edge 69Db is connected to the end of the second edge 62D on the side of the sixth face 36 in the y-direction, and the end of the fourth edge 64D on the side of the fourth face 34 in the x-direction. In the illustrated example, the eleventh edge 69Db is inclined with respect to the x-direction and the y-direction.

### <Leads 1>

Regarding the lead 1 according to this embodiment, although any of the elements is apparently given the same numeral, for the sake of convenience of description, as that of the lead 1 according to the first embodiment, it does not necessarily mean that the mentioned element has the same or similar configuration. The configuration of an element with a numeral is defined by the description relevant to this embodiment. The plurality of leads 1 contain and a metal, have higher heat dissipation characteristics, for example than the substrate 3. The metal to form the lead 1 is not specifically limited, and may be, for example, copper (Cu), aluminum, iron (Fe), oxygen-free copper, or an alloy of the cited metals, such as a Cu—Sn alloy, a Cu—Zr alloy, or a Cu—Fe alloy. The plurality of leads 1 may be plated with nickel (Ni). Examples of the forming method of the plurality of leads 1 include pressing a metal plate with a die, and patterning a metal plate by etching, without limitation thereto. The thickness of the lead 1 is not specifically limited, but may be, for example, approximately 0.4 mm to 0.8 mm.

The plurality of leads 1 include a plurality of leads 1A to 1G, as shown in FIG. 35 to FIG. 43. The plurality of leads 1A to 1G constitute conduction paths, for example to the semiconductor chips 4A to 4F.

The lead 1A is located on the substrate 3 and, in this embodiment, on the first face 31. The lead 1A exemplifies a first lead in the present disclosure. The lead 1A is bonded to the bonding section 6A, via a bonding material 81. It is preferable to employ a material having high thermal conductivity as the bonding material 81, such as silver paste, copper paste, or solder. However, the bonding material 81 may be an insulative material such as an epoxy-based resin or a silicone-based resin. In the case where the bonding section 6A is not provided on the substrate 3, the lead 1A may be bonded to the substrate 3.

The configuration of the lead 1A is not specifically limited and, in this embodiment, the lead 1A includes a first portion 11A, a second portion 12A, a third portion 13A, and a fourth portion 14A, each of which will be described hereunder.

As shown in FIG. 39, FIG. 40, FIG. 41, and FIG. 42, the first portion 11A includes a main surface 111A, a back surface 112A, a first face 121A, a second face 122A, a third face 123A, a fourth face 124A, a fifth face 125A, a sixth face 126A, a seventh face 127Aa, an eighth face 128A, a ninth face 127Ab, a plurality of recesses 1111A, and a groove 1112A. The first portion 11A overlaps with the sixth face 36 of the substrate 3, as viewed in the z-direction.

The main surface 111A is oriented in the same direction as the first face 31, in the z-direction.

The back surface 112A is oriented to the opposite side of the main surface 111A in the z-direction and, in the illustrated example, a planar surface. The back surface 112A is bonded to the bonding section 6A via the bonding material 81, as shown in FIG. 41 and FIG. 42.

The first face 121A is located between the main surface 111A and the back surface 112A in the z-direction, and oriented in the same direction as the third face 33 as a whole, in the x-direction. In the illustrated example, the first face 121A is connected to the main surface 111A and the back surface 112A.

The second face 122A is located on the opposite side of the first face 121A in the x-direction, and oriented in the same direction as the fourth face 34, in the x-direction. The second face 122A is located between the main surface 111A and the back surface 112A in the z-direction and, in the illustrated example, connected to the main surface 111A and the back surface 112A. The second face 122A is smaller in size in the y-direction, than the first face 121A.

The third face 123A is located between the first face 121A and the second face 122A in the x-direction, and oriented in the same direction as the fifth face 35, in the y-direction. The third face 123A is located between the main surface 111A and the back surface 112A in the z-direction and, in the illustrated example, connected to the main surface 111A and the back surface 112A.

The fourth face 124A is located on the opposite side of the third face 123A in the y-direction, and oriented in the same direction as the sixth face 36 in the y-direction. The fourth face 124A is located between the main surface 111A and the back surface 112A in the z-direction and, in the illustrated example, connected to the main surface 111A and the back surface 112A. The fourth face 124A is smaller in size in the x-direction, than the third face 123A.

The fifth face 125A is located between the first face 121A and the second face 122A in the x-direction, at a position close to the second face 122A. The fifth face 125A extends along the x-direction. The fifth face 125A is located between the main surface 111A and the back surface 112A in the z-direction and, in the illustrated example, connected to the main surface 111A and the back surface 112A.

The sixth face 126A is located between the fourth face 124A and the fifth face 125A, in the x-direction, and the y-direction. In the illustrated example, the sixth face 126A is connected to the fourth face 124A and the fifth face 125A. The sixth face 126A is inclined with respect to the x-direction and the y-direction. The sixth face 126A is located between the main surface 111A and the back surface 112A in the z-direction and, in the illustrated example, connected to the main surface 111A and the back surface 112A.

The seventh face 127Aa is located between the first face 121A and the third face 123A in the x-direction, and between the first face 121A and the third face 123A in the y-direction. The seventh face 127Aa is connected to the first face 121A and the third face 123A. In the illustrated example, the seventh face 127Aa forms a convex curved surface, as viewed in the z-direction. The seventh face 127Aa is located between the main surface 111A and the back surface 112A in the z-direction and, in the illustrated example, connected to the main surface 111A and the back surface 112A. The eleventh face 127Ab is located between the second face 122A and the third face 123A in the x-direction, and between the second face 122A and the third face 123A in the y-direction. The ninth face 127Ab is connected to the second face 122A and the third face 123A. In the illustrated example, the ninth face 127Ab forms a convex curved surface, as viewed in the z-direction. The ninth face 127Ab is located between the main surface 111A and the back surface 112A in the z-direction and, in the illustrated example, connected to the main surface 111A and the back surface 112A.

The eighth face 128A is located between the second face 122A and the fifth face 125A, in the x-direction and the y-direction. In the illustrated example, the eighth face 128A is connected to the second face 122A and the fifth face 125A. In the illustrated example, the eighth face 128A is inclined with respect to the x-direction and the y-direction. The eighth face 128A is located between the main surface 111A and the back surface 112A in the z-direction and, in the illustrated example, connected to the main surface 111A and the back surface 112A.

In the illustrated example, the first face 121A and the second face 122A each include a plurality of protrusions 131A. The plurality of protrusions 131A each protrude outwardly of the first portion 11A as viewed in the z-direction, and extend along the z-direction. Here, the plurality of protrusions 131A may be formed on the first portion 11A, in portions other than the first face 121A and the second face 122A. In addition, at least one of the first face 121A and the second face 122A may be without the plurality of protrusions 131A.

The plurality of recesses 1111A are each recessed from the main surface 111A in the z-direction. The shape of the recess 1111A in a z-direction view is not specifically limited, and may be, for example, circular, elliptical, rectangular, or triangular. In the illustrated example, the plurality of recesses 1111A are arranged in a matrix pattern.

The number of rows of the plurality of recesses 1111A in the y-direction is larger in the region between the groove 1112A and the third face 123A, than in the region between the groove 1112A and the fourth face 124A.

The number of rows of the plurality of recesses 1111A in the y-direction is larger in the region between the groove 1112A and the third face 123A, than in the region between the groove 1112A and the fourth face 124A.

The groove 1112A is recessed from the main surface 111A in the z-direction. The shape of the groove 1112A in a z-direction view is not specifically limited. In the illustrated example, the groove 1112A includes three rectangular sections, and three sections extending along the x-direction in the respective rectangular sections. The cross-sectional shape of the groove 1112A is not specifically limited and may be, for example, circular, elliptical, rectangular, or triangular.

The third portion 13A and the fourth portion 14A are covered with the encapsulating resin 7. The third portion 13A is connected to the first portion 11A and the fourth portion 14A. In the illustrated example, the third portion 13A is connected to a portion of the first portion 11A adjacent to the fourth face 124A. In addition, the third portion 13A is spaced apart from the sixth face 36, as viewed in the z-direction. Like a third portion 13B and a fourth portion 14B shown in FIG. 40, the fourth portion 14A is shifted from the first portion 11A in the z-direction, to the side to which the main surface 111A is oriented. The end portion of the fourth portion 14A is flush with a sixth face 76 of the resin 7.

The second portion 12A is connected to the end portion of the fourth portion 14A, and corresponds to a portion of the lead 1A sticking out from the encapsulating resin 7. The second portion 12A sticks out to the opposite side of the first portion 11A, in the y-direction. The second portion 12A is used, for example, to electrically connect the semiconductor device A2 to an external circuit. In the illustrated example, the second portion 12A is bent in the z-direction, to the side to which the main surface 111A is oriented. In this embodiment, the lead 1A includes a pair of second portions 12A, which are spaced apart from each other in the x-direction.

The lead 1B is located on the substrate 3 and, in this embodiment, on the first face 31. The lead 1B exemplifies a first lead in the present disclosure. The lead 1B is bonded to the bonding section 6B, via the bonding material 81. In the case where the bonding section 6B is not provided on the substrate 3, the lead 1B may be bonded to the substrate 3.

The configuration of the lead 1B is not specifically limited. In this embodiment the lead 1B includes, as shown in FIG. 39 to FIG. 41, and FIG. 43, a first portion 11B, a second portion 12B, a third portion 13B, and a fourth portion 14B, each of which will be described hereunder.

The first portion 11B includes a main surface 111B, a back surface 112B, a first face 121B, a second face 122B, a third face 123B, a fourth face 124Ba, a fifth face 125B, a sixth face 126Ba, a seventh face 127Ba, an eighth face 128B, a ninth face 129B, a tenth face 124Bb, an eleventh face 126Bb, a twelfth face 127Bb, a plurality of recesses 1111B, and a groove 1112B.

The main surface 111B is oriented in the same direction as the first face 31, in the z-direction.

The back surface 112B is oriented to the opposite side of the main surface 111B in the z-direction and, in the illustrated example, a planar surface. The back surface 112B is bonded to the bonding section 6B via the bonding material 81.

The first face 121B is located between the main surface 111B and the back surface 112B in the z-direction, and oriented in the same direction as the third face 33 as a whole, in the x-direction. In the illustrated example, the first face 121B is connected to the main surface 111B and the back surface 112B. The first face 121B is opposed to the second face 122A.

The second face 122B is located on the opposite side of the first face 121B in the x-direction, and oriented in the same direction as the fourth face 34, in the x-direction. The second face 122B is located between the main surface 111B and the back surface 112B in the z-direction and, in the illustrated example, connected to the main surface 111B and the back surface 112B. The second face 122B is generally the same in size in the y-direction, as the first face 121B (exactly the same, or different by within ±5%).

The third face 123B is located between the first face 121B and the second face 122B in the x-direction, and oriented in the same direction as the fifth face 35, in the y-direction. The third face 123B is located between the main surface 111B and the back surface 112B in the z-direction and, in the illustrated example, connected to the main surface 111B and the back surface 112B.

The fourth face 124Ba is located on the side of the sixth face 36 in the y-direction, with respect to the first face 121B and the second face 122B, and extends along the x-direction. The fourth face 124Ba is oriented in the same direction as the fifth face 35 in the y-direction, and opposed to the fifth face 125A. The fourth face 124Ba is located between the main surface 111B and the back surface 112B in the z-direction and, in the illustrated example, connected to the main surface 111B and the back surface 112B. In the illustrated example, the fourth face 124Ba overlaps with the first portion 11A, as viewed in the y-direction. The tenth face 124Bb is located on the side of the sixth face 36 in the y-direction, with respect to the first face 121B and the second face 122B, and extends along the x-direction. The tenth face 124Bb is oriented in the same direction as the sixth face 36 in the y-direction. The tenth face 124Bb is located between the main surface 111B and the back surface 112B in the z-direction and, in the illustrated example, connected to the main surface 111B and the back surface 112B. In the illustrated example, the tenth face 124Bb overlaps with the first portion 11A, as viewed in the y-direction.

The fifth face 125B is located between the second face 122B and the fourth face 124Ba in the x-direction, at a position close to the second face 122B. The fifth face 125B extends along the x-direction. The fifth face 125B overlaps with the third face 123B, as viewed in the y-direction. The fifth face 125B is located between the main surface 111B and the back surface 112B in the z-direction and, in the illustrated example, connected to the main surface 111B and the back surface 112B.

The sixth face 126Ba is inclined with respect to the x-direction and the y-direction. In the illustrated example, the sixth face 126Ba is connected to the fourth face 124Ba and the fifth face 125B. The sixth face 126Ba is connected to the first face 121B and the fourth face 124Ba, and opposed to the eighth face 128A. The sixth face 126Ba is located between the main surface 111B and the back surface 112B in the z-direction and, in the illustrated example, connected to the main surface 111B and the back surface 112B. The eleventh face 126Bb is inclined with respect to the x-direction and the y-direction. In the illustrated example, the eleventh face 126Bb is connected to the fifth face 125B and the fourth face 124Ba. The eleventh face 126Bb is located between the main surface 111B and the back surface 112B in the z-direction and, in the illustrated example, connected to the main surface 111B and the back surface 112B.

The seventh face 127Ba is located between the second face 122B and the third face 123B in the x-direction, and between the first face 121B and the second face 122B in the y-direction. The seventh face 127Ba is connected to the first face 121B and the third face 123B. In the illustrated example, the seventh face 127Ba forms a convex curved surface, as viewed in the z-direction. The seventh face 127Ba is located between the main surface 111B and the back surface 112B in the z-direction and, in the illustrated example, connected to the main surface 111B and the back surface 112B. The twelfth face 127Bb is located between the second face 122B and the third face 123B in the x-direction, and between the second face 122B and the third face 123B in the y-direction. The twelfth face 127Bb is connected to the second face 122B and the third face 123B. In the illustrated example, the twelfth face 127Bb forms a convex curved surface, as viewed in the z-direction. The twelfth face 127Bb is located between the main surface 111B and the back surface 112B in the z-direction and, in the illustrated example, connected to the main surface 111B and the back surface 112B.

The eighth face 128B is located between the second face 122B and the fifth face 125B, in the x-direction and the y-direction, and connected to the second face 122B and the fifth face 125B. In the illustrated example, the eighth face 128B is inclined with respect to the x-direction and the y-direction. The eighth face 128B is located between the main surface 111B and the back surface 112B in the z-direction and, in the illustrated example, connected to the main surface 111B and the back surface 112B.

The ninth face 129B is connected to the end of the fourth face 124Ba on the side of the third face 33 in the x-direction. The ninth face 129B is inclined with respect to the x-direction and the y-direction. The ninth face 129B is opposed to the sixth face 126A. The ninth face 129B is located between the main surface 111B and the back surface 112B in the z-direction and, in the illustrated example, connected to the main surface 111B and the back surface 112B.

In the illustrated example, the third face 123B includes a plurality of protrusions 131B. The plurality of protrusions 131B each protrude outwardly of the first portion 11B as viewed in the z-direction, and extend along the z-direction. Here, the plurality of protrusions 131B may be formed on the first portion 11B, in portions other than the third face 123B. In addition, the third face 123B may be without the plurality of protrusions 131B.

The plurality of recesses 1111B are each recessed from the main surface 111B in the z-direction. The shape of the recess 1111B in a z-direction view is not specifically limited, and may be, for example, circular, elliptical, rectangular, or triangular. In the illustrated example, the plurality of recesses 1111B are arranged in a matrix pattern.

The groove 1112B is recessed from the main surface 111B in the z-direction. In the illustrated example, the shape of the groove 1112B in a z-direction view is not specifically limited and, in the illustrated example, the groove 1112B includes a rectangular section, and a section extending along the x-direction inside the rectangular section. The cross-sectional shape of the groove 1112B is not specifically limited, and may be, for example, circular, elliptical, rectangular, or triangular.

The number of rows of the plurality of recesses 1111B in the y-direction is larger in the region between the groove 1112B and the tenth face 124Bb, than in the region between the groove 1112B and the third face 123B.

The third portion 13B and the fourth portion 14B are covered with the encapsulating resin 7. The third portion 13B is connected to the first portion 11B and the fourth portion 14B. In the illustrated example, the third portion 13B is connected to a portion of the first portion 11B adjacent to the fourth face 124Ba. In addition, the third portion 13B overlaps with the sixth face 36, as viewed in the z-direction. The fourth portion 14B is shifted from the first portion 11B in the z-direction, to the side to which the main surface 111B is oriented. The end portion of the fourth portion 14B is flush with the sixth face 76 of the resin 7.

The second portion 12B is connected to the fourth portion 14B, and corresponds to a portion of the lead 1B sticking out from the encapsulating resin 7. The second portion 12B sticks out to the opposite side of the first portion 11B, in the y-direction. The second portion 12B is used, for example, to electrically connect the semiconductor device A2 to an external circuit. In the illustrated example, the second portion 12B is bent in the z-direction, to the side to which the main surface 111B is oriented.

The lead 1C is located on the substrate 3 and, in this embodiment, on the first face 31. The lead 1C exemplifies a first lead in the present disclosure. The lead 1C is bonded to the bonding section 6C, via the bonding material 81. In the case where the bonding section 6C is not provided on the substrate 3, the lead 1C may be bonded to the substrate 3.

The configuration of the lead 1C is not specifically limited. In this embodiment the lead 1C includes, as shown in FIG. 39, FIG. 41, and FIG. 43, a first portion 11C, a second portion 12C, a third portion 13C, and a fourth portion 14C, each of which will be described hereunder.

The first portion 11C includes a main surface 111C, a back surface 112C, a first face 121C, a second face 122C, a third face 123C, a fourth face 124Ca, a fifth face 125C, a sixth face 126Ca, a seventh face 127Ca, an eighth face 128C, a ninth face 129C, a tenth face 124Cb, an eleventh face 126Cb, a twelfth face 127Cb, a plurality of recesses 1111C, and a groove 1112C. The first portion 11C overlaps with the sixth face 36 of the substrate 3, as viewed in the z-direction.

The main surface 111C is oriented in the same direction as the first face 31, in the z-direction.

The back surface 112C is oriented to the opposite side of the main surface 111C in the z-direction and, in the illustrated example, a planar surface. The back surface 112C is bonded to the bonding section 6C via the bonding material 81.

The first face 121C is located between the main surface 111C and the back surface 112C in the z-direction, and oriented in the same direction as the third face 33 as a whole, in the x-direction. In the illustrated example, the first face 121C is connected to the main surface 111C and the back surface 112C. The first face 121C is opposed to the second face 122B.

The second face 122C is located on the opposite side of the first face 121C in the x-direction, and oriented in the same direction as the fourth face 34, in the x-direction. The second face 122C is located between the main surface 111C and the back surface 112C in the z-direction and, in the illustrated example, connected to the main surface 111C and the back surface 112C. The second face 122C is generally the same in size in the y-direction, as the first face 121C (exactly the same, or different by within ±5%).

The third face 123C is located between the first face 121C and the second face 122C in the x-direction, and oriented in the same direction as the fifth face 35, in the y-direction. The third face 123C is located between the main surface 111C and the back surface 112C in the z-direction and, in the illustrated example, connected to the main surface 111C and the back surface 112C.

The fourth face 124Ca is located on the side of the sixth face 36 in the y-direction, with respect to the first face 121C and the second face 122C, and extends along the x-direction. The fourth face 124Ca is oriented in the same direction as the fifth face 35 in the y-direction, and opposed to the fifth face 125B. The fourth face 124Ca is located between the main surface 111C and the back surface 112C in the z-direction and, in the illustrated example, connected to the main surface 111C and the back surface 112C. In the illustrated example, the fourth face 124Ca overlaps with the first portion 11B, as viewed in the y-direction. The tenth face 124Cb is located on the side of the sixth face 36 in the y-direction, with respect to the first face 121C and the second face 122C, and extends along the x-direction. The tenth face 124Cb is oriented in the same direction as the sixth face 36 in the y-direction. The tenth face 124Cb is located between the main surface 111C and the back surface 112C in the z-direction and, in the illustrated example, connected to the main surface 111C and the back surface 112C. In the illustrated example, the tenth face 124Cb overlaps with the first portion 11B, as viewed in the y-direction.

The fifth face 125C is located between the second face 122C and the fourth face 124Ca in the x-direction, at a position close to the second face 122C. The fifth face 125C extends along the x-direction. The fifth face 125C overlaps with the third face 123C, as viewed in the y-direction. The fifth face 125C is located between the main surface 111C and the back surface 112C in the z-direction and, in the illustrated example, connected to the main surface 111C and the back surface 112C.

The sixth face 126Ca is inclined with respect to the x-direction and the y-direction. In the illustrated example, the sixth face 126Ca is connected to the fourth face 124C and the fifth face 125C. The sixth face 126Ca is connected to the first face 121C and the fourth face 124Ca, and opposed to the eighth face 128B. The sixth face 126Ca is located between the main surface 111C and the back surface 112C in the z-direction and, in the illustrated example, connected to the main surface 111C and the back surface 112C. The eleventh face 126Cb is inclined with respect to the x-direction and the y-direction. In the illustrated example, the eleventh face 126Cb is connected to the tenth face 124Cb and the fifth face 125C. The eleventh face 126Cb is located between the main surface 111C and the back surface 112C in the z-direction and, in the illustrated example, connected to the main surface 111C and the back surface 112C.

The seventh face 127Ca is located between the first face 121C and the third face 123C in the x-direction, and between the first face 121C and the third face 123C in the y-direction. The seventh face 127Ca is connected to the first face 121C and the third face 123C. In the illustrated example, the seventh face 127Ca forms a convex curved surface, as viewed in the z-direction. The seventh face 127Ca is located between the main surface 111C and the back surface 112C in the z-direction and, in the illustrated example, connected to the main surface 111C and the back surface 112C. The twelfth face 127Cb is located between the second face 122C and the third face 123C in the x-direction, and between the second face 122C and the third face 123C in the y-direction. The twelfth face 127Cb is connected to the second the twelfth face 127Cb forms a convex curved surface, as viewed in the z-direction. The twelfth face 127Cb is located between the main surface 111C and the back surface 112C in the z-direction and, in the illustrated example, connected to the main surface 111C and the back surface 112C.

The eighth face 128C is located between the second face 122C and the fifth face 125C in the x-direction and the y-direction, and connected to the second face 122C and the fifth face 125C. In the illustrated example, the eighth face 128C is inclined with respect to the x-direction and the y-direction. The eighth face 128C is located between the main surface 111C and the back surface 112C in the z-direction and, in the illustrated example, connected to the main surface 111C and the back surface 112C.

The ninth face 129C is connected to the end portion of the fourth face 124C on the side of the third face 33 in the x-direction. The ninth face 129C is inclined with respect to the x-direction and the y-direction. The ninth face 129C is opposed to the sixth face 126B. The ninth face 129C is located between the main surface 111C and the back surface 112C in the z-direction and, in the illustrated example, connected to the main surface 111C and the back surface 112C.

In the illustrated example, the third face 123C includes a plurality of protrusions 131C. The plurality of protrusions 131C each protrude outwardly of the first portion 11C as viewed in the z-direction, and extend along the z-direction. Here, the plurality of protrusions 131C may be formed on the first portion 11C, in portions other than the third face 123C. In addition, the third face 123C may be without the plurality of protrusions 131C.

The plurality of recesses 1111C are each recessed from the main surface 111C in the z-direction. The shape of the recess 1111C in a z-direction view is not specifically limited, and may be, for example, circular, elliptical, rectangular, or triangular. In the illustrated example, the plurality of recesses 1111C are arranged in a matrix pattern.

The groove 1112C is recessed from the main surface 111C in the z-direction. In the illustrated example, the shape of the groove 1112C in a z-direction view is not specifically limited and, in the illustrated example, the groove 1112C includes a rectangular section, and a section extending along the x-direction inside the rectangular shape. The cross-sectional shape of the groove 1112C is not specifically limited, and may be, for example, circular, elliptical, rectangular, or triangular.

The number of rows of the plurality of recesses 1111C in the y-direction is larger in the region between the groove 1112C and the tenth face 124Cb, than in the region between the groove 1112C and the third face 123C.

The third portion 13C and the fourth portion 14C are covered with the encapsulating resin 7. The third portion 13C is connected to the first portion 11C and the fourth portion 14C. In the illustrated example, the third portion 13C is connected to a portion of the first portion 11C adjacent to the fourth face 124Ca. The fourth portion 14C is, like the fourth portion 14B of the lead 1B, shifted from the first portion 11C in the z-direction, to the side to which the main surface 111C is oriented. The end portion of the fourth portion 14C is flush with the sixth face 76 of the resin 7.

The second portion 12C is connected to the end portion of the fourth portion 14C, and corresponds to a portion of the lead 1C sticking out from the encapsulating resin 7. The second portion 12C sticks out to the opposite side of the first portion 11C, in the y-direction. The second portion 12C is used, for example, to electrically connect the semiconductor device A2 to an external circuit. In the illustrated example, the second portion 12C is bent in the z-direction, to the side to which the main surface 111C is oriented.

The lead 1D is located on the substrate 3 and, in this embodiment, on the first face 31. The lead 1D exemplifies a first lead in the present disclosure. The lead 1D is bonded to the bonding section 6D, via the bonding material 81. In the case where the bonding section 6D is not provided on the substrate 3, the lead 1D may be bonded to the substrate 3.

The configuration of the lead 1D is not specifically limited. In this embodiment the lead 1D includes, as shown in FIG. 4 and FIG. 14, a first portion 11D, a second portion 12D, a third portion 13D, and a fourth portion 14D, each of which will be described hereunder.

As shown in FIG. 41 and FIG. 43, the first portion 11D includes a main surface 111D, a back surface 112D, a first face 121D, a second face 122D, a third face 123D, a fourth face 124Da, a sixth face 126D, a seventh face 127Da, an eighth face 128D, a ninth face 129D, a tenth face 124Db, an eleventh face 127Db, a plurality of recesses 1111D, and a groove 1112D. The first portion 11D overlaps with the sixth face 36 of the substrate 3, as viewed in the z-direction.

The main surface 111D is oriented in the same direction as the first face 31, in the z-direction.

The back surface 112D is oriented to the opposite side of the main surface 111D in the z-direction and, in the illustrated example, a planar surface. The back surface 112D is bonded to the bonding section 6D via the bonding material 81.

The first face 121D is located between the main surface 111D and the back surface 112D in the z-direction, and oriented in the same direction as the third face 33 as a whole, in the x-direction. In the illustrated example, the first face 121D is connected to the main surface 111D and the back surface 112D. The first face 121D is opposed to the second face 122C.

The second face 122D is located on the opposite side of the first face 121D in the x-direction, and oriented in the same direction as the fourth face 34, in the x-direction. The second face 122D is located between the main surface 111D and the back surface 112D in the z-direction and, in the illustrated example, connected to the main surface 111D and the back surface 112D. The second face 122D is larger in size in the y-direction, than the first face 121D.

The third face 123D is located between the first face 121D and the second face 122D in the x-direction, and oriented in the same direction as the fifth face 35, in the y-direction. The third face 123D is located between the main surface 111D and the back surface 112D in the z-direction and, in the illustrated example, connected to the main surface 111D and the back surface 112D.

The fourth face 124Da is located on the side of the sixth face 36 in the y-direction, with respect to the first face 121D and the second face 122D, and extends along the x-direction. The fourth face 124Da is oriented in the same direction as the fifth face 35 in the y-direction, and opposed to the fifth face 125C. The fourth face 124Da is located between the main surface 111D and the back surface 112D in the z-direction and, in the illustrated example, connected to the main surface 111D and the back surface 112D. In the illustrated example, the fourth face 124Da overlaps with the first portion 11C, as viewed in the y-direction. The tenth face 124Db is located on the side of the sixth face 36 in the y-direction, with respect to the first face 121D and the second face 122D, and extends along the x-direction. The tenth face 124Db is oriented in the same direction as the sixth face 36 in the y-direction. The tenth face 124Db is located between the main surface 111D and the back surface 112D in the z-direction and, in the illustrated example, connected to the main surface 111D and the back surface 112D. In the illustrated example, the tenth face 124Db overlaps with the first portion 11C, as viewed in the y-direction.

The sixth face 126D is located between the first face 121D and the fourth face 124Da, in the x-direction and the y-direction. In the illustrated example, the sixth face 126D is connected to the first face 121D and the fourth face 124Da. The sixth face 126D is inclined with respect to the x-direction and the y-direction. The sixth face 126D is opposed to the eighth face 128C. The sixth face 126D is located between the main surface 111D and the back surface 112D in the z-direction and, in the illustrated example, connected to the main surface 111D and the back surface 112D.

The seventh face 127Da is located between the first face 121D and the third face 123D, and between the second face 122D and the third face 123D in the x-direction, and between the first face 121D and second face 122D, and the third face 123D, in the y-direction. The seventh face 127Da is connected to the first face 121D and the third face 123D. In the illustrated example, the seventh face 127Da forms a convex curved surface, as viewed in the z-direction. The seventh face 127Da is located between the main surface 111D and the back surface 112D in the z-direction and, in the illustrated example, connected to the main surface 111D and the back surface 112D. The eleventh face 127Db is located between the second face 122D and the third face 123D in the x-direction, and between the second face 122D and the third face 123D in the y-direction. The eleventh face 127Db is connected to the second face 122D and the third face 123D. In the illustrated example, the eleventh face 127Db forms a convex curved surface, as viewed in the z-direction. The eleventh face 127Db is located between the main surface 111D and the back surface 112D in the z-direction and, in the illustrated example, connected to the main surface 111D and the back surface 112D.

The eighth face 128D is located between the second face 122D and the tenth face 124Db in the x-direction and the y-direction, and connected to the second face 122D and the tenth face 124Db. In the illustrated example, the eighth face 128D is inclined with respect to the x-direction and the y-direction. The eighth face 128D is located between the main surface 111D and the back surface 112D in the z-direction and, in the illustrated example, connected to the main surface 111D and the back surface 112D.

The ninth face 129D is connected to the end portion of the fourth face 124Da on the side of the third face 33 in the x-direction. The ninth face 129D is inclined with respect to the x-direction and the y-direction. The ninth face 129D is opposed to the sixth face 126C. The ninth face 129D is located between the main surface 111D and the back surface 112D in the z-direction and, in the illustrated example, connected to the main surface 111D and the back surface 112D.

In the illustrated example, the second face 122D and the third face 123D each include a plurality of protrusions 131D. The plurality of protrusions 131D each protrude outwardly of the first portion 11D as viewed in the z-direction, and extend along the z-direction. Here, the plurality of protrusions 131D may be formed on the first portion 11D, in portions other than the second face 122D and the third face 123D. In addition, at least one of the second face 122D and the third face 123D may be without the plurality of protrusions 131D.

The plurality of recesses 1111D are each recessed from the main surface 111D in the z-direction. The shape of the recess 1111D in a z-direction view is not specifically limited, and may be, for example, circular, elliptical, rectangular, or triangular. In the illustrated example, the plurality of recesses 1111D are arranged in a matrix pattern.

The groove 1112D is recessed from the main surface 111D in the z-direction. In the illustrated example, the shape of the groove 1112D in a z-direction view is not specifically limited and, in the illustrated example, the groove 1112D includes a rectangular section, and a section extending along the x-direction inside the rectangular shape. The cross-sectional shape of the groove 1112D is not specifically limited, and may be, for example, circular, elliptical, rectangular, or triangular.

The number of rows of the plurality of recesses 1111D in the y-direction is larger in the region between the groove 1112D and the tenth face 124Db, than in the region between the groove 1112D and the third face 123D.

The third portion 13D and the fourth portion 14D are covered with the encapsulating resin 7. The third portion 13D is connected to the first portion 11D and the fourth portion 14D. In the illustrated example, the third portion 13D is connected to a portion of the first portion 11D adjacent to the fourth face 124Da. The fourth portion 14D is, like the fourth portion 14B of the lead 1B, shifted from the first portion 11D in the z-direction, to the side to which the main surface 111D is oriented. The end portion of the fourth portion 14D is flush with the sixth face 76 of the resin 7.

The second portion 12D is connected to the end portion of the fourth portion 14D, and corresponds to a portion of the lead 1D sticking out from the encapsulating resin 7. The second portion 12D sticks out to the opposite side of the first portion 11D, in the y-direction. The second portion 12D is used, for example, to electrically connect the semiconductor device A2 to an external circuit. In the illustrated example, the second portion 12D is bent in the z-direction, to the side to which the main surface 111D is oriented.

The lead 1E is spaced apart from the substrate 3, as viewed in the z-direction. In this embodiment, the lead 1E located on the side to which the sixth face 36 is oriented, with respect to the substrate 3 in the y-direction.

The configuration of the lead 1E is not specifically limited. In this embodiment the lead 1E includes, as shown in FIG. 4, a second portion 12E and a fourth portion 14E, each of which will be described hereunder.

The fourth portion 14E is covered with the encapsulating resin 7. The fourth portion 14E is, like the fourth portion 14D of the lead 1D, shifted from the first portion 11E in the z-direction, to the side to which the main surface 111E is oriented. The fourth portion 14E overlaps with the first portion 11C and the first portion 11D, as viewed in the y-direction. The end portion of the fourth portion 14E is flush with the sixth face 76 of the resin 7.

The second portion 12E is connected to the end portion of the fourth portion 14E, and corresponds to a portion of the lead 1E sticking out from the encapsulating resin 7. The second portion 12E sticks out to the opposite side of the fourth portion 14E, in the y-direction. The second portion 12E is used, for example, to electrically connect the semiconductor device A2 to an external circuit. In the illustrated example, the second portion 12E is bent in the z-direction, to the side to which the first face 31 is oriented.

The lead 1F is spaced apart from the substrate 3, as viewed in the z-direction. In this embodiment, the lead 1F is located on the side to which the sixth face 36 is oriented, with respect to the substrate 3 in the y-direction. The lead 1F is located on the opposite side of the fourth portion 14D, across the lead 1E.

The configuration of the lead 1F is not specifically limited. In this embodiment the lead 1F includes, as shown in FIG. 4, a second portion 12F and a fourth portion 14F, each of which will be described hereunder.

The fourth portion 14F is covered with the encapsulating resin 7. The fourth portion 14F is, like the fourth portion 14D of the lead 1D, shifted from the first portion 11D in the z-direction, to the side to which the main surface 111D is oriented. The fourth portion 14F overlaps with the first portion 11D, as viewed in the y-direction. The end portion of the fourth portion 14F is flush with the sixth face 76 of the resin 7.

The second portion 12F is connected to the end portion of the fourth portion 14F, and corresponds to a portion of the lead 1F sticking out from the encapsulating resin 7. The second portion 12F sticks out to the opposite side of the fourth portion 14F, in the y-direction. The second portion 12F is used, for example, to electrically connect the semiconductor device A2 to an external circuit. In the illustrated example, the second portion 12F is bent in the z-direction, to the side to which the first face 31 is oriented.

The lead 1G is spaced apart from the substrate 3, as viewed in the z-direction. In this embodiment, the lead 1G is located on the side to which the fourth face 34 is oriented, with respect to the substrate 3 in the x-direction. The lead 1G is located on the opposite side of the fourth portion 14E, across the lead 1F.

The configuration of the lead 1G is not specifically limited. In this embodiment the lead 1G includes, as shown in FIG. 4, a second portion 12G and a fourth portion 14G, each of which will be described hereunder.

The fourth portion 14G is covered with the encapsulating resin 7. The fourth portion 14G is, like the fourth portion 14D of the lead 1D, shifted from the first portion 11D in the z-direction, to the side to which the main surface 111D is oriented. The fourth portion 14G overlaps with the fourth portion 14F, as viewed in the y-direction. In addition, the fourth portion 14G overlaps with the first portion 11D, as viewed in the x-direction. The end portion of the fourth portion 14G is flush with the sixth face 76 of the resin 7.

The second portion 12G is connected to the end portion of the fourth portion 14G, and corresponds to a portion of the lead 1G sticking out from the encapsulating resin 7. The second portion 12G sticks out to the opposite side of the fourth portion 14G, in the y-direction. The second portion 12G is used, for example, to electrically connect the semiconductor device A2 to an external circuit. In the illustrated example, the second portion 12G is bent in the z-direction, to the side to which the first face 31 is oriented.

As shown in FIG. 39, the pair of second portions 12A are aligned with a clearances G11 therebetween, as viewed in the x-direction. The second portions 12A to 12E are aligned in the x-direction, with clearances G12 between each other. The difference among the clearances G12 is within ±5% from each other. The clearances G12 are wider than the clearance G11. The second portions 12E to G are aligned in the x-direction, with clearances G13 between each other. The clearances G13 are narrower than the clearances G12 and, in the illustrated example, also narrower than the clearance G11. The difference among the clearances G13 is within ±5% from each other.

In this embodiment, as shown in FIG. 42 and FIG. 43, the main surface 111A includes three first regions Ra, Rb, and Rc, and three second regions R1a, R1b, and R1c, defined by the groove 1112A. The three first regions Ra, Rb, and Rc are located on the side of the lead 2, in the y-direction. The shape of the three first regions Ra, Rb, and Rc is not specifically limited. In the illustrated example, the mentioned regions have an elongate rectangular shape having the long sides extending along the y-direction, as viewed in the z-direction. The three first regions Ra, Rb, and Rc overlap with each other, as viewed in the x-direction. In the illustrated example, further, the three first regions Ra, Rb, and Rc generally coincide with each other, as viewed in the x-direction. Here, the expression “generally coincide” as viewed in the x-direction refers to, for example, exactly coinciding with each other, or being deviated by within ±5% of the characteristic size (size of the first region Ra, Rb, or Rc in the y-direction).

The three second regions R1a, R1b, and R1c are located on the opposite side of the lead 2 with respect to the first regions Ra, Rb, and Rc, in the y-direction. The shape of the three second regions R1a, R1b, and R1c is not specifically limited. In the illustrated example, the mentioned regions have a rectangular shape, as viewed in the z-direction. The three second regions R1a, R1b, and R1c overlap with each other, as viewed in the x-direction. In the illustrated example, further, the three second regions R1a, R1b, and R1c generally coincide with each other, as viewed in the x-direction. Here, the expression “generally coincide” as viewed in the x-direction refers to, for example, exactly coinciding with each other, or being deviated by within ±5% of the characteristic size (size of the second region R1a, R1b, or R1c in the y-direction).

The sizes of the three first regions Ra, Rb, and Rc, and the three second regions R1a, R1b, and R1c, are not specifically limited. In the illustrated example, a size y1 of the first regions Ra, Rb, and Rc in the y-direction is larger than a size y2 of the second regions R1a, R1b, and R1c in the y-direction.

The main surface 111B includes a first region Rd and a second region R1d, defined by the groove 1112B. The first region Rd is located on the side of the lead 2, in the y-direction. The shape of the first region Rd is not specifically limited. In the illustrated example, the first region Rd has an elongate rectangular shape having the long sides extending along the y-direction, as viewed in the z-direction. The second region R1d is located on the opposite side of the lead 2 with respect to the first region Rd, in the y-direction. The shape of the second region R1d is not specifically limited. In the illustrated example, the second region R1d has a rectangular shape, as viewed in the z-direction.

The main surface 111C includes a first region Re and a second region R1e, defined by the groove 1112C. The first region Re is located on the side of the lead 2, in the y-direction. The shape of the first region Re is not specifically limited. In the illustrated example, the first region Re has an elongate rectangular shape having the long sides extending along the y-direction, as viewed in the z-direction. The second region R1e is located on the opposite side of the lead 2 with respect to the first region Re, in the y-direction. The shape of the second region R1e is not specifically limited. In the illustrated example, the second region R1e has a rectangular shape, as viewed in the z-direction.

The main surface 111D includes a first region Rf and a second region R1f, defined by the groove 1112D. The first region Rf is located on the side of the lead 2, in the y-direction. The shape of the first region Rf is not specifically limited. In the illustrated example, the first region Rf has an elongate rectangular shape having the long sides extending along the y-direction, as viewed in the z-direction. The second region R1f is located on the opposite side of the lead 2 with respect to the first region Rf, in the y-direction. The shape of the second region R1f is not specifically limited. In the illustrated example, the second region Rif has a rectangular shape, as viewed in the z-direction.

The three first regions Rd, Re, and Rf overlap with each other, as viewed in the x-direction. In addition, in the illustrated example, the three first regions Rd, Re, and Rf generally coincide with each other, as viewed in the x-direction. Here, the expression “generally coincide” as viewed in the x-direction refers to, for example, exactly coinciding with each other, or being deviated by within ±5% of the characteristic size (size of the first region Rd, Re, or Rf in the y-direction). The three second regions R1d, R1e, and Rif overlap with each other, as viewed in the x-direction. In the illustrated example, further, the three second regions R1d, R1e, and R1f generally coincide with each other, as viewed in the x-direction. Here, the expression “generally coincide” as viewed in the x-direction refers to, for example, exactly coinciding with each other, or being deviated by within ±5% of the characteristic size (size of the second region R1d, R1e, or Rif in the y-direction).

The sizes of the three first regions Rd, Re, and Rf and the three second regions R1d, R1e, and Rif are not specifically limited. In the illustrated example, the size y1 of the first regions Rd, Re, and Rf in the y-direction is larger than the size y2 of the second regions R1d, R1e, and Rif in the y-direction.

### <Leads 2>

Regarding the lead 2 according to this embodiment, although any of the elements is apparently given, for the sake of convenience of description, the same numeral as that of the lead 2 according to the first embodiment, it does not necessarily mean that the mentioned element has the same or similar configuration. The configuration of an element with a numeral is defined by the description relevant to this embodiment.

The plurality of leads 2 contain a metal, and have higher heat dissipation characteristics, for example than the substrate 3. The metal to form the lead 2 is not specifically limited, and may be, for example, copper (Cu), aluminum, iron (Fe), oxygen-free copper, or an alloy of the cited metals, such as a Cu—Sn alloy, a Cu—Zr alloy, or a Cu—Fe alloy. The plurality of leads 2 may be plated with nickel (Ni). Examples of the forming method of the plurality of leads 2 include pressing a metal plate with a die, and patterning a metal plate by etching, without limitation thereto. The thickness of the lead 2 is not specifically limited, but may be, for example, approximately 0.4 mm to 0.8 mm. The plurality of leads 2 are located so as to overlap with the second region 30B, as viewed in the z-direction.

In this embodiment, the plurality of leads 2 include a plurality of leads 2A to 2O, as shown in FIG. 35 to FIG. 40, FIG. 44, and FIG. 45. The plurality of leads 2A to 2H, and 2S to 2U respectively constitute conduction paths to the control chips 4G and 4H. The plurality of leads 2I to 2R constitute conduction paths to the primary-side circuit chip 4J.

The lead 2A is spaced apart from the plurality of leads 1. The lead 2A is located on the conductive section 5. The lead 2A is electrically connected to the conductive section 5. The lead 2A exemplifies a second lead in the present disclosure. The lead 2A is bonded to the second portion 52A of the wiring 50A in the conductive section 5, via a conductive bonding material 82. The conductive bonding material 82 may be any material that is capable of bonding, and electrically connecting, the lead 2A to the second portion 52A. For example, silver paste, copper paste, or solder may be employed as the conductive bonding material 82. The conductive bonding material 82 corresponds to the first conductive bonding material in the present disclosure.

The configuration of the lead 2A is not specifically limited. In this embodiment the lead 2A includes, as shown in FIG. 44, a first portion 21A, a second portion 22A, a third portion 23A, and a fourth portion 24A, each of which will be described hereunder.

The first portion 21A is bonded to the second portion 52A of the wiring 50A. The shape of the first portion 21A is not specifically limited, and a desired shape may be selected from a rectangular shape, a polygonal shape, a circular shape, an elliptical shape, and so forth. In the illustrated example, the first portion 21A has a bent shape including a portion extending along the x-direction, and a portion extending along the y-direction. The first portion 21A overlaps with the third face 33 of the substrate 3 as viewed in the z-direction, and sticks out in the x-direction, toward the side to which the third face 33 is oriented. In the illustrated example, the first portion 21A overlaps with the second portion 52A, as viewed in the z-direction. In addition, the first portion 21A includes a through hole 211A. The through hole 211A is formed so as to penetrate through the first portion 21A, in the z-direction. The inside of the through hole 211A is filled with the conductive bonding material 82, like a through hole 211I in a first portion 21I of the lead 2I shown in FIG. 40. The conductive bonding material 82 covers a part of the surface of the lead 2A. However, the conductive bonding material 82 may be provided only inside the through hole 211A, so as not to reach the surface of the lead 2A.

The third portion 23A and the fourth portion 24A are covered with the encapsulating resin 7. The third portion 23A is connected to the first portion 21A and the fourth portion 24A. The fourth portion 24A is shifted in the z-direction with respect to the first portion 21A, to the side to which the first face 31 is oriented, like a third portion 23I and a fourth portion 24I of the lead 2I shown in FIG. 40. The end portion of the fourth portion 24A is flush with a fifth face 75 of the resin 7. In the illustrated example, the third portion 23A and the fourth portion 24A generally coincide with each other, as viewed in the y-direction. Here, the expression “generally coincide” as viewed in the y-direction refers to, for example, exactly coinciding with each other, or being deviated by within ±5% of the characteristic size (size of the third portion 23A, or fourth portion 24A in the x-direction).

The second portion 22A is connected to the end portion of the fourth portion 24A, and corresponds to a portion of the lead 2A sticking out from the encapsulating resin 7 to the opposite side of the plurality of leads 1, as viewed in the y-direction. The second portion 22A sticks out to the opposite side of the first portion 21A, in the y-direction. The second portion 22A is used, for example, to electrically connect the semiconductor device A1 to an external circuit. In the illustrated example, the second portion 22A is bent in the z-direction, to the side to which the first face 31 is oriented. The second portion 22A, the third portion 23A, and the fourth portion 24A each include, on the respective sides thereof in the x-direction, edges extending along the y-direction.

The lead 2B is spaced apart from the plurality of leads 1. The lead 2B is located on the conductive section 5. The lead 2B is electrically connected to the conductive section 5. The lead 2B exemplifies a second lead in the present disclosure. The lead 2B is bonded to the second portion 52B of the wiring 50B in the conductive section 5, via the conductive bonding material 82.

The configuration of the lead 2B is not specifically limited. In this embodiment the lead 2B includes, as shown in FIG. 44, a first portion 21B, a second portion 22B, a third portion 23B, and a fourth portion 24B, each of which will be described hereunder.

The first portion 21B is bonded to the second portion 52B of the wiring 50B. The shape of the first portion 21B is not specifically limited, and a desired shape may be selected from a rectangular shape, a polygonal shape, a circular shape, an elliptical shape, and so forth. In the illustrated example, the first portion 21B has a bent shape including a portion inclined with respect to the x-direction and the y-direction, and a portion extending along the y-direction. The first portion 21B overlaps with the third face 33 of the substrate 3 as viewed in the z-direction, and sticks out in the x-direction, toward the side to which the third face 33 is oriented. In the illustrated example, the first portion 21B overlaps with the second portion 52B, as viewed in the z-direction. In addition, the first portion 21B includes a through hole 211B. The through hole 211B is formed so as to penetrate through the first portion 21B, in the z-direction. The inside of the through hole 211B is filled with the conductive bonding material 82, like the through hole 211I in the first portion 21I of the lead 2I shown in FIG. 40. The conductive bonding material 82 covers a part of the surface of the lead 2B. However, the conductive bonding material 82 may be provided only inside the through hole 211B, so as not to reach the surface of the lead 2B.

The third portion 23B and the fourth portion 24B are covered with the encapsulating resin 7. The third portion 23B is connected to the first portion 21B and the fourth portion 24B. The fourth portion 24B is shifted in the z-direction with respect to the first portion 21B, to the side to which the first face 31 is oriented, like the third portion 23I and the fourth portion 24I of the lead 2I shown in FIG. 40. The end portion of the fourth portion 24B is flush with the fifth face 75 of the resin 7. In the illustrated example, the third portion 23B and the fourth portion 24B generally coincide with each other, as viewed in the y-direction. Here, the expression “generally coincide” as viewed in the y-direction refers to, for example, exactly coinciding with each other, or being deviated by within ±5% of the characteristic size (size of the third portion 23B or fourth portion 24B in the x-direction).

The second portion 22B is connected to the end portion of the fourth portion 24B, and corresponds to a portion of the lead 2B sticking out from the encapsulating resin 7 to the opposite side of the plurality of leads 1, as viewed in the y-direction. The second portion 22B sticks out to the opposite side of the first portion 21B, in the y-direction. The second portion 22B is used, for example, to electrically connect the semiconductor device A2 to an external circuit. In the illustrated example, the second portion 22B is bent in the z-direction, to the side to which the first face 31 is oriented. The second portion 22B, the third portion 23B, and the fourth portion 24B each include, on the respective sides thereof in the x-direction, edges extending along the y-direction. The edges of the second portion 22B, the third portion 23B, and the fourth portion 24B, on the side of the third face 33 in the x-direction, are respectively opposed to the edges of the second portion 22A, the third portion 23A, and the fourth portion 24A, on the side of the fourth face 34 in the x-direction.

The lead 2C is spaced apart from the plurality of leads 1. The lead 2C is located on the conductive section 5. The lead 2C is electrically connected to the conductive section 5. The lead 2C exemplifies a second lead in the present disclosure. The lead 2C is bonded to the second portion 52C of the wiring 50C in the conductive section 5, via the conductive bonding material 82.

The configuration of the lead 2C is not specifically limited. In this embodiment the lead 2C includes, as shown in FIG. 44, a first portion 21C, a second portion 22C, a third portion 23C, and a fourth portion 24C, each of which will be described hereunder.

The first portion 21C is bonded to the second portion 52C of the wiring 50C. The shape of the first portion 21C is not specifically limited, and a desired shape may be selected from a rectangular shape, a polygonal shape, a circular shape, an elliptical shape, and so forth. In the illustrated example, the first portion 21C has a bent shape including two portions extending along the y-direction, and a portion interposed therebetween and inclined with respect to the x-direction and the y-direction. The first portion 21C overlaps with the fifth face 35 of the substrate 3 as viewed in the z-direction, and sticks out in the y-direction, toward the side to which the fifth face 35 is oriented. In the illustrated example, the first portion 21C overlaps with the second portion 52C, as viewed in the z-direction. In addition, the first portion 21C includes a through hole 211C. The through hole 211C is formed so as to penetrate through the first portion 21C, in the z-direction. The inside of the through hole 211C is filled with the conductive bonding material 82, like the through hole 211I in the first portion 21I of the lead 2I shown in FIG. 40. The conductive bonding material 82 covers a part of the surface of the lead 2C. However, the conductive bonding material 82 may be provided only inside the through hole 211C, so as not to reach the surface of the lead 2C.

The third portion 23C and the fourth portion 24C are covered with the encapsulating resin 7. The third portion 23C is connected to the first portion 21C and the fourth portion 24C. The fourth portion 24C is shifted in the z-direction with respect to the first portion 21C, to the side to which the first face 31 is oriented, like the third portion 23I and the fourth portion 24I of the lead 2I shown in FIG. 40. The end portion of the fourth portion 24C is flush with the fifth face 75 of the resin 7. In the illustrated example, the third portion 23C and the fourth portion 24C generally coincide with each other, as viewed in the y-direction. Here, the expression “generally coincide” as viewed in the y-direction refers to, for example, exactly coinciding with each other, or being deviated by within ±5% of the characteristic size (size of the third portion 23C or fourth portion 24C in the x-direction).

The second portion 22C is connected to the end portion of the fourth portion 24C, and corresponds to a portion of the lead 2C sticking out from the encapsulating resin 7 to the opposite side of the plurality of leads 1, as viewed in the y-direction. The second portion 22C sticks out to the opposite side of the first portion 21C, in the y-direction. The second portion 22C is used, for example, to electrically connect the semiconductor device A2 to an external circuit. In the illustrated example, the second portion 22C is bent in the z-direction, to the side to which the first face 31 is oriented. The second portion 22C, the third portion 23C, and the fourth portion 24C each include, on the respective sides thereof in the x-direction, edges extending along the y-direction. The edges of the second portion 22C, the third portion 23C, and the fourth portion 24C, on the side of the third face 33 in the x-direction, are respectively opposed to the edges of the second portion 22B, the third portion 23B, and the fourth portion 24B, on the side of the fourth face 34 in the x-direction.

The lead 2D is spaced apart from the plurality of leads 1. The lead 2D is located on the conductive section 5. The lead 2D is electrically connected to the conductive section 5. The lead 2D exemplifies a second lead in the present disclosure. The lead 2D is bonded to the second portion 52D of the wiring 50D in the conductive section 5, via the conductive bonding material 82.

The configuration of the lead 2D is not specifically limited. In this embodiment the lead 2D includes, as shown in FIG. 44, a first portion 21D, a second portion 22D, a third portion 23D, and a fourth portion 24D, each of which will be described hereunder.

The first portion 21D is bonded to the second portion 52D of the wiring 50D. The shape of the first portion 21D is not specifically limited, and a desired shape may be selected from a rectangular shape, a polygonal shape, a circular shape, an elliptical shape, and so forth. In the illustrated example, the first portion 21D has two portions extending along the y-direction, and a portion interposed therebetween and inclined with respect to the x-direction and the y-direction. The first portion 21D overlaps with the fifth face 35 of the substrate 3 as viewed in the z-direction, and sticks out in the y-direction, toward the side to which the fifth face 35 is oriented. In the illustrated example, the first portion 21D overlaps with the second portion 52D, as viewed in the z-direction. In addition, the first portion 21D includes a through hole 211D. The through hole 211D is formed so as to penetrate through the first portion 21D, in the z-direction. The inside of the through hole 211D is filled with the conductive bonding material 82, like the through hole 211I in the first portion 21I of the lead 2I shown in FIG. 40. The conductive bonding material 82 covers a part of the surface of the lead 2D. However, the conductive bonding material 82 may be provided only inside the through hole 211D, so as not to reach the surface of the lead 2D.

The third portion 23D and the fourth portion 24D are covered with the encapsulating resin 7. The third portion 23D is connected to the first portion 21D and the fourth portion 24D. The fourth portion 24D is shifted in the z-direction with respect to the first portion 21D, to the side to which the first face 31 is oriented, like the third portion 23I and the fourth portion 24I of the lead 2I shown in FIG. 40. The end portion of the fourth portion 24D is flush with the fifth face 75 of the resin 7. In the illustrated example, the third portion 23D and the fourth portion 24D generally coincide with each other, as viewed in the y-direction. Here, the expression “generally coincide” as viewed in the y-direction refers to, for example, exactly coinciding with each other, or being deviated by within ±5% of the characteristic size (size of the third portion 23D or fourth portion 24D in the x-direction).

The second portion 22D is connected to the end portion of the fourth portion 24D, and corresponds to a portion of the lead 2D sticking out from the encapsulating resin 7 to the opposite side of the plurality of leads 1, as viewed in the y-direction. The second portion 22D sticks out to the opposite side of the first portion 21D, in the y-direction. The second portion 22D is used, for example, to electrically connect the semiconductor device A2 to an external circuit. In the illustrated example, the second portion 22D is bent in the z-direction, to the side to which the first face 31 is oriented. The second portion 22D, the third portion 23D, and the fourth portion 24D each include, on the respective sides thereof in the x-direction, edges extending along the y-direction. The edges of the second portion 22D, the third portion 23D, and the fourth portion 24D, on the side of the third face 33 in the x-direction, are respectively opposed to the edges of the second portion 22C, the third portion 23C, and the fourth portion 24C, on the side of the fourth face 34 in the x-direction.

The lead 2E is spaced apart from the plurality of leads 1. The lead 2E is located on the conductive section 5. The lead 2E is electrically connected to the conductive section 5. The lead 2E exemplifies a second lead in the present disclosure. The lead 2E is bonded to the second portion 52E of the wiring 50E in the conductive section 5, via the conductive bonding material 82.

The configuration of the lead 2E is not specifically limited. In this embodiment the lead 2E includes, as shown in FIG. 44, a first portion 21E, a second portion 22E, a third portion 23E, and a fourth portion 24E, each of which will be described hereunder.

The first portion 21E is bonded to the second portion 52E of the wiring 50E. The shape of the first portion 21E is not specifically limited, and a desired shape may be selected from a rectangular shape, a polygonal shape, a circular shape, an elliptical shape, and so forth. In the illustrated example, the first portion 21E has a bent shape including two portions extending along the y-direction, and a portion interposed therebetween and inclined with respect to the x-direction and the y-direction. The first portion 21E overlaps with the fifth face 35 of the substrate 3 as viewed in the z-direction, and sticks out in the y-direction, toward the side to which the fifth face 35 is oriented. In the illustrated example, the first portion 21E overlaps with the second portion 52E, as viewed in the z-direction. In addition, the first portion 21E includes a through hole 211E. The through hole 211E is formed so as to penetrate through the first portion 21E, in the z-direction. The inside of the through hole 211E is filled with the conductive bonding material 82, like the through hole 211I in the first portion 21I of the lead 2I shown in FIG. 40. The conductive bonding material 82 covers a part of the surface of the lead 2E. However, the conductive bonding material 82 may be provided only inside the through hole 211E, so as not to reach the surface of the lead 2E.

The third portion 23E and the fourth portion 24E are covered with the encapsulating resin 7. The third portion 23E is connected to the first portion 21E and the fourth portion 24E. The fourth portion 24E is shifted in the z-direction with respect to the first portion 21E, to the side to which the first face 31 is oriented, like the third portion 23I and the fourth portion 24I of the lead 2I shown in FIG. 40. The end portion of the fourth portion 24E is flush with the fifth face 75 of the resin 7. In the illustrated example, the third portion 23E and the fourth portion 24E generally coincide with each other, as viewed in the y-direction. Here, the expression “generally coincide” as viewed in the y-direction refers to, for example, exactly coinciding with each other, or being deviated by within ±5% of the characteristic size (size of the third portion 23E or fourth portion 24E in the x-direction).

The second portion 22E is connected to the end portion of the fourth portion 24E, and corresponds to a portion of the lead 2E sticking out from the encapsulating resin 7 to the opposite side of the plurality of leads 1, as viewed in the y-direction. The second portion 22E sticks out to the opposite side of the first portion 21E, in the y-direction. The second portion 22E is used, for example, to electrically connect the semiconductor device A2 to an external circuit. In the illustrated example, the second portion 22E is bent in the z-direction, to the side to which the first face 31 is oriented. The second portion 22E, the third portion 23E, and the fourth portion 24E each include, on the respective sides thereof in the x-direction, edges extending along the y-direction. The edges of the second portion 22E, the third portion 23E, and the fourth portion 24E, on the side of the third face 33 in the x-direction, are respectively opposed to the edges of the second portion 22D, the third portion 23D, and the fourth portion 24D, on the side of the fourth face 34 in the x-direction.

The lead 2F is spaced apart from the plurality of leads 1. The lead 2F is located on the conductive section 5. The lead 2F is electrically connected to the conductive section 5. The lead 2F exemplifies a second lead in the present disclosure. The lead 2F is bonded to the second portion 52F of the wiring 50F in the conductive section 5, via the conductive bonding material 82.

The configuration of the lead 2F is not specifically limited. In this embodiment the lead 2F includes, as shown in FIG. 44, a first portion 21F, a second portion 22F, a third portion 23F, and a fourth portion 24F, each of which will be described hereunder.

The first portion 21F is bonded to the second portion 52F of the wiring 50F. The shape of the first portion 21F is not specifically limited, and a desired shape may be selected from a rectangular shape, a polygonal shape, a circular shape, an elliptical shape, and so forth. In the illustrated example, the first portion 21F has a bent shape including a portion extending along the y-direction, and a portion inclined with respect to the x-direction and the y-direction. The first portion 21F overlaps with the fifth face 35 of the substrate 3 as viewed in the z-direction, and sticks out in the y-direction, toward the side to which the fifth face 35 is oriented. In the illustrated example, the first portion 21F overlaps with the second portion 52F, as viewed in the z-direction. In addition, the first portion 21F includes a through hole 211F. The through hole 211F is formed so as to penetrate through the first portion 21F, in the z-direction. The inside of the through hole 211F is filled with the conductive bonding material 82, like the through hole 211I in the first portion 21I of the lead 2I shown in FIG. 40. The conductive bonding material 82 covers a part of the surface of the lead 2F. However, the conductive bonding material 82 may be provided only inside the through hole 211F, so as not to reach the surface of the lead 2F.

The third portion 23F and the fourth portion 24F are covered with the encapsulating resin 7. The third portion 23F is connected to the first portion 21F and the fourth portion 24F. The fourth portion 24F is shifted in the z-direction with respect to the first portion 21F, to the side to which the first face 31 is oriented, like the third portion 23I and the fourth portion 24I of the lead 2I shown in FIG. 40. The end portion of the fourth portion 24F is flush with the fifth face 75 of the resin 7. In the illustrated example, the third portion 23F and the fourth portion 24F generally coincide with each other, as viewed in the y-direction. Here, the expression “generally coincide” as viewed in the y-direction refers to, for example, exactly coinciding with each other, or being deviated by within ±5% of the characteristic size (size of the third portion 23F or fourth portion 24F in the x-direction).

The second portion 22F is connected to the end portion of the fourth portion 24F, and corresponds to a portion of the lead 2F sticking out from the encapsulating resin 7 to the opposite side of the plurality of leads 1, as viewed in the y-direction. The second portion 22F sticks out to the opposite side of the first portion 21F, in the y-direction. The second portion 22F is used, for example, to electrically connect the semiconductor device A2 to an external circuit. In the illustrated example, the second portion 22F is bent in the z-direction, to the side to which the first face 31 is oriented. The second portion 22F, the third portion 23F, and the fourth portion 24F each include, on the respective sides thereof in the x-direction, edges extending along the y-direction. The edges of the second portion 22F, the third portion 23F, and the fourth portion 24F, on the side of the third face 33 in the x-direction, are respectively opposed to the edges of the second portion 22E, the third portion 23E, and the fourth portion 24E, on the side of the fourth face 34 in the x-direction.

The lead 2G is spaced apart from the plurality of leads 1. The lead 2G is located on the conductive section 5. The lead 2G is electrically connected to the conductive section 5. The lead 2G exemplifies a second lead in the present disclosure. The lead 2G is bonded to the second portion 52G of the wiring 50G in the conductive section 5, via the conductive bonding material 82.

The configuration of the lead 2G is not specifically limited. In this embodiment the lead 2G includes, as shown in FIG. 44, a first portion 21G, a second portion 22G, a third portion 23G, and a fourth portion 24G, each of which will be described hereunder.

The first portion 21G is bonded to the second portion 52G of the wiring 50G. The shape of the first portion 21G is not specifically limited, and a desired shape may be selected from a rectangular shape, a polygonal shape, a circular shape, an elliptical shape, and so forth. In the illustrated example, the first portion 21G has a strip shape extending along the y-direction. The first portion 21G overlaps with the fifth face 35 of the substrate 3 as viewed in the z-direction, and sticks out in the y-direction, toward the side to which the fifth face 35 is oriented. In the illustrated example, the first portion 21G overlaps with the second portion 52G, as viewed in the z-direction. In addition, the first portion 21G includes a through hole 211G. The through hole 211G is formed so as to penetrate through the first portion 21G, in the z-direction. The inside of the through hole 211G is filled with the conductive bonding material 82, like the through hole 211I in the first portion 21I of the lead 2I shown in FIG. 40. The conductive bonding material 82 covers a part of the surface of the lead 2G. However, the conductive bonding material 82 may be provided only inside the through hole 211G, so as not to reach the surface of the lead 2G.

The third portion 23G and the fourth portion 24G are covered with the encapsulating resin 7. The third portion 23G is connected to the first portion 21G and the fourth portion 24G. The fourth portion 24G is shifted in the z-direction with respect to the first portion 21G, to the side to which the first face 31 is oriented, like the third portion 23I and the fourth portion 24I of the lead 2I shown in FIG. 40. The end portion of the fourth portion 24G is flush with the fifth face 75 of the resin 7. In the illustrated example, the third portion 23G and the fourth portion 24G generally coincide with each other, as viewed in the y-direction. Here, the expression “generally coincide” as viewed in the y-direction refers to, for example, exactly coinciding with each other, or being deviated by within ±5% of the characteristic size (size of the third portion 23G or fourth portion 24G in the x-direction).

The second portion 22G is connected to the fourth portion 24G, and corresponds to a portion of the lead 2G sticking out from the encapsulating resin 7 to the opposite side of the plurality of leads 1, as viewed in the y-direction. The second portion 22G sticks out to the opposite side of the first portion 21G, in the y-direction. The second portion 22G is used, for example, to electrically connect the semiconductor device A2 to an external circuit. In the illustrated example, the second portion 22G is bent in the z-direction, to the side to which the first face 31 is oriented. The second portion 22G, the third portion 23G, and the fourth portion 24G each include, on the respective sides thereof in the x-direction, edges extending along the y-direction. The edges of the second portion 22G, the third portion 23G, and the fourth portion 24G, on the side of the third face 33 in the x-direction, are respectively opposed to the edges of the second portion 22F, the third portion 23F, and the fourth portion 24F, on the side of the fourth face 34 in the x-direction.

The lead 2H is spaced apart from the plurality of leads 1. The lead 2H is located on the conductive section 5. The lead 2H is electrically connected to the conductive section 5. The lead 2H exemplifies a second lead in the present disclosure. The lead 2H is bonded to the second portion 52H of the wiring 50H in the conductive section 5, via the conductive bonding material 82.

The configuration of the lead 2H is not specifically limited. In this embodiment the lead 2H includes, as shown in FIG. 44, a first portion 21H, a second portion 22H, a third portion 23H, and a fourth portion 24H, each of which will be described hereunder.

The first portion 21H is bonded to the second portion 52H of the wiring 50H. The shape of the first portion 21H is not specifically limited, and a desired shape may be selected from a rectangular shape, a polygonal shape, a circular shape, an elliptical shape, and so forth. In the illustrated example, the first portion 21H has a strip shape extending along the y-direction. The first portion 21H overlaps with the fifth face 35 of the substrate 3 as viewed in the z-direction, and sticks out in the y-direction, toward the side to which the fifth face 35 is oriented. In the illustrated example, the first portion 21H overlaps with the second portion 52H, as viewed in the z-direction. In addition, the first portion 21H includes a through hole 211H. The through hole 211H is formed so as to penetrate through the first portion 21H, in the z-direction. The inside of the through hole 211H is filled with the conductive bonding material 82, like the through hole 211I in the first portion 21I of the lead 2I shown in FIG. 40. The conductive bonding material 82 covers a part of the surface of the lead 2H. However, the conductive bonding material 82 may be provided only inside the through hole 211H, so as not to reach the surface of the lead 2H.

The third portion 23H and the fourth portion 24H are covered with the encapsulating resin 7. The third portion 23H is connected to the first portion 21H and the fourth portion 24H. The fourth portion 24H is shifted in the z-direction with respect to the first portion 21H, to the side to which the first face 31 is oriented, like the third portion 23I and the fourth portion 24I of the lead 2I shown in FIG. 40. The end portion of the fourth portion 24H is flush with the fifth face 75 of the resin 7. In the illustrated example, the third portion 23H and the fourth portion 24H generally coincide with each other, as viewed in the y-direction. Here, the expression “generally coincide” as viewed in the y-direction refers to, for example, exactly coinciding with each other, or being deviated by within ±5% of the characteristic size (size of the third portion 23H or fourth portion 24H in the x-direction).

The second portion 22H is connected to the end portion of the fourth portion 24H, and corresponds to a portion of the lead 2H sticking out from the encapsulating resin 7 to the opposite side of the plurality of leads 1, as viewed in the y-direction. The second portion 22H sticks out to the opposite side of the first portion 21H, in the y-direction. The second portion 22H is used, for example, to electrically connect the semiconductor device A2 to an external circuit. In the illustrated example, the second portion 22H is bent in the z-direction, to the side to which the first face 31 is oriented. The second portion 22H, the third portion 23H, and the fourth portion 24H each include, on the respective sides thereof in the x-direction, edges extending along the y-direction. The edges of the second portion 22H, the third portion 23H, and the fourth portion 24H, on the side of the third face 33 in the x-direction, are respectively opposed to the edges of the second portion 22G, the third portion 23G, and the fourth portion 24G, on the side of the fourth face 34 in the x-direction.

The lead 2I is spaced apart from the plurality of leads 1. The lead 2I is located on the conductive section 5. The lead 2I is electrically connected to the conductive section 5. The lead 2I exemplifies a second lead in the present disclosure. The lead 2I is bonded to the second portion 52I of the wiring 50I in the conductive section 5, via the conductive bonding material 82.

The configuration of the lead 2I is not specifically limited. In this embodiment the lead 2I includes, as shown in FIG. 45, a first portion 21I, a second portion 22I, a third portion 23I, and a fourth portion 24I, each of which will be described hereunder.

The first portion 21I is bonded to the second portion 52I of the wiring 50I. The shape of the first portion 21I is not specifically limited, and a desired shape may be selected from a rectangular shape, a polygonal shape, a circular shape, an elliptical shape, and so forth. In the illustrated example, the first portion 21I has a strip shape extending along the y-direction. The first portion 21I overlaps with the fifth face 35 of the substrate 3 as viewed in the z-direction, and includes a portion sticking out in the y-direction, toward the side to which the fifth face 35 is oriented. In the illustrated example, the first portion 21I overlaps with the second portion 52I, as viewed in the z-direction. In addition, the first portion 21I includes a through hole 211I. The through hole 211I is formed so as to penetrate through the first portion 21I, in the z-direction. The inside of the through hole 211I is filled with the conductive bonding material 82, as shown in FIG. 40 illustrating the lead 2I. The conductive bonding material 82 covers a part of the surface of the lead 2I. However, the conductive bonding material 82 may be provided only inside the through hole 211I, so as not to reach the surface of the lead 2I.

The third portion 23I and the fourth portion 24I are covered with the encapsulating resin 7. The third portion 23I is connected to the first portion 21I and the fourth portion 24I. The fourth portion 24I is shifted in the z-direction with respect to the first portion 21I, to the side to which the first face 31 is oriented, as shown in FIG. 40 illustrating the lead 2I. The end portion of the fourth portion 24I is flush with the fifth face 75 of the resin 7. In the illustrated example, the third portion 23I and the fourth portion 24I generally coincide with each other, as viewed in the y-direction. Here, the expression “generally coincide” as viewed in the y-direction refers to, for example, exactly coinciding with each other, or being deviated by within ±5% of the characteristic size (size of the third portion 23I or fourth portion 24I in the x-direction).

The second portion 22I is connected to the end portion of the fourth portion 24I, and corresponds to a portion of the lead 2I sticking out from the encapsulating resin 7 to the opposite side of the plurality of leads 1, as viewed in the y-direction. The second portion 22I sticks out to the opposite side of the first portion 21I, in the y-direction. The second portion 22I is used, for example, to electrically connect the semiconductor device A2 to an external circuit. In the illustrated example, the second portion 22I is bent in the z-direction, to the side to which the first face 31 is oriented. The second portion 22I, the third portion 23I, and the fourth portion 24I each include, on the respective sides thereof in the x-direction, edges extending along the y-direction. The edges of the second portion 22I, the third portion 23I, and the fourth portion 24I, on the side of the third face 33 in the x-direction, are respectively opposed to the edges of the second portion 22H, the third portion 23H, and the fourth portion 24H, on the side of the fourth face 34 in the x-direction.

The lead 2J is spaced apart from the plurality of leads 1. The lead 2J is located on the conductive section 5. The lead 2J is electrically connected to the conductive section 5. The lead 2J exemplifies a second lead in the present disclosure. The lead 2J is bonded to the second portion 52J of the wiring 50J in the conductive section 5, via the conductive bonding material 82.

The configuration of the lead 2J is not specifically limited. In this embodiment the lead 2J includes, as shown in FIG. 45, a first portion 21J, a second portion 22J, a third portion 23J, and a fourth portion 24J, each of which will be described hereunder.

The first portion 21J is bonded to the second portion 52J of the wiring 50J. The shape of the first portion 21J is not specifically limited, and a desired shape may be selected from a rectangular shape, a polygonal shape, a circular shape, an elliptical shape, and so forth. In the illustrated example, the first portion 21J has a strip shape extending along the y-direction. The first portion 21J overlaps with the fifth face 35 of the substrate 3 as viewed in the z-direction, and includes a portion extending from the fifth face 35 in the y-direction, toward the side to which the fifth face 35 is oriented. In the illustrated example, the first portion 21J overlaps with the second portion 52J, as viewed in the z-direction. In addition, the first portion 21J includes a through hole 211J. The through hole 211J is formed so as to penetrate through the first portion 21J, in the z-direction. The inside of the through hole 211J is filled with the conductive bonding material 82, as illustrated in FIG. 45 with regard to the lead 2J. The conductive bonding material 82 covers a part of the surface of the lead 2J. However, the conductive bonding material 82 may be provided only inside the through hole 211J, so as not to reach the surface of the lead 2J.

The third portion 23J and the fourth portion 24J are covered with the encapsulating resin 7. The third portion 23J is connected to the first portion 21J and the fourth portion 24J. The fourth portion 24J is shifted in the z-direction with respect to the first portion 21J, to the side to which the first face 31 is oriented, as illustrated in FIG. 40 with regard to the lead 2I. The end portion of the fourth portion 24J is flush with the fifth face 75 of the resin 7. In the illustrated example, the third portion 23J and the fourth portion 24J generally coincide with each other, as viewed in the y-direction. Here, the expression “generally coincide” as viewed in the y-direction refers to, for example, exactly coinciding with each other, or being deviated by within ±5% of the characteristic size (size of the third portion 23J or fourth portion 24J in the x-direction).

The second portion 22J is connected to the end portion of the fourth portion 24J, and corresponds to a portion of the lead 2J sticking out from the encapsulating resin 7 to the opposite side of the plurality of leads 1, as viewed in the y-direction. The second portion 22J sticks out to the opposite side of the first portion 21J, in the y-direction. The second portion 22J is used, for example, to electrically connect the semiconductor device A2 to an external circuit. In the illustrated example, the second portion 22J is bent in the z-direction, to the side to which the first face 31 is oriented. The second portion 22J, the third portion 23J, and the fourth portion 24J each include, on the respective sides thereof in the x-direction, edges extending along the y-direction. The edges of the second portion 22J, the third portion 23J, and the fourth portion 24J, on the side of the third face 33 in the x-direction, are respectively opposed to the edges of the second portion 22I, the third portion 23I, and the fourth portion 24I, on the side of the fourth face 34 in the x-direction.

The lead 2K is spaced apart from the plurality of leads 1. The lead 2K is located on the conductive section 5. The lead 2K is electrically connected to the conductive section 5. The lead 2K exemplifies a second lead in the present disclosure. The lead 2K is bonded to the second portion 52K of the wiring 50K in the conductive section 5, via the conductive bonding material 82.

The configuration of the lead 2K is not specifically limited. In this embodiment the lead 2K includes, as shown in FIG. 45, a first portion 21K, a second portion 22K, a third portion 23K, and a fourth portion 24K, each of which will be described hereunder.

The first portion 21K is bonded to the second portion 52K of the wiring 50K. The shape of the first portion 21K is not specifically limited, and a desired shape may be selected from a rectangular shape, a polygonal shape, a circular shape, an elliptical shape, and so forth. In the illustrated example, the first portion 21K has a strip shape extending along the y-direction. The first portion 21K overlaps with the fifth face 35 of the substrate 3 as viewed in the z-direction, and includes a portion extending from the fifth face 35 in the y-direction, toward the side to which the fifth face 35 is oriented. In the illustrated example, the first portion 21K overlaps with the second portion 52K, as viewed in the z-direction. In addition, the first portion 21K includes a through hole 211K. The through hole 211K is formed so as to penetrate through the first portion 21K, in the z-direction. The inside of the through hole 211K is filled with the conductive bonding material 82, as illustrated in FIG. 45 with regard to the lead 2K. The conductive bonding material 82 covers a part of the surface of the lead 2K. However, the conductive bonding material 82 may be provided only inside the through hole 211K, so as not to reach the surface of the lead 2K.

The third portion 23K and the fourth portion 24K are covered with the encapsulating resin 7. The third portion 23K is connected to the first portion 21K and the fourth portion 24K. The fourth portion 24K is shifted in the z-direction with respect to the first portion 21K, to the side to which the first face 31 is oriented, as illustrated in FIG. 40 with regard to the lead 2I. The end portion of the fourth portion 24K is flush with the fifth face 75 of the resin 7. In the illustrated example, the third portion 23K and the fourth portion 24K generally coincide with each other, as viewed in the y-direction. Here, the expression “generally coincide” as viewed in the y-direction refers to, for example, exactly coinciding with each other, or being deviated by within ±5% of the characteristic size (size of the third portion 23K or fourth portion 24K in the x-direction).

The second portion 22K is connected to the end portion of the fourth portion 24K, and corresponds to a portion of the lead 2K sticking out from the encapsulating resin 7 to the opposite side of the plurality of leads 1, as viewed in the y-direction. The second portion 22K sticks out to the opposite side of the first portion 21K, in the y-direction. The second portion 22K is used, for example, to electrically connect the semiconductor device A2 to an external circuit. In the illustrated example, the second portion 22K is bent in the z-direction, to the side to which the first face 31 is oriented. The second portion 22K, the third portion 23K, and the fourth portion 24K each include, on the respective sides thereof in the x-direction, edges extending along the y-direction. The edges of the second portion 22K, the third portion 23K, and the fourth portion 24K, on the side of the third face 33 in the x-direction, are respectively opposed to the edges of the second portion 22J, the third portion 23J, and the fourth portion 24J, on the side of the fourth face 34 in the x-direction.

The lead 2L is spaced apart from the plurality of leads 1. The lead 2L is located on the conductive section 5. The lead 2L is electrically connected to the conductive section 5. The lead 2L exemplifies a second lead in the present disclosure. The lead 2L is bonded to the second portion 52L of the wiring 50L in the conductive section 5, via the conductive bonding material 82.

The configuration of the lead 2L is not specifically limited. In this embodiment the lead 2L includes, as shown in FIG. 45, a first portion 21L, a second portion 22L, a third portion 23L, and a fourth portion 24L, each of which will be described hereunder.

The first portion 21L is bonded to the second portion 52L of the wiring 50L. The shape of the first portion 21L is not specifically limited, and a desired shape may be selected from a rectangular shape, a polygonal shape, a circular shape, an elliptical shape, and so forth. In the illustrated example, the first portion 21L has a strip shape extending along the y-direction. The first portion 21L overlaps with the fifth face 35 of the substrate 3 as viewed in the z-direction, and includes a portion extending from the fifth face 35 in the y-direction, toward the side to which the fifth face 35 is oriented. In the illustrated example, the first portion 21L overlaps with the second portion 52L, as viewed in the z-direction. In addition, the first portion 21L includes a through hole 211L. The through hole 211L is formed so as to penetrate through the first portion 21L, in the z-direction. The inside of the through hole 211L is filled with the conductive bonding material 82, as illustrated in FIG. 45 with regard to the lead 2L. The conductive bonding material 82 covers a part of the surface of the lead 2L. However, the conductive bonding material 82 may be provided only inside the through hole 211L, so as not to reach the surface of the lead 2L.

The third portion 23L and the fourth portion 24L are covered with the encapsulating resin 7. The third portion 23L is connected to the first portion 21L and the fourth portion 24L. The fourth portion 24L is shifted in the z-direction with respect to the first portion 21L, to the side to which the first face 31 is oriented, as illustrated in FIG. 40 with regard to the lead 2I. The end portion of the fourth portion 24L is flush with the fifth face 75 of the resin 7. In the illustrated example, the third portion 23L and the fourth portion 24L generally coincide with each other, as viewed in the y-direction. Here, the expression “generally coincide” as viewed in the y-direction refers to, for example, exactly coinciding with each other, or being deviated by within ±5% of the characteristic size (size of the third portion 23L or fourth portion 24L in the x-direction).

The second portion 22L is connected to the end portion of the fourth portion 24L, and corresponds to a portion of the lead 2L sticking out from the encapsulating resin 7 to the opposite side of the plurality of leads 1, as viewed in the y-direction. The second portion 22L sticks out to the opposite side of the first portion 21L, in the y-direction. The second portion 22L is used, for example, to electrically connect the semiconductor device A2 to an external circuit. In the illustrated example, the second portion 22L is bent in the z-direction, to the side to which the first face 31 is oriented. The second portion 22L, the third portion 23L, and the fourth portion 24L each include, on the respective sides thereof in the x-direction, edges extending along the y-direction. The edges of the second portion 22L, the third portion 23L, and the fourth portion 24L, on the side of the third face 33 in the x-direction, are respectively opposed to the edges of the second portion 22K, the third portion 23K, and the fourth portion 24K, on the side of the fourth face 34 in the x-direction.

The lead 2M is spaced apart from the plurality of leads 1. The lead 2M is located on the conductive section 5. The lead 2M is electrically connected to the conductive section 5. The lead 2M exemplifies a second lead in the present disclosure. The lead 2M is bonded to the second portion 52M of the wiring 50M in the conductive section 5, via the conductive bonding material 82.

The configuration of the lead 2M is not specifically limited. In this embodiment the lead 2M includes, as shown in FIG. 45, a first portion 21M, a second portion 22M, a third portion 23M, and a fourth portion 24M, each of which will be described hereunder.

The first portion 21M is bonded to the second portion 52M of the wiring 50M. The shape of the first portion 21M is not specifically limited, and a desired shape may be selected from a rectangular shape, a polygonal shape, a circular shape, an elliptical shape, and so forth. In the illustrated example, the first portion 21M has a strip shape extending along the y-direction. The first portion 21M overlaps with the fifth face 35 of the substrate 3 as viewed in the z-direction, and includes a portion extending from the fifth face 35 in the y-direction, toward the side to which the fifth face 35 is oriented. In the illustrated example, the first portion 21M overlaps with the second portion 52M, as viewed in the z-direction. In addition, the first portion 21M includes a through hole 211M. The through hole 211M is formed so as to penetrate through the first portion 21M, in the z-direction. The inside of the through hole 211M is filled with the conductive bonding material 82, as illustrated in FIG. 45 with regard to the lead 2M. The conductive bonding material 82 covers a part of the surface of the lead 2M. However, the conductive bonding material 82 may be provided only inside the through hole 211M, so as not to reach the surface of the lead 2M.

The third portion 23M and the fourth portion 24M are covered with the encapsulating resin 7. The third portion 23M is connected to the first portion 21M and the fourth portion 24M. The fourth portion 24M is shifted in the z-direction with respect to the first portion 21M, to the side to which the first face 31 is oriented, as illustrated in FIG. 40 with regard to the lead 2I. The end portion of the fourth portion 24M is flush with the fifth face 75 of the resin 7. In the illustrated example, the third portion 23M and the fourth portion 24M generally coincide with each other, as viewed in the y-direction. Here, the expression “generally coincide” as viewed in the y-direction refers to, for example, exactly coinciding with each other, or being deviated by within ±5% of the characteristic size (size of the third portion 23M or fourth portion 24M in the x-direction).

The second portion 22M is connected to the end portion of the fourth portion 24M, and corresponds to a portion of the lead 2M sticking out from the encapsulating resin 7 to the opposite side of the plurality of leads 1, as viewed in the y-direction. The second portion 22M sticks out to the opposite side of the first portion 21M, in the y-direction. The second portion 22M is used, for example, to electrically connect the semiconductor device A2 to an external circuit. In the illustrated example, the second portion 22M is bent in the z-direction, to the side to which the first face 31 is oriented. The second portion 22M, the third portion 23M, and the fourth portion 24M each include, on the respective sides thereof in the x-direction, edges extending along the y-direction. The edges of the second portion 22M, the third portion 23M, and the fourth portion 24M, on the side of the third face 33 in the x-direction, are respectively opposed to the edges of the second portion 22L, the third portion 23L, and the fourth portion 24L, on the side of the fourth face 34 in the x-direction.

The lead 2N is spaced apart from the plurality of leads 1. The lead 2N is located on the conductive section 5. The lead 2N is electrically connected to the conductive section 5. The lead 2N exemplifies a second lead in the present disclosure. The lead 2N is bonded to the second portion 52N of the wiring 50N in the conductive section 5, via the conductive bonding material 82.

The configuration of the lead 2N is not specifically limited. In this embodiment the lead 2N includes, as shown in FIG. 45, a first portion 21N, a second portion 22N, a third portion 23N, and a fourth portion 24N, each of which will be described hereunder.

The first portion 21N is bonded to the second portion 52N of the wiring 50N. The shape of the first portion 21N is not specifically limited, and a desired shape may be selected from a rectangular shape, a polygonal shape, a circular shape, an elliptical shape, and so forth. In the illustrated example, the first portion 21N has a strip shape extending along the y-direction. The first portion 21N overlaps with the fifth face 35 of the substrate 3 as viewed in the z-direction, and includes a portion extending from the fifth face 35 in the y-direction, toward the side to which the fifth face 35 is oriented. In the illustrated example, the first portion 21N overlaps with the second portion 52N, as viewed in the z-direction. In addition, the first portion 21N includes a through hole 211N. The through hole 211N is formed so as to penetrate through the first portion 21N, in the z-direction. The inside of the through hole 211N is filled with the conductive bonding material 82, as illustrated in FIG. 45 with regard to the lead 2N. The conductive bonding material 82 covers a part of the surface of the lead 2N. However, the conductive bonding material 82 may be provided only inside the through hole 211N, so as not to reach the surface of the lead 2N.

The third portion 23N and the fourth portion 24N are covered with the encapsulating resin 7. The third portion 23N is connected to the first portion 21N and the fourth portion 24N. The fourth portion 24N is shifted in the z-direction with respect to the first portion 21N, to the side to which the first face 31 is oriented, as illustrated in FIG. 40 with regard to the lead 2I. The end portion of the fourth portion 24N is flush with the fifth face 75 of the resin 7. In the illustrated example, the third portion 23N and the fourth portion 24N generally coincide with each other, as viewed in the y-direction. Here, the expression “generally coincide” as viewed in the y-direction refers to, for example, exactly coinciding with each other, or being deviated by within ±5% of the characteristic size (size of the third portion 23N or fourth portion 24N in the x-direction).

The second portion 22N is connected to the end portion of the fourth portion 24N, and corresponds to a portion of the lead 2N sticking out from the encapsulating resin 7 to the opposite side of the plurality of leads 1, as viewed in the y-direction. The second portion 22N sticks out to the opposite side of the first portion 21N, in the y-direction. The second portion 22N is used, for example, to electrically connect the semiconductor device A2 to an external circuit. In the illustrated example, the second portion 22N is bent in the z-direction, to the side to which the first face 31 is oriented. The second portion 22N, the third portion 23N, and the fourth portion 24N each include, on the respective sides thereof in the x-direction, edges extending along the y-direction. The edges of the second portion 22N, the third portion 23N, and the fourth portion 24N, on the side of the third face 33 in the x-direction, are respectively opposed to the edges of the second portion 22M, the third portion 23M, and the fourth portion 24M, on the side of the fourth face 34 in the x-direction.

The lead 2O is spaced apart from the plurality of leads 1. The lead 2O is located on the conductive section 5. The lead 2O is electrically connected to the conductive section 5. The lead 2O exemplifies a second lead in the present disclosure. The lead 2O is bonded to the second portion 52O of the wiring 50O in the conductive section 5, via the conductive bonding material 82.

The configuration of the lead 2O is not specifically limited. In this embodiment the lead 2O includes, as shown in FIG. 45, a first portion 21O, a second portion 22O, a third portion 23O, and a fourth portion 24O, each of which will be described hereunder.

The first portion 21O is bonded to the second portion 52O of the wiring 50O. The shape of the first portion 21O is not specifically limited, and a desired shape may be selected from a rectangular shape, a polygonal shape, a circular shape, an elliptical shape, and so forth. In the illustrated example, the first portion 21O has a strip shape extending along the y-direction. The first portion 21O overlaps with the fifth face 35 of the substrate 3 as viewed in the z-direction, and includes a portion extending from the fifth face 35 in the y-direction, toward the side to which the fifth face 35 is oriented. In the illustrated example, the first portion 21O overlaps with the second portion 52O, as viewed in the z-direction. In addition, the first portion 21O includes a through hole 211O. The through hole 211O is formed so as to penetrate through the first portion 21O, in the z-direction. The inside of the through hole 211O is filled with the conductive bonding material 82, as illustrated in FIG. 45 with regard to the lead 2O. The conductive bonding material 82 covers a part of the surface of the lead 2O. However, the conductive bonding material 82 may be provided only inside the through hole 211O, so as not to reach the surface of the lead 2O.

The third portion 23O and the fourth portion 24O are covered with the encapsulating resin 7. The third portion 23O is connected to the first portion 21O and the fourth portion 24O. The fourth portion 24O is shifted in the z-direction with respect to the first portion 21O, to the side to which the first face 31 is oriented, as illustrated in FIG. 45 with regard to the lead 2O. The end portion of the fourth portion 24O is flush with the fifth face 75 of the resin 7. In the illustrated example, the third portion 23O and the fourth portion 24O generally coincide with each other, as viewed in the y-direction. Here, the expression “generally coincide” as viewed in the y-direction refers to, for example, exactly coinciding with each other, or being deviated by within ±5% of the characteristic size (size of the third portion 23O or fourth portion 24O in the x-direction).

The second portion 22O is connected to the end portion of the fourth portion 24O, and corresponds to a portion of the lead 2O sticking out from the encapsulating resin 7 to the opposite side of the plurality of leads 1, as viewed in the y-direction. The second portion 22O sticks out to the opposite side of the first portion 21O, in the y-direction. The second portion 22O is used, for example, to electrically connect the semiconductor device A2 to an external circuit. In the illustrated example, the second portion 22O is bent in the z-direction, to the side to which the first face 31 is oriented. The second portion 22O, the third portion 23O, and the fourth portion 24O each include, on the respective sides thereof in the x-direction, edges extending along the y-direction. The edges of the second portion 22O, the third portion 23O, and the fourth portion 24O, on the side of the third face 33 in the x-direction, are respectively opposed to the edges of the second portion 22N, the third portion 23N, and the fourth portion 24N, on the side of the fourth face 34 in the x-direction.

The lead 2P is spaced apart from the plurality of leads 1. The lead 2P is located on the conductive section 5. The lead 2P is electrically connected to the conductive section 5. The lead 2P exemplifies a second lead in the present disclosure. The lead 2P is bonded to the second portion 52P of the wiring 50P in the conductive section 5, via the conductive bonding material 82.

The configuration of the lead 2P is not specifically limited. In this embodiment the lead 2P includes, as shown in FIG. 45, a first portion 21P, a second portion 22P, a third portion 23P, and a fourth portion 24P, each of which will be described hereunder.

The first portion 21P is bonded to the second portion 52P of the wiring 50P. The shape of the first portion 21P is not specifically limited, and a desired shape may be selected from a rectangular shape, a polygonal shape, a circular shape, an elliptical shape, and so forth. In the illustrated example, the first portion 21P has a strip shape extending along the y-direction. The first portion 21P overlaps with the fifth face 35 of the substrate 3 as viewed in the z-direction, and includes a portion extending from the fifth face 35 in the y-direction, toward the side to which the fifth face 35 is oriented. In the illustrated example, the first portion 21P overlaps with the second portion 52P, as viewed in the z-direction. In addition, the first portion 21P includes a through hole 211P. The through hole 211P is formed so as to penetrate through the first portion 21P, in the z-direction. The inside of the through hole 211P is filled with the conductive bonding material 82, as illustrated in FIG. 45 with regard to the lead 2P. The conductive bonding material 82 covers a part of the surface of the lead 2P. However, the conductive bonding material 82 may be provided only inside the through hole 211P, so as not to reach the surface of the lead 2P.

The third portion 23P and the fourth portion 24P are covered with the encapsulating resin 7. The third portion 23P is connected to the first portion 21P and the fourth portion 24P. The fourth portion 24P is shifted in the z-direction with respect to the first portion 21P, to the side to which the first face 31 is oriented, as illustrated in FIG. 40 with regard to the lead 2I. The end portion of the fourth portion 24P is flush with the fifth face 75 of the resin 7. In the illustrated example, the third portion 23P and the fourth portion 24P generally coincide with each other, as viewed in the y-direction. Here, the expression “generally coincide” as viewed in the y-direction refers to, for example, exactly coinciding with each other, or being deviated by within ±5% of the characteristic size (size of the third portion 23P or fourth portion 24P in the x-direction).

The second portion 22P is connected to the end portion of the fourth portion 24P, and corresponds to a portion of the lead 2P sticking out from the encapsulating resin 7 to the opposite side of the plurality of leads 1, as viewed in the y-direction. The second portion 22P sticks out to the opposite side of the first portion 21P, in the y-direction. The second portion 22P is used, for example, to electrically connect the semiconductor device A2 to an external circuit. In the illustrated example, the second portion 22P is bent in the z-direction, to the side to which the first face 31 is oriented. The second portion 22P, the third portion 23P, and the fourth portion 24P each include, on the respective sides thereof in the x-direction, edges extending along the y-direction. The edges of the second portion 22P, the third portion 23P, and the fourth portion 24P, on the side of the third face 33 in the x-direction, are respectively opposed to the edges of the second portion 22O, the third portion 23O, and the fourth portion 24O, on the side of the fourth face 34 in the x-direction.

The lead 2Q is spaced apart from the plurality of leads 1. The lead 2Q is located on the conductive section 5. The lead 2Q is electrically connected to the conductive section 5. The lead 2Q exemplifies a second lead in the present disclosure. The lead 2Q is bonded to the second portion 52Q of the wiring 50Q in the conductive section 5, via the conductive bonding material 82.

The configuration of the lead 2Q is not specifically limited. In this embodiment the lead 2Q includes, as shown in FIG. 45, a first portion 21Q, a second portion 22Q, a third portion 23Q, and a fourth portion 24Q, each of which will be described hereunder.

The first portion 21Q is bonded to the second portion 52Q of the wiring 50Q. The shape of the first portion 21Q is not specifically limited, and a desired shape may be selected from a rectangular shape, a polygonal shape, a circular shape, an elliptical shape, and so forth. In the illustrated example, the first portion 21Q has a strip shape extending along the y-direction. The first portion 21Q overlaps with the fifth face 35 of the substrate 3 as viewed in the z-direction, and includes a portion extending from the fifth face 35 in the y-direction, toward the side to which the fifth face 35 is oriented. In the illustrated example, the first portion 21Q overlaps with the second portion 52Q, as viewed in the z-direction. In addition, the first portion 21Q includes a through hole 211Q. The through hole 211Q is formed so as to penetrate through the first portion 21Q, in the z-direction. The inside of the through hole 211Q is filled with the conductive bonding material 82, as illustrated in FIG. 45 with regard to the lead 2Q. The conductive bonding material 82 covers a part of the surface of the lead 2Q. However, the conductive bonding material 82 may be provided only inside the through hole 211Q, so as not to reach the surface of the lead 2Q.

The third portion 23Q and the fourth portion 24Q are covered with the encapsulating resin 7. The third portion 23Q is connected to the first portion 21Q and the fourth portion 24Q. The fourth portion 24Q is shifted in the z-direction with respect to the first portion 21Q, to the side to which the first face 31 is oriented, as illustrated in FIG. 40 with regard to the lead 2I. The end portion of the fourth portion 24Q is flush with the fifth face 75 of the resin 7. In the illustrated example, the third portion 23Q and the fourth portion 24Q generally coincide with each other, as viewed in the y-direction. Here, the expression “generally coincide” as viewed in the y-direction refers to, for example, exactly coinciding with each other, or being deviated by within ±5% of the characteristic size (size of the third portion 23Q or fourth portion 24Q in the x-direction).

The second portion 22Q is connected to the end portion of the fourth portion 24Q, and corresponds to a portion of the lead 2Q sticking out from the encapsulating resin 7 to the opposite side of the plurality of leads 1, as viewed in the y-direction. The second portion 22Q sticks out to the opposite side of the first portion 21Q, in the y-direction. The second portion 22Q is used, for example, to electrically connect the semiconductor device A2 to an external circuit. In the illustrated example, the second portion 22Q is bent in the z-direction, to the side to which the first face 31 is oriented. The second portion 22Q, the third portion 23Q, and the fourth portion 24Q each include, on the respective sides thereof in the x-direction, edges extending along the y-direction. The edges of the second portion 22Q, the third portion 23Q, and the fourth portion 24Q, on the side of the third face 33 in the x-direction, are respectively opposed to the edges of the second portion 22P, the third portion 23P, and the fourth portion 24P, on the side of the fourth face 34 in the x-direction.

The lead 2R is spaced apart from the plurality of leads 1. The lead 2R is located on the conductive section 5. The lead 2R is electrically connected to the conductive section 5. The lead 2R exemplifies a second lead in the present disclosure. The lead 2R is bonded to the second portion 52R of the wiring 50R in the conductive section 5, via the conductive bonding material 82.

The configuration of the lead 2R is not specifically limited. In this embodiment the lead 2R includes, as shown in FIG. 45, a first portion 21R, a second portion 22R, a third portion 23R, and a fourth portion 24R, each of which will be described hereunder.

The first portion 21R is bonded to the second portion 52R of the wiring 50R. The shape of the first portion 21R is not specifically limited, and a desired shape may be selected from a rectangular shape, a polygonal shape, a circular shape, an elliptical shape, and so forth. In the illustrated example, the first portion 21R has a strip shape extending along the y-direction. The first portion 21R overlaps with the fifth face 35 of the substrate 3 as viewed in the z-direction, and includes a portion extending from the fifth face 35 in the y-direction, toward the side to which the fifth face 35 is oriented. In the illustrated example, the first portion 21R overlaps with the second portion 52R, as viewed in the z-direction. In addition, the first portion 21R includes a through hole 211R. The through hole 211R is formed so as to penetrate through the first portion 21R, in the z-direction. The inside of the through hole 211R is filled with the conductive bonding material 82, as illustrated in FIG. 45 with regard to the lead 2R. The conductive bonding material 82 covers a part of the surface of the lead 2R. However, the conductive bonding material 82 may be provided only inside the through hole 211R, so as not to reach the surface of the lead 2R.

The third portion 23R and the fourth portion 24R are covered with the encapsulating resin 7. The third portion 23R is connected to the first portion 21R and the fourth portion 24R. The fourth portion 24R is shifted in the z-direction with respect to the first portion 21R, to the side to which the first face 31 is oriented, as illustrated in FIG. 40 with regard to the lead 2I. The end portion of the fourth portion 24R is flush with the fifth face 75 of the resin 7. In the illustrated example, the third portion 23R and the fourth portion 24R generally coincide with each other, as viewed in the y-direction. Here, the expression “generally coincide” as viewed in the y-direction refers to, for example, exactly coinciding with each other, or being deviated by within ±5% of the characteristic size (size of the third portion 23R or fourth portion 24R in the x-direction).

The second portion 22R is connected to the end portion of the fourth portion 24R, and corresponds to a portion of the lead 2R sticking out from the encapsulating resin 7 to the opposite side of the plurality of leads 1, as viewed in the y-direction. The second portion 22R sticks out to the opposite side of the first portion 21R, in the y-direction. The second portion 22R is used, for example, to electrically connect the semiconductor device A2 to an external circuit. In the illustrated example, the second portion 22R is bent in the z-direction, to the side to which the first face 31 is oriented. The second portion 22R, the third portion 23R, and the fourth portion 24R each include, on the respective sides thereof in the x-direction, edges extending along the y-direction. The edges of the second portion 22R, the third portion 23R, and the fourth portion 24R, on the side of the third face 33 in the x-direction, are respectively opposed to the edges of the second portion 22Q, the third portion 23Q, and the fourth portion 24Q, on the side of the fourth face 34 in the x-direction.

The lead 2S is spaced apart from the plurality of leads 1. The lead 2S is located on the conductive section 5. The lead 2S is electrically connected to the conductive section 5. The lead 2S exemplifies a second lead in the present disclosure. The lead 2S is bonded to the second portion 52S of the wiring 50S in the conductive section 5, via the conductive bonding material 82.

The configuration of the lead 2S is not specifically limited. In this embodiment the lead 2S includes, as shown in FIG. 45, a first portion 21S, a second portion 22S, a third portion 23S, and a fourth portion 24S, each of which will be described hereunder.

The first portion 21S is bonded to the second portion 52S of the wiring 50S. The shape of the first portion 21S is not specifically limited, and a desired shape may be selected from a rectangular shape, a polygonal shape, a circular shape, an elliptical shape, and so forth. In the illustrated example, the first portion 21S has a bent shape including a portion extending along the x-direction, and a portion inclined with respect to the x-direction and the y-direction. The first portion 21S overlaps with the fourth face 34 of the substrate 3 as viewed in the z-direction, and sticks out in the x-direction, toward the side to which the fourth face 34 is oriented. In the illustrated example, the first portion 21S overlaps with the second portion 52S, as viewed in the z-direction. In addition, the first portion 21S includes a through hole 211S. The through hole 211S is formed so as to penetrate through the first portion 21S, in the z-direction. The inside of the through hole 211S is filled with the conductive bonding material 82, like the through hole 211I in the first portion 21I of the lead 2I shown in FIG. 40. The conductive bonding material 82 covers a part of the surface of the lead 2S. However, the conductive bonding material 82 may be provided only inside the through hole 211S, so as not to reach the surface of the lead 2S.

The third portion 23S and the fourth portion 24S are covered with the encapsulating resin 7. The third portion 23S is connected to the first portion 21S and the fourth portion 24S. The fourth portion 24S is shifted in the z-direction with respect to the first portion 21S, to the side to which the first face 31 is oriented, like the third portion 23I and the fourth portion 24I of the lead 2I shown in FIG. 40. The end portion of the fourth portion 24S is flush with the fifth face 75 of the resin 7. In the illustrated example, the third portion 23S and the fourth portion 24S generally coincide with each other, as viewed in the y-direction. Here, the expression “generally coincide” as viewed in the y-direction refers to, for example, exactly coinciding with each other, or being deviated by within ±5% of the characteristic size (size of the third portion 23S or fourth portion 24S in the x-direction).

The second portion 22S is connected to the end portion of the fourth portion 24S, and corresponds to a portion of the lead 2S sticking out from the encapsulating resin 7 to the opposite side of the plurality of leads 1, as viewed in the y-direction. The second portion 22S sticks out to the opposite side of the first portion 21S, in the y-direction. The second portion 22S is used, for example, to electrically connect the semiconductor device A2 to an external circuit. In the illustrated example, the second portion 22S is bent in the z-direction, to the side to which the first face 31 is oriented. The second portion 22S, the third portion 23S, and the fourth portion 24S each include, on the respective sides thereof in the x-direction, edges extending along the y-direction. The edges of the second portion 22S, the third portion 23S, and the fourth portion 24S, on the side of the third face 33 in the x-direction, are respectively opposed to the edges of the second portion 22R, the third portion 23R, and the fourth portion 24R, on the side of the fourth face 34 in the x-direction.

The lead 2T is spaced apart from the plurality of leads 1. The lead 2T is located on the conductive section 5. The lead 2T is electrically connected to the conductive section 5. The lead 2T exemplifies a second lead in the present disclosure. The lead 2T is bonded to the second portion 52T of the wiring 50T in the conductive section 5, via the conductive bonding material 82.

The configuration of the lead 2T is not specifically limited. In this embodiment the lead 2T includes, as shown in FIG. 45, a first portion 21T, a second portion 22T, a third portion 23T, and a fourth portion 24T, each of which will be described hereunder.

The first portion 21T is bonded to the second portion 52T of the wiring 50T. The shape of the first portion 21T is not specifically limited, and a desired shape may be selected from a rectangular shape, a polygonal shape, a circular shape, an elliptical shape, and so forth. In the illustrated example, the first portion 21T has a bent shape including a portion extending along the x-direction, a portion inclined with respect to the x-direction and the y-direction, and a portion extending along the y-direction. The first portion 21T overlaps with the fourth face 34 of the substrate 3 as viewed in the z-direction, and sticks out in the x-direction, toward the side to which the fourth face 34 is oriented. In the illustrated example, the first portion 21T overlaps with the second portion 52T, as viewed in the z-direction. In addition, the first portion 21T includes a through hole 211T. The through hole 211T is formed so as to penetrate through the first portion 21T, in the z-direction. The inside of the through hole 211T is filled with the conductive bonding material 82, like the through hole 211I in the first portion 21I of the lead 2I shown in FIG. 40. The conductive bonding material 82 covers a part of the surface of the lead 2T. However, the conductive bonding material 82 may be provided only inside the through hole 211T, so as not to reach the surface of the lead 2T.

The third portion 23T and the fourth portion 24T are covered with the encapsulating resin 7. The third portion 23T is connected to the first portion 21T and the fourth portion 24T. The fourth portion 24T is shifted in the z-direction with respect to the first portion 21T, to the side to which the first face 31 is oriented, like the third portion 23I and the fourth portion 24I of the lead 2I shown in FIG. 40. The end portion of the fourth portion 24T is flush with the fifth face 75 of the resin 7. In the illustrated example, the third portion 23T and the fourth portion 24T generally coincide with each other, as viewed in the y-direction. Here, the expression “generally coincide” as viewed in the y-direction refers to, for example, exactly coinciding with each other, or being deviated by within ±5% of the characteristic size (size of the third portion 23T or fourth portion 24T in the x-direction).

The second portion 22T is connected to the end portion of the fourth portion 24T, and corresponds to a portion of the lead 2T sticking out from the encapsulating resin 7 to the opposite side of the plurality of leads 1, as viewed in the y-direction. The second portion 22T sticks out to the opposite side of the first portion 21T, in the y-direction. The second portion 22T is used, for example, to electrically connect the semiconductor device A2 to an external circuit. In the illustrated example, the second portion 22T is bent in the z-direction, to the side to which the first face 31 is oriented. The second portion 22T, the third portion 23T, and the fourth portion 24T each include, on the respective sides thereof in the x-direction, edges extending along the y-direction. The edges of the second portion 22T, the third portion 23T, and the fourth portion 24T, on the side of the third face 33 in the x-direction, are respectively opposed to the edges of the second portion 22S, the third portion 23S, and the fourth portion 24S, on the side of the fourth face 34 in the x-direction.

The lead 2U is spaced apart from the plurality of leads 1. The lead 2U is located on the conductive section 5. The lead 2U is electrically connected to the conductive section 5. The lead 2U exemplifies a second lead in the present disclosure. The lead 2U is bonded to the second portion 52O of the wiring 50U in the conductive section 5, via the conductive bonding material 82.

The configuration of the lead 2U is not specifically limited. In this embodiment the lead 2U includes, as shown in FIG. 45, a first portion 21U, a second portion 22U, a third portion 23U, and a fourth portion 24U, each of which will be described hereunder.

The first portion 21U is bonded to the second portion 52U of the wiring 50U. The shape of the first portion 21O is not specifically limited, and a desired shape may be selected from a rectangular shape, a polygonal shape, a circular shape, an elliptical shape, and so forth. In the illustrated example, the first portion 21U has a bent shape including a portion extending along the x-direction, a portion inclined with respect to the x-direction and the y-direction, and a portion extending along the y-direction. The first portion 21U overlaps with the fourth face 34 of the substrate 3 as viewed in the z-direction, and sticks out in the x-direction, toward the side to which the fourth face 34 is oriented. In the illustrated example, the first portion 21U overlaps with the second portion 52U, as viewed in the z-direction. In addition, the first portion 21U includes a through hole 211U. The through hole 211U is formed so as to penetrate through the first portion 21U, in the z-direction. The inside of the through hole 211U is filled with the conductive bonding material 82, like the through hole 211I in the first portion 21I of the lead 2I shown in FIG. 40. The conductive bonding material 82 covers a part of the surface of the lead 2U. However, the conductive bonding material 82 may be provided only inside the through hole 211U, so as not to reach the surface of the lead 2U.

The third portion 23U and the fourth portion 24U are covered with the encapsulating resin 7. The third portion 23U is connected to the first portion 21U and the fourth portion 24U. The fourth portion 24U is shifted in the z-direction with respect to the first portion 21U, to the side to which the first face 31 is oriented, like the third portion 23I and the fourth portion 24I of the lead 2I shown in FIG. 40. The end portion of the fourth portion 24U is flush with the fifth face 75 of the resin 7. In the illustrated example, the third portion 23U and the fourth portion 24U generally coincide with each other, as viewed in the y-direction. Here, the expression “generally coincide” as viewed in the y-direction refers to, for example, exactly coinciding with each other, or being deviated by within ±5% of the characteristic size (size of the third portion 23O or fourth portion 24U in the x-direction).

The second portion 22U is connected to the end portion of the fourth portion 24U, and corresponds to a portion of the lead 2U sticking out from the encapsulating resin 7 to the opposite side of the plurality of leads 1, as viewed in the y-direction. The second portion 22U sticks out to the opposite side of the first portion 21U, in the y-direction. The second portion 22U is used, for example, to electrically connect the semiconductor device A2 to an external circuit. In the illustrated example, the second portion 22U is bent in the z-direction, to the side to which the first face 31 is oriented. The second portion 22U, the third portion 23U, and the fourth portion 24U each include, on the respective sides thereof in the x-direction, edges extending along the y-direction. The edges of the second portion 22O, the third portion 23U, and the fourth portion 24U, on the side of the third face 33 in the x-direction, are respectively opposed to the edges of the second portion 22T, the third portion 23T, and the fourth portion 24T, on the side of the fourth face 34 in the x-direction.

As shown in FIG. 44 and FIG. 45, the second portion 22A and the second portion 22B are aligned in the x-direction, with a clearance G21 therebetween. The second portion 22B and the second portion 22C are aligned in the x-direction, with a clearance G22 therebetween. The clearances G22 is wider than the clearance G21. The second portion 22C and the second portion 22D are aligned in the x-direction, with a clearance G23 therebetween. The clearance G23 is narrower than the clearances G22, and generally the same as the clearance G21 (exactly the same, or different by within ±5%). The second portion 22D and the second portion 22E are aligned in the x-direction, with a clearance G24 therebetween. The clearance G24 is wider than the clearance G23, and generally the same as the clearance G22 (exactly the same, or different by within ±5%). The second portion 22E and the second portion 22F are aligned in the x-direction, with a clearance G25 therebetween. The clearance G25 is narrower than the clearances G24, and generally the same as the clearance G23 (exactly the same, or different by within ±5%). The second portion 22F and the second portion 22G are aligned in the x-direction, with a clearance G26 therebetween. The clearance G26 is wider than the clearance G25, and generally the same as the clearance G24 (exactly the same, or different by within ±5%). The second portion 22G and the second portion 22H are aligned in the x-direction, with a clearance G27 therebetween. The clearance G27 is narrower than the clearances G26, and generally the same as the clearance G25 (exactly the same, or different by within ±5%). The second portion 22H and the second portion 22I are aligned in the x-direction, with a clearance G28 therebetween. The clearance G28 is wider than the clearances G21 to G27. The second portions 221 to 22R are aligned in the x-direction, with clearances G29 therebetween. The clearances G29 are narrower than the clearances G21 to G28. The difference in width of the clearances G29 is within ±5% from each other. The second portion 22R and the second portion 22S are aligned in the x-direction, with a clearance G2a therebetween. The clearance G2a is generally the same as the clearance G28 (exactly the same, or different by within ±5%). The second portion 22S and the second portion 22T are aligned in the x-direction, with a clearance G2b therebetween. The clearance G2b is generally the same as the clearance G29 (exactly the same, or different by within ±5%). The second portion 22T and the second portion 22U are aligned in the x-direction, with the clearance G2b therebetween. The clearance G2b is generally the same as the clearance G29 (exactly the same, or different by within ±5%).

As shown in FIG. 36, projection lengths y12 of the second portions 12A to 12G from the sixth face 76 in the y-direction are generally the same (exactly the same, or different by within ±5%), in this embodiment. Projection lengths y22 of the second portions 22A to 22H and the second portions 22S to 22U from the fifth face 75 are generally the same (exactly the same, or different by within ±5%). Projection lengths y21 of the second portions 221 to 22R from the fifth face 75 are generally the same (exactly the same, or different by within ±5%). The projection length y21 is longer than the projection length y22.

### <Semiconductor Chips 4A to 4F>

The semiconductor chips 4A to 4F, located on the plurality of leads 1, each exemplify a semiconductor chip in the present disclosure. The type and the function of the semiconductor chips 4A to 4F are not specifically limited. In this embodiment, the semiconductor chips 4A to 4F are a transistor. Although six semiconductor chips 4A to 4F are provided in the illustrated example, the number of semiconductor chips is by no means limited.

The semiconductor chips 4A to 4F in the illustrated example are, for example, a transistor configured as an IGBT, like the ones in the semiconductor device A11.

In this embodiment, as shown in FIG. 39, FIG. 40, FIG. 41, and FIG. 42, three semiconductor chips 4A, 4B, and 4C are provided on the main surface 111A of the first portion 11A of the lead 1A. The three semiconductor chips 4A, 4B, and 4C are spaced apart from each other in the x-direction, and overlap with each other as viewed in the x-direction. Here, the number of semiconductor chips to be mounted on the lead 1A is by no means limited. The semiconductor chip 4A is located in the first region Ra surrounded by the groove 1112A in the main surface 111A, in a plan view. The semiconductor chip 4B is located in the first region Rb surrounded by the groove 1112A in the main surface 111A, in a plan view. The semiconductor chip 4C is located in the first region Rc surrounded by the groove 1112A in the main surface 111A, in a plan view. In the illustrated example, the semiconductor chips 4A, 4B, and 4C are arranged such that, as viewed in the z-direction, the respective gate electrodes GP are located on the side of the plurality of leads 2, with respect to the center of the semiconductor chips 4A, 4B, and 4C in the y-direction. In the illustrated example, in addition, the respective collector electrodes CP of the semiconductor chips 4A, 4B, and 4C are bonded to the main surface 111A, via the conductive bonding material 83.

The conductive bonding material 83 may be any material that is capable of bonding, and electrically connecting, the collector electrode CP of the semiconductor chips 4A, 4B, and 4C, to the main surface 111A. For example, silver paste, copper paste, or solder may be employed as the conductive bonding material 83. The conductive bonding material 83 corresponds to the second conductive bonding material in the present disclosure. In this embodiment, the conductive bonding material 83 extends outwardly from the outer periphery of the semiconductor chips 4A, 4B, and 4C, in a plan view. A reason of such a configuration is that, for example, when the conductive bonding material 83 performs the bonding function by curing after the fused state, the conductive bonding material 83 is apt to be formed in contact with the edge of the groove 1112A. This is because the surface tension of the fused conductive bonding material 83, generated at the edge of the groove 1112A when the conductive bonding material 83 is about to spread around, prevents the conductive bonding material 83 from spreading further.

In this embodiment, as shown in FIG. 39, FIG. 40, FIG. 41, and FIG. 43, the semiconductor chip 4D is provided on the main surface 111B of the first portion 11B of the lead 1B. Here, the number of semiconductor chips to be mounted on the lead 1B is by no means limited. In the illustrated example, the semiconductor chip 4D is arranged such that, as viewed in the z-direction, the gate electrode GP is located on the side of the plurality of leads 2, with respect to the center of the semiconductor chip 4D in the y-direction. In the illustrated example, in addition, the collector electrode CP of the semiconductor chip 4D is bonded to the main surface 111B, via the conductive bonding material 83.

In this embodiment, as shown in FIG. 39, FIG. 40, FIG. 41, and FIG. 43, the semiconductor chip 4E is provided on the main surface 111C of the first portion 11C of the lead 1C. Here, the number of semiconductor chips to be mounted on the lead 1C is by no means limited. In the illustrated example, the semiconductor chip 4E is arranged such that, as viewed in the z-direction, the gate electrode GP is located on the side of the plurality of leads 2, with respect to the center of the semiconductor chip 4E in the y-direction. In the illustrated example, in addition, the collector electrode CP of the semiconductor chip 4E is bonded to the main surface 111C, via the conductive bonding material 83.

In this embodiment, as shown in FIG. 39, FIG. 40, FIG. 41, and FIG. 43, the semiconductor chip 4F is provided on the main surface 111D of the first portion 11D of the lead 1D. Here, the number of semiconductor chips to be mounted on the lead 1D is by no means limited. In the illustrated example, the semiconductor chip 4F is arranged such that, as viewed in the z-direction, the gate electrode GP is located on the side of the plurality of leads 2, with respect to the center of the semiconductor chip 4F in the y-direction. In the illustrated example, in addition, the collector electrode CP of the semiconductor chip 4F is bonded to the main surface 111D, via the conductive bonding material 83. In the illustrated example, as shown in FIG. 39, the semiconductor chip 4C and the semiconductor chip 4D overlap with the connecting portion 57 of the conductive section 5, as viewed in the y-direction. As shown in FIG. 40, the semiconductor chip 4D is located on the side of the substrate 3 with respect to the upper face of the fourth portion 14B, in the z-direction.

### <Diodes 41A to 41F>

The configuration of the diodes 41A to 41F is not specifically limited and may be, for example, similar to that of the diodes 41A to 41F of the semiconductor device A11.

As in the semiconductor device A11, the semiconductor chip 4A is mounted in the first region Ra. The semiconductor chip 4B is mounted in the first region Rb. The semiconductor chip 4C is mounted in the first region Rc. The diode 41A is mounted in the second region R1a. The diode 41B is mounted in the second region R1b. The diode 41C is mounted in the second region R1c. The semiconductor chip 4D is mounted in the first region Rd. The semiconductor chip 4E is mounted in the first region Re. The semiconductor chip 4F is mounted in the first region Rf. The diode 41D is mounted in the second region R1d. The diode 41E is mounted in the second region R1e. The diode 41F is mounted in the second region Rif.

As shown in FIG. 42, the diode 41A is located in the second region R1a on the main surface 111A of the first portion 11A of the lead 1A. In the illustrated example, in addition, the diode 41A is bonded to the main surface 111A via the conductive bonding material 85. The conductive bonding material 85 is constituted of, for example, a material similar to that of the conductive bonding material 83.

As shown in FIG. 42, the diode 41B is located in the second region Rb on the main surface 111A of the first portion 11A of the lead 1A. In the illustrated example, in addition, the diode 41B is bonded to the main surface 111A via the conductive bonding material 85.

As shown in FIG. 42, the diode 41C is located in the second region R1a on the main surface 111A of the first portion 11A of the lead 1A. In the illustrated example, in addition, the diode 41C is bonded to the main surface 111A via the conductive bonding material 85.

The diode 41A overlaps with the semiconductor chip 4A, as viewed in the y-direction. The diode 41B overlaps with the semiconductor chip 4B, as viewed in the y-direction. The diode 41C overlaps with the semiconductor chip 4C, as viewed in the y-direction. The diodes 41A, 41B, and 41C overlap with each other, as viewed in the x-direction.

As shown in FIG. 43, the diode 41D is located in the second region R1d on the main surface 111B of the first portion 11B of the lead 1B. In the illustrated example, in addition, the diode 41D is bonded to the main surface 111B via the conductive bonding material 85.

As shown in FIG. 43, the diode 41E is located in the second region R1e on the main surface 111C of the first portion 11C of the lead 1C. In the illustrated example, in addition, the diode 41E is bonded to the main surface 111C via the conductive bonding material 85.

As shown in FIG. 43, the diode 41F is located in the second region Rif on the main surface 111D of the first portion 11D of the lead 1D. In the illustrated example, in addition, the diode 41F is bonded to the main surface 111D via the conductive bonding material 85.

The diode 41D overlaps with the semiconductor chip 4D, as viewed in the y-direction. The diode 41E overlaps with the semiconductor chip 4E, as viewed in the y-direction. The diode 41F overlaps with the semiconductor chip 4F, as viewed in the y-direction. The diodes 41D, 41E, and 41F overlap with each other, as viewed in the x-direction.

### <Control Chips 4G, 4H>

The configuration of the control chips 4G and 4H is not specifically limited and may be, for example, similar to that of the control chips 4G and 4H of the semiconductor device A1.

In this embodiment, the control chip 4G is mounted on the first base portion 55 of the conductive section 5. The control chip 4H is mounted on the second base portion 56 of the conductive section 5. In this embodiment, the control chip 4G is bonded to the first base portion 55, via the conductive bonding material 84. The control chip 4H is bonded to the second base portion 56, via the conductive bonding material 84.

The conductive bonding material 84 may be any material that is capable of bonding, and electrically connecting, the control chip 4G to the first base portion 55, and the control chip 4H to the second base portion 56. For example, silver paste, copper paste, or solder may be employed as the conductive bonding material 84. The conductive bonding material 84 corresponds to the third conductive material in the present disclosure. In this embodiment, the conductive bonding material 84 extends outwardly from the outer periphery of the control chips 4G and 4H, in a plan view. A reason of such a configuration is that, for example, when the conductive bonding material 84 performs the bonding function by curing after the fused state, the conductive bonding material 84 in the fused state spreads around the control chip 4G (control chip 4H) as viewed in the z-direction. Therefore, in the illustrated example, the conductive bonding material 84 protrudes from the respective outer edges of the control chips 4G and 4H, as viewed in the z-direction. However, the specific shape of the conductive bonding material 84 is by no means limited. Here, the control chips 4G and 4H may be bonded to the first base portion 55 via an insulative bonding material, instead of the conductive bonding material 84. In the illustrated example, the conductive bonding material 84 has an uneven outer edge, as viewed in the z-direction. Such formation of the conductive bonding material 84 allows the control chips 4G and 4H to be bonded to a region of the conductive section 5 more distant from the control chips 4G and 4H, thereby further stabilizing the adhesion of the control chips 4G and 4H.

As shown in FIG. 44, the control chip 4G is located between the leads 2B to 2O and the leads 1A to 1G, as viewed in the x-direction. The control chip 4H is located between the leads 2B to 2O and the leads 1A to 1G, as viewed in the x-direction. The control chips 4G and the control chips 4H overlap with each other, as viewed in the x-direction. The control chip 4G overlaps with the semiconductor chips 4B and 4C, as viewed in the y-direction. As shown in FIG. 45, the control chip 4H overlaps with the semiconductor chips 4D and 4E, as viewed in the y-direction. The control chip 4H overlaps with the transmission circuit chip 4I and the primary-side circuit chip 4J, as viewed in the y-direction. The control chip 4G may overlap with the semiconductor chip 4A, as viewed in the y-direction. The control chip 4H may overlap with the semiconductor chip 4F, as viewed in the y-direction.

As shown in FIG. 44, in the illustrated example, the control chip 4G overlaps with the wiring 50C (first portion 51C), the wiring 50D (first portion 51D), the wiring 50E (first portion 51E), and the wiring 50F (first portion 51F), as viewed in the y-direction. In addition, the control chip 4G overlaps with the second base portion 56 and the control chip 4H, as viewed in the x-direction. As shown in FIG. 45, the control chip 4H overlaps with the wirings 50I to 50P (first portions 51I to 51P), as viewed in the y-direction.

The control chip 4G is located on the side of the substrate 3, with respect to the upper end of the fourth portion 24C in the z-direction. Further, the control chip 4G is located on the side of the substrate 3, in other words on the lower side, with respect to the upper end of the first portion 21C in the z-direction. The control chip 4H is located on the side of the substrate 3, with respect to the upper end of the fourth portion 24C in the z-direction. Further, the control chip 4H is located on the side of the substrate 3, in other words on the lower side, with respect to the upper face of the first portion 21C in the z-direction.

As shown in FIG. 44, a portion of the first base portion 55 extending from the control chip 4G toward the lead 2 in the y-direction is longer than a portion of the first base portion 55 extending from the control chip 4G toward the lead 1A in the y-direction. As shown in FIG. 45, a portion of the second base portion 56 extending from the control chip 4H toward the lead 2 in the y-direction is longer than a portion of the second base portion 56 extending from the control chip 4H toward the lead 1C in the y-direction.

### <Transmission Circuit Chip 4I>

The transmission circuit chip 4I includes the first transmission circuit in the present disclosure. The transmission circuit chip 4I has a transformer structure including at least two coils opposed to each other with a gap therebetween, to transmit electrical signals. In this embodiment, as shown in FIG. 40 and FIG. 45, the transmission circuit chip 4I is, for example, mounted on the third base portion 58 via the conductive bonding material 84. As shown in FIG. 45, the transmission circuit chip 4I is located between the control chip 4H and the primary-side circuit chip 4J, as viewed in the x-direction. The transmission circuit chip 4I overlaps with the control chip 4H, as viewed in the y-direction. Further, the transmission circuit chip 4I overlaps with the first portions 51I to 51O (wirings 50I to 50O), as viewed in the y-direction. In the illustrated example, the conductive bonding material 84 protrudes from the outer edge of the transmission circuit chip 4I, as viewed in the z-direction.

Referring to FIG. 51 to FIG. 57, an example of the configuration of the transmission circuit chip 4I will be described. Here, although the transmission circuit chip 4I according s embodiment includes six transformers, the description will be given on the assumption that four transformers are provided, for the sake of simplicity. The four transformer correspond, for example, to transformers 691 to 694 (see FIG. 49).

FIG. 51 illustrates schematically the connection arrangement among the primary-side circuit chip 4J, the transmission circuit chip 4I, and the control chip 4H. In FIG. 51, the number of fourth wires 94 connecting the primary-side circuit chip 4J and the transmission circuit chip 4I, and the number of third wires 93 connecting the transmission circuit chip 4I and the control chip 4H, are reduced to two each, for the sake of clarity.

The transmission circuit chip 4I includes a lower coil 721, an upper coil 722, a semiconductor substrate 723, an insulation multilayer structure 724, a plurality of high-voltage pads 733, an inner coil end wiring 735, an outer coil end wiring 736, a via 737, an inner coil end wiring 747, an outer coil end wiring 748, a plurality of low-voltage pads 749, a low-voltage a wiring 750, a low-voltage wiring 751, shield layers 772 to 775, a cover film 778, a passivation film 779, a coil cover film 780, and a capacitor 783.

The lower coil 721 is a primary-side low-voltage coil. The upper coil 722 is a secondary-side high-voltage coil. The lower coil 721 and the upper coil 722 are opposed to each other in the z-direction (in the up-down direction), with a gap therebetween. The lower coil 721 and the upper coil 722 are each formed of a helical conductor wire. To the inner coil end (inner end of the helix) and the outer coil end (outer end of the helix) of the lower coil 721, the primary-side circuit chip 4J is electrically connected. To the inner coil end (inner end of the helix) and the outer coil end (outer end of the helix) of the upper coil 722, the control chip 4H is electrically connected.

In the transmission circuit chip 4I, a periodical pulse voltage is generated in the lower coil 721, for example by pulse generators 665U and 665L (see FIG. 49). In the transmission circuit chip 4I, only AC signals, based on the pulse voltage generated in the lower coil 721, are selectively transmitted to the upper coil 722 by electromagnetic induction, while DC signals are blocked between the lower coil 721 and the upper coil 722. The AC signals thus transmitted are boosted according to a transformation ratio between the lower coil 721 and the upper coil 722, and transmitted to the control chip 4H through the plurality of third wires 93.

Referring to FIG. 55, the semiconductor substrate 723 may be a silicon (Si) substrate, or a silicon carbide (SiC) substrate. The insulation multilayer structure 4 is formed on the semiconductor substrate 723.

The insulation multilayer structure 724 is composed of a plurality of insulation layers 725. The plurality of insulation layers 725 are sequentially stacked on the surface of the semiconductor substrate 723, and twelve layers are formed in the example shown in FIG. 55. The plurality of insulation layers 725 each include an etch stopper film 726 on the lower side, and an interlayer dielectric film 727 on the upper side, except the lowermost insulation layer 725 in contact with the surface of the semiconductor substrate 723. The lowermost insulation layer 725 only includes the interlayer dielectric film 727. The etch stopper film 726 may be formed of, for example, a silicon nitride (SiN) film, a silicon carbide (SiC) film, or a nitrogen-added silicon carbide (SiCN) film, and the interlayer dielectric film 727 may be formed of, for example, a silicon dioxide (SiO₂) film.

The lower coil 721 and the upper coil 722 are respectively formed in different insulation layers 725 in the insulation multilayer structure 724, and opposed to each other across one or more insulation layers 725. In this embodiment, the lower coil 721 is formed in the fourth insulation layer 725 from the semiconductor substrate 723, and the upper coil 722 is formed in the eleventh insulation layer 725, with six insulation layers 725 interposed between the upper coil 722 and the lower coil 721.

The shape of the lower coil 721 and the upper coil 722 is not specifically limited and may be, for example, an elliptical shape as viewed in the z-direction, as shown in FIG. 52 to FIG. 54. The lower coil 721 and the upper coil 722 are internally provided with inner regions 728 and 729, respectively.

FIG. 56 illustrates an essential part of the upper coil 722. In a region surrounding the inner region 729, a coil groove 730 is formed in the insulation layer 725. The coil groove 730 is used to form the upper coil 722 therein. The coil groove 730 is formed so as to penetrate through the interlayer dielectric film 727, and the etch stopper film 726 located thereunder, which are formed, for example, in an elliptical helical shape. Accordingly, the upper and lower ends of the coil groove 730 respectively reach the etch stopper film 726 of the insulation layer 725 on the upper side and the interlayer dielectric film 727 of the insulation layer 725 on the lower side.

In the illustrated example, the upper coil 722 includes a barrier metal 731 and a copper wiring material 732. The barrier metal 731 is formed on the inner face (side face and bottom face) of the coil groove 730. The barrier metal 731 is formed in a film shape according to the side face and the bottom face, with an opening oriented upward. In this embodiment, the barrier metal 731 includes, for example, a tantalum (Ta) film, a tantalum nitride (TaN) film, and a tantalum film formed in this order from the side of the inner face of the coil groove 730. The copper wiring material 732 is formed by filling the inside of the barrier metal 731, for example with copper (Cu).

The upper coil 722 is formed such that the upper face becomes flush with the upper face of the insulation layer 725. Accordingly, the upper coil 722 is in contact with different ones of the insulation layers 725, via the side face, the upper face, and the lower face. More specifically, in the insulation layer 725 in which the upper coil 722 is buried, the etch stopper film 726 and the interlayer dielectric film 727 is in contact with the upper coil 722, and only the etch stopper film 726 on the lower side, in another insulation layer 725 formed on the first mentioned insulation layer 725, is in contact with the upper coil 722. As to the insulation layer 725 formed under the upper coil 722, only the interlayer dielectric film 727 on the upper side is in contact with the upper coil 722.

Here, although detailed description is omitted, the lower coil 721 is also formed by filling the coil groove with the barrier metal and the copper (Cu) wiring material, like the upper coil 722.

As shown in FIG. 52, FIG. 55, and FIG. 56, the plurality of high-voltage pads 733 are formed on the surface of the insulation multilayer structure 724 (interlayer dielectric film 727 of the uppermost insulation layer 725), and the third wire 93 is connected to the high-voltage pads 733. The high-voltage pad 733 is located in the central high-voltage region (HV region) 734 where the upper coil 722 is provided, as viewed in the z-direction.

The high-voltage region 734 includes a region where a wiring of the same potential as the upper coil 722 and the lower coil 721 is formed, and the periphery of the mentioned region, in the insulation layer 725 in which the upper coil 722 is buried. In this embodiment, as shown in FIG. 54, four upper coils 722 are aligned along the longitudinal direction of the transmission circuit chip 4I, so as to form two pairs with a spacing between the pairs.

The inner coil end wiring 735 and the outer coil end wiring 736 are respectively formed in the inner region 729 of each of the upper coils 722, and between the upper coils 722 adjacent to each other, in each pair. In each pair, one upper coil 722 and the other upper coil 722 are electrically connected to each other via the common outer coil end wiring 736, and both of the upper coils 722, the outer coil end wiring 736 interposed therebetween, and the inner coil end wiring 735 in each of the upper coils 722, all have the same potential. In the relevant insulation layer 725, the inner region 729 of each of the upper coils 722, and the region between the upper coils 722 in each pair, are included in the high-voltage region 734, because these regions are within the range covered with the electric field from the upper coil 722, the inner coil end wiring 735, or the outer coil end wiring 736. Here, although the region where the lower coil 721 (low-voltage coil) is located coincides with the high-voltage region 734, as viewed in the z-direction, this region is isolated from the upper coil 722 by the plurality of insulation layers 725. Therefore, this region is not included in the high-voltage region 734 referred to this embodiment, because the mentioned region is barely affected by the electric field from the upper coil 722.

As shown in FIG. 52, the high-voltage pad 733 is located on the upper side of the inner region 729 of each of the upper coils 722, and on the upper side of the region between the upper coils 722 in each pair, in other words totally six high-voltage pads 733 are provided.

As shown in FIG. 55 and FIG. 56 for example, the via 737 is connecting a high-voltage pad 733 to the inner coil end wiring 735 buried in the same insulation layer 725 in which the upper coil 722 is buried. Though not illustrated, another high-voltage pad 733 is likewise connected, by means of the via, to the outer coil end wiring 736 buried in the same insulation layer 725 in which the upper coil 722 is buried. With such an arrangement, the AC signal transmitted to the upper coil 722 can be outputted from the high-voltage pad 733, through the inner coil end wiring 735 and the via 737, as well as through the outer coil end wiring 736 and another via (not shown).

The inner coil end wiring 735 and the via 737 are, like the upper coil 722, respectively formed by filling the wiring trenches 738 and 739 with the barrier metals 740 and 741 and the copper (Cu) wiring materials 742 and 743, as shown in FIG. 56 (the same applies to the outer coil end wiring 736 and the via connected thereto). The barrier metals 740 and 741 may be formed of the same material as the barrier metal 731.

In the insulation multilayer structure 724, a low-voltage region 744 (FIG. 53 and FIG. 55), an outer low-voltage region 745 (FIG. 52 and FIG. 53), and an intermediate region 746 (FIG. 51 to FIG. 56) are provided, as low-potential regions (LV regions) electrically isolated from the high-voltage region 734.

The low-voltage region 744 includes regions of the insulation layer 725 in which the lower coil 721 is buried, such as a region formed with the lower coil 721, a region formed with a wiring of the same potential as that of the lower coil 721, and peripheral regions of the former two regions. The low-voltage region 744 is opposed to the high-voltage region 734 across one or more insulation layers 725, like the positional relation between the lower coil 721 and the upper coil 722. In this embodiment, two pairs, namely four lower coils 721 are aligned in the x-direction so as to oppose the upper coil 722, with a spacing between the pairs, as shown in FIG. 53.

The inner coil end wiring 747 and the outer coil end wiring 748 are respectively formed in the inner region 728 of each of the lower coils 721, and between the lower coils 721 adjacent to each other, in each pair. In each pair, accordingly, one lower coil 721 and the other lower coil 721 are electrically connected to each other via the common outer coil end wiring 748, and both of the lower coils 721, the outer coil end wiring 748 interposed therebetween, and the inner coil end wiring 747 in each of the lower coils 721, all have the same potential. Therefore, in the relevant insulation layer 725, the inner region 728 of each of the lower coils 721, and the region between the lower coils 721 in each pair, are included in the low-voltage region 744, because these regions are within the range covered with the electric field from the lower coil 721, the inner coil end wiring 747, or the outer coil end wiring 748. Here, the inner coil end wiring 747 is located at a position shifted from the inner coil end wiring 735 of the high-voltage position in a plan view, as shown in FIG. 54.

The outer low-voltage region 745 is provided so as to surround the high-voltage region 734 and the low-voltage region 744, and the intermediate region 746 is provided between the high-voltage region 734 and the outer low-voltage region 745, and between the low-voltage region 744 and the outer low-voltage region 745, as shown in FIG. 55.

As shown in FIG. 52, FIG. 55, and FIG. 56, the low-voltage pad 749 is formed on the surface of the insulation multilayer structure 724 (interlayer dielectric film 727 of the uppermost insulation layer 725), in the outer low-voltage region 745, and the fourth wire 94 is connected to the low-voltage pad 749. In this embodiment, the low-voltage pad 749 is located on the lateral side of each of the six high-voltage pads 733, aligned with a spacing in the x-direction, in other words totally six low-voltage pads 749 are provided. The low-voltage pads 749 are each connected to the lower coil 721, via the low-voltage wirings 750 and 751 routed in the insulation multilayer structure 724.

The low-voltage wiring 750 includes a through wiring 752 and a lead-out wiring 753. The through wiring 752 is formed in the outer low-voltage region 745, in a column shape extending from the low-voltage pad 749, so as to penetrate at least the insulation layer 725 in which the lower coil 721 is formed, and reach the insulation layer 725 on the lower side of the lower coil 721. More specifically, the through wiring 752 includes low-voltage layer wirings 754 and 755, and a plurality of vias 756, 757, and 758.

Each of the low-voltage layer wirings 754 and 755 is an island-shaped portion (rectangular shape) buried in the same insulation layer 725 in which the upper coil 722 and the lower coil 721 are buried. The plurality of vias 756 each serve to connect between the low-voltage layer wirings 754 and 755. The via 757 is for connecting the low-voltage layer wiring 754 on the upper side and the low-voltage pad 749. The via 758 is for connecting the low-voltage layer wiring 755 on the lower side and the lead-out wiring 753.

The lead-out wiring 753 is formed in a linear shape, drawn out from the low-voltage region 744 to the outer low-voltage region 745 through the insulation layer 725 on the lower side of the lower coil 721. More specifically, the lead-out wiring 753 includes the inner coil end wiring 747, a linear lead-out layer wiring 759 buried in the insulation layer 725 on the lower side of the lower coil 721 so as to cross the insulation layer 725 under the lower coil 721, and a via 760 connecting between the lead-out layer wiring 759 and the inner coil end wiring 747. The lead-out layer wiring 759 is connected to the semiconductor substrate 723, through the via 761. Thus, the low-voltage wiring 750 is fixed to the substrate voltage (e.g., ground voltage).

Here, the wirings 747, 754, 755, and 759, and the vias 756 to 758 and 760 are each formed by filling the wiring trenches with the copper (Cu) wiring material, like the upper coil 722. As shown in FIG. 56 for example, the low-voltage layer wiring 754 and the vias 756 and 757 are each formed by filling the wiring trenches 762 to 764 with the barrier metals 765 to 767 and the copper (Cu) wiring materials 768 to 770. The barrier metals 765 to 767 may be formed of the same material as the barrier metal 731.

Though details are omitted, the low-voltage wiring 755 also includes a through wiring (not shown) and a lead-out wiring 771 (FIG. 52 to FIG. 54), like the low-voltage layer wiring 754.

One of the low-voltage pads 749 is connected to the inner coil end wiring 747 of the lower coil 721, through the through wiring 752 and the lead-out wiring 753, as shown in FIG. 52 to FIG. 55. Another low-voltage pad 749 is connected to the outer coil end wiring 748 of the lower coil 721, through the through wiring and the lead-out wiring 771, as shown in FIG. 52 to FIG. 54. Therefore, the signal inputted to the low-voltage pad 749 can be transmitted to the lower coil 721, through the through wiring 752 and the lead-out wiring 753.

The shield layer 772 is formed on a further outer side of the low-voltage layer wiring 754, in the insulation multilayer structure 724. The shield layer 772 prevents intrusion of moisture from outside into the device, and spreading of a crack on an end face into an inner region.

The shield layer 772 is, as shown in FIG. 52 to FIG. 55, formed in a wall shape along the end face of the transmission circuit chip 4I, and connected to the semiconductor substrate 723 via the bottom portion. Accordingly, the shield layer 772 is fixed to the substrate voltage (e.g., ground voltage). More specifically, the shield layer 772 includes shield layer wirings 773 to 775 and a plurality of vias 777, as shown in FIG. 55. The shield layer wirings 773 to 775 are buried in the same insulation layer 725 in which the upper coil 722, the lower coil 721, and the lead-out layer wiring 759 are buried. One of the vias 777 is connecting the shield layer wirings 773 to 775 to each other. Another via 777 is connecting the lowermost shield layer wiring 775 and the semiconductor substrate 723. The shield layer wirings 773 to 775 and the vias 776 and 777 are each formed by filling the wiring trenches with the barrier metal and the copper (Cu) wiring material, like the upper coil 722.

The cover film 778 and the passivation film 779 are stacked in this order, over the entirety of the insulation multilayer structure 724. The coil cover film 780 is formed in an elliptical ring shape, so as to selectively cover a region right above the upper coil 722, on the passivation film 779. The cover film 778, the passivation film 779, and the coil cover film 780 include pad openings 781 and 782, to expose the low-voltage pad 749 and the high-voltage pad 733, respectively.

The cover film 778 is formed of silicon dioxide (SiO₂) for example, and has a thickness of approximately 150 nm. The passivation film 779 is formed of silicon nitride (SiN) for example, and has a thickness of approximately 1000 nm. The coil cover film 780 is formed of polyimide for example, and has a thickness of approximately 4000 nm.

A large potential difference (e.g., approximately 1200V) is generated between the lower coil 721 and the upper coil 722, constituting a transformer 690 (FIG. 49) to be subsequently described. Accordingly, the insulation layer 725 provided between the lower coil 721 and the upper coil 722 has to have a thickness that can secure a sufficient t withstand voltage to prevent insulation breakdown due to the potential difference.

In this embodiment, therefore, a plurality of insulation layers 725 (e.g., six layers), each including the etch stopper film 726 of approximately 300 nm and the interlayer dielectric film 727 of approximately 2100 nm, are interposed between the coils as shown in FIG. 55, so that the insulation layer 725 attains a total thickness L2 of 12.0 μm to 16.8 μm, thus securing DC insulation in the vertical direction between the lower coil 721 and the upper coil 722.

However, the experiment carried out by the present inventors, with regard to the relation between the thickness of an interlayer film in a semiconductor device having a transformer and a surge breakdown voltage, has provided a result shown in FIG. 57. In FIG. 57, the interlayer film refers to a film having a similar structure to that of the insulation layer 725 according to this embodiment. From FIG. 57, it is understood that, although the DC insulation in the vertical direction is sufficiently achieved, by increasing the number of layers of the interlayer film between the coils, thus increasing the total film thickness, breakdown in the transverse direction, for example between the upper coil 722 and the low-voltage pad 749 (between coil and pad), and between the upper coil 722 and the shield layer 772 (between coil and shield), predominantly takes place.

Normally, a distance L0 between the upper coil 722 and the outer low-voltage region 745 (in this embodiment, width of the intermediate region 746) shown in FIG. 53 is larger than the total thickness L2 of the insulation layer 725 between the lower coil 721 and the upper coil 722 shown in FIG. 55. For example, the distance L0 is normally 100 μm to 450 μm, which corresponds to a ratio of 6/1 to 40/1 to the thickness L2 (distance L0/thickness L2). Accordingly, for example, even though a potential difference, equivalent to a difference between the lower coil 721 and the upper coil 722 (between the high-voltage region 734 and the low-voltage region 744), is generated between the high-voltage region 734 and the outer low-voltage region 745, the insulation breakdown is not incurred theoretically, since the distance L0 is larger than the thickness L2, when only the distance between these regions is taken into account. However, as proven by FIG. 57, the breakdown in the transverse direction predominantly takes place, when the thickness of the interlayer film between the coils is increased. Here, although the thickness L2 is apparently larger than the distance L0 in FIG. 55, actually the distance L0 is much larger than the thickness L2.

In this relation, the present inventors have discovered that providing a shield, formed of an electrically floating metal material, between the high-voltage region 734 and the outer low-voltage region 745 mitigates concentration of an electric field to a specific portion of the outer low-voltage region 745, to thereby prevent the breakdown in the transverse direction.

In this embodiment, therefore, a capacitor 783 is provided in the intermediate region 746, so as to surround the high-voltage region 734 in a plan view, as shown in FIG. 52 and FIG. 54. Although the plurality of high-voltage regions 734 are surrounded by the same capacitor 783 in FIG. 52 and FIG. 53, each of the high-voltage regions 734 may be individually surrounded.

The cross-sectional structure of the capacitor 783 is shown in FIG. 55 and FIG. 56. The capacitor 783 is buried in the insulation layer 725 in which the upper coil 722 is buried, the insulation layer 725 in which the lower coil 721 is buried, and each of the insulation layers 725 provided therebetween, and formed in a wall shape as a whole, so as to surround the region in the insulation layer 725 where the coils are formed.

The capacitor 783 includes a plurality of electrode plates 784 buried in each of the insulation layers 725. At least three (five in FIG. 55 and FIG. 56) electrode plates 784 are provided at regular intervals, each of which is electrically floating. In addition, the electrode plates 784 buried in the respective insulation layers 725 are serially aligned in the up-down direction. In other words, in terms of the cross-section of the insulation multilayer structure 724, the electrode plate 784 constituting a given capacitor 783 is superposed on the adjacent electrode plate 784 on the upper and lower sides. Accordingly, the plurality of electrode plates 784, respectively buried in different insulation layers 725, form a shield plate without a gap, along the stacking direction of the insulation multilayer structure 724.

The electrode plates 784 are each formed by filling the wiring trench 785 with the barrier metal 786 and the copper (Cu) wiring material 787 as shown in FIG. 56, like the upper coil 722. The barrier metal 786 may be formed of a similar material to that of the barrier metal 731.

Further, a distance L1 in the transverse direction between the upper coil 722 and the capacitor 783 shown in FIG. 55 is larger than the total thickness L2 of the insulation layers 725 between the upper coil 722 and the lower coil 721. The distance L1 is, for example, 25 μm to 400 μm. Here, although the thickness L2 is apparently larger than the distance L1 in FIG. 33, actually the distance L1 is much larger than the thickness L2.

The capacitor 783 serves to mitigate concentration of an electric field to the low-potential conductive section (e.g., low-voltage pad 749, low-voltage layer wiring 754, via 756, low-voltage layer wiring 755, and shield layer 772) located in the outer low-voltage region 745, when a high voltage is applied between the upper coil 722 and the lower coil 721. In particular, in the case of the low-voltage pad 749 and the low-voltage layer wiring 754 having a rectangular shape, located in the same layer as the upper coil 722 (high-voltage coil) and neighboring layers, the electric field is prone to concentrate on a corner portion, thus causing surge breakdown. However, the presence of the capacitor 783 effectively suppresses such surge breakdown. In this embodiment, in addition, since the capacitor 783 is surrounding the high-voltage region 734, the electric field emitted from the upper coil 722 is mitigated, regardless of the direction. Consequently, the withstand voltage between the high-voltage region 734 and the outer low-voltage region 745 can be improved.

Further, since the electrode plates 784 constituting the capacitor 783 are buried in the same insulation layer 725 in which the elements of the shield layer 772 are buried, the capacitor 783 and the shield layer 772 can be fabricated at a time, through the same process.

### <Primary-Side Circuit Chip 4J>

The primary-side circuit chip 4J transmits command signals to the control chip 4H, through the transmission circuit chip 4I. In this embodiment, as shown in FIG. 40 and FIG. 45, the primary-side circuit chip 4J is, for example, mounted on the third base portion 58 via the conductive bonding material 84. The primary-side circuit chip 4J is located on the side of the fifth face 35 in the y-direction, with respect to the transmission circuit chip 4I. As shown in FIG. 45, the primary-side circuit chip 4J overlaps with the first portion 51Q (wiring 50Q), as viewed in the x-direction. The primary-side circuit chip 4J overlaps with the control chip 4H and the transmission circuit chip 4I, as viewed in the y-direction. Further, the transmission circuit chip 4I overlaps with the first portions 51I to 51O (wirings 50I to 50O), as viewed in the y-direction.

As shown in FIG. 40, the control chip 4H, the transmission circuit chip 4I, and the primary-side circuit chip 4J are located on the side of the substrate 3, in other words on the lower side, with respect to the upper end of the fourth portion 24I in the z-direction. Further, the control chip 4H, the transmission circuit chip 4I, and the primary-side circuit chip 4J are located on the side of the substrate 3, in other words on the lower side, with respect to the upper end of the first portion 21I in the z-direction. Such positional relation also applies to the control chip 4G.

### <Diodes 49U, 49V, 49W>

The configuration of the diodes 49U, 49V, and 49W is not specifically limited and may be, for example, similar to that of the diodes 49U, 49V, and 49W of the semiconductor device A1.

### <First Wires 91A to 91F>

Regarding the first wires 91A to 91F according to this embodiment, although any of the elements is apparently given, for the sake of convenience of description, the same numeral as that of the first wires 91A to 91F according to the first embodiment, it does not necessarily mean that the mentioned element has the same or similar configuration. The configuration of an element with a numeral is defined by the description relevant to this embodiment.

The first wires 91A to 91F are each connected to one of the semiconductor chips 4A to 4F and one of the plurality of leads 1. The material of the first wires 91A to 91F is not specifically limited and, for example, aluminum (Al) or copper (Cu) may be employed. The wire diameter of the first wires 91A to 91F is not specifically limited and, for example, may be approximately 250 to 500 μm. The first wires 91A to 91F correspond to the first conductive material in the present disclosure. Here, for example leads formed of copper may be employed, in place of the first wires 91A to 91F.

The collector electrode CP of the semiconductor chip 4A and the cathode electrode of the diode 41A are connected to each other, via the first portion 11A and the conductive bonding material 83. The collector electrode CP of the semiconductor chip 4B and the cathode electrode of the diode 41B are connected to each other, via the first portion 11A and the conductive bonding material 83. The collector electrode CP of the semiconductor chip C and the cathode electrode of the diode 41C are connected to each other, via the first portion 11A and the conductive bonding material 83.

In this embodiment, as shown in FIG. 42, the first wire 91A includes a first portion 911A and a second portion 912A, each of which will be described hereunder. An end of the first portion 911A is connected to the emitter electrode EP of the semiconductor chip 4A, and the other end is connected to the anode electrode of the diode 41A. In the illustrated example, the first portion 911A extends along the y-direction. An end of the second portion 912A is connected to the anode electrode of the diode 41A, and the other end is connected to the fourth portion 14B of the lead 1B. In the illustrated example, the second portion 912A is inclined with respect to the x-direction and the y-direction. The number of first wires 91A is not specifically limited. In the illustrated example, three first wires 91A are provided.

In this embodiment, the first wire 91B includes a first portion 911B and a second portion 912B, each of which will be described hereunder. An end of the first portion 911B is connected to the emitter electrode EP of the semiconductor chip 4B, and the other end is connected to the anode electrode of the diode 41B. In the illustrated example, the first portion 911B extends along the y-direction. An end of the second portion 912B is connected to the anode electrode of the diode 41B, and the other end is connected to the fourth portion 14C of the lead 1C. In the illustrated example, the second portion 912B is inclined with respect to the x-direction and the y-direction. The number of first wires 91B is not specifically limited. In the illustrated example, three first wires 91B are provided.

In this embodiment, the first wire 91C includes a first portion 911C and a second portion 912C, each of which will be described hereunder. An end of the first portion 911C is connected to the emitter electrode EP of the semiconductor chip 4C, and the other end is connected to the anode electrode of the diode 41C. In the illustrated example, the first portion 911C extends along the y-direction. An end of the second portion 912C is connected to the anode electrode of the diode 41C, and the other end is connected to the fourth portion 14D of the lead 1D. In the illustrated example, the second portion 912C is inclined with respect to the x-direction and the y-direction. The number of first wires 91C is not specifically limited. In the illustrated example, three first wires 91C are provided.

The collector electrode CP of the semiconductor chip 4D and the cathode electrode of the diode 41D are connected to each other, via the first portion 11B and the conductive bonding material 83. The collector electrode CP of the semiconductor chip 4E and the cathode electrode of the diode 41E are connected to each other, via the first portion 11C and the conductive bonding material 83. The collector electrode CP of the semiconductor chip 4F and the cathode electrode of the diode 41F are connected to each other, via the first portion 11D and the conductive bonding material 83.

In this embodiment, as shown in FIG. 42, the first wire 91D includes a first portion 911D and a second portion 912D, each of which will be described hereunder. An end of the first portion 911D is connected to the emitter electrode EP of the semiconductor chip 4D, and the other end is connected to the anode electrode of the diode 41D. In the illustrated example, the first portion 911D extends along the y-direction. An end of the second portion 912D is connected to the anode electrode of the diode 41D, and the other end is connected to the fourth portion 14E of the lead 1E. In the illustrated example, the second portion 912D is inclined with respect to the x-direction and the y-direction. The number of first wires 91D is not specifically limited. In the illustrated example, three first wires 91A are provided.

In this embodiment, the first wire 91E includes a first portion 911E and a second portion 912E, each of which will be described hereunder. An end of the first portion 911E is connected to the emitter electrode EP of the semiconductor chip 4E, and the other end is connected to the anode electrode of the diode 41E. In the illustrated example, the first portion 911E extends along the y-direction. An end of the second portion 912E is connected to the anode electrode of the diode 41E, and the other end is connected to the fourth portion 14F of the lead 1F. In the illustrated example, the second portion 912E is inclined with respect to the x-direction and the y-direction. The number of first wires 91E is not specifically limited. In the illustrated example, three first wires 91E are provided.

In this embodiment, the first wire 91F includes a first portion 911F and a second portion 912F, each of which will be described hereunder. An end of the first portion 911F is connected to the emitter electrode EP of the semiconductor chip 4F, and the other end is connected to the anode electrode of the diode 41F. In the illustrated example, the first portion 911F extends along the y-direction. An end of the second portion 912F is connected to the anode electrode of the diode 41F, and the other end is connected to the fourth portion 14G of the lead 1G. In the illustrated example, the second portion 912F is inclined with respect to the x-direction and the y-direction. The number of first wires 91F is not specifically limited. In the illustrated example, three first wires 91F are provided.

### <Second Wires 92>

Regarding the second wire 92 according to this embodiment, although any of the elements is apparently given, for the sake of convenience of description, the same numeral as that of the second wire 92 according to the first embodiment, it does not necessarily mean that the mentioned element has the same or similar configuration. The configuration of an element with a numeral is defined by the description relevant to this embodiment.

The plurality of second wires 92 are each connected to one of the control chips 4G and 4H, as shown in FIG. 39, FIG. 44, and FIG. 45. The material of the second wires 92 is not specifically limited and, for example, gold (Au) may be employed. The wire diameter of the second wires 92 is not specifically limited and, in this embodiment, finer than the first wires 91A to 91F. The wire diameter of the second wires 92 is, for example, approximately 10 μm to 50 μm. The second wires 92 correspond to the second conductive material in the present disclosure. In the subsequent description, the second wires 92 connected to the control chip 4G will be referred to as second wires 92G, and the second wires 92 connected to the control chip 4H will be referred to as second wires 92H.

The second wire 92G is connected to the gate electrode GP of the semiconductor chip 4A, and the second portion 52a of the wiring 50a. Another second wire 92G is connected to the emitter electrode EP of the semiconductor chip 4A, and the second portion 52b. The latter second wire 92G is connected to a position on the emitter electrode EP of the semiconductor chip 4A on the opposite side of the semiconductor chip 4B in the x-direction, with respect to the gate electrode GP.

The second wire 92G is connected to the gate electrode GP of the semiconductor chip 4B, and to a position on the control chip 4G on the side of the first portion 11A, with respect to the center of the control chip 4G in the y-direction. Another second wire 92G is connected to the emitter electrode EP of the semiconductor chip 4B, and to a position on the control chip 4G on the side of the first portion 11A, with respect to the center of the control chip 4G in the y-direction. The latter second wire 92G is connected to a position on the emitter electrode EP of the semiconductor chip 4B closer to the semiconductor chip 4C in the x-direction, with respect to the gate electrode GP.

The second wire 92G is connected to the gate electrode GP of the semiconductor chip 4C, and to a position on the control chip 4G on the side of the first portion 11A, with respect to the center of the control chip 4G in the y-direction. Another second wire 92G is connected to the emitter electrode EP of the semiconductor chip 4C, and to a position on the control chip 4G on the side of the first portion 11A, with respect to the center of the control chip 4G in the y-direction. The latter second wire 92G is connected to a position on the emitter electrode EP of the semiconductor chip 4B closer to the semiconductor chip 4B in the x-direction, with respect to the gate electrode GP.

The second wire 92H is connected to the gate electrode GP of the semiconductor chip 4D, and to a position on the control chip 4H on the side of the first portion 11A, with respect to the center of the control chip 4H in the y-direction. Another second wire 92H is connected to the gate electrode GP of the semiconductor chip 4E, and to a position on the control chip 4H on the side of the first portion 11A, with respect to the center of the control chip 4H in the y-direction. Further, still another second wire 92H is connected to the gate electrode GP of the semiconductor chip 4F, and the second portion 52F of the wiring 50f.

### <Third Wires 93>

As shown in FIG. 39, FIG. 44, and FIG. 45, the plurality of third wires 93 are connected to one of the control chips 4G and 4H. The material of the third wire 93 is not specifically limited and, for example, a similar material to that of the second wire 92 may be employed.

As shown in FIG. 44, a third wire 93 is connected to the first portion 51A, and a position on the control chip 4G close to the center in the y-direction. Two third wires 93 are connected to the first portion 51B, and a position on the control chip 4G close to the center in the y-direction. Another third wire 93 is connected to the diode 49U, and a position on the control chip 4G on the side of the fifth face 35 in the y-direction. Another third wire 93 is connected to the first portion 51C, and a position on the control chip 4G close to the center in the y-direction. Two third wires 93 are connected to the first portion 51D, and a position on the control chip 4G close to the center in the y-direction. Another third wire 93 is connected to the diode 49V, and a position on the control chip 4G on the side of the fifth face 35 in the y-direction. Another third wire 93 is connected to the first portion 51E, and a position on the control chip 4G close to the center in the y-direction. Two third wires 93 is connected to the first portion 51F, and a position on the control chip 4G close to the center in the y-direction. Another third wire 93 is connected to the diode 49W, and a position on the control chip 4G on the side of the fifth face 35 in the y-direction. Another third wire 93 is connected to the third portion 53H, and a position on the control chip 4G on the side of the fifth face 35 in the y-direction.

As shown in FIG. 45, two third wires 93 are connected to the third portion 573 of the connecting portion 57, and a position on the control chip 4H on the side of the third face 33 in the x-direction. Another third wire 93 is connected to the second portion 52c, and a position on the control chip 4H on the side of the third face 33 in the x-direction. Another third wire 93 is connected to the second portion 52d, and a position on the control chip 4H on the side of the third face 33 in the x-direction. Another third wire 93 is connected to the second portion 52e, and a position on the control chip 4H on the side of the third face 33 in the x-direction. Two third wires 93 are each connected to a position on the first portion 51H on the side of the fourth face 34 in the x-direction, and a position on the control chip 4H on the side of the third face 33 in the x-direction. A plurality of third wires 93 are each connected to a position on the control chip 4H on the side of the fifth face 35 in the y-direction, and a position on the transmission circuit chip 4I close to the center in the y-direction. The number of third wires 93 extending from the control chip 4G toward the transmission circuit chip 4I in the y-direction is larger than the number of second wires 92 extending from the control chip 4H toward the semiconductor chips 4D and 4E (leads 1B and 1C) in the y-direction.

### <Fourth Wires 94>

As shown in FIG. 39 and FIG. 45, the plurality of fourth wires 94 are connected to the transmission circuit chip 4I and the primary-side circuit chip 4J. The material of the fourth wires 94 is not specifically limited and, for example, a similar material to that of the second wire 92 may be employed.

As shown in FIG. 45, in the illustrated example, the plurality of fourth wires 94 are each connected to a position on the transmission circuit chip 4I on the side of the fifth face 35 in the y-direction, and a position on the primary-side circuit chip 4J on the side of the sixth face 36 in the y-direction.

### <Fifth Wires 95>

As shown in FIG. 39 and FIG. 44, the plurality of fifth wires 95 are connected to the transmission circuit chip 4I and the primary-side circuit chip 4J. The material of the fifth wires 95 is not specifically limited and, for example, a similar material to that of the second wire 92 may be employed.

As shown in FIG. 45, a fifth wire 95 is connected to the first portion 51I, and a position on the primary-side circuit chip 4J on the side of the fifth face 35 in the y-direction. Another fifth wire 95 is connected to the first portion 51J, and a position on the primary-side circuit chip 4J on the side of the fifth face 35 in the y-direction. Another fifth wire 95 is connected to the first portion 51K, and a position on the primary-side circuit chip 4J on the side of the fifth face 35 in the y-direction. Another fifth wire 95 is connected to the first portion 51L, and a position on the primary-side circuit chip 4J on the side of the fifth face 35 in the y-direction. Another fifth wire 95 is connected to the first portion 51M, and a position on the primary-side circuit chip 4J on the side of the fifth face 35 in the y-direction. Another fifth wire 95 is connected to the first portion 51N, and a position on the primary-side circuit chip 4J on the side of the fifth face 35 in the y-direction. Another fifth wire 95 is connected to the first portion 51O, and a position on the primary-side circuit chip 4J on the side of the fifth face 35 in the y-direction. Another fifth wire 95 is connected to the first portion 51P, and a position on the primary-side circuit chip 4J on the side of the fifth face 35 in the y-direction. Another fifth wire 95 is connected to the first portion 51O, and a position on the primary-side circuit chip 4J on the side of the fifth face 35 in the y-direction. Two fifth wires 95 are connected to the third base portion 58, and a position on the primary-side circuit chip 4J on the side of the fourth face 34 in the x-direction.

### <Sixth Wires 96>

As shown in FIG. 39 and FIG. 44, the plurality of sixth wires 96 are connected to the control chip 4G and the conductive section 5. The material of the sixth wire 96 is not specifically limited and, for example, a similar material to that of the second wire 92 may be employed.

As shown in FIG. 45, a sixth wire 96 is connected to the first portion 51a, and a position on the control chip 4G on the side of the sixth face 36 in the y-direction. Another sixth wire 96 is connected to the first portion 51b, and a position on the control chip 4G on the side of the sixth face 36 in the y-direction. Two sixth wires 96 are connected to the second portion 572, and a position on the control chip 4G on the side of the fourth face 34 in the x-direction. Another sixth wire 96 is connected to the first portion 51c, and a position on the control chip 4G on the side of the fourth face 34 in the x-direction. Another sixth wire 96 is connected to the first portion 51d, and a position on the control chip 4G on the side of the fourth face 34 in the x-direction. Another sixth wire 96 is connected to the first portion 51e, and a position on the control chip 4G on the side of the fourth face 34 in the x-direction.

### <Seventh Wires 97>

As shown in FIG. 39 and FIG. 45, the plurality of seventh wires 97 are connected to the control chip 4G and the conductive section 5. The material of the seventh wires 97 is not specifically limited and, for example, a similar material to that of the second wire 92 may be employed.

As shown in FIG. 45, a seventh wire 97 is connected to the first portion 51f, and a position on the control chip 4H on the side of the fourth face 34 in the x-direction. Three seventh wires 97 are connected to the first portion 51T, and a position on the control chip 4H on the side of the fourth face 34 in the x-direction. Another seventh wire 97 is connected to the first portion 51S, and a position on the control chip 4H on the side of the fourth face 34 in the x-direction.

### <Resin 7>

Regarding the resin 7 according to this embodiment, although any of the elements is apparently given, for the sake of convenience of description, the same numeral as that of the resin 7 according to the first embodiment, it does not necessarily mean that the mentioned element has the same or similar configuration. The configuration of an element with a numeral is defined by the description relevant to this embodiment.

The resin 7 covers at least the semiconductor chips 4A to 4F, the control chips 4G and 4H, the transmission circuit chip 4I, the primary-side circuit chip 4J, a part of each of the plurality of leads 1, and a part of each of the plurality of leads 2. In this embodiment, in addition, the resin 7 covers the diodes 41A to 41F, the diodes 49U, 49V, and 49W, the plurality of first wires 91A to 91F, the plurality of second wires 92, the plurality of third wires 93, the plurality of fourth wires 94, the plurality of fifth wires 95, the plurality of sixth wires 96, and the plurality of seventh wires 97. The material of the resin 7 is not specifically limited. Though not specifically limited, for example an insulative material such as an epoxy resin or silicone gel may be employed to form the resin 7.

In this embodiment, the resin 7 includes a first face 71, a second face 72, a third face 73, a fourth face 74, a fifth face 75, a sixth face 76, a recess 731, a recess 732, a recess 733, a hole 741, and a hole 742.

The first face 71 intersects with the z-direction and, in the illustrated example, is perpendicular to the z-direction. The first face 71 is oriented in the same direction as the first face 31 of the substrate 3. The second face 72 intersects with the z-direction and, in the illustrated example, is perpendicular to the z-direction. The second face 72 is oriented in the opposite direction to the first face 71, and in the same direction as the second face 32 of the substrate 3.

The third face 73 is located between the first face 71 and the second face 72 in the z-direction, and connected to the first face 71 and the second face 72, in the illustrated example. The third face 73 intersects with the x-direction, and is oriented in the same direction as the third face 33 of the substrate 3. The fourth face 74 is located between the first face 71 and the second face 72 in the z-direction, and connected to the first face 71 and the second face 72, in the illustrated example. The fourth face 74 intersects with the x-direction, and is oriented in the opposite direction to the third face 73, and in the same direction as the fourth face 34 of the substrate 3.

The fifth face 75 is located between the first face 71 and the second face 72 in the z-direction, and connected to the first face 71 and the second face 72, in the illustrated example. The fifth face 75 intersects with the y-direction, and is oriented in the same direction as the fifth face 35 of the substrate 3. The sixth face 76 is located between the first face 71 and the second face 72 in the z-direction, and connected to the first face 71 and the second face 72, in the illustrated example. The sixth face 76 intersects with the y-direction, and is oriented in the opposite direction to the fifth face 75, and in the same direction as the sixth face 36.

The hole 741 is formed so as to penetrate through the resin 7, in the z-direction. The shape of the hole 741 is not specifically limited and, in the illustrated example, a circular shape as viewed in the z-direction. The hole 741 is located between the third face 33 of the substrate 3 and the third face 73, as viewed in the z-direction.

The hole 742 is formed so as to penetrate through the resin 7, in the z-direction. The shape of the hole 742 is not specifically limited and, in the illustrated example, a circular shape as viewed in the z-direction. The hole 742 is located between the fourth face 34 of the substrate 3 and the fourth face 74, as viewed in the z-direction.

As shown in FIG. 36 and FIG. 39, the recess 731, the recess 732, and the recess 733 are portions receding from the fifth face 75 in the y-direction. The recess 731 is located between the second portion 22B of the lead 2B and the second portion 22C of the lead 2C, as viewed in the y-direction. The recess 732 is located between the second portion 22D of the lead 2D and the second portion 22E of the lead 2E, as viewed in the y-direction. The recess 733 is located between the second portion 22F of the lead 2F and the second portion 22G of the lead 2G, as viewed in the y-direction.

### <Circuit Configuration of Semiconductor Device A2>

Hereunder, a circuit configuration of the semiconductor device A2 will be described.

FIG. 49 illustrates an example of a control circuit 600Y for driving a switching arm 40U of the semiconductor device A2. The semiconductor device A2 includes a control circuit similar to the control circuit 600Y, also for each of the switching arms 40V and 40W. The control circuit 600Y of the semiconductor device A2 may be modified in various manners, without limitation to the configuration shown in FIG. 49.

A voltage level applied to the U terminal (lead 1B), the V terminal (lead 1C), and the W terminal (lead 1D) is, for example, approximately 0 V to 650 V. A voltage level applied to the NU terminal (lead 1E), the NV terminal (lead 1F), and the NW terminal (lead 1G) is, for example, approximately 0V, and lower than the voltage level applied to the terminal (lead 1B), the V terminal (lead 1C), and the W terminal (lead 1D). The semiconductor chips 4A to 4C each constitute a high-potential side transistor of a three-phase inverter circuit, and the semiconductor chips 4D to 4F each constitute a low-potential side transistor of the three-phase inverter circuit.

As shown in FIG. 49, the control circuit 600Y includes a primary-side circuit 660, a secondary-side circuit 670, and a transformer 690. The control circuit 600Y utilizes the transformer 690 to insulate between the primary-side circuit 660 and the secondary-side circuit 670, transmit signals from the primary-side circuit 660 to the secondary-side circuit 670, and transmit signals from the secondary-side circuit 670 to the primary-side circuit 660.

In this embodiment, the primary-side circuit 660 is included in the primary-side circuit chip 4J. At least a part of the secondary-side circuit 670 is included in the control chip 4H and the control chip 4G. The transformer 690 is included in the transmission circuit chip 4I.

The primary-side circuit 660 includes an under voltage lock out circuit 661, an oscillation (OSC) circuit 662, a signal transmission circuit 6600 connected to the HINU terminal (lead 2I), a signal transmission circuit 660L connected to the LINU terminal (lead 2L), and a fault protection circuit 660F connected to the FO terminal (lead 2P).

The signal transmission circuit 660U serves to supply a gate signal voltage to the gate electrode GP of the semiconductor chip 4A, and includes a resistance 663U, a Schmitt trigger 664U, a pulse generator 665U, and output buffers 667UA and 667UB, in this order from the HINU terminal toward the transformer 690. The resistance 663U and the Schmitt trigger 664U correspond to the resistance 461 and the Schmitt trigger 462 of the semiconductor device A1. The output terminal of the Schmitt trigger 664U is connected to the pulse generator 665U. The first output terminal of the pulse generator 665U is connected to the output buffer 667UA, and the second output terminal of the pulse generator 665U is connected to the output buffer 667UB.

The signal transmission circuit 660L serves to supply a gate signal voltage to the gate of the semiconductor chip 4D, and includes a resistance 663L, a Schmitt trigger 664L, a pulse generator 665L, and output buffers 667LA and 667LB, in this order from the LINU terminal toward the transformer 690. The resistance 663L and the Schmitt trigger 664L correspond to the resistance 471 and the Schmitt trigger 472 of the semiconductor device A1. The output terminal of the Schmitt trigger 664L is connected to the pulse generator 665L. The first output terminal of the pulse generator 665L is connected to the output buffer 667LA, and the second output terminal of the pulse generator 665L is connected to the output buffer 667LB.

The fault protection circuit 660F serves to output, when a fault occurs in the semiconductor device A2, information regarding the fault in the semiconductor device A2 to outside of the semiconductor device A2, and includes an RS flip-flop circuit 666, input buffers 667FA and 667FB, a driver 668, and a transistor 669.

The output terminal of the input buffer 667FA is connected to the S terminal of the RS flip-flop circuit 666, and the output terminal of the input buffer 667FB is connected to the R terminal of the RS flip-flop circuit 666. The Q terminal of the RS flip-flop circuit 666 is connected to the driver 668. The output terminal of the driver 668 is connected to the gate of the transistor 669. The source of the transistor 669 is grounded, and the drain of the transistor 669 is connected to the FO terminal.

The under voltage lock out circuit 661 monitors the source voltage VCC of the primary-side circuit 660. The under voltage lock out circuit 661 is connected to the set terminal (S terminal) of the RS flip-flop circuit 666. The under voltage lock out circuit 661 switches the lock out signal from the logic level in the normal condition (e.g., low level) to the logic level in an abnormal condition (e.g., high level), when the source voltage VCC of the primary-side circuit 660 falls below a predetermined threshold voltage. The oscillation circuit 662 outputs a clock signal to each of the pulse generators 665U and 665L, the RS flip-flop circuit 666, and the driver 668.

The secondary-side circuit 670 includes an oscillation circuit 671, a signal transmission circuit 670U, a signal transmission circuit 670L, and a fault protection circuit 670F.

The signal transmission circuit 670U serves to supply a gate signal voltage of the signal transmission circuit 6600 in the primary-side circuit 660 to the gate of the semiconductor chip 4A. The signal transmission circuit 670U includes input buffers 672UA and 672UB, an RS flip-flop circuit 673U, a pulse generator 674U, a level shifter circuit 675U, an RS flip-flop circuit 676, and a driver 677U, in this order from the transformer 690 to the semiconductor chip 4A. The signal transmission circuit 670U also includes the diode 49U and a current controller 49X that controls the current to the diode 49U. The current controller 49X may be a current limiting resistor.

The output terminal of the input buffer 672UA is connected to the S terminal of the RS flip-flop circuit 673U, and the output terminal of the input buffer 672UB is connected to the R terminal of the RS flip-flop circuit 673U. The Q terminal and the QB terminal of the RS flip-flop circuit 673U is connected to the pulse generator 674U. The pulse generator 674U is connected to the level shifter circuit 675U. The level shifter circuit 675U is configured to input a signal from the Q terminal of the RS flip-flop circuit 673U to the S terminal of the RS flip-flop circuit 673U, and input a signal from the QB terminal of the RS flip-flop circuit 673U to the R terminal of the RS flip-flop circuit 673U. The Q terminal of the RS flip-flop circuit 676U is connected to the driver 677U. The output terminal of the driver 677U is connected to the gate of the semiconductor chip 4A. To the R terminal of the RS flip-flop circuit 676U, the under voltage lock out circuit 678 is connected. The pulse generator 674U, the level shifter circuit 675U, the RS flip-flop circuit 676U, and the driver 677U respectively correspond to the pulse generator 465, the level shifter 466, the RS flip-flop circuit 468, and the driver 469 of the semiconductor device A1.

The signal transmission circuit 670L serves to supply a gate signal voltage of the signal transmission circuit 660L of the primary-side circuit 660, to the gate of the semiconductor chip 4D. The signal transmission circuit 670L includes input buffers 672LA and 672LB, an RS flip-flop circuit 673L, and a driver 677L, in this order from the transformer 690 toward the semiconductor chip 4D.

The output terminal of the input buffer 672LA is connected to the S terminal of the RS flip-flop circuit 673L, and the output terminal of the input buffer 672LB is connected to the R terminal of the RS flip-flop circuit 673L. The Q terminal and the QB terminal of the RS flip-flop circuit 673L are connected to the driver 677L. The driver 677L is connected to the gate of the semiconductor chip 4D.

The fault protection circuit 670F serves to output, when a fault occurs in the semiconductor device A2, information regarding the fault in the semiconductor device A2 to the primary-side circuit 660. The fault protection circuit 670F includes output buffers 672FA and 672FB, a fault signal generation circuit 679, a thermal shut down circuit 680, an under voltage lock out circuit 681, and a current limiting circuit 682. To the fault protection circuit 670F, the VCC terminal (lead 2O) and the CIN terminal (lead 2S, detection terminal CIN) of the secondary-side circuit 670 are connected.

To the fault signal generation circuit 679, the thermal shut down circuit 680, the under voltage lock out circuit 681, and the current limiting circuit 682 are connected. The first output terminal of the fault signal generation circuit 679 is connected to the output buffer 671FA, and the second output terminal is connected to the output buffer 671FB. To the output buffer 671FB, the R terminals of the RS flip-flop circuits 673U and 673L are connected.

The oscillation circuit 671 outputs the clock signal to each of the RS flip-flop circuits 673U and 673L, and the fault signal generation circuit 679.

The transformer 690 includes transformers 691 to 696. The transformers 691 to 696 each include a primary-side coil and a secondary-side coil.

The first terminal of the primary-side coil of the transformer 691 is connected to the output terminal of the output buffer 667UA, and the second terminal of the primary-side coil of the transformer 691 is grounded. The first terminal of the secondary-side coil of the transformer 691 is connected to the input buffer 672UA, and the second terminal of the secondary-side coil of the transformer 691 is grounded.

The first terminal of the primary-side coil of the transformer 692 is connected to the output terminal of the output buffer 667UB, and the second terminal of the primary-side coil of the transformer 692 is grounded. The first terminal of the secondary-side coil of the transformer 692 is connected to the input buffer 672UB, and the second terminal of the secondary-side coil of the transformer 692 is grounded.

The first terminal of the primary-side coil of the transformer 693 is connected to the output terminal of the output buffer 667LA, and the second terminal of the primary-side coil of the transformer 693 is grounded. The first terminal of the secondary-side coil of the transformer 693 is connected to the input buffer 672LA, and the second terminal of the secondary-side coil of the transformer 693 is grounded.

The first terminal of the primary-side coil of the transformer 694 is connected to the output terminal of the output buffer 667LB, and the second terminal of the primary-side coil of the transformer 694 is grounded. The first terminal of the secondary-side coil of the transformer 694 is connected to the input buffer 672LB, and the second terminal of the secondary-side coil of the transformer 694 is grounded.

The first terminal of the primary-side coil of the transformer 695 is connected to the input buffer 667FA, and the second terminal of the primary-side coil of the transformer 695 is grounded. The first terminal of the secondary-side coil of the transformer 695 is connected to the output terminal of the output buffer 672FA, and the second terminal of the secondary-side coil of the transformer 695 is grounded.

The first terminal of the primary-side coil of the transformer 696 is connected to the input buffer 667FB, and the second terminal of the primary-side coil of the transformer 696 is grounded. The first terminal of the secondary-side coil of the transformer 696 is connected to the output terminal of the output buffer 672FB, and the second terminal of the secondary-side coil of the transformer 696 is grounded.

In this embodiment, the lead 2A may be referred to as a VSU terminal. The lead 2B corresponds to the VBU terminal in the semiconductor device A1. The lead 2C may be referred to as a VSV terminal. The lead 2D corresponds to the VBV terminal in the semiconductor device A1. The lead 2E may be referred to as a VSW terminal. The lead 2F corresponds to the VBW terminal in the semiconductor device A1. The lead 2G corresponds to the first GND terminal in the semiconductor device A1. The lead 2H corresponds to the first VCC terminal in the semiconductor device A1. The lead 2I corresponds to the HINU terminal in the semiconductor device A1. The lead 2J corresponds to the HINV terminal in the semiconductor device A1. The lead 2K corresponds to the HINW terminal in the semiconductor device A1. The lead 2L corresponds to the LINU terminal. The lead 2M corresponds to the LINV terminal in the semiconductor device A1. The lead 2N corresponds to the LINW terminal in the semiconductor device A1. The lead 2O corresponds to the FO terminal. The lead 2P corresponds to the VOT terminal. The lead 2O may be referred to as a third VCC terminal. The lead 2R may be referred to as a third GND. The lead 2S corresponds to the CIN terminal. The lead 2T corresponds to the second VCC terminal in the semiconductor device A1. The lead 2U corresponds to the second GND terminal.

As shown in FIG. 50, the semiconductor device A2 is mounted, for example, on the circuit board 91. On the circuit board 91, a control chip 92 is provided. The control chip 92 controls the chips in the semiconductor device A2. The semiconductor device A2 and the control chip 92 are connected to each other, via the wiring pattern formed on the circuit board 91. In the illustrated example, the leads 2I to 2R of the semiconductor device A2 and the control chip 92 are connected to each other.

This embodiment provides the following advantageous effects, in addition to those provided by the semiconductor device A1.

The semiconductor device A2 includes the transformer 690 (transmission circuit chip 4I). Accordingly, in case that the power circuit on the secondary-side, such as the switching arms 40U, 40V, and 40W breaks down, the transformer 690 (transmission circuit chip 4I) prevents the impact of the breaking down from reaching the primary-side circuit 660 (primary-side circuit chip 4J). Therefore, a microcomputer or the like, connected from outside to the primary-side circuit 660 (primary-side circuit chip 4J) or primary-side circuit 660 (primary-side circuit chip 4J), can be protected.

As shown in FIG. 39, the transmission circuit chip 4I is located on the opposite side of the semiconductor chips 4A to 4F in the y-direction, across the control chip 4H. In addition, the primary-side circuit chip 4J is located on the opposite side of the control chip 4H in the y-direction, across the transmission circuit chip 4I. Therefore, the leads 2I to 2R electrically connected to the primary-side circuit 660 (primary-side circuit chip 4J) can be located more distant from the portion electrically connected to the control chip 4H, 4G, in the y-direction.

The leads 2A to 2H and the leads 2S to 2O, electrically connected to the secondary-side circuit 670, are separately located on the respective sides of the leads 2I to 2R electrically connected to the primary-side circuit 660 (primary-side circuit chip 4J), in the x-direction. Such a configuration prevents complication of the wiring paths of the conductive section 5 electrically connected to the leads 2A to 2H and the leads 2S to 2U, unlike the case where the leads 2A to 2H and the leads 2S to 2U are unevenly located only on either side in the x-direction.

As shown in FIG. 44 and FIG. 45, the clearance G28 between the second portion 22H and the second portion 22I is wider than the clearances G21 to G27 and the clearance G29. In addition, the clearance G2a between the second portion 22R and the second portion 22S is wider than the clearance G29 and the clearance G2b. Therefore, the primary-side circuit 660 and the secondary-side circuit 670 can be effectively insulated from each other.

As shown in FIG. 39 and FIG. 44, the second portion 52a of the wiring 50a overlaps with the semiconductor chip 4A, as viewed in the y-direction. Therefore, the second wire 92, connected to the gate electrode GP of the semiconductor chip 4A and the second portion 52a, can be shortened. In addition, the second portion 52b of the wiring 50b overlaps with the semiconductor chip 4A, as viewed in the y-direction. Therefore, the second wire 92, connected to the emitter electrode EP of the semiconductor chip 4A and the second portion 52b, can be shortened. Locating thus the second portion 52b and the second portion 52a so as to overlap as viewed in the x-direction is desirable from the viewpoint of shortening the second wire 92 connected to the emitter electrode EP of the semiconductor chip 4A and the second portion 52b.

As shown in FIG. 36, the projection length y21 of the second portions 221 to 22R from the fifth face 75 is longer than the projection length y22 of the second portions 22A to 22H and the second portions 22S to 22U from the fifth face 75, as viewed in the z-direction. Therefore, the leads 2I to 2R electrically connected to the primary-side circuit chip 4J can be insulated from the leads 2A to 2H electrically connected to the control chip 4G, and the leads 2S to 2O electrically connected to the control chip 4H, when the semiconductor device A2 is mounted on the circuit board.

As shown in FIG. 39, the control chip 4G and the semiconductor chip 4B overlap, as viewed in the y-direction. Such a configuration shortens the length of the second wire 92G connected to the semiconductor chip 4B and the control chip 4G, thereby contributing to improving the integration level of the semiconductor device.

As shown in FIG. 39, the control chip 4H overlaps with the semiconductor chip 4E, the transmission circuit chip 4I, and the primary-side circuit chip 4J, as viewed in the y-direction. Such a configuration shortens the length of the wires for connection among the semiconductor chip 4E, the transmission circuit chip 41, and the primary-side circuit chip 4J, thereby contributing to improving the integration level of the semiconductor device.

As shown in FIG. 39, the control chips 4G and 4H overlap with each other, as viewed in the x-direction. Such a configuration facilitates the semiconductor chips 4A to 4F and the plurality of leads 2 to be arranged along the x-direction, thereby contributing to improving the integration level of the semiconductor device.

As shown in FIG. 39, the number of second wires 92H extending from the control chip 4H toward the semiconductor chips 4D and 4E (leads 1B and 1C) in the y-direction is fewer than the number of third wires 93 extending from the control chip 4H toward the transmission circuit chip 4I. When temperature changes during the manufacturing process, or during the use of the semiconductor device A2, the leads 1A to 1D and the substrate 3 incur thermal expansion. The thermal expansion of the leads 1A to 1D, which are made of a metal, is larger than the thermal expansion of the substrate 3 made of a ceramic. In this embodiment, the control chip 4H and the transmission circuit chip 4I are both located on the substrate 3. In contrast, the semiconductor chips 4D and 4E are located on the lead 1B and the lead 1C. Accordingly, a change in positional relation between the control chip 4H and the semiconductor chips 4D and 4E, caused by the temperature change, is larger than a change in positional relation between the control chip 4H and the transmission circuit chip 4I. Providing a fewer number of second wires 92H, susceptible to stress from the resin 7 originating from the change in positional relation, than the third wires 93 suppresses the impact of the stress to which the second wire 92H may be subjected.

Further, the second wire 92H is connected, as shown in FIG. 40, to the semiconductor chip 4D located on the first portion 11B of the lead 1B, the semiconductor chip 4E located on the first portion 11C of the lead 1C, and the control chip 4H. The third wire 93 is connected to the control chip 4H and the transmission circuit chip 4I, both located on the substrate 3. Accordingly, the third wire 93 is shorter than the second wire 92H. Conversely, the second wire 92H is longer than the third wire 93. Making thus the second wire 92H longer than the third wire 93 prevents disconnection of the second wire 92H, susceptible to the impact of the change in positional relation, even when the change in positional relation takes place owing to a temperature change.

As shown in FIG. 42 and FIG. 43, the third face 123A, the third face 123B, the third face 123C, and the third face 123D are rougher than the second face 122A, the first face 121B, the second face 122B, the first face 121C, the second face 122C, and the first face 121D. With such a configuration, the third face 123A, the third face 123B, the third face 123C, and the third face 123D contributes to improving the adhesion strength between the leads 1A to 1D and the resin 7, and also insulation can be secured between the second face 122A and the first face 121B, the second face 122B and the first face 121C, the second face 122C and the first face 121D, which are opposed to each other.

As shown in FIG. 44, the portion of the first base portion 55 extending from the control chip 4G toward the lead 2 in the y-direction is longer than the portion of the first base portion 55 extending from the control chip 4G toward the lead 1A in the y-direction. As shown in FIG. 45, the portion of the second base portion 56 extending from the control chip 4H toward the lead 2 in the y-direction is longer than the portion of the second base portion 56 extending from the control chip 4H toward the lead 1C in the y-direction. Such a configuration prevents the first base portion 55 and the second base portion 56 from accidentally making an electrical contact with the leads 1A to 1D.

The transmission circuit chip 4I includes the first transmission circuit according to the present disclosure, and is covered with the resin 7. As shown in FIG. 50, the semiconductor device A2 is mounted, for example, on the circuit board 91. In this case, the control chip 92 is located on the circuit board 91, at a position outside the semiconductor device A2. When attempting to secure a physical spacing of the conduction path connecting between the control chip 92 and the semiconductor chips incorporated in the semiconductor device A2, at least a photocoupler can be excluded. Therefore, the size of the circuit board 91 can be reduced.

### Seventh Embodiment

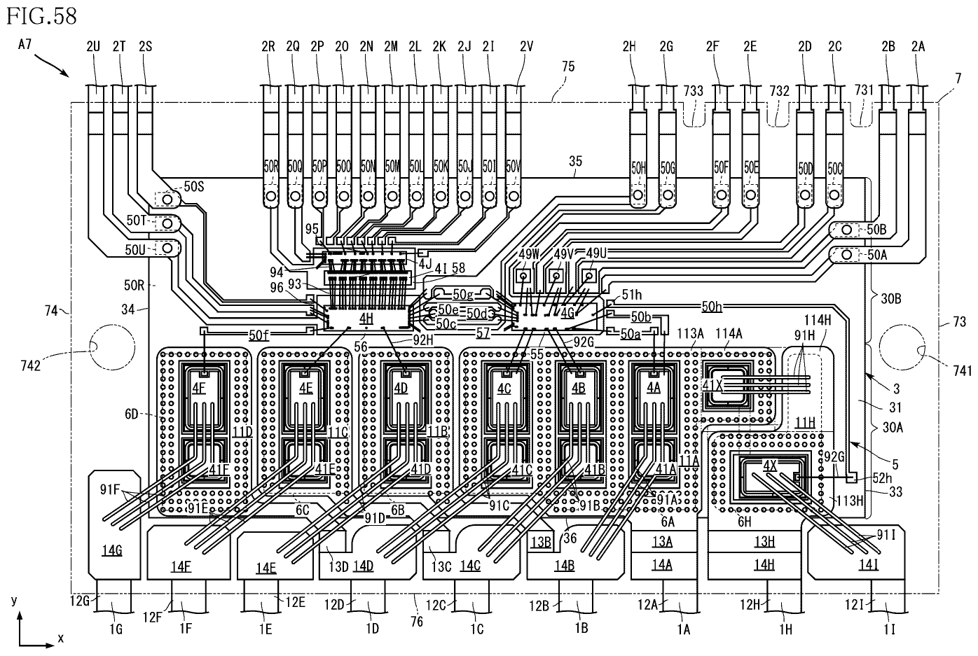

Referring to FIG. 58 to FIG. 60, a semiconductor device according to a seventh embodiment of the present disclosure will be described. The semiconductor device A7 according to this embodiment includes a plurality of leads 1, a plurality of leads 2, a substrate 3, a plurality of semiconductor chips 4, a diode 41, a plurality of control chips 4, a transmission circuit chip 4I, a primary-side circuit chip 4J, a plurality of diodes 49, a conductive section 5, a plurality of bonding sections 6, a plurality of first wires 91, a plurality of second wires 92, a plurality of third wires 93, a plurality of fourth wires 94, a plurality of fifth wires 95, a plurality of sixth wires 96, a plurality of seventh wires 97, and an encapsulating resin 7.

The semiconductor device A7 according to this embodiment includes similar elements to those of the semiconductor device A3 according to the third embodiment. Such elements will be given the same numeral, and a part or the whole of the description thereof may be omitted. Regarding an element on which no specific description is given, a similar configuration to that of the corresponding element of the semiconductor device A3 may be adopted, as appropriate.

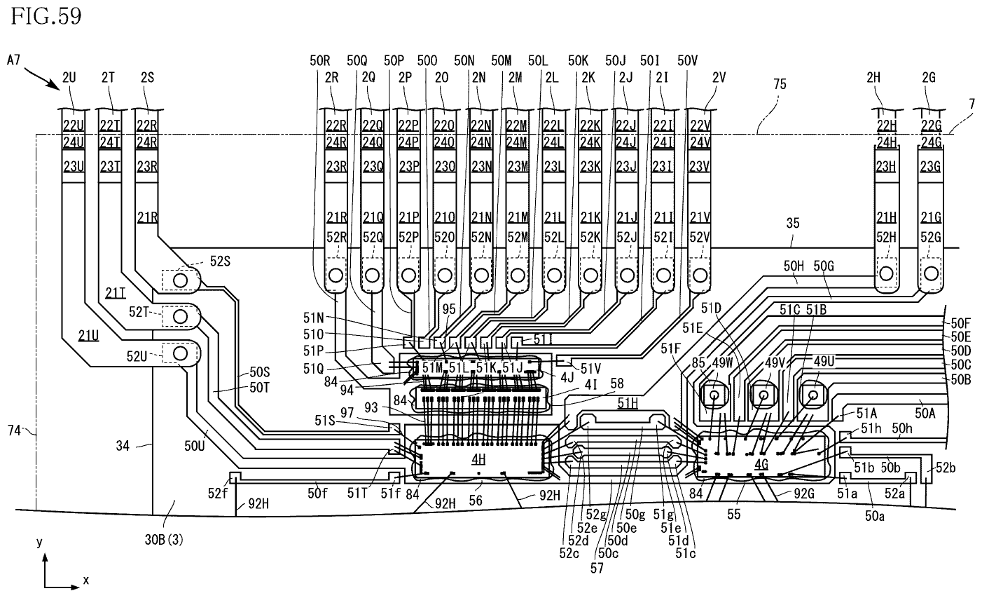

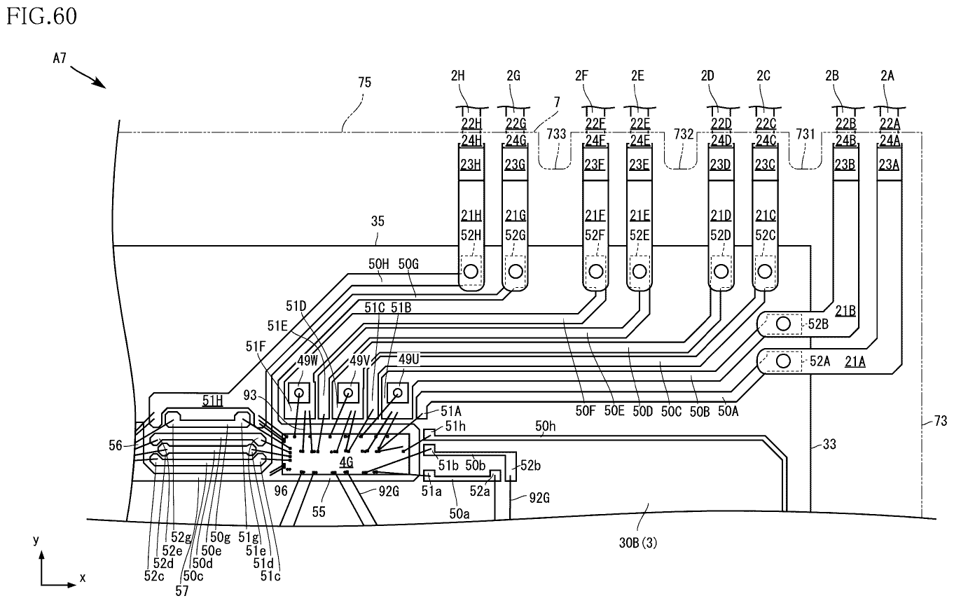

FIG. 58 is a plan view showing the semiconductor device A7. FIG. 59 and FIG. 60 are enlarged partial plan views of the semiconductor device A7.

### <Substrate 3>

The shape, size, and material of the substrate 3 are not specifically limited. The substrate 3 may be configured, for example, similarly to the substrate 3 of the semiconductor device A3.

### <Conductive Section 5>

Regarding the conductive section 5 according to this embodiment, although any of the elements is apparently given, for the sake of convenience of description, the same numeral as that of the conductive section 5 according to the third embodiment, it does not necessarily mean that the mentioned element has the same or similar configuration. The configuration of an element with a numeral is defined by the description relevant to this embodiment. Regarding a portion or structure on which no specific description is given, a similar configuration to that of the conductive section 5 of the semiconductor device A3 may be adopted, as appropriate.

The conductive section 5 is formed on the substrate 3. In this embodiment, the conductive section 5 is formed on the first face 31 of the substrate 3. The conductive section 5 is formed of a conductive material. The conductive material to form the conductive section 5 is not specifically limited. Examples of the conductive material to form the conductive section 5 include materials containing silver (Ag), copper (Cu), or gold (Au). In the subsequent description, it will be assumed that the conductive section 5 contains silver. However, the conductive section 5 may contain copper instead of silver, or gold instead of silver or copper. Alternatively, the conductive section 5 may contain Ag—Pt or Ag—Pd. The forming method of the conductive section 5 is not limited. For example, the conductive section 5 may be formed by sintering a paste containing the mentioned metal. The thickness of the conductive section 5 is not specifically limited, but may be, for example, approximately 5 μm to 30 μm.

In this embodiment, as shown in FIG. 59 and FIG. 60, the conductive section 5 includes wirings 50A to 50V, wirings 50a to 50h, first base portion 55, a second base portion 56, a connecting portion 57, and a third base portion 58, each of which will be described hereunder.

The shape of the first base portion 55 is not specifically limited, and a desired shape may be selected from a rectangular shape, a polygonal shape, a circular shape, an elliptical shape, and so forth. In the illustrated example, the first base portion 55 has a rectangular shape. In the illustrated example, the first base portion 55 has an elongate rectangular shape, having the long sides extending along the x-direction.

The shape of the second base portion 56 is not specifically limited, and a desired shape may be selected from a rectangular shape, a polygonal shape, a circular shape, an elliptical shape, and so forth. In the illustrated example, the second base portion 56 has a rectangular shape. In the illustrated example, the second base portion 56 has an elongate rectangular shape, having the long sides extending along the x-direction.

The connecting portion 57 is interposed between the first base portion 55 and the second base portion 56 and, in the illustrated example, connecting the first base portion 55 and the second base portion 56. In the illustrated example, the connecting portion 57 is located between the first base portion 55 and the second base portion 56, as viewed in the y-direction. The shape of the connecting portion 57 is not specifically limited.

In the illustrated example, the respective edges of the first base portion 55, the second base portion 56, and the connecting portion 57 on the side of the sixth face 36 in the y-direction, are located generally at the same position in the y-direction. Here, the expression “located generally at the same position” in the y-direction refers to, for example, being located exactly at the same position, or being deviated by within ±5% of the characteristic size (size of the first base portion 55 or second base portion 56 in the y-direction).

The shape of the third base portion 58 is not specifically limited, and a desired shape may be selected from a rectangular shape, a polygonal shape, a circular shape, an elliptical shape, and so forth. The third base portion 58 is located on the side of the fifth face 35 in the y-direction, with respect to the second base portion 56. The third base portion 58 overlaps with the second base portion 56, as viewed in the y-direction. The wiring 50A includes a first portion 51A and a second portion 52A.

The first portion 51A is located on the side of the third face 33 in the x-direction, and on the side of the fifth face 35 in the y-direction, with respect to the first base portion 55. The shape of the first portion 51A is not specifically limited, and a desired shape may be selected from a rectangular shape, a polygonal shape, a circular shape, an elliptical shape, and so forth. In the illustrated example, the first portion 51A has a strip shape extending along the y-direction. In the illustrated example, in addition, the first portion 51A is spaced apart from the first base portion 55, as viewed in the x-direction.

The second portion 52A is located on the side of the fifth face 35 in the y-direction, and on the side of the third face 33 in the x-direction, with respect to the first portion 51A. The shape of the second portion 52A is not specifically limited, and a desired shape may be selected from a rectangular shape, a polygonal shape, a circular shape, an elliptical shape, and so forth. In the illustrated example, the first portion 51A has a rectangular shape.

The wiring 50A includes a strip-shaped portion connecting the first portion 51A and the second portion 52A. The strip-shaped portion includes a portion extending from the first portion 51A along the x-direction, and a portion extending obliquely toward the second portion 52A.

The wiring 50B includes a first portion 51B and a second portion 52B.

The shape of the first portion 51B is not specifically limited, and a desired shape may be selected from a rectangular shape, a polygonal shape, a circular shape, an elliptical shape, and so forth. The first portion 51B is located on the side of the fourth face 34 in the x-direction with respect to the first portion 51A, and on the side of the fifth face 35 in the y-direction, with respect to the first base portion 55. In the illustrated example, a part of the first portion 51B overlaps with the first base portion 55 as viewed in the y-direction, and with the first portion 51A, as viewed in the x-direction.

The second portion 52B is located on the side of the fifth face 35 in the y-direction, and on the side of the third face 33 in the x-direction, with respect to the first portion 51B. The second portion 52B overlaps with the second portion 52A, as viewed in the y-direction. The shape of the second portion 52B is not specifically limited, and a desired shape may be selected from a rectangular shape, a polygonal shape, a circular shape, an elliptical shape, and so forth. In the illustrated example, the second portion 52B has a rectangular shape.

The wiring 50B includes a strip-shaped portion connecting the first portion 51B and the second portion 52B. The strip-shaped portion includes a portion extending from the first portion 51B along the x-direction, a portion extending obliquely toward the second portion 52B.

The wiring 50C includes a first portion 51C and a second portion 52C.

The first portion 51C is located on the side of the fifth face 35 in the y-direction, with respect to the first base portion 55 with a spacing therefrom, and on the side of the fourth face 34 in the x-direction, with respect to the first portion 51B with a spacing therefrom. In the illustrated example, the first portion 51C overlaps with the first base portion 55, as viewed in the y-direction. The shape of the first portion 51C is not specifically limited. In the illustrated example, the first portion 51C has a strip shape extending along the y-direction.

The second portion 52C is located on the side of the fifth face 35 with respect to the first portion 51C, in the y-direction. The second portion 52C is located on the side of the fifth face 35 in the y-direction, with respect to the second portion 52A and the second portion 52B. The shape of the second portion 52C is not specifically limited, and a desired shape may be selected from a rectangular shape, a polygonal shape, a circular shape, an elliptical shape, and so forth. In the illustrated example, the second portion 52C has a rectangular shape.

The wiring 50C includes a strip-shaped portion connecting the first portion 51C and the second portion 52C. The strip-shaped portion includes a portion extending obliquely from the first portion 51C, a portion extending along the x-direction, a portion extending obliquely, and a portion extending along the y-direction toward the second portion 52C.

The wiring 50D includes a first portion 51D and a second portion 52D.

The shape of the first portion 51D is not specifically limited, and a desired shape may be selected from a rectangular shape, a polygonal shape, a circular shape, an elliptical shape, and so forth. In the illustrated example, the first portion 51D has a trapezoidal shape. The first portion 51D is located on the side of the fifth face 35 in the y-direction, with respect to the first base portion 55, and spaced therefrom. The first portion 51D is located on the side of the fourth face 34 in the x-direction with respect to the first portion 51C, and spaced therefrom. In addition, in the illustrated example, the first portion 51D overlaps with the first portion 51C as viewed in the x-direction, and with the first base portion 55 as viewed in the y-direction.

The second portion 52D is located on the side of the fifth face 35 with respect to the first portion 51D, in the y-direction. The second portion 52D is located on the side of the fourth face 34 in the x-direction, with respect to the second portion 52C. The second portion 52D overlaps with the second portion 52C, as viewed in the x-direction. The shape of the second portion 52D is not specifically limited, and a desired shape may be selected from a rectangular shape, a polygonal shape, a circular shape, an elliptical shape, and so forth. In the illustrated example, the second portion 52E has a rectangular shape.

The wiring 50D includes a strip-shaped portion connecting the first portion 51D and the second portion 52D. The strip-shaped portion includes a portion extending obliquely from the first portion 51D, a portion extending along the x-direction, a portion extending obliquely, and a portion extending along the y-direction toward the second portion 52D.

The wiring 50E includes a first portion 51E and a second portion 52E.

The first portion 51E is located on the side of the fifth face 35 in the y-direction, with respect to the first base portion 55 with a spacing therefrom, and on the side of the fourth face 34 in the x-direction, with respect to the first portion 51D with a spacing therefrom. In the illustrated example, the first portion 51E overlaps with the first base portion 55, as viewed in the y-direction. The shape of the first portion 51E is not specifically limited. In the illustrated example, the first portion 51E has a strip shape extending along the y-direction.

The second portion 52E is located on the side of the fifth face 35 with respect to the first portion 51E, in the y-direction. The second portion 52E is located on the side of the fourth face 34 with respect to the second portion 52D, in the x-direction. The second portion 52E overlaps with the second portion 52D, as viewed in the x-direction. The shape of the second portion 52E is not specifically limited, and a desired shape may be selected from a rectangular shape, a polygonal shape, a circular shape, an elliptical shape, and so forth. In the illustrated example, the second portion 52B has a rectangular shape.

The wiring 50E includes a strip-shaped portion connecting the first portion 51E and the second portion 52E. The strip-shaped portion includes a portion extending obliquely from the first portion 51E, a portion extending along the x-direction, a portion extending obliquely, and a portion extending along the y-direction toward the second portion 52E.

The wiring 50F includes a first portion 51F and a second portion 52F.

The shape of the first portion 51F is not specifically limited, and a desired shape may be selected from a rectangular shape, a polygonal shape, a circular shape, an elliptical shape, and so forth. In the illustrated example, the first portion 51F has a rectangular shape. The first portion 51F is located on the side of the fifth face 35 in the y-direction, with respect to the first base portion 55, and spaced therefrom. The first portion 51F is located on the side of the fourth face 34 in the x-direction with respect to the first portion 51E, and spaced therefrom. In the illustrated example, the first portion 51F overlaps with the first portion 51E as viewed in the x-direction, and with the first base portion 55 as viewed in the y-direction.

The second portion 52F is located on the side of the fifth face 35 with respect to the first portion 51F, in the y-direction. The second portion 52F is located on the side of the fourth face 34 in the x-direction with respect to the second portion 52E, and spaced therefrom. The second portion 52F overlaps with the second portion 52E, as viewed in the x-direction. The shape of the second portion 52F is not specifically limited, and a desired shape may be selected from a rectangular shape, a polygonal shape, a circular shape, an elliptical shape, and so forth. In the illustrated example, the second portion 52F has a rectangular shape.

The wiring 50F includes a strip-shaped portion connecting the first portion 51F and the second portion 52F. The strip-shaped portion includes a portion extending obliquely from the first portion 51F, a portion extending along the x-direction, a portion extending obliquely, and a portion extending along the y-direction toward the second portion 52F.

The wiring 50G includes a second portion 52G.

The second portion 52G is located on the side of the fifth face 35 with respect to the first base portion 55, in the y-direction. The second portion 52G is located on the side of the fourth face 34 in the x-direction with respect to the second portion 52F, and spaced therefrom. The second portion 52G overlaps with the second portion 52F, as viewed in the x-direction. The second portion 52G is spaced apart from the first base portion 55, as viewed in the y-direction. The shape of the second portion 52G is not specifically limited, and a desired shape may be selected from a rectangular shape, a polygonal shape, a circular shape, an elliptical shape, and so forth. In the illustrated example, the second portion 52G has a rectangular shape.

The wiring 50G includes a strip-shaped portion connecting the second portion 52G and the first base portion 55. The strip-shaped portion includes a portion extending from the first base portion 55 along the y-direction, a portion extending obliquely, a portion extending along the x-direction, and a portion extending obliquely toward the second portion 52G.

The wiring 50H includes a first portion 51H and a second portion 52H.

The first portion 51H is located between the first base portion 55 and the second base portion 56, as viewed in the y-direction. In the illustrated example, a part of the first portion 51H overlaps with the first base portion 55 and the second base portion 56, as viewed in the x-direction. The first portion 51H overlaps with the first portion 51F, as viewed in the x-direction. The shape of the first portion 51H is not specifically limited. In the illustrated example, the first portion 51H includes a portion extending along the x-direction, and a pair of portions extending along the y-direction toward the sixth face 36, from the respective end portions of the portion extending along the x-direction.

The second portion 52H is located on the side of the fifth face 35 in the y-direction, and on the side of the third face 33 in the x-direction, with respect to the first portion 51H. The second portion 52H is located on the side of the fourth face 34 in the x-direction with respect to the second portion 52G. The second portion 52H overlaps with the second portion 52G, as viewed in the x-direction. The shape of the second portion 52H is not specifically limited, and a desired shape may be selected from a rectangular shape, a polygonal shape, a circular shape, an elliptical shape, and so forth. In the illustrated example, the second portion 52H has a rectangular shape.

The wiring 50H includes a strip-shaped portion connecting the first portion 51H and the second portion 52H. The strip-shaped portion includes a portion extending obliquely from the first portion 51H, and a portion extending along the x-direction toward the second portion 52H.

The wiring 50V includes a first portion 51V and a second portion 52V.

The first portion 51V is located on the side of the third face 33 in the x-direction with respect to the third base portion 58, and spaced therefrom. In the illustrated example, the first portion 51V overlaps with the third base portion 58, as viewed in the x-direction. The shape of the first portion 51V is not specifically limited. In the illustrated example, the first portion 51V has a rectangular shape.

The second portion 52V is located on the side of the fifth face 35 with respect to the first portion 51V, in the y-direction. The second portion 52V is located on the side of the fourth face 34 in the x-direction with respect to the second portion 52H, and spaced therefrom. The second portion 52V is spaced apart from the third base portion 58, as viewed in the x-direction. The second portion 52V overlaps with the second portion 52H, as viewed in the x-direction. The shape of the second portion 52V is not specifically limited, and a desired shape may be selected from a rectangular shape, a polygonal shape, a circular shape, an elliptical shape, and so forth. In the illustrated example, the second portion 52V has a rectangular shape.

The wiring 50V includes a strip-shaped portion connecting the first portion 51V and the second portion 52V. The strip-shaped portion includes a portion extending from the first portion 51V along the x-direction, a portion extending obliquely, and a portion extending along the y-direction toward the second portion 52V.

The wiring 50I includes a first portion 51I and a second portion 52I.

The first portion 51I is located on the side of the fifth face 35 in the y-direction with respect to the third base portion 58, and spaced therefrom. In the illustrated example, the first portion 51I overlaps with the third base portion 58, as viewed in the y-direction. The shape of the first portion 51I is not specifically limited. In the illustrated example, the first portion 51I has a rectangular shape.

The second portion 52I is located on the side of the fifth face 35 with respect to the first portion 51I, in the y-direction. The second portion 52I is located on the side of the fourth face 34 in the x-direction with respect to the second portion 52V, and spaced therefrom. The second portion 52I is spaced apart from the third base portion 58, as viewed in the y-direction. The second portion 52I overlaps with the second portion 52V, as viewed in the x-direction. The shape of the second portion 52I is not specifically limited, and a desired shape may be selected from a rectangular shape, a polygonal shape, a circular shape, an elliptical shape, and so forth. In the illustrated example, the second portion 52I has a rectangular shape.

The wiring 50I includes a strip-shaped portion connecting the first portion 51I and the second portion 52I. The strip-shaped portion includes a portion extending from the first portion 51I along the x-direction, a portion extending obliquely, and a portion extending along the y-direction toward the second portion 52I.

The wiring 50J includes a first portion 51J and a second portion 52J.

The first portion 51J is located on the side of the fifth face 35 in the y-direction with respect to the third base portion 58, and spaced therefrom. The first portion 51J is located on the side of the fourth face 34 in the x-direction with respect to the first portion 51I, and spaced therefrom. In the illustrated example, the first portion 51J overlaps with the first portion 51I as viewed in the x-direction, and with the third base portion 58 as viewed in the y-direction. The shape of the first portion 51J is not specifically limited. In the illustrated example, the first portion 51J has a rectangular shape.

The second portion 52J is located on the side of the fifth face 35 with respect to the first portion 51J, in the y-direction. The second portion 52J is located on the side of the fourth face 34 in the x-direction with respect to the second portion 52I, and spaced therefrom. The second portion 52J overlaps with the second portion 52I, as viewed in the x-direction. The shape of the second portion 52J is not specifically limited, and a desired shape may be selected from a rectangular shape, a polygonal shape, a circular shape, an elliptical shape, and so forth. In the illustrated example, the second portion 52J has a rectangular shape.

The wiring 50J includes a strip-shaped portion connecting the first portion 51J and the second portion 52J. The strip-shaped portion includes a portion extending obliquely from the first portion 51J, a portion extending along the x-direction, a portion extending obliquely, and a portion extending along the y-direction toward the second portion 52J.

The wiring 50K includes a first portion 51K and a second portion 52K.

The first portion 51K is located on the side of the fifth face 35 in the y-direction with respect to the third base portion 58, and spaced therefrom. In the illustrated example, the first portion 51K overlaps with the third base portion 58, as viewed in the y-direction. The first portion 51K is located on the side of the fourth face 34 in the x-direction with respect to the first portion 51J, and spaced therefrom. The first portion 51K overlaps with the first portion 51J, as viewed in the x-direction. The shape of the first portion 51K is not specifically limited. In the illustrated example, the first portion 51K has a rectangular shape.

The second portion 52K is located on the side of the fifth face 35 with respect to the first portion 51K, in the y-direction. The second portion 52K is located on the side of the fourth face 34 in the x-direction with respect to the second portion 52J, and spaced therefrom. The second portion 52K is spaced apart from the third base portion 58, as viewed in the y-direction. The second portion 52K overlaps with the second portion 52J, as viewed in the x-direction. The shape of the second portion 52K is not specifically limited, and a desired shape may be selected from a rectangular shape, a polygonal shape, a circular shape, an elliptical shape, and so forth. In the illustrated example, the second portion 52K has a rectangular shape.

The wiring 50K includes a strip-shaped portion connecting the first portion 51K and the second portion 52K. The strip-shaped portion includes a portion extending obliquely from the first portion 51K, a portion extending along the x-direction, a portion extending obliquely, and a portion extending along the y-direction toward the second portion 52K.

The wiring 50L includes a first portion 51L and a second portion 52L.

The first portion 51L is located on the side of the fifth face 35 in the y-direction with respect to the third base portion 58, and spaced therefrom. In the illustrated example, the first portion 51L overlaps with the third base portion 58, as viewed in the y-direction. The first portion 51L is located on the side of the fourth face 34 in the x-direction with respect to the first portion 51K, and spaced therefrom. The first portion 51L overlaps with the first portion 51K, as viewed in the x-direction. The shape of the first portion 51L is not specifically limited. In the illustrated example, the first portion 51L has a rectangular shape.

The second portion 52L is located on the side of the fifth face 35 with respect to the first portion 51L, in the y-direction. The second portion 52L is located on the side of the fourth face 34 in the x-direction with respect to the second portion 52K, and spaced therefrom. The second portion 52L overlaps with the third base portion 58, as viewed in the y-direction. The second portion 52L overlaps with the second portion 52K, as viewed in the x-direction. The shape of the second portion 52L is not specifically limited, and a desired shape may be selected from a rectangular shape, a polygonal shape, a circular shape, an elliptical shape, and so forth. In the illustrated example, the second portion 52L has a rectangular shape.

The wiring 50L includes a strip-shaped portion connecting the first portion 51L and the second portion 52L. The strip-shaped portion includes a portion extending obliquely from the first portion 51L, a portion extending along the x-direction, a portion extending obliquely, and a portion extending along the y-direction toward the second portion 52L.

The wiring 50M includes a first portion 51M and a second portion 52M.

The first portion 51M is located on the side of the fifth face 35 in the y-direction with respect to the third base portion 58, and spaced therefrom. In the illustrated example, the first portion 51M overlaps with the third base portion 58, as viewed in the y-direction. The first portion 51M is located on the side of the fourth face 34 in the x-direction with respect to the first portion 51L, and spaced therefrom. The first portion 51M overlaps with the first portion 51L, as viewed in the x-direction. The shape of the first portion 51M is not specifically limited. In the illustrated example, the first portion 51M has a rectangular shape.

The second portion 52M is located on the side of the fifth face 35 with respect to the first portion 51M, in the y-direction. The second portion 52M is located on the side of the fourth face 34 in the x-direction with respect to the second portion 52L, and spaced therefrom. The second portion 52M overlaps with the third base portion 58, as viewed in the y-direction. The second portion 52M overlaps with the second portion 52L, as viewed in the x-direction. The shape of the second portion 52M is not specifically limited, and a desired shape may be selected from a rectangular shape, a polygonal shape, a circular shape, an elliptical shape, and so forth. In the illustrated example, the second portion 52M has a rectangular shape.

The wiring 50M includes a strip-shaped portion connecting the first portion 51M and the second portion 52M. The strip-shaped portion includes a portion extending obliquely from the first portion 51M, a portion extending along the x-direction, a portion extending obliquely, and a portion extending along the y-direction toward the second portion 52M.

The wiring 50N includes a first portion 51N and a second portion 52N.

The first portion 51N is located on the side of the fifth face 35 in the y-direction with respect to the third base portion 58, and spaced therefrom. In the illustrated example, the first portion 51N overlaps with the third base portion 58, as viewed in the y-direction. The first portion 51N is located on the side of the fourth face 34 in the x-direction with respect to the first portion 51M, and spaced therefrom. The first portion 51N overlaps with the first portion 51M, as viewed in the x-direction. The shape of the first portion 51N is not specifically limited. In the illustrated example, the first portion 51N has a rectangular shape.

The second portion 52N is located on the side of the fifth face 35 with respect to the first portion 51N, in the y-direction. The second portion 52N is located on the side of the fourth face 34 in the x-direction with respect to the second portion 52M, and spaced therefrom. The second portion 52N overlaps with the third base portion 58, as viewed in the y-direction. The second portion 52N overlaps with the second portion 52M, as viewed in the x-direction. The shape of the second portion 52N is not specifically limited, and a desired shape may be selected from a rectangular shape, a polygonal shape, a circular shape, an elliptical shape, and so forth. In the illustrated example, the second portion 52N has a rectangular shape.

The wiring 50N includes a strip-shaped portion connecting the first portion 51N and the second portion 52N. The strip-shaped portion includes a portion extending obliquely from the first portion 51N, and a portion extending obliquely toward the second portion 52N.

The wiring 50O includes a first portion 51O and a second portion 52O.

The first portion 51O is located on the side of the fifth face 35 in the y-direction with respect to the third base portion 58, and spaced therefrom. In the illustrated example, the first portion 51O overlaps with the third base portion 58, as viewed in the y-direction. The first portion 51O is located on the side of the fourth face 34 in the x-direction with respect to the first portion 51N, and spaced therefrom. The first portion 51O overlaps with the first portion 51N, as viewed in the x-direction. The shape of the first portion 51O is not specifically limited. In the illustrated example, the first portion 51O has a rectangular shape.

The second portion 52O is located on the side of the fifth face 35 with respect to the first portion 51O, in the y-direction. The second portion 52O is located on the side of the fourth face 34 in the x-direction with respect to the second portion 52N, and spaced therefrom. The second portion 52O overlaps with the third base portion 58, as viewed in the y-direction. The second portion 52O overlaps with the second portion 52N, as viewed in the x-direction. The shape of the second portion 52O is not specifically limited, and a desired shape may be selected from a rectangular shape, a polygonal shape, a circular shape, an elliptical shape, and so forth. In the illustrated example, the second portion 52O has a rectangular shape.

The wiring 50O includes a strip-shaped portion connecting the first portion 51O and the second portion 52O. The strip-shaped portion includes a portion extending obliquely from the first portion 51O, and a portion extending along the y-direction toward the second portion 52O.

The wiring 50P includes a first portion 51P and a second portion 52P.

The first portion 51P is located on the side of the fifth face 35 in the y-direction with respect to the third base portion 58, and spaced therefrom. In the illustrated example, the first portion 51P overlaps with the third base portion 58, as viewed in the y-direction. The first portion 51P is located on the side of the fourth face 34 in the x-direction with respect to the first portion 51O, and spaced therefrom. The first portion 51P overlaps with the first portion 51O, as viewed in the x-direction. The shape of the first portion 51P is not specifically limited. In the illustrated example, the first portion 51P has a rectangular shape.

The second portion 52P is located on the side of the fifth face 35 with respect to the first portion 51P, in the y-direction. The second portion 52P is located on the side of the fourth face 34 in the x-direction with respect to the second portion 52O, and spaced therefrom. The second portion 52P overlaps with the third base portion 58, as viewed in the y-direction. The second portion 52P overlaps with the second portion 52O, as viewed in the x-direction. The shape of the second portion 52P is not specifically limited, and a desired shape may be selected from a rectangular shape, a polygonal shape, a circular shape, an elliptical shape, and so forth. In the illustrated example, the second portion 52P has a rectangular shape.

The wiring 50P includes a strip-shaped portion connecting the first portion 51P and the second portion 52P. The strip-shaped portion includes a portion extending along the y-direction, from the first portion 51P toward the second portion 52P. The wiring 50O includes a first portion 51O and a second portion 52Q.

The first portion 51O is located on the side of the fourth face 34 in the x-direction, with respect to the third base portion 58. The first portion 51Q overlaps with a part of the third base portion 58, as viewed in the x-direction. The first portion 51O overlaps with a part of the third base portion 58, as viewed in the y-direction. The shape of the first portion 51O is not specifically limited. In the illustrated example, the first portion 51O has a polygonal shape.

The second portion 52Q is located on the side of the fifth face 35 with respect to the first portion 51Q, in the y-direction. The second portion 52Q is located on the side of the fourth face 34 in the x-direction with respect to the second portion 52P, and spaced therefrom. The second portion 52Q is spaced apart from the third base portion 58, as viewed in the y-direction. The second portion 52Q overlaps with the second portion 52P, as viewed in the x-direction. The shape of the second portion 52Q is not specifically limited, and a desired shape may be selected from a rectangular shape, a polygonal shape, a circular shape, an elliptical shape, and so forth. In the illustrated example, the second portion 52Q has a rectangular shape.

The wiring 50Q includes a strip-shaped portion connecting the first portion 51Q and the second portion 52Q. The strip-shaped portion includes a portion extending along the y-direction, from the first portion 51Q toward the second portion 52Q.

The wiring 50R includes a first portion 51R and a second portion 52R.

The second portion 52R is located on the side of the fifth face 35 with respect to the third base portion 58, in the y-direction. The second portion 52R is located on the side of the fourth face 34 in the x-direction with respect to the second portion 52Q, and spaced therefrom. The second portion 52R is spaced apart from the third base portion 58, as viewed in the y-direction. The second portion 52R overlaps with the second portion 52Q, as viewed in the x-direction. The shape of the second portion 52R is not specifically limited, and a desired shape may be selected from a rectangular shape, a polygonal shape, a circular shape, an elliptical shape, and so forth. In the illustrated example, the second portion 52R has a rectangular shape.

The wiring 50R includes a strip-shaped portion connecting the third base portion 58 and the second portion 52R. The strip-shaped portion includes a portion extending from the third base portion 58 along the x-direction, a portion extending obliquely, and a portion extending along the y-direction toward the second portion 52R.

The wiring 50S includes a first portion 51S and a second portion 52S.

The first portion 51S is located on the side of the fourth face 34 in the x-direction, with respect to the second base portion 56. The first portion 51S overlaps with the second base portion 56, as viewed in the x-direction. The shape of the first portion 51S is not specifically limited. In the illustrated example, the first portion 51S has a rectangular shape.

The second portion 52S is located on the side of the fifth face 35 with respect to the first portion 51S, in the y-direction. The second portion 52S is located on the side of the fourth face 34 in the x-direction with respect to the second portion 52R, and spaced therefrom. The second portion 52S is spaced apart from the second base portion 56 and the third base portion 58, as viewed in the y-direction. The second portion 52S overlaps with the second portion 52R, as viewed in the x-direction. The shape of the second portion 52S is not specifically limited, and a desired shape may be selected from a rectangular shape, a polygonal shape, a circular shape, an elliptical shape, and so forth. In the illustrated example, the second portion 52S has a rectangular shape.

The wiring 50S includes a strip-shaped portion connecting the first portion 51S and the second portion 52S. The strip-shaped portion includes a portion extending from the first portion 51S along the x-direction, a portion extending obliquely, a portion extending along the y-direction, a portion extending obliquely, and a portion extending along the x-direction toward the second portion 52S.

The wiring 50T includes a first portion 51T and a second portion 52T.

The first portion 51T is located on the side of the fourth face 34 in the x-direction, with respect to the second base portion 56, and spaced therefrom. The first portion 51T is located on the side of the sixth face 36 in the y-direction, with respect to the first portion 51S, and spaced therefrom. In the illustrated example, the first portion 51T overlaps with the first portion 51S, as viewed in the y-direction. The first portion 51T overlaps with the second base portion 56, as viewed in the x-direction. The shape of the first portion 51T is not specifically limited. In the illustrated example, the first portion 51T has a rectangular shape.

The second portion 52T is located on the side of the fifth face 35 with respect to the first portion 51T, in the y-direction. The second portion 52T is located on the side of the sixth face 36 in the y-direction with respect to the second portion 52S, and spaced therefrom. The second portion 52T is spaced apart from the third base portion 58, as viewed in the y-direction. The second portion 52T overlaps with the second portion 52S, as viewed in the y-direction. The shape of the second portion 52T is not specifically limited, and a desired shape may be selected from a rectangular shape, a polygonal shape, a circular shape, an elliptical shape, and so forth. In the illustrated example, the second portion 52T has a rectangular shape.

The wiring 50T includes a strip-shaped portion connecting the first portion 51T and the second portion 52T. The strip-shaped portion includes a portion extending from the first portion 51T along the x-direction, a portion extending obliquely, a portion extending along the y-direction, and a portion extending obliquely toward the second portion 52T.

The wiring 50U includes a first portion 51U and a second portion 52U.

The second portion 52U is located on the side of the fifth face 35 with respect to the second base portion 56, in the y-direction. The second portion 52O is located on the side of the sixth face 36 in the y-direction with respect to the second portion 52T, and spaced therefrom. The second portion 52O is spaced apart from the third base portion 58, as viewed in the y-direction. The second portion 52U overlaps with the second portion 52T, as viewed in the y-direction. The shape of the second portion 52U is not specifically limited, and a desired shape may be selected from a rectangular shape, a polygonal shape, a circular shape, an elliptical shape, and so forth. In the illustrated example, the second portion 52O has a rectangular shape.

The wiring 50U includes a strip-shaped portion connecting the second base portion 56 and the second portion 52U. The strip-shaped portion includes a portion extending from the second base portion 56 along the x-direction, a portion extending obliquely, and a portion extending along the y-direction toward the second portion 52U.

The wiring 50a includes a first portion 51a and a first portion 51b.

The first portion 51a is located on the side of the third face 33 in the x-direction, with respect to the first base portion 55, and spaced therefrom. The first portion 51a overlaps with the first base portion 55, as viewed in the x-direction. The shape of the second portion 51a is not specifically limited, and a desired shape may be selected from a rectangular shape, a polygonal shape, a circular shape, an elliptical shape, and so forth. In the illustrated example, the second portion 51a has a rectangular shape.

The second portion 52a is located on the side of the third face 33 in the x-direction, with respect to the first portion 51a. The second portion 52a overlaps with the first portion 51a, as viewed in the x-direction. The shape of the second portion 52a is not specifically limited, and a desired shape may be selected from a rectangular shape, a polygonal shape, a circular shape, an elliptical shape, and so forth. In the illustrated example, the second portion 52a has a rectangular shape.

The wiring 50a includes a strip-shaped portion connecting the first portion 51a and the second portion 52a. The strip-shaped portion includes a portion extending along the x-direction. The wiring 50b includes a first portion 51b and a second portion 52b.

The first portion 51b is located on the side of the third face 33 in the x-direction, with respect to the first base portion 55, and spaced therefrom. The first portion 51b overlaps with the first base portion 55, as viewed in the x-direction. The first portion 51b overlaps with the first portion 51a, as viewed in the y-direction. The shape of the second portion 51b is not specifically limited, and a desired shape may be selected from a rectangular shape, a polygonal shape, a circular shape, an elliptical shape, and so forth. In the illustrated example, the second portion 51b has a rectangular shape.

The second portion 52b is located on the side of the third face 33 in the x-direction, with respect to the first portion 51b, and spaced therefrom. The second portion 52b is located on the side of the third face 33 in the x-direction, with respect to the second portion 52a, and spaced therefrom. The second portion 52b overlaps with the first base portion 55 and the second portion 52a, as viewed in the x-direction. The shape of the second portion 52b is not specifically limited, and a desired shape may be selected from a rectangular shape, a polygonal shape, a circular shape, an elliptical shape, and so forth. In the illustrated example, the second portion 52b has a rectangular shape having the long sides extending along the y-direction.

The wiring 50b includes a strip-shaped portion connecting the first portion 51b and the second portion 52b. The strip-shaped portion includes a portion extending along the x-direction.

The wiring 50h includes a first portion 51h and a second portion 52h.

The first portion 51h is located on the side of the third face 33 in the x-direction, with respect to the first base portion 55, and spaced therefrom. The first portion 51h overlaps with the first base portion 55, as viewed in the x-direction. The first portion 51h overlaps with the first portion 51b, as viewed in the y-direction. The shape of the second portion 51h is not specifically limited, and a desired shape may be selected from a rectangular shape, a polygonal shape, a circular shape, an elliptical shape, and so forth. In the illustrated example, the second portion 51h has a rectangular shape.

As shown in FIG. 58, the second portion 52h is located on the side of the third face 33 in the x-direction, with respect to the first portion 51h, and spaced therefrom. The second portion 52h is located on the side of the sixth face 36 in the y-direction, with respect to the first portion 51h, and spaced therefrom. The second portion 52h is spaced apart from the first base portion 55, as viewed in the x-direction. The second portion 52h overlaps with the wiring 50A, as viewed in the y-direction. The shape of the second portion 52h is not specifically limited, and a desired shape may be selected from a rectangular shape, a polygonal shape, a circular shape, an elliptical shape, and so forth. In the illustrated example, the second portion 52h has a rectangular shape.

The wiring 50h includes a strip-shaped portion connecting the first portion 51h and the second portion 52h. The strip-shaped portion includes a portion extending from the first portion 51h along the x-direction, a portion extending obliquely, and a portion extending along the y-direction toward the second portion 52h.

The wiring 50c includes a first portion 51c and a second portion 52c.

The first portion 51c is located on the side of the fourth face 34 in the x-direction with respect to the first base portion 55, and spaced therefrom. The first portion 51c is located between the connecting portion 57 and the first portion 51H, in the y-direction. The first portion 51c overlaps with the first base portion 55, as viewed in the x-direction. The shape of the first portion 51c is not specifically limited. In the illustrated example, the first portion 51c has a rectangular shape.

The second portion 52c is located on the side of the fourth face 34 in the x-direction with respect to the first portion 51c, with a spacing therefrom, and on the side of the third face 33 in the x-direction with respect to the second base portion 56, with a spacing therefrom. The second portion 52c overlaps with the second base portion 56, as viewed in the x-direction. The shape of the second portion 52c is not specifically limited, and a desired shape may be selected from a rectangular shape, a polygonal shape, a circular shape, an elliptical shape, and so forth. In the illustrated example, the second portion 52c has a rectangular shape.

The wiring 50c includes a strip-shaped portion connecting the first portion 51c and the second portion 52c. The strip-shaped portion extends along the x-direction.

The wiring 50d includes a first portion 51d and a second portion 52d.

The first portion 51d is located on the side of the fourth face 34 in the x-direction with respect to the first base portion 55, with a spacing therefrom, and shifted toward the fourth face 34 from the first portion 51c. The first portion 51d is located between the connecting portion 57 and the first portion 51H in the y-direction, at a position shifted toward the fifth face 35 from the first portion 51c. In the illustrated example, the first portion 51d overlaps with the connecting portion 57, as viewed in the y-direction. The first portion 51d overlaps with the first base portion 55 and the first portion 51c, as viewed in the x-direction. The shape of the first portion 51d is not specifically limited. In the illustrated example, the first portion 51d has a polygonal shape.

The second portion 52d is located on the side of the fourth face 34 in the x-direction with respect to the first portion 51d, with a spacing therefrom, and on the side of the third face 33 in the x-direction with respect to the second base portion 56, with a spacing therefrom. The second portion 52d is located at a position shifted toward the fourth face 34 in the x-direction, from the second portion 52c. The second portion 52d overlaps with the second base portion 56, as viewed in the x-direction. The second portion 52d overlaps with the connecting portion 57, as viewed in the y-direction. The shape of the second portion 52d is not specifically limited, and a desired shape may be selected from a rectangular shape, a polygonal shape, a circular shape, an elliptical shape, and so forth. In the illustrated example, the second portion 52d has a polygonal shape.

The wiring 50d includes a strip-shaped portion connecting the first portion 51d and the second portion 52d. The strip-shaped portion extends along the x-direction.

The wiring 50e includes a first portion 51e and a second portion 52e.

The first portion 51e is located on the side of the fourth face 34 in the x-direction with respect to the first base portion 55, and spaced therefrom. The first portion 51e is located between the connecting portion 57 and the first portion 51H in the y-direction, at a position shifted toward the fifth face 35 from the first portion 51d. In the illustrated example, the first portion 51e overlaps with the connecting portion 57, as viewed in the y-direction. The first portion 51e overlaps with the first base portion 55 and the first portion 51d, as viewed in the x-direction. The shape of the first portion 51e is not specifically limited. In the illustrated example, the first portion 51e has a polygonal shape.

The second portion 52e is located on the side of the fourth face 34 in the x-direction with respect to the first portion 51e, with a spacing therefrom, and on the side of the third face 33 in the x-direction with respect to the second base portion 56, with a spacing therefrom. The second portion 52e is located at a position shifted toward the fourth face 34 in the x-direction, from the second portion 52d. The second portion 52e overlaps with the second base portion 56 and the second portion 52d, as viewed in the x-direction. The second portion 52e overlaps with the second portion 52d and the connecting portion 57, as viewed in the y-direction. The shape of the second portion 52e is not specifically limited, and a desired shape may be selected from a rectangular shape, a polygonal shape, a circular shape, an elliptical shape, and so forth. In the illustrated example, the second portion 52e has a polygonal shape.

The wiring 50e includes a strip-shaped portion connecting the first portion 51e and the second portion 52e. The strip-shaped portion extends along the x-direction.

The wiring 50g includes a first portion 51g and a second portion 52g.

The first portion 51g is located on the side of the fourth face 34 in the x-direction with respect to the first base portion 55, and spaced therefrom. The first portion 51g is located between the connecting portion 57 and the first portion 51H in the y-direction, at a position shifted toward the fifth face 35 from the first portion 51e. In the illustrated example, the first portion 51g overlaps with the connecting portion 57 and the first portion 51H, as viewed in the y-direction. The first portion 51g overlaps with the first portion 51H, as viewed in the x-direction. The shape of the first portion 51g is not specifically limited. In the illustrated example, the first portion 51g has a polygonal shape.

The second portion 52g is located on the side of the fourth face 34 in the x-direction with respect to the first portion 51g, with a spacing therefrom, and on the side of the third face 33 in the x-direction with respect to the second base portion 56, with a spacing therefrom. The second portion 52g overlaps with the first portion 51H, as viewed in the x-direction. The second portion 52g overlaps with the first portion 51H and the connecting portion 57, as viewed in the y-direction. The shape of the second portion 52g is not specifically limited, and a desired shape may be selected from a rectangular shape, a polygonal shape, a circular shape, an elliptical shape, and so forth. In the illustrated example, the second portion 52g has a polygonal shape.

The wiring 50g includes a strip-shaped portion connecting the first portion 51g and the second portion 52g. The strip-shaped portion extends along the x-direction.

The wiring 50f includes a first portion 51f and a second portion 52f.

The first portion 51f is located on the side of the fourth face 34 in the x-direction with respect to the second base portion 56, and spaced therefrom. The first portion 51f is located on the side of the sixth face 36 in the y-direction with respect to the wiring 50U, and spaced therefrom. In the illustrated example, the wiring 50f overlaps with the second base portion 56, as viewed in the x-direction. The wiring 50f overlaps with the wiring 50U, the first portion 51T, and the first portion 51S, as viewed in the y-direction. The shape of the first portion 51f is not specifically limited. In the illustrated example, the first portion 51f has a rectangular shape.

The second portion 52f is located on the side of the fourth face 34 in the x-direction with respect to the first portion 51f, and spaced therefrom. The second portion 52f overlaps with the second base portion 56 and the first portion 51f, as viewed in the x-direction. The second portion 52f overlaps with the wiring 50S, the wiring 50T, and the wiring 50U, as viewed in the y-direction. The shape of the second portion 52f is not specifically limited, and a desired shape may be selected from a rectangular shape, a polygonal shape, a circular shape, an elliptical shape, and so forth. In the illustrated example, the second portion 52f has a rectangular shape.

The wiring 50f includes a strip-shaped portion connecting the first portion 51f and the second portion 52f. The strip-shaped portion extends along the x-direction.

### <Bonding Section 6>

Regarding the bonding section 6 according to this embodiment, although any of the elements is apparently given, for the sake of convenience of description, the same numeral as that of the bonding section 6 according to the third embodiment, it does not necessarily mean that the mentioned element has the same or similar configuration. The configuration of an element with a numeral is defined by the description relevant to this embodiment. Regarding a portion or structure on which no specific description is given, a similar configuration to that of the bonding section 6 of the semiconductor device A3 may be adopted, as appropriate.

The plurality of bonding sections 6 are formed on the substrate 3. In this embodiment, the plurality of bonding sections 6 are formed on the first face 31 of the substrate 3. The bonding section 6 is formed of, for example, a conductive material. The conductive material to form the bonding section 6 is not specifically limited. Examples of the conductive material to form the bonding section 6 include materials containing silver (Ag), copper (Cu), or gold (Au). In the subsequent description, it will be assumed that the bonding section 6 contains silver. The bonding section 6 according to this embodiment contains the same conductive material as that employed to form the conductive section 5. However, the bonding section 6 may contain copper instead of silver, or gold instead of silver or copper. Alternatively, the conductive section 5 may contain Ag—Pt or Ag—Pd. The forming method of the bonding section 6 is not limited. For example, the bonding section 6 may be formed, like the conductive section 5, by sintering a paste containing the mentioned metal. The thickness of the bonding section 6 is not specifically limited, but may be, for example, approximately 5 μm to 30 μm.

In this embodiment, as shown in FIG. 58, the plurality of bonding sections 6 include a bonding sections 6A to 6D, and 6H.

The bonding section 6A is located on the side of the sixth face 36 with respect to the conductive section 5, in the y-direction. The bonding section 6A overlaps with the entirety of the first base portion 55, as viewed in the y-direction. The shape of the bonding section 6A is not specifically limited.

The bonding section 6B is located on the side of the sixth face 36 with respect to the conductive section 5, in the y-direction. The bonding section 6B is located on the side of the fourth face 34 with respect to the bonding section 6A, in the x-direction. In the illustrated example, the bonding section 6B overlaps with the connecting portion 57, the wirings 50c to 50g, and the second base portion 56, as viewed in the y-direction. The shape of the bonding section 6B is not specifically limited.

The bonding section 6C is located on the side of the sixth face 36 with respect to the conductive section 5, in the y-direction. The bonding section 6C is located on the side of the fourth face 34 with respect to the bonding section 6B, in the x-direction. In the illustrated example, the bonding section 6C overlaps with the wirings 50S to 50U, the wiring 50f, and the second base portion 56, as viewed in the y-direction. The shape of the bonding section 6C is not specifically limited.

The bonding section 6D is located on the side of the sixth face 36 with respect to the conductive section 5, in the y-direction. The bonding section 6D is located on the side of the fourth face 34 with respect to the bonding section 6C, in the x-direction. In the illustrated example, the bonding section 6D overlaps with the wirings 50S to 50U and the wiring 50f, and is spaced apart from the second base portion 56, as viewed in the y-direction. The shape of the bonding section 6D is not specifically limited.

The bonding section 6H is located on the side of the sixth face 36 with respect to the conductive section 5, in the y-direction. The bonding section 6D is shifted toward the third face 33 in the x-direction, from the bonding section 6A. In the illustrated example, the bonding section 6D overlaps with the bonding section 6A, as viewed in the x-direction and the y-direction. The shape of the bonding section 6H is not specifically limited.

### <Leads 1>

Regarding the lead 1 according to this embodiment, although any of the elements is apparently given, for the sake of convenience of description, the same numeral as that of the lead 1 according to the first embodiment, it does not necessarily mean that the mentioned element has the same or similar configuration. The configuration of an element with a numeral is defined by the description relevant to this embodiment. However, the configuration of the lead 1 of the semiconductor device A3 may be adopted, as appropriate. The plurality of leads 1 contain a metal, and have higher heat dissipation characteristics, for example than the substrate 3. The metal to form the lead 1 is not specifically limited, and may be, for example, copper (Cu), aluminum, iron (Fe), oxygen-free copper, or an alloy of the cited metals, such as a Cu—Sn alloy, a Cu—Zr alloy, or a Cu—Fe alloy. The plurality of leads 1 may be plated with nickel (Ni). Examples of the forming method of the plurality of leads 1 include pressing a metal plate with a die, and patterning a metal plate by etching, without limitation thereto. The thickness of the lead 1 is not specifically limited, but may be, for example, approximately 0.4 mm to 0.8 mm.

The plurality of leads 1 include a plurality of leads 1A to 1I, as shown in FIG. 58. The plurality of leads 1A to 1I constitute conduction paths to the semiconductor chips 4A to 4F, and 4X.

The lead 1A is located on the substrate 3 and, in this embodiment, on the first face 31. The lead 1A exemplifies a first lead in the present disclosure. The lead 1A is bonded to the bonding section 6A, via a bonding material 81. It is preferable to employ a material having high thermal conductivity as the bonding material 81, such as silver paste, copper paste, or solder. However, the bonding material 81 may be an insulative material such as an epoxy-based resin or a silicone-based resin. In the case where the bonding section 6A is not provided on the substrate 3, the lead 1A may be bonded to the substrate 3.

The configuration of the lead 1A is not specifically limited and, in this embodiment, the lead 1A includes a first portion 11A, a second portion 12A, a third portion 13A, and a fourth portion 14A, each of which will be described hereunder.

The first portion 11A overlaps with the substrate 3 as viewed in the z-direction, and is bonded to the bonding section 6A via the bonding material 81.

In the illustrated example, the first portion 11A includes a first portion 113A and a second portion 114A.

The first portion 113A occupies a majority of the first portion 11A. The first portion 113A overlaps with the second base portion 56, and the wirings 50a, 50b, and 50h, as viewed in the y-direction.

The second portion 114A is connected to the first portion 113A on the side of the third face 33, in the x-direction. The center of the second portion 114A in the y-direction is shifted toward the fifth face 35, from the center of the first portion 113A in the y-direction. In the illustrated example, the edge of the first portion 113A on the side of the fifth face 35 in the y-direction, and the edge of the second portion 114A on the side of the fifth face 35 in the y-direction generally coincide with each other, as viewed in the x-direction. Here, the expression “generally coincide” as viewed in the x-direction refers to, for example, exactly coinciding with each other, or being deviated by within ±5% of the characteristic size (size of the first portion 113A or second portion 114A in the y-direction).

The third portion 13A and the fourth portion 14A are covered with the encapsulating resin 7. The third portion 13A is connected to the first portion 11A and the fourth portion 14A. In the illustrated example, the third portion 13A is connected to the first portion 11A. In addition, the third portion 13A is spaced apart from the sixth face 36, as viewed in the z-direction. The fourth portion 14A is shifted from the first portion 11A in the z-direction. The end portion of the fourth portion 14A is flush with a sixth face 76 of the resin 7.

The second portion 12A is connected to the end portion of the fourth portion 14A, and corresponds to a portion of the lead 1A sticking out from the encapsulating resin 7. The second portion 12A sticks out to the opposite side of the first portion 11A, in the y-direction. The second portion 12A is used, for example, to electrically connect the semiconductor device A7 to an external circuit. The second portion 12A is bent, for example, in the z-direction.

The lead 1B is located on the substrate 3 and, in this embodiment, on the first face 31. The lead 1B exemplifies a first lead in the present disclosure. The lead 1B is bonded to the bonding section 6B, via the bonding material 81. In the case where the bonding section 6B is not provided on the substrate 3, the lead 1B may be bonded to the substrate 3.

The configuration of the lead 1B is not specifically limited. In this embodiment, the lead 1B includes a first portion 11B, a second portion 12B, a third portion 13B, and a fourth portion 14B, each of which will be described hereunder.

The first portion 11B overlaps with the substrate 3 as viewed in the z-direction, and is bonded to the bonding section 6B via the bonding material 81. The first portion 11B overlaps with the second base portion 56, as viewed in the y-direction

The third portion 13B and the fourth portion 14B are covered with the encapsulating resin 7. The third portion 13B is connected to the first portion 11B and the fourth portion 14B. In the illustrated example, the third portion 13B is connected to the first portion 11B. In addition, the third portion 13B overlaps with the sixth face 36, as viewed in the z-direction. The fourth portion 14B is shifted from the first portion 11B in the z-direction. The end portion of the fourth portion 14B is flush with the sixth face 76 of the resin 7.

The second portion 12B is connected to the fourth portion 14B, and corresponds to a portion of the lead 1B sticking out from the encapsulating resin 7. The second portion 12B sticks out to the opposite side of the first portion 11B, in the y-direction. The second portion 12B is used, for example, to electrically connect the semiconductor device A7 to an external circuit. In the illustrated example, the second portion 12B is bent, for example, in the z-direction.

The lead 1C is located on the substrate 3 and, in this embodiment, on the first face 31. The lead 1C exemplifies a first lead in the present disclosure. The lead 1C is bonded to the bonding section 6C, via the bonding material 81. In the case where the bonding section 6C is not provided on the substrate 3, the lead 1C may be bonded to the substrate 3.

The configuration of the lead 1C is not specifically limited. In this embodiment, the lead 1C includes a first portion 11C, a second portion 12C, a third portion 13C, and a fourth portion 14C, each of which will be described hereunder.

The first portion 11C overlaps with the substrate 3 as viewed in the z-direction, and is bonded to the bonding section 6C via the bonding material 81. The first portion 11C overlaps with the second base portion 56, as viewed in the y-direction

The third portion 13C and the fourth portion 14C are covered with the encapsulating resin 7. The third portion 13C is connected to the first portion 11C and the fourth portion 14C. In the illustrated example, the third portion 13C is connected to the first portion 11C. The fourth portion 14C is, like the fourth portion 14B of the lead 1B, shifted from the first portion 11C in the z-direction. The end portion of the fourth portion 14C is flush with the sixth face 76 of the resin 7.

The second portion 12C is connected to the end portion of the fourth portion 14C, and corresponds to a portion of the lead 1C sticking out from the encapsulating resin 7. The second portion 12C sticks out to the opposite side of the first portion 11C, in the y-direction. The second portion 12C is used, for example, to electrically connect the semiconductor device A7 to an external circuit. In the illustrated example, the second portion 12C is bent, for example, in the z-direction.

The lead 1D is located on the substrate 3 and, in this embodiment, on the first face 31. The lead 1D exemplifies a first lead in the present disclosure. The lead 1D is bonded to the bonding section 6D, via the bonding material 81. In the case where the bonding section 6D is not provided on the substrate 3, the lead 1D may be bonded to the substrate 3.

The configuration of the lead 1D is not specifically limited. In this embodiment the lead 1D includes, as shown in FIG. 4 and FIG. 14, a first portion 11D, a second portion 12D, a third portion 13D, and a fourth portion 14D, each of which will be described hereunder.

The first portion 11D overlaps with the substrate 3 as viewed in the z-direction, and is bonded to the bonding section 6D via the bonding material 81. The first portion 11D overlaps with the second base portion 56, as viewed in the y-direction

The third portion 13D and the fourth portion 14D are covered with the encapsulating resin 7. The third portion 13D is connected to the first portion 11D and the fourth portion 14D. In the illustrated example, the third portion 13D is connected to the first portion 11D. The fourth portion 14D is, like the fourth portion 14B of the lead 1B, shifted from the first portion 11D in the z-direction. The end portion of the fourth portion 14D is flush with the sixth face 76 of the resin 7.

The second portion 12D is connected to the end portion of the fourth portion 14D, and corresponds to a portion of the lead 1D sticking out from the encapsulating resin 7. The second portion 12D sticks out to the opposite side of the first portion 11D, in the y-direction. The second portion 12D is used, for example, to electrically connect the semiconductor device A7 to an external circuit. In the illustrated example, the second portion 12D is bent, for example, in the z-direction.

The lead 1E is spaced apart from the substrate 3, as viewed in the z-direction. In this embodiment, the lead 1E located on the side to which the sixth face 36 is oriented, with respect to the substrate 3 in the y-direction.

The configuration of the lead 1E is not specifically limited. In this embodiment the lead 1E includes a second portion 12E and a fourth portion 14E, each of which will be described hereunder.

The fourth portion 14E is covered with the encapsulating resin 7. The fourth portion 14E is, like the fourth portion 14D of the lead 1D, shifted from the first portion 11E in the z-direction. The fourth portion 14E overlaps with the first portion 11C and the first portion 11D, as viewed in the y-direction. The end portion of the fourth portion 14E is flush with the sixth face 76 of the resin 7.

The second portion 12E is connected to the end portion of the fourth portion 14E, and corresponds to a portion of the lead 1E sticking out from the encapsulating resin 7. The second portion 12E sticks out to the opposite side of the fourth portion 14E, in the y-direction. The second portion 12E is used, for example, to electrically connect the semiconductor device A7 to an external circuit. In the illustrated example, the second portion 12E is bent, for example, in the z-direction.

The lead 1F is spaced apart from the substrate 3, as viewed in the z-direction. In this embodiment, the lead 1F is located on the side to which the sixth face 36 is oriented, with respect to the substrate 3 in the y-direction. The lead 1F is located on the opposite side of the fourth portion 14D, across the lead 1E.

The configuration of the lead 1F is not specifically limited. In this embodiment the lead 1F includes a second portion 12F and a fourth portion 14F, each of which will be described hereunder.

The fourth portion 14F is covered with the encapsulating resin 7. The fourth portion 14F is, like the fourth portion 14D of the lead 1D, shifted from the first portion 11F in the z-direction. The fourth portion 14F overlaps with the first portion 11D, as viewed in the y-direction. The end portion of the fourth portion 14F is flush with the sixth face 76 of the resin 7.

The second portion 12F is connected to the end portion of the fourth portion 14F, and corresponds to a portion of the lead 1F sticking out from the encapsulating resin 7. The second portion 12F sticks out to the opposite side of the fourth portion 14F, in the y-direction. The second portion 12F is used, for example, to electrically connect the semiconductor device A7 to an external circuit. In the illustrated example, the second portion 12F is bent, for example, in the z-direction.

The lead 1G is spaced apart from the substrate 3, as viewed in the z-direction. In this embodiment, the lead 1G is located on the side to which the fourth face 34 is oriented, with respect to the substrate 3 in the x-direction. The lead 1G is located on the opposite side of the fourth portion 14E, across the lead 1F.

The configuration of the lead 1G is not specifically limited. In this embodiment the lead 1G includes a second portion 12G and a fourth portion 14G, each of which will be described hereunder.

The fourth portion 14G is covered with the encapsulating resin 7. The fourth portion 14G is, like the fourth portion 14D of the lead 1D, shifted from the first portion 11G in the z-direction. The fourth portion 14G overlaps with the fourth portion 14F, as viewed in the y-direction. In addition, the fourth portion 14G overlaps with the first portion 11D, as viewed in the x-direction. The end portion of the fourth portion 14G is flush with the sixth face 76 of the resin 7.

The second portion 12G is connected to the fourth portion 14G, and corresponds to a portion of the lead 1G sticking out from the encapsulating resin 7. The second portion 12G sticks out to the opposite side of the fourth portion 14G, in the y-direction. The second portion 12G is used, for example, to electrically connect the semiconductor device A7 to an external circuit. In the illustrated example, the second portion 12G is bent, for example, in the z-direction.

The lead 1H is located on the substrate 3 and, in this embodiment, on the first face 31. The lead 1H exemplifies a first lead in the present disclosure. The lead 1H is bonded to the bonding section 6H, via the bonding material 81. In the case where the bonding section 6H is not provided on the substrate 3, the lead 1H may be bonded to the substrate 3.

The configuration of the lead 1H is not specifically limited. In this embodiment the lead 1H includes, as shown in FIG. 4 and FIG. 14, a first portion 11H, a second portion 12H, a third portion 13H, and a fourth portion 14H, each of which will be described hereunder.

The first portion 11H overlaps with the substrate 3 as viewed in the z-direction, and is bonded to the bonding section 6H via the bonding material 81.

In the illustrated example, the first portion 11H includes a first portion 113H and a second portion 114H.

The first portion 113H occupies a majority of the first portion 11H. The first portion 113H is located on the side of the third face 33 with respect to the first portion 113A, as viewed in the x-direction. The first portion 113H overlaps with the first portion 113A, as viewed in the x-direction. The first portion 113H is located on the side of the sixth face 36 in the y-direction, with respect to the second portion 114A. The first portion 113H overlaps with the second portion 114A, as viewed in the y-direction.

The second portion 114H is connected to the first portion 113H on the side of the fifth face 35, in the y-direction. The center of the second portion 114H in the x-direction is shifted toward the third face 33, from the center of the first portion 113H in the x-direction. The second portion 114H overlaps with the second portion 114A, as viewed in the x-direction. The second portion 114H is spaced apart from the second portion 114A, as viewed in the y-direction. In the illustrated example, the edge of the first portion 113H on the side of the third face 33 in the x-direction, and the edge of the second portion 114H on the side of the third face 33 in the x-direction generally coincide with each other, as viewed in the y-direction. Here, the expression “generally coincide” as viewed in the y-direction refers to, for example, exactly coinciding with each other, or being deviated by within ±5% of the characteristic size (size of the first portion 113H or second portion 114H in the x-direction).

The third portion 13H and the fourth portion 14H are covered with the encapsulating resin 7. The third portion 13H is connected to the first portion 11H and the fourth portion 14H. In the illustrated example, the third portion 13H is connected to the first portion 11H. In addition, the third portion 13H is spaced apart from the sixth face 36, as viewed in the z-direction. The fourth portion 14H is shifted from the first portion 11H in the z-direction. The end portion of the fourth portion 14H is flush with a sixth face 76 of the resin 7.

The second portion 12H is connected to the end portion of the fourth portion 14H, and corresponds to a portion of the lead 1H sticking out from the encapsulating resin 7. The second portion 12H sticks out to the opposite side of the first portion 11H, in the y-direction. The second portion 12H is used, for example, to electrically connect the semiconductor device A7 to an external circuit. The second portion 12H is bent, for example, in the z-direction.

The lead 1I is spaced apart from the substrate 3, as viewed in the z-direction. In this embodiment, the lead 1I located on the side to which the sixth face 36 is oriented, with respect to the substrate 3 in the y-direction. In addition, the lead 1I is located on the opposite side of the fourth portion 14A across the lead 1H, in the x-direction.

The configuration of the lead 1I is not specifically limited. In this embodiment the lead 1I includes a second portion 12I and a fourth portion 14I, each of which will be described hereunder.

The fourth portion 14I is covered with the encapsulating resin 7. The fourth portion 14I is, like the fourth portion 14D of the lead 1D, shifted from the first portion 11I in the z-direction. The fourth portion 14I overlaps with the first portion 11H, as viewed in the y-direction. In addition, the fourth portion 14I overlaps with the fourth portion 14H, as viewed in the x-direction. The end portion of the fourth portion 14I is flush with the sixth face 76 of the resin 7.

The second portion 12I is connected to the fourth portion 14I, and corresponds to a portion of the lead 1I sticking out from the encapsulating resin 7. The second portion 12I sticks out to the opposite side of the fourth portion 14I, in the y-direction. The second portion 12I is used, for example, to electrically connect the semiconductor device A33 to an external circuit. In the illustrated example, the second portion 12I is bent, for example, in the z-direction.

### <Leads 2>

Regarding the lead 2 according to this embodiment, although any of the elements is apparently given, for the sake of convenience of description, the same numeral as that of the lead 2 according to the third embodiment, it does not necessarily mean that the mentioned element has the same or similar configuration. The configuration of an element with a numeral is defined by the description relevant to this embodiment. Regarding an element on which no specific description is given, a similar configuration to that of the corresponding element of the lead 2 of the semiconductor device A3 may be adopted, as appropriate.

The plurality of leads 2 contain a metal, and have higher heat dissipation characteristics, for example than the substrate 3. The metal to form the lead 2 is not specifically limited, and may be, for example, copper (Cu), aluminum, iron (Fe), oxygen-free copper, or an alloy of the cited metals, such as a Cu—Sn alloy, a Cu—Zr alloy, or a Cu—Fe alloy. The plurality of leads 2 may be plated with nickel (Ni). Examples of the forming method of the plurality of leads 2 include pressing a metal plate with a die, and patterning a metal plate by etching, without limitation thereto. The thickness of the lead 2 is not specifically limited, but may be, for example, approximately 0.4 mm to 0.8 mm. The plurality of leads 2 are located so as to overlap with the second region 30B of the substrate 3, as viewed in the z-direction.

In this embodiment, the plurality of leads 2 include a plurality of leads 2A to 2V, as shown in FIG. 58 and FIG. 59. The plurality of leads 2A to 2H, and 2S to 2O respectively constitute conduction paths to the control chips 4G and 4H. The plurality of leads 2I to 2R, and 2V constitute conduction paths to the primary-side circuit chip 4J.

The lead 2A is spaced apart from the plurality of leads 1. The lead 2A is located on the conductive section 5. The lead 2A is electrically connected to the conductive section 5. The lead 2A exemplifies a second lead in the present disclosure. The lead 2A is bonded to the second portion 52A of the wiring 50A in the conductive section 5, via a conductive bonding material 82. The conductive bonding material 82 may be any material that is capable of bonding, and electrically connecting, the lead 2A to the second may be employed as the conductive bonding material 82. The conductive bonding material 82 corresponds to the first conductive bonding material in the present disclosure.

The configuration of the lead 2A is not specifically limited. In this embodiment the lead 2A includes, like that of the semiconductor device A3, a first portion 21A, a second portion 22A, a third portion 23A, and a fourth portion 24A, each of which will be described hereunder.

The first portion 21A is bonded to the second portion 52A of the wiring 50A. The shape of the first portion 21A is not specifically limited, and a desired shape may be selected from a rectangular shape, a polygonal shape, a circular shape, an elliptical shape, and so forth. In the illustrated example, the first portion 21A has a bent shape including a portion extending along the x-direction, and a portion extending along the y-direction. The first portion 21A overlaps with the third face 33 of the substrate 3 as viewed in the z-direction, and sticks out in the x-direction, toward the side to which the third face 33 is oriented.

The third portion 23A and the fourth portion 24A are covered with the encapsulating resin 7. The third portion 23A is connected to the first portion 21A and the fourth portion 24A. The fourth portion 24A is shifted in the z-direction with respect to the first portion 21A. The end portion of the fourth portion 24A is flush with a fifth face 75 of the resin 7. In the illustrated example, the third portion 23A and the fourth portion 24A generally coincide with each other, as viewed in the y-direction. Here, the expression “generally coincide” as viewed in the y-direction refers to, for example, exactly coinciding with each other, or being deviated by within ±5% of the characteristic size (size of the third portion 23A, or fourth portion 24A in the x-direction).

The second portion 22A is connected to the end portion of the fourth portion 24A, and corresponds to a portion of the lead 2A sticking out from the encapsulating resin 7 to the opposite side of the plurality of leads 1, as viewed in the y-direction. The second portion 22A sticks out to the opposite side of the first portion 21A, in the y-direction. The second portion 22A is used, for example, to electrically connect the semiconductor device A7 to an external circuit. In the illustrated example, the second portion 22A is bent, for example, in the z-direction. The second portion 22A, the third portion 23A, and the fourth portion 24A each include, on the respective sides thereof in the x-direction, edges extending along the y-direction.

The lead 2B is spaced apart from the plurality of leads 1. The lead 2B is located on the conductive section 5. The lead 2B is electrically connected to the conductive section 5. The lead 2B exemplifies a second lead in the present disclosure. The lead 2B is bonded to the second portion 52B of the wiring 50B in the conductive section 5, via the conductive bonding material 82.

The configuration of the lead 2B is not specifically limited. In this embodiment, the lead 2B includes a first portion 21B, a second portion 22B, a third portion 23B, and a fourth portion 24B, each of which will be described hereunder.

The first portion 21B is bonded to the second portion 52B of the wiring 50B. The shape of the first portion 21B is not specifically limited, and a desired shape may be selected from a rectangular shape, a polygonal shape, a circular shape, an elliptical shape, and so forth. In the illustrated example, the first portion 21B has a bent shape including a portion extending along the x-direction, and a portion extending along the y-direction. The first portion 21B overlaps with the third face 33 of the substrate 3 as viewed in the z-direction, and sticks out in the x-direction, toward the side to which the third face 33 is oriented. In the illustrated example, the first portion 21B overlaps with the second portion 52B, as viewed in the z-direction.

The third portion 23B and the fourth portion 24B are covered with the encapsulating resin 7. The third portion 23B is connected to the first portion 21B and the fourth portion 24B. The fourth portion 24B is shifted in the z-direction with respect to the first portion 21B. The end portion of the fourth portion 24B is flush with the fifth face 75 of the resin 7. In the illustrated example, the third portion 23B and the fourth portion 24B generally coincide with each other, as viewed in the y-direction. Here, the expression “generally coincide” as viewed in the y-direction refers to, for example, exactly coinciding with each other, or being deviated by within ±5% of the characteristic size (size of the third portion 23B or fourth portion 24B in the x-direction).

The second portion 22B is connected to the end portion of the fourth portion 24B, and corresponds to a portion of the lead 2B sticking out from the encapsulating resin 7 to the opposite side of the plurality of leads 1, as viewed in the y-direction. The second portion 22B sticks out to the opposite side of the first portion 21B, in the y-direction. The second portion 22B is used, for example, to electrically connect the semiconductor device A7 to an external circuit. In the illustrated example, the second portion 22B is bent, for example, in the z-direction. The second portion 22B, the third portion 23B, and the fourth portion 24B each include, on the respective sides thereof in the x-direction, edges extending along the y-direction. The edges of the second portion 22B, the third portion 23B, and the fourth portion 24B, on the side of the third face 33 in the x-direction, are respectively opposed to the edges of the second portion 22A, the third portion 23A, and the fourth portion 24A, on the side of the fourth face 34 in the x-direction.

The lead 2C is spaced apart from the plurality of leads 1. The lead 2C is located on the conductive section 5. The lead 2C is electrically connected to the conductive section 5. The lead 2C exemplifies a second lead in the present disclosure. The lead 2C is bonded to the second portion 52C of the wiring 50C in the conductive section 5, via the conductive bonding material 82.

The configuration of the lead 2C is not specifically limited. In this embodiment, the lead 2C includes a first portion 21C, a second portion 22C, a third portion 23C, and a fourth portion 24C, each of which will be described hereunder.

The first portion 21C is bonded to the second portion 52C of the wiring 50C. The shape of the first portion 21C is not specifically limited, and a desired shape may be selected from a rectangular shape, a polygonal shape, a circular shape, an elliptical shape, and so forth. In the illustrated example, the first portion 21C has a strip shape extending along the y-direction. The first portion 21C overlaps with the fifth face 35 of the substrate 3 as viewed in the z-direction, and sticks out in the y-direction toward the side to which the fifth face 35 is oriented. In the illustrated example, the first portion 21C overlaps with the second portion 52C, as viewed in the z-direction.

The third portion 23C and the fourth portion 24C are covered with the encapsulating resin 7. The third portion 23C is connected to the first portion 21C and the fourth portion 24C. The fourth portion 24C is shifted in the z-direction with respect to the first portion 21C. The end portion of the fourth portion 24C is flush with the fifth face 75 of the resin 7. In the illustrated example, the third portion 23C and the fourth portion 24C generally coincide with each other, as viewed in the y-direction. Here, the expression “generally coincide” as viewed in the y-direction refers to, for example, exactly coinciding with each other, or being deviated by within ±5% of the characteristic size (size of the third portion 23C or fourth portion 24C in the x-direction).

The second portion 22C is connected to the end portion of the fourth portion 24C, and corresponds to a portion of the lead 2C sticking out from the encapsulating resin 7 to the opposite side of the plurality of leads 1, as viewed in the y-direction. The second portion 22C sticks out to the opposite side of the first portion 21C, in the y-direction. The second portion 22C is used, for example, to electrically connect the semiconductor device A7 to an external circuit. In the illustrated example, the second portion 22C is bent, for example, in the z-direction. The second portion 22C, the third portion 23C, and the fourth portion 24C each include, on the respective sides thereof in the x-direction, edges extending along the y-direction. The edges of the second portion 22C, the third portion 23C, and the fourth portion 24C, on the side of the third face 33 in the x-direction, are respectively opposed to the edges of the second portion 22B, the third portion 23B, and the fourth portion 24B, on the side of the fourth face 34 in the x-direction.

The lead 2D is spaced apart from the plurality of leads 1. The lead 2D is located on the conductive section 5. The lead 2D is electrically connected to the conductive section 5. The lead 2D exemplifies a second lead in the present disclosure. The lead 2D is bonded to the second portion 52D of the wiring 50D in the conductive section 5, via the conductive bonding material 82.

The configuration of the lead 2D is not specifically limited. In this embodiment, as shown in FIG. 59, the lead 2D includes a first portion 21D, a second portion 22D, a third portion 23D, and a fourth portion 24D, each of which will be described hereunder.

The first portion 21D is bonded to the second portion 52D of the wiring 50D. The shape of the first portion 21D is not specifically limited, and a desired shape may be selected from a rectangular shape, a polygonal shape, a circular shape, an elliptical shape, and so forth. In the illustrated example, the first portion 21D has a strip shape extending along the y-direction. The first portion 21D overlaps with the fifth face 35 of the substrate 3 as viewed in the z-direction, and sticks out in the y-direction toward the side to which the fifth face 35 is oriented. In the illustrated example, the first portion 21D overlaps with the second portion 52D, as viewed in the z-direction.

The third portion 23D and the fourth portion 24D are covered with the encapsulating resin 7. The third portion 23D is connected to the first portion 21D and the fourth portion 24D. The fourth portion 24D is shifted in the z-direction with respect to the first portion 21D. The end portion of the fourth portion 24D is flush with the fifth face 75 of the resin 7. In the illustrated example, the third portion 23D and the fourth portion 24D generally coincide with each other, as viewed in the y-direction. Here, the expression “generally coincide” as viewed in the y-direction refers to, for example, exactly coinciding with each other, or being deviated by within ±5% of the characteristic size (size of the third portion 23D or fourth portion 24D in the x-direction).

The second portion 22D is connected to the end portion of the fourth portion 24D, and corresponds to a portion of the lead 2D sticking out from the encapsulating resin 7 to the opposite side of the plurality of leads 1, as viewed in the y-direction. The second portion 22D sticks out to the opposite side of the first portion 21D, in the y-direction. The second portion 22D is used, for example, to electrically connect the semiconductor device A7 to an external circuit. In the illustrated example, the second portion 22D is bent in the z-direction. The second portion 22D, the third portion 23D, and the fourth portion 24D each include, on the respective sides thereof in the x-direction, edges extending along the y-direction. The edges of the second portion 22D, the third portion 23D, and the fourth portion 24D, on the side of the third face 33 in the x-direction, are respectively opposed to the edges of the second portion 22C, the third portion 23C, and the fourth portion 24C, on the side of the fourth face 34 in the x-direction.

The lead 2E is spaced apart from the plurality of leads 1. The lead 2E is located on the conductive section 5. The lead 2E is electrically connected to the conductive section 5. The lead 2E exemplifies a second lead in the present disclosure. The lead 2E is bonded to the second portion 52E of the wiring 50E in the conductive section 5, via the conductive bonding material 82.

The configuration of the lead 2E is not specifically limited. In this embodiment, as shown in FIG. 59, the lead 2E includes a first portion 21E, a second portion 22E, a third portion 23E, and a fourth portion 24E, each of which will be described hereunder.

The first portion 21E is bonded to the second portion 52E of the wiring 50E. The shape of the first portion 21E is not specifically limited, and a desired shape may be selected from a rectangular shape, a polygonal shape, a circular shape, an elliptical shape, and so forth. In the illustrated example, the first portion 21E has a strip shape extending along the y-direction. The first portion 21E overlaps with the fifth face 35 of the substrate 3 as viewed in the z-direction, and sticks out in the y-direction toward the side to which the fifth face 35 is oriented. In the illustrated example, the first portion 21E overlaps with the second portion 52E, as viewed in the z-direction.

The third portion 23E and the fourth portion 24E are covered with the encapsulating resin 7. The third portion 23E is connected to the first portion 21E and the fourth portion 24E. The fourth portion 24E is shifted in the z-direction with respect to the first portion 21E. The end portion of the fourth portion 24E is flush with the fifth face 75 of the resin 7. In the illustrated example, the third portion 23E and the fourth portion 24E generally coincide with each other, as viewed in the y-direction. Here, the expression “generally coincide” as viewed in the y-direction refers to, for example, exactly coinciding with each other, or being deviated by within ±5% of the characteristic size (size of the third portion 23E or fourth portion 24E in the x-direction).

The second portion 22E is connected to the end portion of the fourth portion 24E, and corresponds to a portion of the lead 2E sticking out from the encapsulating resin 7 to the opposite side of the plurality of leads 1, as viewed in the y-direction. The second portion 22E sticks out to the opposite side of the first portion 21E, in the y-direction. The second portion 22E is used, for example, to electrically connect the semiconductor device A7 to an external circuit. In the illustrated example, the second portion 22E is bent in the z-direction. The second portion 22E, the third portion 23E, and the fourth portion 24E each include, on the respective sides thereof in the x-direction, edges extending along the y-direction. The edges of the second portion 22E, the third portion 23E, and the fourth portion 24E, on the side of the third face 33 in the x-direction, are respectively opposed to the edges of the second portion 22D, the third portion 23D, and the fourth portion 24D, on the side of the fourth face 34 in the x-direction.

The lead 2F is spaced apart from the plurality of leads 1. The lead 2F is located on the conductive section 5. The lead 2F is electrically connected to the conductive section 5. The lead 2F exemplifies a second lead in the present disclosure. The lead 2F is bonded to the second portion 52F of the wiring 50F in the conductive section 5, via the conductive bonding material 82.

The configuration of the lead 2F is not specifically limited. In this embodiment, the lead 2F includes a first portion 21F, a second portion 22F, a third portion 23F, and a fourth portion 24F, each of which will be described hereunder.

The first portion 21F is bonded to the second portion 52F of the wiring 50F. The shape of the first portion 21F is not specifically limited, and a desired shape may be selected from a rectangular shape, a polygonal shape, a circular shape, an elliptical shape, and so forth. In the illustrated example, the first portion 21F has a strip shape extending along the y-direction. The first portion 21F overlaps with the fifth face 35 of the substrate 3 as viewed in the z-direction, and sticks out in the y-direction toward the side to which the fifth face 35 is oriented. In the illustrated example, the first portion 21F overlaps with the second portion 52F, as viewed in the z-direction.

The third portion 23F and the fourth portion 24F are covered with the encapsulating resin 7. The third portion 23F is connected to the first portion 21F and the fourth portion 24F. The fourth portion 24F is shifted in the z-direction with respect to the first portion 21F. The end portion of the fourth portion 24F is flush with the fifth face 75 of the resin 7. In the illustrated example, the third portion 23F and the fourth portion 24F generally coincide with each other, as viewed in the y-direction. Here, the expression “generally coincide” as viewed in the y-direction refers to, for example, exactly coinciding with each other, or being deviated by within ±5% of the characteristic size (size of the third portion 23F or fourth portion 24F in the x-direction).

The second portion 22F is connected to the end portion of the fourth portion 24F, and corresponds to a portion of the lead 2F sticking out from the encapsulating resin 7 to the opposite side of the plurality of leads 1, as viewed in the y-direction. The second portion 22F sticks out to the opposite side of the first portion 21F, in the y-direction. The second portion 22F is used, for example, to electrically connect the semiconductor device A7 to an external circuit. In the illustrated example, the second portion 22F is bent, for example, in the z-direction. The second portion 22F, the third portion 23F, and the fourth portion 24F each include, on the respective sides thereof in the x-direction, edges extending along the y-direction. The edges of the second portion 22F, the third portion 23F, and the fourth portion 24F, on the side of the third face 33 in the x-direction, are respectively opposed to the edges of the second portion 22E, the third portion 23E, and the fourth portion 24E, on the side of the fourth face 34 in the x-direction.

The lead 2G is spaced apart from the plurality of leads 1. The lead 2G is located on the conductive section 5. The lead 2G is electrically connected to the conductive section 5. The lead 2G exemplifies a second lead in the present disclosure. The lead 2G is bonded to the second portion 52G of the wiring 50G in the conductive section 5, via the conductive bonding material 82.

The configuration of the lead 2G is not specifically limited. In this embodiment, the lead 2G includes a first portion 21G, a second portion 22G, a third portion 23G, and a fourth portion 24G, each of which will be described hereunder.

The first portion 21G is bonded to the second portion 52G of the wiring 50G. The shape of the first portion 21G is not specifically limited, and a desired shape may be selected from a rectangular shape, a polygonal shape, a circular shape, an elliptical shape, and so forth. In the illustrated example, the first portion 21G has a strip shape extending along the y-direction. The first portion 21G overlaps with the fifth face 35 of the substrate 3 as viewed in the z-direction, and sticks out in the y-direction toward the side to which the fifth face 35 is oriented. In the illustrated example, the first portion 21G overlaps with the second portion 52G, as viewed in the z-direction.

The third portion 23G and the fourth portion 24G are covered with the encapsulating resin 7. The third portion 23G is connected to the first portion 21G and the fourth portion 24G. The fourth portion 24G is shifted in the z-direction with respect to the first portion 21G. The end portion of the fourth portion 24G is flush with the fifth face 75 of the resin 7. In the illustrated example, the third portion 23G and the fourth portion 24G generally coincide with each other, as viewed in the y-direction. Here, the expression “generally coincide” as viewed in the y-direction refers to, for example, exactly coinciding with each other, or being deviated by within ±5% of the characteristic size (size of the third portion 23G or fourth portion 24G in the x-direction).

The second portion 22G is connected to the end portion of the fourth portion 24G, and corresponds to a portion of the lead 2G sticking out from the encapsulating resin 7 to the opposite side of the plurality of leads 1, as viewed in the y-direction. The second portion 22G sticks out to the opposite side of the first portion 21G, in the y-direction. The second portion 22G is used, for example, to electrically connect the semiconductor device A7 to an external circuit. In the illustrated example, the second portion 22G is bent, for example, in the z-direction. The second portion 22G, the third portion 23G, and the fourth portion 24G each include, on the respective sides thereof in the x-direction, edges extending along the y-direction. The edges of the second portion 22G, the third portion 23G, and the fourth portion 24G, on the side of the third face 33 in the x-direction, are respectively opposed to the edges of the second portion 22F, the third portion 23F, and the fourth portion 24F, on the side of the fourth face 34 in the x-direction.

The lead 2H is spaced apart from the plurality of leads 1. The lead 2H is located on the conductive section 5. The lead 2H is electrically connected to the conductive section 5. The lead 2H exemplifies a second lead in the present disclosure. The lead 2H is bonded to the second portion 52H of the wiring 50H in the conductive section 5, via the conductive bonding material 82.

The configuration of the lead 2H is not specifically limited. In this embodiment, the lead 2H includes a first portion 21H, a second portion 22H, a third portion 23H, and a fourth portion 24H, each of which will be described hereunder.

The first portion 21H is bonded to the second portion 52H of the wiring 50H. The shape of the first portion 21H is not specifically limited, and a desired shape may be selected from a rectangular shape, a polygonal shape, a circular shape, an elliptical shape, and so forth. In the illustrated example, the first portion 21H has a strip shape extending along the y-direction. The first portion 21H overlaps with the fifth face 35 of the substrate 3 as viewed in the z-direction, and sticks out in the y-direction toward the side to which the fifth face 35 is oriented. In the illustrated example, the first portion 21H overlaps with the second portion 52H, as viewed in the z-direction.

The third portion 23H and the fourth portion 24H are covered with the encapsulating resin 7. The third portion 23H is connected to the first portion 21H and the fourth portion 24H. The fourth portion 24H is shifted in the z-direction with respect to the first portion 21H. The end portion of the fourth portion 24H is flush with the fifth face 75 of the resin 7. In the illustrated example, the third portion 23H and the fourth portion 24H generally coincide with each other, as viewed in the y-direction. Here, the expression “generally coincide” as viewed in the y-direction refers to, for example, exactly coinciding with each other, or being deviated by within ±5% of the characteristic size (size of the third portion 23H or fourth portion 24H in the x-direction).

The second portion 22H is connected to the end portion of the fourth portion 24H, and corresponds to a portion of the lead 2H sticking out from the encapsulating resin 7 to the opposite side of the plurality of leads 1, as viewed in the y-direction. The second portion 22H sticks out to the opposite side of the first portion 21H, in the y-direction. The second portion 22H is used, for example, to electrically connect the semiconductor device A7 to an external circuit. In the illustrated example, the second portion 22H is bent, for example, in the z-direction. The second portion 22H, the third portion 23H, and the fourth portion 24H each include, on the respective sides thereof in the x-direction, edges extending along the y-direction. The edges of the second portion 22H, the third portion 23H, and the fourth portion 24H, on the side of the third face 33 in the x-direction, are respectively opposed to the edges of the second portion 22G, the third portion 23G, and the fourth portion 24G, on the side of the fourth face 34 in the x-direction.

The lead 2V is spaced apart from the plurality of leads 1. The lead 2V is located on the conductive section 5. The lead 2V is electrically connected to the conductive section 5. The lead 2V exemplifies a second lead in the present disclosure. The lead 2V is bonded to the second portion 52V of the wiring 50V in the conductive section 5, via the conductive bonding material 82.

The configuration of the lead 2V is not specifically limited. In this embodiment, as shown in FIG. 59, the lead 2V includes a first portion 21V, a second portion 22V, a third portion 23V, and a fourth portion 24V, each of which will be described hereunder.

The first portion 21V is bonded to the second portion 52V of the wiring 50V. The shape of the first portion 21V is not specifically limited, and a desired shape may be selected from a rectangular shape, a polygonal shape, a circular shape, an elliptical shape, and so forth. In the illustrated example, the first portion 21V has a strip shape extending along the y-direction. The first portion 21V overlaps with the fifth face 35 as viewed in the z-direction, and includes a portion extending from the fifth face 35 along the y-direction, toward the side to which the fifth face 35 is oriented. In the illustrated example, the first portion 21V overlaps with the second portion 52V, as viewed in the z-direction.

The third portion 23V and the fourth portion 24V are covered with the encapsulating resin 7. The third portion 23V is connected to the first portion 21V and the fourth portion 24V. The fourth portion 24V is shifted in the z-direction with respect to the first portion 21V. The end portion of the fourth portion 24V is flush with the fifth face 75 of the resin 7. In the illustrated example, the first portion 21V, the third portion 23V, and the fourth portion 24V generally coincide with each other, as viewed in the y-direction. Here, the expression “generally coincide” as viewed in the y-direction refers to, for example, exactly coinciding with each other, or being deviated by within ±5% of the characteristic size (size of the first portion 21V, third portion 23V, or fourth portion 24V in the x-direction). The third portion 23V overlaps with the fifth face 35 of the substrate 3, as viewed in the z-direction.

The second portion 22V is connected to the end portion of the fourth portion 24V, and corresponds to a portion of the lead 2V sticking out from the encapsulating resin 7 to the opposite side of the plurality of leads 1, as viewed in the y-direction. The second portion 22V sticks out to the opposite side of the first portion 21V, in the y-direction. The second portion 22V is used, for example, to electrically connect the semiconductor device A7 to an external circuit. In the illustrated example, the second portion 22V is bent, for example, in the z-direction. The second portion 22V, the third portion 23V, and the fourth portion 24V each include, on the respective sides thereof in the x-direction, edges extending along the y-direction. The edges of the second portion 22V, the third portion 23V, and the fourth portion 24V, on the side of the third face 33 in the x-direction, are respectively opposed to the edges of the second portion 22H, the third portion 23H, and the fourth portion 24H, on the side of the fourth face 34 in the x-direction.

The lead 2I is spaced apart from the plurality of leads 1. The lead 2I is located on the conductive section 5. The lead 2I is electrically connected to the conductive section 5. The lead 2I exemplifies a second lead in the present disclosure. The lead 2I is bonded to the second portion 52I of the wiring 50I in the conductive section 5, via the conductive bonding material 82.

The configuration of the lead 2I is not specifically limited. In this embodiment, as shown in FIG. 59, the lead 2I includes a first portion 21I, a second portion 22I, a third portion 23I, and a fourth portion 24I, each of which will be described hereunder.

The first portion 21I is bonded to the second portion 52I of the wiring 50I. The shape of the first portion 21I is not specifically limited, and a desired shape may be selected from a rectangular shape, a polygonal shape, a circular shape, an elliptical shape, and so forth. In the illustrated example, the first portion 21I has a strip shape extending along the y-direction. The first portion 21I overlaps with the fifth face 35 as viewed in the z-direction, and includes a portion extending from the fifth face 35 along the y-direction, toward the side to which the fifth face 35 is oriented. In the illustrated example, the first portion 21I overlaps with the second portion 52I, as viewed in the z-direction.

The third portion 23I and the fourth portion 24I are covered with the encapsulating resin 7. The third portion 23I is connected to the first portion 21I and the fourth portion 24I. The fourth portion 24I is shifted in the z-direction with respect to the first portion 21I. The end portion of the fourth portion 24I is flush with the fifth face 75 of the resin 7. In the illustrated example, the first portion 21I, the third portion 23I, and the fourth portion 24I generally coincide with each other, as viewed in the y-direction. Here, the expression “generally coincide” as viewed in the y-direction refers to, for example, exactly coinciding with each other, or being deviated by within ±5% of the characteristic size (size of the first portion 21I, third portion 23I, or fourth portion 24I in the x-direction). The third portion 23I overlaps with the fifth face 35 of the substrate 3, as viewed in the z-direction.

The second portion 22I is connected to the end portion of the fourth portion 24I, and corresponds to a portion of the lead 2I sticking out from the encapsulating resin 7 to the opposite side of the plurality of leads 1, as viewed in the y-direction. The second portion 22I sticks out to the opposite side of the first portion 21I, in the y-direction. The second portion 22I is used, for example, to electrically connect the semiconductor device A7 to an external circuit. In the illustrated example, the second portion 22I is bent, for example, in the z-direction. The second portion 22I, the third portion 23I, and the fourth portion 24I each include, on the respective sides thereof in the x-direction, edges extending along the y-direction. The edges of the second portion 22I, the third portion 23I, and the fourth portion 24I, on the side of the third face 33 in the x-direction, are respectively opposed to the edges of the second portion 22V, the third portion 23V, and the fourth portion 24V, on the side of the fourth face 34 in the x-direction.

The lead 2J is spaced apart from the plurality of leads 1. The lead 2J is located on the conductive section 5. The lead 2J is electrically connected to the conductive section 5. The lead 2J exemplifies a second lead in the present disclosure. The lead 2J is bonded to the second portion 52J of the wiring 50J in the conductive section 5, via the conductive bonding material 82.

The configuration of the lead 2J is not specifically limited. In this embodiment, as shown in FIG. 59, the lead 2J includes a first portion 21J, a second portion 22J, a third portion 23J, and a fourth portion 24J, each of which will be described hereunder.

The first portion 21J is bonded to the second portion 52J of the wiring 50J. The shape of the first portion 21J is not specifically limited, and a desired shape may be selected from a rectangular shape, a polygonal shape, a circular shape, an elliptical shape, and so forth. In the illustrated example, the first portion 21J has a strip shape extending along the y-direction. The first portion 21J overlaps with the fifth face 35 as viewed in the z-direction, and includes a portion extending from the fifth face 35 along the y-direction, toward the side to which the fifth face 35 is oriented. In the illustrated example, the first portion 21J overlaps with the second portion 52J, as viewed in the z-direction.

The third portion 23J and the fourth portion 24J are covered with the encapsulating resin 7. The third portion 23J is connected to the first portion 21J and the fourth portion 24J. The fourth portion 24J is shifted in the z-direction with respect to the first portion 21J. The end portion of the fourth portion 24J is flush with the fifth face 75 of the resin 7. In the illustrated example, the first portion 21J, the third portion 23J, and the fourth portion 24J generally coincide with each other, as viewed in the y-direction. Here, the expression “generally coincide” as viewed in the y-direction refers to, for example, exactly coinciding with each other, or being deviated by within ±5% of the characteristic size (size of the first portion 21J, third portion 23J, or fourth portion 24J in the x-direction). The third portion 23J overlaps with the fifth face 35 of the substrate 3, as viewed in the z-direction.

The second portion 22J is connected to the end portion of the fourth portion 24J, and corresponds to a portion of the lead 2J sticking out from the encapsulating resin 7 to the opposite side of the plurality of leads 1, as viewed in the y-direction. The second portion 22J sticks out to the opposite side of the first portion 21J, in the y-direction. The second portion 22J is used, for example, to electrically connect the semiconductor device A7 to an external circuit. In the illustrated example, the second portion 22J is bent, for example, in the z-direction. The second portion 22J, the third portion 23J, and the fourth portion 24J each include, on the respective sides thereof in the x-direction, edges extending along the y-direction. The edges of the second portion 22J, the third portion 23J, and the fourth portion 24J, on the side of the third face 33 in the x-direction, are respectively opposed to the edges of the second portion 22I, the third portion 23I, and the fourth portion 24I, on the side of the fourth face 34 in the x-direction.

The lead 2K is spaced apart from the plurality of leads 1. The lead 2K is located on the conductive section 5. The lead 2K is electrically connected to the conductive section 5. The lead 2K exemplifies a second lead in the present disclosure. The lead 2K is bonded to the second portion 52K of the wiring 50K in the conductive section 5, via the conductive bonding material 82.

The configuration of the lead 2K is not specifically limited. In this embodiment, as shown in FIG. 59, the lead 2K includes a first portion 21K, a second portion 22K, a third portion 23K, and a fourth portion 24K, each of which will be described hereunder.

The first portion 21K is bonded to the second portion 52K of the wiring 50K. The shape of the first portion 21K is not specifically limited, and a desired shape may be selected from a rectangular shape, a polygonal shape, a circular shape, an elliptical shape, and so forth. In the illustrated example, the first portion 21K has a strip shape extending along the y-direction. The first portion 21K overlaps with the fifth face 35 as viewed in the z-direction, and includes a portion extending from the fifth face 35 along the y-direction, toward the side to which the fifth face 35 is oriented. In the illustrated example, the first portion 21K overlaps with the second portion 52K, as viewed in the z-direction.

The third portion 23K and the fourth portion 24K are covered with the encapsulating resin 7. The third portion 23K is connected to the first portion 21K and the fourth portion 24K. The fourth portion 24K is shifted in the z-direction with respect to the first portion 21K. The end portion of the fourth portion 24K is flush with the fifth face 75 of the resin 7. In the illustrated example, the first portion 21K, the third portion 23K, and the fourth portion 24K generally coincide with each other, as viewed in the y-direction. Here, the expression “generally coincide” as viewed in the y-direction refers to, for example, exactly coinciding with each other, or being deviated by within ±5% of the characteristic size (size of the first portion 21K, third portion 23K, or fourth portion 24K in the x-direction). The third portion 23K overlaps with the fifth face 35 of the substrate 3, as viewed in the z-direction.

The second portion 22K is connected to the end portion of the fourth portion 24K, and corresponds to a portion of the lead 2K sticking out from the encapsulating resin 7 to the opposite side of the plurality of leads 1, as viewed in the y-direction. The second portion 22K sticks out to the opposite side of the first portion 21K, in the y-direction. The second portion 22K is used, for example, to electrically connect the semiconductor device A7 to an external circuit. In the illustrated example, the second portion 22K is bent, for example, in the z-direction. The second portion 22K, the third portion 23K, and the fourth portion 24K each include, on the respective sides thereof in the x-direction, edges extending along the y-direction. The edges of the second portion 22K, the third portion 23K, and the fourth portion 24K, on the side of the third face 33 in the x-direction, are respectively opposed to the edges of the second portion 22J, the third portion 23J, and the fourth portion 24J, on the side of the fourth face 34 in the x-direction.

The lead 2L is spaced apart from the plurality of leads 1. The lead 2L is located on the conductive section 5. The lead 2L is electrically connected to the conductive section 5. The lead 2L exemplifies a second lead in the present disclosure. The lead 2L is bonded to the second portion 52L of the wiring 50L in the conductive section 5, via the conductive bonding material 82.

The configuration of the lead 2L is not specifically limited. In this embodiment, as shown in FIG. 59, the lead 2L includes a first portion 21L, a second portion 22L, a third portion 23L, and a fourth portion 24L, each of which will be described hereunder.

The first portion 21L is bonded to the second portion 52L of the wiring 50L. The shape of the first portion 21L is not specifically limited, and a desired shape may be selected from a rectangular shape, a polygonal shape, a circular shape, an elliptical shape, and so forth. In the illustrated example, the first portion 21L has a strip shape extending along the y-direction. The first portion 21L overlaps with the fifth face 35 as viewed in the z-direction, and includes a portion extending from the fifth face 35 along the y-direction, toward the side to which the fifth face 35 is oriented. In the illustrated example, the first portion 21L overlaps with the second portion 52L, as viewed in the z-direction.

The third portion 23L and the fourth portion 24L are covered with the encapsulating resin 7. The third portion 23L is connected to the first portion 21L and the fourth portion 24L. The fourth portion 24L is shifted in the z-direction with respect to the first portion 21L. The end portion of the fourth portion 24L is flush with the fifth face 75 of the resin 7. In the illustrated example, the first portion 21L, the third portion 23L, and the fourth portion 24L generally coincide with each other, as viewed in the y-direction. Here, the expression “generally coincide” as viewed in the y-direction refers to, for example, exactly coinciding with each other, or being deviated by within ±5% of the characteristic size (size of the first portion 21L, third portion 23L, or fourth portion 24L in the x-direction). The third portion 23L overlaps with the fifth face 35 of the substrate 3, as viewed in the z-direction.

The second portion 22L is connected to the end portion of the fourth portion 24L, and corresponds to a portion of the lead 2L sticking out from the encapsulating resin 7 to the opposite side of the plurality of leads 1, as viewed in the y-direction. The second portion 22L sticks out to the opposite side of the first portion 21L, in the y-direction. The second portion 22L is used, for example, to electrically connect the semiconductor device A7 to an external circuit. In the illustrated example, the second portion 22L is bent, for example, in the z-direction. The second portion 22L, the third portion 23L, and the fourth portion 24L each include, on the respective sides thereof in the x-direction, edges extending along the y-direction. The edges of the second portion 22L, the third portion 23L, and the fourth portion 24L, on the side of the third face 33 in the x-direction, are respectively opposed to the edges of the second portion 22K, the third portion 23K, and the fourth portion 24K, on the side of the fourth face 34 in the x-direction.

The lead 2M is spaced apart from the plurality of leads 1. The lead 2M is located on the conductive section 5. The lead 2M is electrically connected to the conductive section 5. The lead 2M exemplifies a second lead in the present disclosure. The lead 2M is bonded to the second portion 52M of the wiring 50M in the conductive section 5, via the conductive bonding material 82.

The configuration of the lead 2M is not specifically limited. In this embodiment, as shown in FIG. 59, the lead 2M includes a first portion 21M, a second portion 22M, a third portion 23M, and a fourth portion 24M, each of which will be described hereunder.

The first portion 21M is bonded to the second portion 52M of the wiring 50M. The shape of the first portion 21M is not specifically limited, and a desired shape may be selected from a rectangular shape, a polygonal shape, a circular shape, an elliptical shape, and so forth. In the illustrated example, the first portion 21M has a strip shape extending along the y-direction. The first portion 21M overlaps with the fifth face 35 as viewed in the z-direction, and includes a portion extending from the fifth face 35 along the y-direction, toward the side to which the fifth face 35 is oriented. In the illustrated example, the first portion 21M overlaps with the second portion 52M, as viewed in the z-direction.

The third portion 23M and the fourth portion 24M are covered with the encapsulating resin 7. The third portion 23M is connected to the first portion 21M and the fourth portion 24M. The fourth portion 24M is shifted in the z-direction with respect to the first portion 21M. The end portion of the fourth portion 24M is flush with the fifth face 75 of the resin 7. In the illustrated example, the first portion 21M, the third portion 23M, and the fourth portion 24M generally coincide with each other, as viewed in the y-direction. Here, the expression “generally coincide” as viewed in the y-direction refers to, for example, exactly coinciding with each other, or being deviated by within ±5% of the characteristic size (size of the first portion 21M, third portion 23M, or fourth portion 24M in the x-direction). The third portion 23M overlaps with the fifth face 35 of the substrate 3, as viewed in the z-direction.

The second portion 22M is connected to the end portion of the fourth portion 24M, and corresponds to a portion of the lead 2M sticking out from the encapsulating resin 7 to the opposite side of the plurality of leads 1, as viewed in the y-direction. The second portion 22M sticks out to the opposite side of the first portion 21M, in the y-direction. The second portion 22M is used, for example, to electrically connect the semiconductor device A7 to an external circuit. In the illustrated example, the second portion 22M is bent, for example, in the z-direction. The second portion 22M, the third portion 23M, and the fourth portion 24M each include, on the respective sides thereof in the x-direction, edges extending along the y-direction. The edges of the second portion 22M, the third portion 23M, and the fourth portion 24M, on the side of the third face 33 in the x-direction, are respectively opposed to the edges of the second portion 22L, the third portion 23L, and the fourth portion 24L, on the side of the fourth face 34 in the x-direction.

The lead 2N is spaced apart from the plurality of leads 1. The lead 2N is located on the conductive section 5. The lead 2N is electrically connected to the conductive section 5. The lead 2N exemplifies a second lead in the present disclosure. The lead 2N is bonded to the second portion 52N of the wiring 50N in the conductive section 5, via the conductive bonding material 82.

The configuration of the lead 2N is not specifically limited. In this embodiment, as shown in FIG. 59, the lead 2N includes a first portion 21N, a second portion 22N, a third portion 23N, and a fourth portion 24N, each of which will be described hereunder.

The first portion 21N is bonded to the second portion 52N of the wiring 50N. The shape of the first portion 21N is not specifically limited, and a desired shape may be selected from a rectangular shape, a polygonal shape, a circular shape, an elliptical shape, and so forth. In the illustrated example, the first portion 21N has a strip shape extending along the y-direction. The first portion 21N overlaps with the fifth face 35 as viewed in the z-direction, and includes a portion extending from the fifth face 35 along the y-direction, toward the side to which the fifth face 35 is oriented. In the illustrated example, the first portion 21N overlaps with the second portion 52N, as viewed in the z-direction.

The third portion 23N and the fourth portion 24N are covered with the encapsulating resin 7. The third portion 23N is connected to the first portion 21N and the fourth portion 24N. The fourth portion 24N is shifted in the z-direction with respect to the first portion 21N. The end portion of the fourth portion 24N is flush with the fifth face 75 of the resin 7. In the illustrated example, the first portion 21N, the third portion 23N, and the fourth portion 24N generally coincide with each other, as viewed in the y-direction. Here, the expression “generally coincide” as viewed in the y-direction refers to, for example, exactly coinciding with each other, or being deviated by within ±5% of the characteristic size (size of the first portion 21N, third portion 23N, or fourth portion 24N in the x-direction). The third portion 23N overlaps with the fifth face 35 of the substrate 3, as viewed in the z-direction.

The second portion 22N is connected to the end portion of the fourth portion 24N, and corresponds to a portion of the lead 2N sticking out from the encapsulating resin 7 to the opposite side of the plurality of leads 1, as viewed in the y-direction. The second portion 22N sticks out to the opposite side of the first portion 21N, in the y-direction. The second portion 22N is used, for example, to electrically connect the semiconductor device A7 to an external circuit. In the illustrated example, the second portion 22N is bent, for example, in the z-direction. The second portion 22N, the third portion 23N, and the fourth portion 24N each include, on the respective sides thereof in the x-direction, edges extending along the y-direction. The edges of the second portion 22N, the third portion 23N, and the fourth portion 24N, on the side of the third face 33 in the x-direction, are respectively opposed to the edges of the second portion 22M, the third portion 23M, and the fourth portion 24M, on the side of the fourth face 34 in the x-direction.

The lead 2O is spaced apart from the plurality of leads 1. The lead 2O is located on the conductive section 5. The lead 2O is electrically connected to the conductive section 5. The lead 2O exemplifies a second lead in the present disclosure. The lead 2O is bonded to the second portion 52O of the wiring 50O in the conductive section 5, via the conductive bonding material 82.

The configuration of the lead 2O is not specifically limited. In this embodiment, as shown in FIG. 59, the lead 2O includes a first portion 21O, a second portion 22O, a third portion 23O, and a fourth portion 24O, each of which will be described hereunder.

The first portion 21O is bonded to the second portion 52O of the wiring 50O. The shape of the first portion 21O is not specifically limited, and a desired shape may be selected from a rectangular shape, a polygonal shape, a circular shape, an elliptical shape, and so forth. In the illustrated example, the first portion 21O has a strip shape extending along the y-direction. The first portion 21O overlaps with the fifth face 35 as viewed in the z-direction, and includes a portion extending from the fifth face 35 along the y-direction, toward the side to which the fifth face 35 is oriented. In the illustrated example, the first portion 21O overlaps with the second portion 52O, as viewed in the z-direction.

The third portion 23O and the fourth portion 24O are covered with the encapsulating resin 7. The third portion 23O is connected to the first portion 21O and the fourth portion 24O. The fourth portion 24O is shifted in the z-direction with respect to the first portion 21O. The end portion of the fourth portion 24O is flush with the fifth face 75 of the resin 7. In the illustrated example, the first portion 21O, the third portion 23O, and the fourth portion 24O generally coincide with each other, as viewed in the y-direction. Here, the expression “generally coincide” as viewed in the y-direction refers to, for example, exactly coinciding with each other, or being deviated by within ±5% of the characteristic size (size of the first portion 21O, third portion 23O, or fourth portion 24O in the x-direction). The third portion 23O overlaps with the fifth face 35 of the substrate 3, as viewed in the z-direction.

The second portion 22O is connected to the end portion of the fourth portion 24O, and corresponds to a portion of the lead 2O sticking out from the encapsulating resin 7 to the opposite side of the plurality of leads 1, as viewed in the y-direction. The second portion 22O sticks out to the opposite side of the first portion 21O, in the y-direction. The second portion 22O is used, for example, to electrically connect the semiconductor device A7 to an external circuit. In the illustrated example, the second portion 22O is bent, for example, in the z-direction. The second portion 22O, the third portion 23O, and the fourth portion 24O each include, on the respective sides thereof in the x-direction, edges extending along the y-direction. The edges of the second portion 22O, the third portion 23O, and the fourth portion 24O, on the side of the third face 33 in the x-direction, are respectively opposed to the edges of the second portion 22N, the third portion 23N, and the fourth portion 24N, on the side of the fourth face 34 in the x-direction.

The lead 2P is spaced apart from the plurality of leads 1. The lead 2P is located on the conductive section 5. The lead 2P is electrically connected to the conductive section 5. The lead 2P exemplifies a second lead in the present disclosure. The lead 2P is bonded to the second portion 52P of the wiring 50P in the conductive section 5, via the conductive bonding material 82.

The configuration of the lead 2P is not specifically limited. In this embodiment, as shown in FIG. 59, the lead 2P includes a first portion 21P, a second portion 22P, a third portion 23P, and a fourth portion 24P, each of which will be described hereunder.

The first portion 21P is bonded to the second portion 52P of the wiring 50P. The shape of the first portion 21P is not specifically limited, and a desired shape may be selected from a rectangular shape, a polygonal shape, a circular shape, an elliptical shape, and so forth. In the illustrated example, the first portion 21P has a strip shape extending along the y-direction. The first portion 21P overlaps with the fifth face 35 as viewed in the z-direction, and includes a portion extending from the fifth face 35 along the y-direction, toward the side to which the fifth face 35 is oriented. In the illustrated example, the first portion 21P overlaps with the second portion 52P, as viewed in the z-direction.

The third portion 23P and the fourth portion 24P are covered with the encapsulating resin 7. The third portion 23P is connected to the first portion 21P and the fourth portion 24P. The fourth portion 24P is shifted in the z-direction with respect to the first portion 21P. The end portion of the fourth portion 24P is flush with the fifth face 75 of the resin 7. In the illustrated example, the first portion 21P, the third portion 23P, and the fourth portion 24P generally coincide with each other, as viewed in the y-direction. Here, the expression “generally coincide” as viewed in the y-direction refers to, for example, exactly coinciding with each other, or being deviated by within ±5% of the characteristic size (size of the first portion 21P, third portion 23P, or fourth portion 24P in the x-direction). The third portion 23P overlaps with the fifth face 35 of the substrate 3, as viewed in the z-direction.

The second portion 22P is connected to the end portion of the fourth portion 24P, and corresponds to a portion of the lead 2P sticking out from the encapsulating resin 7 to the opposite side of the plurality of leads 1, as viewed in the y-direction. The second portion 22P sticks out to the opposite side of the first portion 21P, in the y-direction. The second portion 22P is used, for example, to electrically connect the semiconductor device A7 to an external circuit. In the illustrated example, the second portion 22P is bent, for example, in the z-direction. The second portion 22P, the third portion 23P, and the fourth portion 24P each include, on the respective sides thereof in the x-direction, edges extending along the y-direction. The edges of the second portion 22P, the third portion 23P, and the fourth portion 24P, on the side of the third face 33 in the x-direction, are respectively opposed to the edges of the second portion 22Q, the third portion 23Q, and the fourth portion 24Q, on the side of the fourth face 34 in the x-direction.

The lead 2Q is spaced apart from the plurality of leads 1. The lead 2Q is located on the conductive section 5. The lead 2Q is electrically connected to the conductive section 5. The lead 2Q exemplifies a second lead in the present disclosure. The lead 2Q is bonded to the second portion 52Q of the wiring 50Q in the conductive section 5, via the conductive bonding material 82.

The configuration of the lead 2Q is not specifically limited. In this embodiment, as shown in FIG. 59, the lead 2Q includes a first portion 21Q, a second portion 22Q, a third portion 23Q, and a fourth portion 24Q, each of which will be described hereunder.

The first portion 21Q is bonded to the second portion 52Q of the wiring 50Q. The shape of the first portion 21Q is not specifically limited, and a desired shape may be selected from a rectangular shape, a polygonal a circular shape, an elliptical shape, and so forth. In the illustrated example, the first portion 21Q has a strip shape extending along the y-direction. The first portion 21Q overlaps with the fifth face 35 as viewed in the z-direction, and includes a portion extending from the fifth face 35 along the y-direction, toward the side to which the fifth face 35 is oriented. In the illustrated example, the first portion 21Q overlaps with the second portion 52Q, as viewed in the z-direction.

The third portion 23Q and the fourth portion 24Q are covered with the encapsulating resin 7. The third portion 23Q is connected to the first portion 21Q and the fourth portion 24Q. The fourth portion 24Q is shifted in the z-direction with respect to the first portion 21Q. The end portion of the fourth portion 24Q is flush with the fifth face 75 of the resin 7. In the illustrated example, the first portion 21Q, the third portion 23Q, and the fourth portion 24Q generally coincide with each other, as viewed in the y-direction. Here, the expression “generally coincide” as viewed in the y-direction refers to, for example, exactly coinciding with each other, or being deviated by within ±5% of the characteristic size (size of the first portion 21Q, third portion 23Q, or fourth portion 24Q in the x-direction). The third portion 23Q overlaps with the fifth face 35 of the substrate 3, as viewed in the z-direction.

The second portion 22Q is connected to the end portion of the fourth portion 24Q, and corresponds to a portion of the lead 2Q sticking out from the encapsulating resin 7 to the opposite side of the plurality of leads 1, as viewed in the y-direction. The second portion 22Q sticks out to the opposite side of the first portion 21Q, in the y-direction. The second portion 22Q is used, for example, to electrically connect the semiconductor device A7 to an external circuit. In the illustrated example, the second portion 22Q is bent, for example, in the z-direction. The second portion 22Q, the third portion 23Q, and the fourth portion 24Q each include, on the respective sides thereof in the x-direction, edges extending along the y-direction. The edges of the second portion 22Q, the third portion 23Q, and the fourth portion 24Q, on the side of the third face 33 in the x-direction, are respectively opposed to the edges of the second portion 22P, the third portion 23P, and the fourth portion 24P, on the side of the fourth face 34 in the x-direction.

The lead 2R is spaced apart from the plurality of leads 1. The lead 2R is located on the conductive section 5. The lead 2R is electrically connected to the conductive section 5. The lead 2R exemplifies a second lead in the present disclosure. The lead 2R is bonded to the second portion 52R of the wiring 50R in the conductive section 5, via the conductive bonding material 82.

The configuration of the lead 2R is not specifically limited. In this embodiment, as shown in FIG. 59, the lead 2R includes a first portion 21R, a second portion 22R, a third portion 23R, and a fourth portion 24R, each of which will be described hereunder.

The first portion 21R is bonded to the second portion 52R of the wiring 50R. The shape of the first portion 21R is not specifically limited, and a desired shape may be selected from a rectangular shape, a polygonal shape, a circular shape, an elliptical shape, and so forth. In the illustrated example, the first portion 21R has a strip shape extending along the y-direction. The first portion 21R overlaps with the fifth face 35 as viewed in the z-direction, and includes a portion extending from the fifth face 35 along the y-direction, toward the side to which the fifth face 35 is oriented. In the illustrated example, the first portion 21R overlaps with the second portion 52R, as viewed in the z-direction.

The third portion 23R and the fourth portion 24R are covered with the encapsulating resin 7. The third portion 23R is connected to the first portion 21R and the fourth portion 24R. The fourth portion 24R is shifted in the z-direction with respect to the first portion 21R. The end portion of the fourth portion 24R is flush with the fifth face 75 of the resin 7. In the illustrated example, the first portion 21R, the third portion 23R, and the fourth portion 24R generally coincide with each other, as viewed in the y-direction. Here, the expression “generally coincide” as viewed in the y-direction refers to, for example, exactly coinciding with each other, or being deviated by within ±5% of the characteristic size (size of the first portion 21R, third portion 23R, or fourth portion 24R in the x-direction). The third portion 23R overlaps with the fifth face 35 of the substrate 3, as viewed in the z-direction.

The second portion 22R is connected to the end portion of the fourth portion 24R, and corresponds to a portion of the lead 2R sticking out from the encapsulating resin 7 to the opposite side of the plurality of leads 1, as viewed in the y-direction. The second portion 22R sticks out to the opposite side of the first portion 21R, in the y-direction. The second portion 22R is used, for example, to electrically connect the semiconductor device A7 to an external circuit. In the illustrated example, the second portion 22R is bent, for example, in the z-direction. The second portion 22R, the third portion 23R, and the fourth portion 24R each include, on the respective sides thereof in the x-direction, edges extending along the y-direction. The edges of the second portion 22R, the third portion 23R, and the fourth portion 24R, on the side of the third face 33 in the x-direction, are respectively opposed to the edges of the second portion 22Q, the third portion 23Q, and the fourth portion 24Q, on the side of the fourth face 34 in the x-direction.

The lead 2S is spaced apart from the plurality of leads 1. The lead 2S is located on the conductive section 5. The lead 2S is electrically connected to the conductive section 5. The lead 2S exemplifies a second lead in the present disclosure. The lead 2S is bonded to the second portion 52S of the wiring 50S in the conductive section 5, via the conductive bonding material 82.

The configuration of the lead 2S is not specifically limited. In this embodiment, as shown in FIG. 59, the lead 2S includes a first portion 21S, a second portion 22S, a third portion 23S, and a fourth portion 24S, each of which will be described hereunder.

The first portion 21S is bonded to the second portion 52S of the wiring 50S. The shape of the first portion 21S is not specifically limited, and a desired shape may be selected from a rectangular shape, a polygonal shape, a circular shape, an elliptical shape, and so forth. In the illustrated example, the first portion 21S has a bent shape including a portion extending along the x-direction, a portion inclined with respect to the x-direction and the y-direction, and a portion extending along the y-direction. The first portion 21S overlaps with the fourth face 34 of the substrate 3 as viewed in the z-direction, and sticks out in the x-direction, toward the side to which the fourth face 34 is oriented. In the illustrated example, the first portion 21S overlaps with the second portion 52S, as viewed in the z-direction.

The third portion 23S and the fourth portion 24S are covered with the encapsulating resin 7. The third portion 23S is connected to the first portion 21S and the fourth portion 24S. The fourth portion 24S is shifted in the z-direction with respect to the first portion 21S. The end portion of the fourth portion 24S is flush with the fifth face 75 of the resin 7. In the illustrated example, the third portion 23S and the fourth portion 24S generally coincide with each other, as viewed in the y-direction. Here, the expression “generally coincide” as viewed in the y-direction refers to, for example, exactly coinciding with each other, or being deviated by within ±5% of the characteristic size (size of the third portion 23S or fourth portion 24S in the x-direction).

The second portion 22S is connected to the end portion of the fourth portion 24S, and corresponds to a portion of the lead 2S sticking out from the encapsulating resin 7 to the opposite side of the plurality of leads 1, as viewed in the y-direction. The second portion 22S sticks out to the opposite side of the first portion 21S, in the y-direction. The second portion 22S is used, for example, to electrically connect the semiconductor device A7 to an external circuit. In the illustrated example, the second portion 22S is bent, for example, in the z-direction. The second portion 22S, the third portion 23S, and the fourth portion 24S each include, on the respective sides thereof in the x-direction, edges extending along the y-direction. The edges of the second portion 22S, the third portion 23S, and the fourth portion 24S, on the side of the third face 33 in the x-direction, are respectively opposed to the edges of the second portion 22R, the third portion 23R, and the fourth portion 24R, on the side of the fourth face 34 in the x-direction.

The lead 2T is spaced apart from the plurality of leads 1. The lead 2T is located on the conductive section 5. The lead 2T is electrically connected to the conductive section 5. The lead 2T exemplifies a second lead in the present disclosure. The lead 2T is bonded to the second portion 52T of the wiring 50T in the conductive section 5, via the conductive bonding material 82.

The configuration of the lead 2T is not specifically limited. In this embodiment, as shown in FIG. 58 and FIG. 59, the lead 2T includes a first portion 21T, a second portion 22T, a third portion 23T, and a fourth portion 24T, each of which will be described hereunder.

The first portion 21T is bonded to the second portion 52T of the wiring 50T. The shape of the first portion 21T is not specifically limited, and a desired shape may be selected from a rectangular shape, a polygonal shape, a circular shape, an elliptical shape, and so forth. In the illustrated example, the first portion 21T has a bent shape including a portion extending along the x-direction, a portion inclined with respect to the x-direction and the y-direction, and a portion extending along the y-direction. The first portion 21T overlaps with the fourth face 34 of the substrate 3 as viewed in the z-direction, and sticks out in the x-direction, toward the side to which the fourth face 34 is oriented. In the illustrated example, the first portion 21T overlaps with the second portion 52T, as viewed in the z-direction.

The third portion 23T and the fourth portion 24T are covered with the encapsulating resin 7. The third portion 23T is connected to the first portion 21T and the fourth portion 24T. The fourth portion 24T is shifted in the z-direction with respect to the first portion 21T, to the side to which the first face 31 is oriented, like the third portion 23I and the fourth portion 24I of the lead 2I shown in FIG. 40. The end portion of the fourth portion 24T is flush with the fifth face 75 of the resin 7. In the illustrated example, the third portion 23T and the fourth portion 24T generally coincide with each other, as viewed in the y-direction. Here, the expression “generally coincide” as viewed in the y-direction refers to, for example, exactly coinciding with each other, or being deviated by within ±5% of the characteristic size (size of the third portion 23T or fourth portion 24T in the x-direction).

The second portion 22T is connected to the end portion of the fourth portion 24T, and corresponds to a portion of the lead 2T sticking out from the encapsulating resin 7 to the opposite side of the plurality of leads 1, as viewed in the y-direction. The second portion 22T sticks out to the opposite side of the first portion 21T, in the y-direction. The second portion 22T is used, for example, to electrically connect the semiconductor device A7 to an external circuit. In the illustrated example, the second portion 22T is bent, for example, in the z-direction. The second portion 22T, the third portion 23T, and the fourth portion 24T each include, on the respective sides thereof in the x-direction, edges extending along the y-direction. The edges of the second portion 22T, the third portion 23T, and the fourth portion 24T, on the side of the third face 33 in the x-direction, are respectively opposed to the edges of the second portion 22S, the third portion 23S, and the fourth portion 24S, on the side of the fourth face 34 in the x-direction.

The lead 2U is spaced apart from the plurality of leads 1. The lead 2U is located on the conductive section 5. The lead 2U is electrically connected to the conductive section 5. The lead 2U exemplifies a second lead in the present disclosure. The lead 2U is bonded to the second portion 52U of the wiring 50U in the conductive section 5, via the conductive bonding material 82.

The configuration of the lead 2U is not specifically limited. In this embodiment, as shown in FIG. 58 and FIG. 59, the lead 2U includes a first portion 21U, a second portion 22U, a third portion 23U, and a fourth portion 24U, each of which will be described hereunder.

The first portion 21U is bonded to the second portion 52U of the wiring 50U. The shape of the first portion 21U is not specifically limited, and a desired shape may be selected from a rectangular shape, a polygonal shape, a circular shape, an elliptical shape, and so forth. In the illustrated example, the first portion 21U has a bent shape including a portion extending along the x-direction, a portion inclined with respect to the x-direction and the y-direction, and a portion extending along the y-direction. The first portion 21U overlaps with the fourth face 34 of the substrate 3 as viewed in the z-direction, and sticks out in the x-direction, toward the side to which the fourth face 34 is oriented. In the illustrated example, the first portion 21U overlaps with the second portion 52U, as viewed in the z-direction.

The third portion 23U and the fourth portion 24U are covered with the encapsulating resin 7. The third portion 23U is connected to the first portion 21U and the fourth portion 24U. The fourth portion 24U is shifted in the z-direction with respect to the first portion 21U. The end portion of the fourth portion 24U is flush with the fifth face 75 of the resin 7. In the illustrated example, the third portion 23U and the fourth portion 24U generally coincide with each other, as viewed in the y-direction. Here, the expression “generally coincide” as viewed in the y-direction refers to, for example, exactly coinciding with each other, or being deviated by within ±5% of the characteristic size (size of the third portion 23U or fourth portion 24U in the x-direction).

The second portion 22U is connected to the end portion of the fourth portion 24U, and corresponds to a portion of the lead 2U sticking out from the encapsulating resin 7 to the opposite side of the plurality of leads 1, as viewed in the y-direction. The second portion 22U sticks out to the opposite side of the first portion 21U, in the y-direction. The second portion 22U is used, for example, to electrically connect the semiconductor device A7 to an external circuit. In the illustrated example, the second portion 22U is bent, for example, in the z-direction. The second portion 22U, the third portion 23U, and the fourth portion 24U each include, on the respective sides thereof in the x-direction, edges extending along the y-direction. The edges of the second portion 22U, the third portion 23U, and the fourth portion 24U, on the side of the third face 33 in the x-direction, are respectively opposed to the edges of the second portion 22T, the third portion 23T, and the fourth portion 24T, on the side of the fourth face 34 in the x-direction.

### <Semiconductor Chips 4A to 4F, 4X>

The semiconductor chips 4A to 4F and 4X, located on the plurality of leads 1, each exemplify a semiconductor chip in the present disclosure. The type and the function of the semiconductor chips 4A to 4F and 4X are not specifically limited. In this embodiment, the semiconductor chips 4A to 4F, and 4X are a transistor. Although seven semiconductor chips 4A to 4F and 4X are provided in the illustrated example, the number of semiconductor chips is by no means limited.

The semiconductor chips 4A to 4F and 4X in the illustrated example are, for example, a transistor configured as an IGBT, like those of the semiconductor device A3.

In this embodiment, as shown in FIG. 58, three semiconductor chips 4A, 4B, and 4C are provided on the first portion 113A in the first portion 11A of the lead 1A. The three semiconductor chips 4A, 4B, and 4C are spaced apart from each other in the x-direction, and overlap with each other as viewed in the x-direction. Here, the number of semiconductor chips to be mounted on the lead 1A is by no means limited. In the illustrated example, the respective collector electrodes of the semiconductor chips 4A, 4B, and 4C are bonded to the first portion 11A, via the conductive bonding material 83.

The conductive bonding material 83 may be any material that is capable of bonding, and electrically connecting, the collector electrode CP of the semiconductor chips 4A, 4B, and 4C, to the first portion 11A. For example, silver paste, copper paste, or solder may be employed as the conductive bonding material 83. The conductive bonding material 83 corresponds to the second conductive bonding material in the present disclosure.

In this embodiment, the semiconductor chip 4D is provided on the first portion 11B of the lead 1B. Here, the number of semiconductor chips to be mounted on the lead 1B is by no means limited. In the illustrated example, the collector electrode of the semiconductor chip 4D is bonded to the first portion 11B, via the conductive bonding material 83.

In this embodiment, the semiconductor chip 4E is provided on the first portion 11C of the lead 1C. Here, the number of semiconductor chips to be mounted on the lead 1C is by no means limited. In the illustrated example, the collector electrode of the semiconductor chip 4E is bonded to the first portion 11C, via the conductive bonding material 83.

In this embodiment, the semiconductor chip 4F is provided on the first portion 11D of the lead 1D. Here, the number of semiconductor chips to be mounted on the lead 1D is by no means limited. In the illustrated example, the collector electrode of the semiconductor chip 4F is bonded to the first portion 11D, via the conductive bonding material 83.

In this embodiment, the semiconductor chip 4X is provided on the first portion 113H in the first portion 11H of the lead 1H. Here, the number of semiconductor chips to be mounted on the lead 1H is by no means limited. In the illustrated example, the collector electrode of the semiconductor chip 4X is bonded to the first portion 11H, via the conductive bonding material 83.

### <Diodes 41A to 41F, 41X>

The configuration of the diodes 41A to 41F, and 41X is not specifically limited and may be, for example, similar to that of the diodes 41A to 41F of the semiconductor device A3.

As in the semiconductor device A3, the diode 41A, the diode 41B, and the diode 41C are mounted on the first portion 113A in the first portion 11A. The diode 41D is mounted on the first portion 11B. The diode 41E is mounted on the first portion 11C. The diode 41F is mounted on the first portion 11D. The diode 41X is mounted on the second portion 114A in the first portion 11A.

The diode 41A overlaps with the semiconductor chip 4A, as viewed in the y-direction. The diode 41B overlaps with the semiconductor chip 4B, as viewed in the y-direction. The diode 41C overlaps with the semiconductor chip 4C, as viewed in the y-direction. The diodes 41A, 41B, and 41C overlap with each other, as viewed in the x-direction. The diodes 41A, 41B, and 41C overlap with the semiconductor chip 4X, as viewed in the x-direction.

The diode 41D overlaps with the semiconductor chip 4D, as viewed in the y-direction. The diode 41E overlaps with the semiconductor chip 4E, as viewed in the y-direction. The diode 41F overlaps with the semiconductor chip 4F, as viewed in the y-direction. The diodes 41D, 41E, and 41F overlap with each other, as viewed in the x-direction.

The diode 41X overlaps with the semiconductor chip 4X, as viewed in the y-direction. The diode 41X overlaps with the semiconductor chips 4A, 4B, and 4C, as viewed in the x-direction. In addition, the diode 41X overlaps with the second portion 114H, as viewed in the x-direction.

### [Control Chips 4G and 4H]

The configuration of the control chips 4G and 4H is not specifically limited and may be, for example, similar to that of the control chips 4G and 4H of the semiconductor device A3.

In this embodiment, as shown in FIG. 59, the control chip 4G is mounted on the first base portion 55 of the conductive section 5. The control chip 4H is mounted on the second base portion 56 of the conductive section 5. In this embodiment, the control chip 4G is bonded to the first base portion 55, via the conductive bonding material 84. The control chip 4H is bonded to the second base portion 56, via the conductive bonding material 84.

The conductive bonding material 84 may be any material that is capable of bonding, and electrically connecting, the control chip 4G to the first base portion 55, and the control chip 4H to the second base portion 56. For example, silver paste, copper paste, or solder may be employed as the conductive bonding material 84. The conductive bonding material 84 corresponds to the third conductive material in the present disclosure. In this embodiment, the conductive bonding material 84 extends outwardly from the outer periphery of the control chips 4G and 4H, in a plan view. A reason of such a configuration is that, for example, when the conductive bonding material 84 performs the bonding function by curing after the fused state, the conductive bonding material 84 in the fused state spreads around the control chip 4G (control chip 4H) as viewed in the z-direction. Therefore, in the illustrated example, the conductive bonding material 84 protrudes from the respective outer edges of the control chips 4G and 4H, as viewed in the z-direction. However, the specific shape of the conductive bonding material 84 is by no means limited. Here, the control chips 4G and 4H may be bonded to the first base portion 55 via an insulative bonding material, instead of the conductive bonding material 84. In the illustrated example, the conductive bonding material 84 has an uneven outer edge, as viewed in the z-direction. Such formation of the conductive bonding material 84 allows the control chips 4G and 4H to be bonded to a region of the conductive section 5 more distant from the control chips 4G and 4H, thereby further stabilizing the adhesion of the control chips 4G and 4H.

The control chip 4G is located between the leads 2A to 2U and the leads 1A to 1G, as viewed in the x-direction. The control chip 4H is located between the leads 2A to 2U and the leads 1A to 1G, as viewed in the x-direction. The control chips 4G and the control chips 4H overlap with each other, as viewed in the x-direction. The control chip 4G overlaps with the semiconductor chips 4B and 4C, as viewed in the y-direction. The control chip 4H overlaps with the semiconductor chips 4D and 4E, as viewed in the y-direction. The control chip 4H overlaps with the transmission circuit chip 4I and the primary-side circuit chip 4J, as viewed in the y-direction. The control chip 4G may overlap with the semiconductor chip 4A, as viewed in the y-direction. The control chip 4H may overlap with the semiconductor chip 4F, as viewed in the y-direction.

### <Transmission Circuit Chip 4I>

The transmission circuit chip 4I includes the first transmission circuit in the present disclosure. Like the transmission circuit chip 4I in the semiconductor device A3, the transmission circuit chip 4I has a transformer structure including at least two coils opposed to each other with a gap therebetween, to transmit electrical signals. In this embodiment, as shown in FIG. 59, the transmission circuit chip 4I is, for example, mounted on the third base portion 58 via the conductive bonding material 84. The transmission circuit chip 4I is located between the control chip 4H and the primary-side circuit chip 4J, as viewed in the x-direction. The transmission circuit chip 4I overlaps with the control chip 4H, as viewed in the y-direction. Further, the transmission circuit chip 4I overlaps with the first portions 51I to 51N (wirings 50I to 50N), as viewed in the y-direction. In the illustrated example, the conductive bonding material 84 protrudes from the outer edge of the transmission circuit chip 41, as viewed in the z-direction.

### <Primary-Side Circuit Chip 4J>

The primary-side circuit chip 4J transmits command signals to the control chip 4H, through the transmission circuit chip 4I. In this embodiment, as shown in FIG. 59, the primary-side circuit chip 4J is, for example, mounted on the third base portion 58 via the conductive bonding material 84. The primary-side circuit chip 4J is located on the side of the fifth face 35 in the y-direction, with respect to the transmission circuit chip 4I.

### <Diodes 49U, 49V, 49W>

The configuration of the diodes 49U, 49V, and 49W is not specifically limited and may be, for example, similar to that of the diodes 49U, 49V, and 49W of the semiconductor device A3.

### <First Wires 91A to 91F, 91H, 91I>

Regarding the first wires 91A to 91F, 91H, and 91I according to this embodiment, although any of the elements is apparently given, for the sake of convenience of description, the same numeral as that of the first wires 91A to 91F according to the third embodiment, it does not necessarily mean that the mentioned element has the same or similar configuration. The configuration of an element with a numeral is defined by the description relevant to this embodiment. Regarding an element on which no specific description is given, a similar configuration to that of the plurality of first wires 91 according to the third embodiment may be adopted, as appropriate.

The first wires 91A to 91F, 91H, and 91I are each connected to one of the semiconductor chips 4A to 4F and 4X, and the diode 41X, and one of the plurality of leads 1. The material of the first wires 91A to 91F, 91H, and 91I is not specifically limited and, for example, aluminum (Al) or copper (Cu) may be employed. The wire diameter of the first wires 91A to 91F is not specifically limited and, for example, may be approximately 250 to 500 μm. The first wires 91A to 91F, 91H, and 91I correspond to the first conductive material in the present disclosure. Here, for example leads formed of copper may be employed, in place of the first wires 91A to 91F, 91H, and 91I.

The collector electrode of the semiconductor chip 4A and the cathode electrode of the diode 41A are connected to each other, via the first portion 11A and the conductive bonding material 83. The collector electrode CP of the semiconductor chip 4B and the cathode electrode of the diode 41B are connected to each other, via the first portion 11A and the conductive bonding material 83. The collector electrode CP of the semiconductor chip C and the cathode electrode of the diode 41C are connected to each other, via the first portion 11A and the conductive bonding material 83.

The first wire 91A has one end connected to the emitter electrode of the semiconductor chip 4A, an intermediate portion connected to the anode electrode of the diode 41A, and the other end connected to the fourth portion 14B of the lead 1B. The number of first wires 91A is not specifically limited. In the illustrated example, three first wires 91A are provided.

The first wire 91B has one end connected to the emitter electrode of the semiconductor chip 4B, an intermediate portion connected to the anode electrode of the diode 41B, and the other end connected to the fourth portion 14C of the lead 1C. The number of first wires 91B is not specifically limited. In the illustrated example, three first wires 91B are provided.

The first wire 91C has one end connected to the emitter electrode of the semiconductor chip 4C, an intermediate portion connected to the anode electrode of the diode 41C, and the other end connected to the fourth portion 14D of the lead 1D. The number of first wires 91C is not specifically limited. In the illustrated example, three first wires 91C are provided.

The first wire 91D has one end connected to the emitter electrode of the semiconductor chip 4D, an intermediate portion connected to the anode electrode of the diode 41D, and the other end connected to the fourth portion 14E of the lead 1E. The number of first wires 91D is not specifically limited. In the illustrated example, three first wires 91D are provided.

The first wire 91E has one end connected to the emitter electrode of the semiconductor chip 4E, an intermediate portion connected to the anode electrode of the diode 41E, and the other end connected to the fourth portion 14F of the lead 1F. The number of first wires 91E is not specifically limited. In the illustrated example, three first wires 91E are provided.

The first wire 91F has one end connected to the emitter electrode of the semiconductor chip 4F, an intermediate portion connected to the anode electrode of the diode 41F, and the other end connected to the fourth portion 14G of the lead 1G. The number of first wires 91F is not specifically limited. In the illustrated example, three first wires 91F are provided.

The first wire 91H has one end connected to the anode electrode of the diode 41X, and the other end connected to the second portion 114H in the first portion 11H of the lead 1H. The number of first wires 91H is not specifically limited. In the illustrated example, three first wires 91H are provided.

The first wire 911 has one end connected to the anode electrode of the semiconductor chip 4X, and the other end connected to the fourth portion 14I of the lead 1I. The number of first wires 911 is not specifically limited. In the illustrated example, three first wires 91H are provided.

### <Second Wires 92>

Regarding the second wire 92 according to this embodiment, although any of the elements is apparently given, for the sake of convenience of description, the same numeral as that of the second wire 92 according to the third embodiment, it does not necessarily mean that the mentioned element has the same or similar configuration. The configuration of an element with a numeral is defined by the description relevant to this embodiment. Regarding a portion or structure on which no specific description is given, a similar configuration to that of the second wire 92 of the semiconductor device A3 may be adopted, as appropriate.

As shown in FIG. 59 and FIG. 60, second wires 92 may be electrically connected to the control chip 4G or 4H. The material of the second wires 92 is not specifically limited and, for example, gold (Au) may be employed. The wire diameter of the second wires 92 is not specifically limited and, in this embodiment, finer than the first wires 91A to 91F. The wire diameter of the second wires 92 is, for example, approximately 10 μm to 50 μm. The second wires 92 correspond to the second conductive material in the present disclosure. In the subsequent description, the second wires 92 connected to the control chip 4G will be referred to as second wires 92G, and the second wires 92 connected to the control chip 4H will be referred to as second wires 92H.

A second wire 92G is connected at one end to the gate electrode of the semiconductor chip 4A, and at the other end to the second portion 52a of the wiring 50a. Likewise, another second wire 92G is connected to the emitter electrode of the semiconductor chip 4A and to the second portion 52b of the wiring 50b.

A second wire 92G is connected to the gate electrode of the semiconductor chip 4B and to the control chip 4G. Another second wire 92G is connected to the emitter electrode of the semiconductor chip 4B and to the control chip 4G.

A second wire 92G is connected to the gate electrode of the semiconductor chip 4C and to the control chip 4G. Another second wire 92G is connected to the emitter electrode of the semiconductor chip 4C and to the control chip 4G.

A second wire 92H is connected to the gate electrode of the semiconductor chip 4D and to the control chip 4H. Another second wire 92H is connected to the gate electrode of the semiconductor chip 4E and to the control chip 4H. Another second wire 92H is connected to the gate electrode of the semiconductor chip 4F and to the second portion 52f of the wiring 50f.

The second wires 92 according to this embodiment may include a second wire 92G which is connected to the gate electrode of the semiconductor chip 4X and to the second portion 52h of the wiring 50h, as shown in FIG. 58.

### <Third Wire 93>

As shown in FIG. 59 and FIG. 60, the plurality of third wires 93 are connected to one of the control chips 4G and 4H, as in the semiconductor device A3. The material of the third wire 93 is not specifically limited and, for example, a similar material to that of the second wire 92 may be employed.

### <Fourth Wires 94>

As shown in FIG. 59 and FIG. 60, the plurality of fourth wires 94 are connected to the transmission circuit chip 4I and the primary-side circuit chip 4J, as in the semiconductor device A3. The material of the fourth wire 94 is not specifically limited and, for example, a similar material to that of the second wire 92 may be employed.

### <Fifth Wires 95>

As shown in FIG. 59 and FIG. 60, the plurality of fifth wires 95 are connected to the primary-side circuit chip 4J and the conductive section 5, as in the semiconductor device A3. The material of the fifth wire 95 is not specifically limited and, for example, a similar material to that of the second wire 92 may be employed.

### <Sixth Wires 96>

As shown in FIG. 59 and FIG. 60, the plurality of sixth wires 96 are connected to the control chips 4G and the conductive section 5, as in the semiconductor device A3. The material of the sixth wire 96 is not specifically limited and, for example, a similar material to that of the second wire 92 may be employed.

### <Seventh Wires 97>

As shown in FIG. 59 and FIG. 60, the plurality of seventh wires 97 are connected to the control chips 4H and the conductive section 5, as in the semiconductor device A3. The material of the seventh wires 97 is not specifically limited and, for example, a similar material to that of the second wire 92 may be employed.

### <Resin 7>

Regarding the resin 7 according to this embodiment, although any of the elements is apparently given, for the sake of convenience of description, the same numeral as that of the resin 7 according to the second embodiment, it does not necessarily mean that the mentioned element has the same or similar configuration. The configuration of an element with a numeral is defined by the description relevant to this embodiment. Regarding a portion or structure on which no specific description is given, a similar configuration to that of the resin 7 of the semiconductor device A3 may be adopted, as appropriate.

The resin 7 covers at least the semiconductor chips 4A to 4F and 4X, the control chips 4G and 4H, the transmission circuit chip 4I, the primary-side circuit chip 4J, a part of each of the plurality of leads 1, and a part of each of the plurality of leads 2. In this embodiment, in addition, the resin 7 covers the diodes 41A to 41F and 41X, the diodes 49U, 49V, and 49W, the plurality of first wires 91A to 91F, the plurality of second wires 92, the plurality of third wires 93, the plurality of fourth wires 94, the plurality of fifth wires 95, the plurality of sixth wires 96, and the plurality of seventh wires 97. The material of the resin 7 is not specifically limited. Though not specifically limited, for example an insulative material such as an epoxy resin or silicone gel may be employed to form the resin 7.

In this embodiment, the resin 7 includes a first face 71, a second face 72, a third face 73, a fourth face 74, a fifth face 75, a sixth face 76, a recess 731, a recess 732, a recess 733, a hole 741, and a hole 742, which are similar to those of the semiconductor device A3.

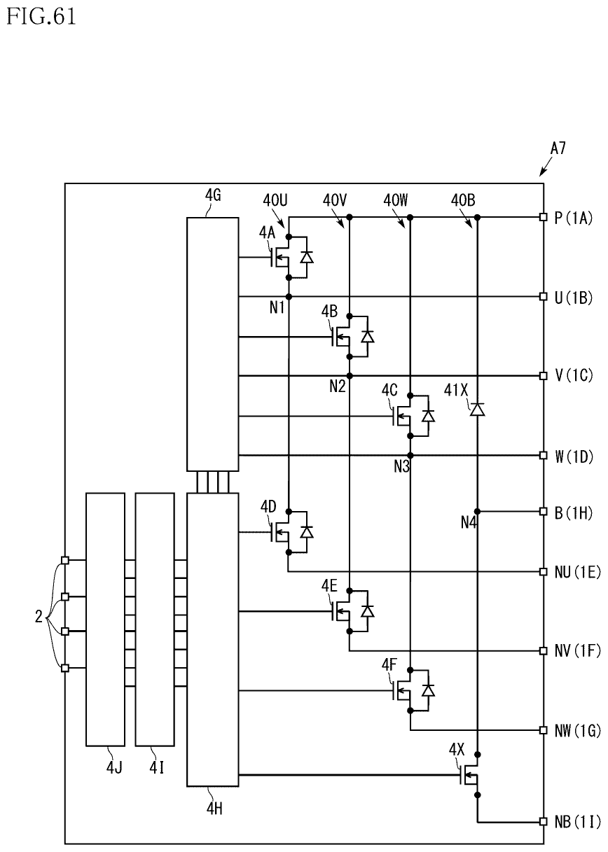

FIG. 61 is a schematic circuit diagram showing an electrical configuration of the semiconductor device A7. The circuit constituted of the semiconductor device A7 includes the switching arms 40U, 40V, and 40W, like the semiconductor device A1. Further, the circuit of the semiconductor device A7 includes a switching circuit 40B. The switching circuit 40B is constituted of the semiconductor chip 4X and the diode 41X. To a node N4, the lead 1H serving as the B terminal is connected.

In this embodiment, the lead 1A is the P terminal. The lead 1B is the U terminal. The lead 1C is the V terminal. The lead 1D is the W terminal. The lead 1E is the NU terminal. The lead 1F is the NV terminal. The lead 1G is the NW terminal. The lead 1H is the B terminal. The lead 1I is the NB terminal. The lead 2A is the VSU terminal. The lead 2B is the VBU terminal. The lead 2C is the VSV terminal. The lead 2D is the VBV terminal. The lead 2E is the VSW terminal. The lead 2F is the VBW terminal. The lead 2G is the first GND terminal. The lead 2H is the first VCC terminal. The lead 2I is the HINU terminal. The lead 2J is the HINV terminal. The lead 2K is the HINW terminal. The lead 2L is the LINU terminal. The lead 2M is the LINV terminal. The lead 2N is the LINW terminal. The lead 2P is the FO terminal. The lead 2Q is the third VCC terminal. The lead 2R is the third GND terminal. The lead 2S is the CIN terminal. The lead 2T is the second VCC terminal. The lead 2U is the second GND terminal. The lead 2V is the Bin terminal.

This embodiment provides similar advantageous effects to those provided by the semiconductor device A3. Further, the switching circuit 40B constituted of the semiconductor chip 4X and the diode 41X enables, for example, control of a braking operation, in addition to operation control of a three-phase AC motor using the switching arms 40U, 40V, and 40W.

Arranging the semiconductor chip 4X and the diode 41X so as to overlap as viewed in the y-direction suppresses an increase in size of the semiconductor device A7 in the x-direction. Arranging the second portion 114A of the first portion 11A and the second portion 114H of the first portion 11H so as to overlap as viewed in the y-direction suppresses an increase in size of the semiconductor device A7 in the x-direction. Arranging the second portion 114H so as to overlap with the diode 41X as viewed in the x-direction allows the length of the first wire 91H to be shortened.

Locating the second portion 52h on the side of the third face 33 in the x-direction with respect to the first portion 113H, and so as to overlap with the semiconductor chip 4X as viewed in the x-direction, allows the length of the second wire 92G, connected to the gate electrode of the semiconductor chip 4X and the second portion 52h, to be shortened.

### <First Variation of Seventh Embodiment>

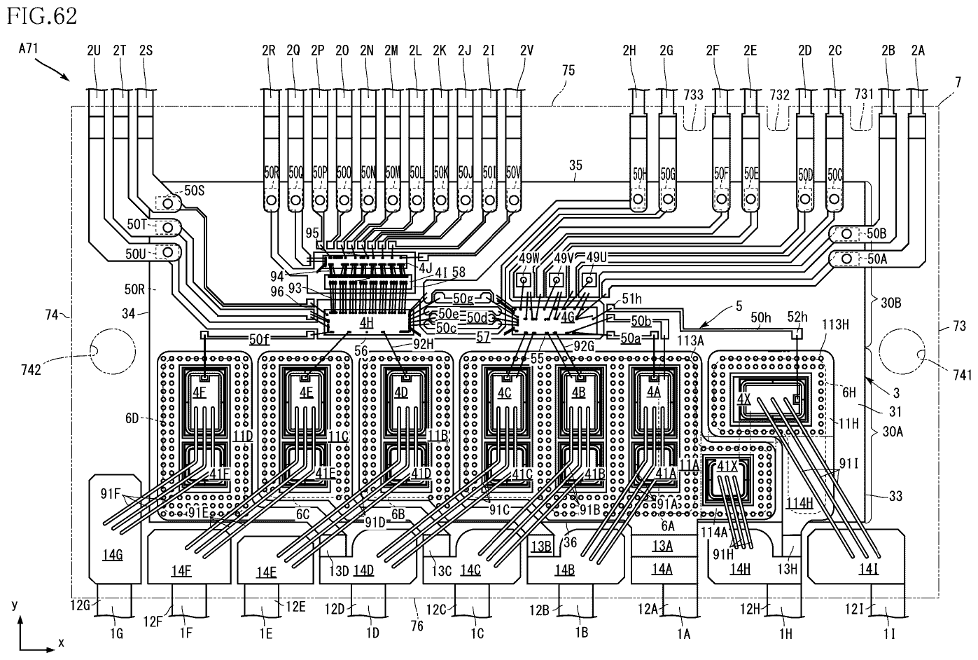

FIG. 62 illustrates a first variation of the semiconductor device A7. The semiconductor device A71 according to this variation may be configured in the same way as the semiconductor device A7, except for the configuration described hereunder.

### <Conductive Section 5>

The second portion 52h according to this variation is located on the side of the third face 33 in the x-direction with respect to the first portion 51h, and spaced therefrom. The second portion 52h is located on the side of the sixth face 36 in the y-direction with respect to the first portion 51h, and spaced therefrom. The second portion 52h overlaps with the first base portion 55, as viewed in the x-direction. The second portion 52h is located on the side of the fifth face 35 in the y-direction, with respect to the bonding section 6H. The second portion 52h overlaps with the bonding section 6H, as viewed in the y-direction. The shape of the second portion 52h is not specifically limited, and a desired shape may be selected from a rectangular shape, a polygonal shape, a circular shape, an elliptical shape, and so forth. In the illustrated example, the second portion 52h has a rectangular shape.

### <Leads 1>

The first portion 11A of the lead 1A according to this variation includes a first portion 113A and a second portion 114A.

The first portion 113A occupies a majority of the first portion 11A. The first portion 113A overlaps with the second base portion 56 and the wirings 50a, 50b, and 50h, as viewed in the y-direction.

The second portion 114A is connected to the first portion 113A on the side of the third face 33, in the x-direction. The center of the second portion 114A in the y-direction is located on the side of the sixth face 36, with respect to the center of the first portion 113A in the y-direction. In the illustrated example, the edge of the first portion 113A on the side of the sixth face 36 in the y-direction, and the edge of the second portion 114A on the side of the fifth face 35 in the y-direction generally coincide with each other, as viewed in the x-direction. Here, the expression “generally coincide” as viewed in the x-direction refers to, for example, exactly coinciding with each other, or being deviated by within ±5% of the characteristic size (size of the first portion 113A or second portion 114A in the y-direction).

The first portion 11H of the lead 1H according to this variation includes a first portion 113H and a second portion 114H.

The first portion 113H occupies a majority of the first portion 11H. The first portion 113H is located on the side of the third face 33 with respect to the first portion 113A, as viewed in the x-direction. The first portion 113H overlaps with the first portion 113A, as viewed in the x-direction. The first portion 113H is located on the side of the fifth face 35 in the y-direction, with respect to the second portion 114A. The first portion 113H overlaps with the second portion 114A, as viewed in the y-direction.

The second portion 114H is connected to the first portion 113H on the side of the sixth face 36, in the y-direction. The center of the second portion 114H in the x-direction is located on the side of the third face 33, with respect to the center of the first portion 113H in the x-direction. The second portion 114H overlaps with the second portion 114A, as viewed in the x-direction. The second portion 114H is spaced apart from the second portion 114A, as viewed in the y-direction. In the illustrated example, the edge of the first portion 113H on the side of the third face 33 in the x-direction, and the edge of the second portion 114H on the side of the third face 33 in the x-direction generally coincide with each other, as viewed in the y-direction. Here, the expression “generally coincide” as viewed in the y-direction refers to, for example, exactly coinciding with each other, or being deviated by within ±5% of the characteristic size (size of the first portion 113H or second portion 114H in the x-direction).

### <Semiconductor Chip 4X, Diode 41X>

In this variation, the semiconductor chip 4X is located on the first portion 113H in the first portion 11H of the lead 1H. Here, the number of semiconductor chips to be mounted on the lead 1H is by no means limited. In the illustrated example, the collector electrode of the semiconductor chip 4X is bonded to the first portion 11H, via the conductive bonding material 83. The semiconductor chip 4X overlaps with the semiconductor chips 4A, 4B, and 4C, as viewed in the x-direction.

The diode 41X is mounted on the second portion 114A of the first portion 11A. The diode 41X overlaps with the semiconductor chip 4X, as viewed in the y-direction. The diode 41X overlaps with the diodes 41A, 41B, and 41C, as viewed in the x-direction. In addition, the diode 41X overlaps with the second portion 114H, as viewed in the x-direction.

### <First Wire 91H>

In this variation, the first wire 91H is connected to the anode electrode of the diode 41X, and the fourth portion 14H of the lead 1H.

This variation also provides similar advantageous effects to those provided by the semiconductor device A7. As is apparent from this variation, the location of the semiconductor chip 4X and the diode 41X is not specifically limited, but may be modified in various manners.

### <Second Variation of Seventh Embodiment>

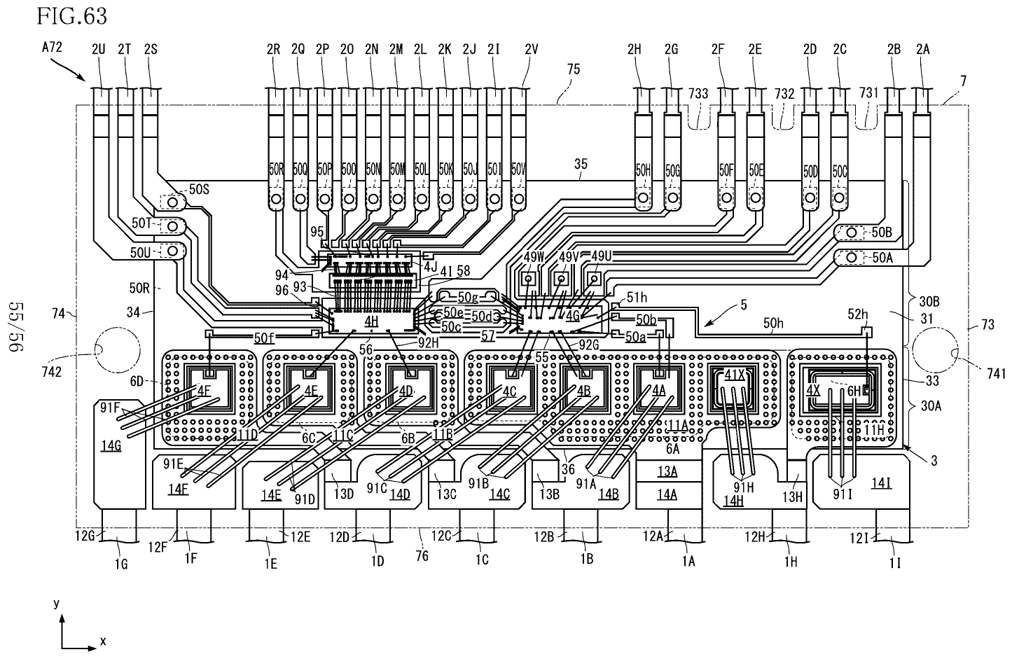

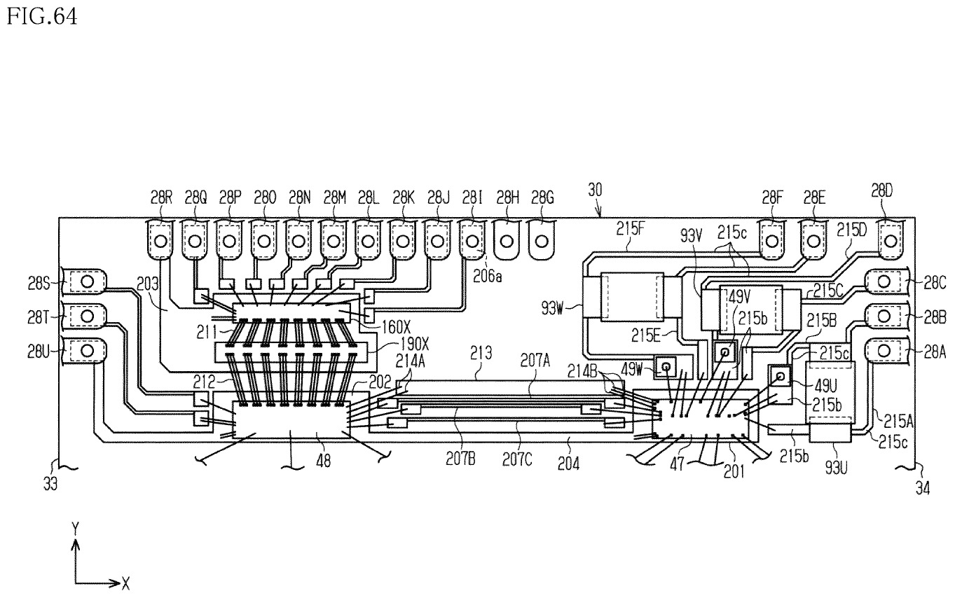

FIG. 63 illustrates a second variation of the semiconductor device A7. The semiconductor device A72 according to this variation may be configured in the same way as the semiconductor devices A7 and A71, except for the configuration described hereunder.

### <Conductive Section 5>

The second portion 52h according to this variation is located on the side of the third face 33 in the x-direction with respect to the first portion 51h, and spaced therefrom. The second portion 52h is located on the side of the sixth face 36 in the y-direction with respect to the first portion 51h, and spaced therefrom. The second portion 52h overlaps with the first base portion 55, as viewed in the x-direction. The second portion 52h is located on the side of the fifth face 35 in the y-direction with respect to the bonding section 6H. The second portion 52h overlaps with the bonding section 6H, as viewed in the y-direction. The shape of the second portion 52h is not specifically limited, and a desired shape may be selected from a rectangular shape, a polygonal shape, a circular shape, an elliptical shape, and so forth. In the illustrated example, the second portion 52h has a rectangular shape.

### <Leads 1>

The first portion 11H of the lead 1H according to this variation is located on the side of the third face 33 in the x-direction, with respect to the first portion 11A. The first portion 11H overlaps with the first portion 11A, as viewed in the x-direction.

### <Semiconductor Chips 4A to 4F, 4X>

In this variation, the semiconductor chips 4A to 4F are a metal-oxide-semiconductor field-effect transistor (MOSFET) formed on a silicon carbide (SiC) substrate, in other words SiC MOSFET. The semiconductor chip 4X is a transistor configured as an IGBT.

### <Diode 41X>

The semiconductor device A72 according to this variation includes the diode 41X. The diode 41X is mounted on the first portion 11A of the lead 1A, together with the semiconductor chips 4A to 4C. The diode 41X overlaps with the semiconductor chips 4A to 4C and the semiconductor chip 4X, as viewed in the x-direction.

This variation also provides similar advantageous effects to those provided by the semiconductor devices A7 and A71. In addition, as is apparent from this variation, the specific configuration of the semiconductor chips 4A to 4F is not specifically limited, but may be modified in various manners.

The semiconductor device and the manufacturing method thereof according to the present disclosure are not limited to the foregoing embodiments. The specific arrangement of the semiconductor device and the manufacturing method thereof according to the present disclosure may be modified in various manners.

Terms and numerals in eighth and subsequent embodiments will be independently defined, from those of the first to seventh embodiments, unless otherwise specifically noted. However, two or more elements or arrangements according to the embodiments and variations of the present disclosure may be combined as desired, unless contradiction is incurred.

In the foregoing embodiments, at least one of the island portions 21a and 22a of the lead frames 20A to 20D may be without the recess 21g (recess 22h).

In the foregoing embodiments, the positional arrangement of the semiconductor chips 41X to 43X may be modified as desired. In an example, the semiconductor chip 41X may be located on the side of the first edge 33 of the substrate 30, with respect to the semiconductor chips 42X and 43X. In addition, the semiconductor chip 43X may be located on the side of the first edge 33 of the substrate 30, with respect to the semiconductor chip 42X.

In the foregoing embodiments, the positional arrangement of the semiconductor chips 44X to 46X may be modified as desired. In an example, the semiconductor chip 44X may be located on the side of the first edge 33 of the substrate 30, with respect to the semiconductor chips 45X and 46X. In addition, the semiconductor chip 45X may be located on the side of the first edge 33 of the substrate 30, with respect to the semiconductor chip 46X.

Although the semiconductor chips 41X to 43X are located on the side of the second edge 34 of the substrate 30, with respect to the semiconductor chips 44X to 46X, in the foregoing embodiments, the semiconductor chips 41X to 43X may be located on the side of the first edge 33 of the substrate 30, with respect to the semiconductor chips 44X to 46X. In this case, the lead frame 20A is located on the side of the first edge 33 of the substrate 30, with respect to the lead frames 20B to 20G. In addition, the lead frames 20E to 20G may be located on the side of the second edge 34 of the substrate 30, with respect to the lead frames 20B to 20D.

In the foregoing embodiments, the substrate 30 may be formed of a metal, instead of a ceramic. In this case, the insulation layer is formed on the surface of the metal substrate, and the wiring pattern 50 (200, 300, 330, 350, and 370) is formed on the insulation layer.

### CLAUSES

The technical concepts perceived on the basis of the foregoing embodiments and variations thereof will be itemized as follows.
[Clause A1]

A semiconductor device including:
a substrate;
a conductive section formed on the substrate and including a conductive material;
a first lead located on the substrate and more heat-dissipative than the substrate;
a semiconductor chip located on the first lead;
a control chip that controls an operation of the semiconductor chip, the control chip being electrically connected to the conductive section and the semiconductor chip and being located on the substrate so as to be spaced apart from the semiconductor chip and the first lead in a plan view; and
a resin covering the semiconductor chip, the control chip, at least a part of the substrate, and a part of the lead.
[Clause A2]

The semiconductor device according to clause A1, in which the substrate includes a first face, and
the conductive section is formed on the first face.
[Clause A3]

The semiconductor device according to clause A2, in which the substrate includes a second face opposite to the first face of the substrate, and
the second face is exposed from the resin.
[Clause A4]

The semiconductor device according to clause A2 or A3, in which the first lead is located on the first face.
[Clause A5]

The semiconductor device according to clause A4, in which the first lead is bonded to the substrate via a first bonding material.
[Clause A6]

The semiconductor device according to clause A5, further including a bonding section formed on the first face of the substrate, in which the first lead is connected to the bonding section via the first bonding material.
[Clause A7]

The semiconductor device according to clause A6, in which the bonding section includes a conductive material that forms the conductive section.
[Clause A8]

The semiconductor device according to any one of clauses A4 to A7, in which the first lead has a part covered with the resin and another part exposed from the resin.
[Clause A9]

The semiconductor device according to any one of clauses A2 to A8, further including a second lead spaced apart from the first lead and located on and electrically connected to the conductive section.
[Clause A10]

The semiconductor device according to clause A9, in which the second lead has a part covered with the resin and another part exposed from the resin.
[Clause A11]

The semiconductor device according to clause A9 or 10, in which the second lead and the conductive section are bonded to each other via a first conductive bonding material.
[Clause A12]

The semiconductor device according to any one of clauses A9 to A11, in which the control chip is located between the semiconductor chip and the second lead as viewed in a first direction orthogonal to a normal direction of the first face of the substrate.
[Clause A13]

The semiconductor device according to any one of clauses A9 to A12, in which the semiconductor chip is bonded to the first lead via a second conductive bonding material.
[Clause A14]

The semiconductor device according to clause A13, in which the semiconductor chip is connected to the first lead via a first conductive material.
[Clause A15]

The semiconductor device according to any one of clauses A9 to A14, in which the control chip is bonded to the conductive section via a third conductive bonding material.
[Clause A16]

The semiconductor device according to any one of clauses A9 to A15, in which the control chip is connected to the conductive section via a second conductive material.
[Clause A17]

The semiconductor device according to any one of clauses A9 to A16, in which a first voltage level of an electrical signal applied to the second lead is lower than a second voltage level for driving the control chip.
[Clause A18]

The semiconductor device according to any one of clauses A9 to A17, further including a first transmission circuit having a transformer structure including at least two coils opposed to each other with a spacing therebetween, the first transmission circuit being configured to transmit an electrical signal, in which the first transmission circuit transmits the electrical signal between the control chip and the second lead.
[Clause A19]

The semiconductor device according to clause A18, in which the first transmission circuit is covered with the resin.
[Clause A20]

The semiconductor device according to any one of clauses A1 to A19, in which the conductive section contains silver.
[Clause A21]

The semiconductor device according to any one of clauses A1 to A19, in which the conductive section contains copper.
[Clause A22]

The semiconductor device according to any one of clauses A1 to A19, in which the conductive section contains gold.
[Clause A23]

The semiconductor device according to any one of clauses A1 to A22, in which the substrate contains a ceramic.
[Clause A24]

The semiconductor device according to any one of clauses A1 to A23, in which the semiconductor chip includes a SiC substrate.
[Clause A25]

The semiconductor device according to any one of clauses A1 to A23, in which the semiconductor chip includes a Si substrate.
[Clause A26]

The semiconductor device according to clause A18, in which the control chip is located between the semiconductor chip and the second lead as viewed in the first direction orthogonal to the normal direction of the first face of the substrate.
[Clause A27]

The semiconductor device according to clause A26, further including a primary-side circuit chip that transmits a command signal to the control chip through the first transmission circuit, in which as viewed in the first direction, a second lead, among a plurality of second leads, that is electrically connected to the primary-side circuit chip has a portion sticking out from the resin, and another second lead electrically connected to the control chip has a portion sticking out from the resin, and the former portion is greater in length than the latter portion.
[Clause A28]

The semiconductor device according to clause A27, in which the semiconductor chip and the control chip overlap with each other, as viewed in a second direction orthogonal to the normal direction of the first face and the first direction.
[Clause A29]

The semiconductor device according to clause A27, in which the semiconductor chip, the control chip, and the first transmission circuit overlap with each other, as viewed in a second direction orthogonal to the normal direction of the first face and the first direction.
[Clause A30]

The semiconductor device according to clause A27, including two control chips, in which the two control chips overlap with each other, as viewed in the first direction.
[Clause A31]

The semiconductor device according to clause A27, further including a plurality of wires connected to the control chip, in which, in a second direction orthogonal to the normal direction of the first face and the first direction, the number of the wires extending from the control chip toward the first transmission circuit is larger than the number of the wires extending from the control chip toward the semiconductor chip.
[Clause A32]

The semiconductor device according to clause A27, in which an edge of a lead oriented in the first direction includes a portion rougher than a portion of an edge of a lead oriented in a second direction orthogonal to the normal direction of the first face and the first direction.
[Clause A33]

The semiconductor device according to clause A27, in which the conductive section includes a base portion on which the control chip is located, and
in a second direction orthogonal to the normal direction of the first face and the first direction, a portion of the base portion extending from the control chip toward the first transmission circuit is longer than a portion of the base portion extending from the control chip toward the semiconductor chip.
[Clause A34]

The semiconductor device according to clause A27, in which the conductive section includes a plurality of second portions respectively bonded to the plurality of second leads, and
a clearance between the plurality of second leads in the first direction is narrower than a clearance between the plurality of second portions of the conductive section.
[Clause A35]

The semiconductor device according to clause A27, in which a clearance in the first direction between two adjacent ones of the plurality of second leads, one electrically connected to the control chip and the other electrically connected to the primary-side circuit chip, is wider than a clearance between second leads electrically connected to the control chip and a clearance between second leads electrically connected to the primary-side circuit chip.
[Clause A36]

The semiconductor device according to any one of clauses A1 to A23, in which the semiconductor chip includes a GaN substrate.
[Clause B1]

A semiconductor package including: a substrate having a wiring pattern formed on a surface thereof; a first lead frame located on the substrate; a first semiconductor chip located on the first lead frame; a first control chip located on the substrate, electrically connected to the wiring pattern and the first semiconductor chip, and configured to control an operation of the first semiconductor chip; and a first resin covering the first semiconductor chip, the first control chip, and a part of the first lead frame.
[Clause B2]

The semiconductor package according to clause B1, further including a second lead frame spaced apart from the first lead frame and located on and electrically connected to the wiring pattern.
[Clause B3]

The semiconductor package according to clause B2, in which the second lead frame has a portion covered with the first resin and another portion exposed from the first resin.
[Clause B4]

The semiconductor package according to clause B2 or B3, in which the second lead frame and the wiring pattern are connected via a first conductive material.
[Clause B5]

The semiconductor package according to any one of clauses B2 to B4, in which the first control chip is located between the second lead frame and the first semiconductor chip as viewed in a first direction perpendicular to a planar direction of the surface of the substrate.
[Clause B6]

The semiconductor package according to any one of clauses B2 to B5, further including a first transmission circuit having a transformer structure including at least two coils opposed to each other with a spacing therebetween, the first transmission circuit being configured to transmit an electrical signal, in which the first transmission circuit transmits the electrical signal between the control chip and the second lead frame.
[Clause B7]

The semiconductor package according to clause B6, in which the first transmission circuit is located between the second lead frame and the first control chip as viewed in the first direction perpendicular to the planar direction of the surface of the substrate.
[Clause B8]

The semiconductor package according to clause B6 or B7, in which a first voltage of an electrical signal applied to the second lead frame is lower than a second voltage for driving the first control chip.
[Clause B9]

The semiconductor package according to any one of clauses B6 to B8, in which the first transmission circuit is located on the substrate and electrically connected to the wiring pattern.
[Clause B10]

The semiconductor package according to clause B9, in which the first transmission circuit is located on a part of the wiring pattern.
[Clause B11]

The semiconductor package according to any one of clauses B1 to B10, in which the first lead frame is connected to the substrate via a second conductive material.
[Clause B12]

The semiconductor package according to any one of clauses B1 to B11, in which the first control chip is located on a part of the wiring pattern.
[Clause B13]

The semiconductor package according to any one of clauses B1 to B12, in which the first control chip is connected to the wiring pattern via a third conductive material.
[Clause B14]

The semiconductor package according to any one of clauses B1 to B13, in which the first lead frame and the first semiconductor chip are connected via a fourth conductive material.
[Clause B15]

The semiconductor package according to any one of clauses B1 to B14, in which the wiring pattern contains silver.
[Clause B16]

The semiconductor package according to any one of clauses B1 to B14, in which the wiring pattern contains copper.
[Clause B17]

The semiconductor package according to any one of clauses B1 to B14, in which the wiring pattern contains gold.
[Clause B18]

The semiconductor package according to any one of clauses B1 to B14, in which the substrate contains a ceramic.
[Clause B19]

The semiconductor package according to any one of clauses B1 to B18, in which the first semiconductor chip includes a SiC substrate.
[Clause B20]

The semiconductor package according to any one of clauses B1 to B18, in which the first semiconductor chip includes a Si substrate.
[Clause B21]

The semiconductor package according to clause B20, in which the first semiconductor chip includes an IGBT element.
[Clause B22]

A semiconductor package including: a substrate having a wiring pattern formed on a surface thereof; a first lead frame located on the substrate; a semiconductor chip located on the first lead frame; a second lead frame connected to the wiring pattern; a control chip electrically connected to the second lead frame via the wiring pattern and configured to control an operation of the semiconductor chip; and an encapsulating resin that encapsulates the wiring pattern, the semiconductor chip, and the control chip.
[Clause B23]

The semiconductor package according to clause B22, in which the first lead frame is connected to a plate-shaped bonding section formed on the substrate.
[Clause B24]

The semiconductor package according to clause B23, in which the wiring pattern and the bonding section are formed of a same material.
[Clause B25]

The semiconductor package according to any one of clauses B22 to B24, in which the substrate is a ceramic substrate.
[Clause B26]

The semiconductor package according to any one of clauses B22 to B25, in which the substrate is divided into a first region and a second region, the first region being formed with the wiring pattern and connected to the second lead frame, the second region being connected to the first lead frame.
[Clause B27]

The semiconductor package according to any one of clauses B22 to B26, in which the wiring pattern and the control chip are electrically connected to each other via a first connection material.
[Clause B28]

The semiconductor package according to clause B27, in which the first connection material is connected to a face of the control chip that is opposite to another face via which the control chip is connected to the wiring pattern.
[Clause B29]

The semiconductor package according to any one of clauses B22 to B28, further including a third lead frame unconnected to the wiring pattern and the substrate, in which the third lead frame is electrically connected to the semiconductor chip via a second connection material.
[Clause B30]

The semiconductor package according to any one of clauses B22 to B29, in which, in one planar direction of the substrate, the first lead frame is provided so as to stick out from one side of the substrate, and the second lead frame is provided so as to stick out from the other side of the substrate.
[Clause B31]

The semiconductor package according to any one of clauses B22 to B30, further including a signal transmission unit, a transformer, and a signal reception unit, in which the signal transmission unit and the transformer are connected to each other via a third connection material, and the transformer and the signal reception unit are connected to each other via a fourth connection material.
[Clause B32]

The semiconductor package according to clause B31, in which the third connection material is shorter than the fourth connection material.
[Clause B33]

The semiconductor package according to clause B29 or B30, further including a signal transmission unit, a transformer, and a signal reception unit, in which the second lead frame includes a plurality of primary-side lead frames to which the signal transmission unit is electrically connected, and a plurality of secondary-side lead frames to which the signal reception unit is electrically connected, and
the plurality of primary-side lead frames and the plurality of secondary-side lead frames are located adjacent to each other, with a clearance therebetween, in a direction orthogonal to the one planar direction of the substrate in which the first lead frame sticks out from the substrate.
[Clause B34]

The semiconductor package according to clause B33, in which a distance between the plurality of primary-side lead frames and the plurality of secondary-side lead frames is longer than an array pitch of the plurality of secondary-side lead frames.
[Clause B35]

The semiconductor package according to clause B33 or B34, in which the array pitch of the plurality of secondary-side lead frames is larger than an array pitch of the plurality of primary-side lead frames.
[Clause B36]

The semiconductor package according to any one of clauses B33 to B35, in which a distal end of the primary-side lead frame and a distal end of the secondary-side lead frame in the second direction are located at different positions.
[Clause B37]

The semiconductor package according to clause B36, in which the distal end of the primary-side lead frame is more distant from the substrate in the second direction than the distal end of the secondary-side lead frame.
[Clause B38]

The semiconductor package according to any one of clauses B22 to B37, in which the semiconductor chip includes a first transistor and a second transistor, and
the control chip includes a first control circuit chip that controls an operation of the first transistor, and a second control circuit chip that controls an operation of the second transistor.
[Clause B39]

The semiconductor package according to clause B38, in which the wiring pattern includes a ground pattern on which the first control circuit chip and the second control circuit chip are mounted.
[Clause B40]

The semiconductor package according to clause B38 or B39, in which the wiring pattern includes a first ground pattern connected to the first control circuit chip, and a first power source pattern that supplies a source voltage to the first control circuit chip.
[Clause B41]

The semiconductor package according to any one of clauses B38 to B40, in which the wiring pattern includes a second ground pattern connected to the second control circuit chip, and a second power source pattern that supplies a source voltage to the second control circuit chip.
[Clause B42]

The semiconductor package according to any one of clauses B38 to B41, in which the wiring pattern includes a signal pattern electrically connected to the first control circuit chip or the second control circuit chip.
[Clause B43]

The semiconductor package according to clause B42, in which the wiring pattern includes a first signal pattern that transmits a control signal for the first transistor to the second control circuit chip.
[Clause B44]

The semiconductor package according to clause B42 or B43, in which the wiring pattern includes a second signal pattern that transmits a control signal for the second transistor to the second control circuit chip.
[Clause B45]

The semiconductor package according to clause B44, in which the wiring pattern includes at least one first intermediary wiring configured to relay the control signal for controlling the operation of the first transistor from the second control circuit chip to the first control circuit chip.
[Clause B46]

The semiconductor package according to clause B45, in which the first control circuit chip and the second control circuit chip are disposed with a clearance therebetween,
a plurality of the first intermediary wirings are formed between the first control circuit chip and the second control circuit chip, and
the plurality of first intermediary wirings each extend along an array direction of the first control circuit chip and the second control circuit chip and are disposed with a clearance between each other in the direction orthogonal to the array direction, as viewed in a plan view of the substrate.
[Clause B47]

The semiconductor package according to clause B46, in which the plurality of first intermediary wirings each include land portions formed at respective end portions in the extending direction, and
the first intermediary wirings adjacent to each other are located so as to overlap with at least one of the land portions of the plurality of first intermediary wirings, as viewed in the array direction.
[Clause B48]

The semiconductor package according to clause B46 or B47, in which the wiring pattern includes a second intermediary wiring that supplies a source voltage from one of the first control circuit chip and the second control circuit chip to the other, and
the second intermediary wiring is formed adjacent to the first intermediary wiring in the direction orthogonal to the array direction, as viewed in a plan view of the substrate.
[Clause B49]

The semiconductor package according to clause B39, in which the second lead frame includes a plurality of lead frames electrically connected to the first control circuit chip and the second control circuit chip,
at least a number of the plurality of lead frames are arranged along one of edges constituting the periphery of the substrate, and
a lead frame of the plurality of lead frames that is connected to the ground pattern is located at an extremity of the plurality of lead frames in the direction along the edge of the substrate.
[Clause B50]

The semiconductor package according to any one of clauses B38 to B49, further including a signal transmission unit and a transformer, in which the signal transmission unit outputs a control signal for controlling the operation of the first and second transistors to the second control circuit chip through the transformer.
[Clause B51]

The semiconductor package according to clause B50, in which the signal transmission unit, the transformer, and the second control circuit chip are arranged in the direction orthogonal to the array direction of the second control circuit chip and the first control circuit chip, as viewed in a plan view of the substrate.
[Clause B52]

The semiconductor package according to clause B50, in which the signal transmission unit, the transformer, and the second control circuit chip are arranged along the array direction of the second control circuit chip and the first control circuit chip.
[Clause B53]

The semiconductor package according to any one of clauses B50 to B52, in which the wiring pattern includes a ground pattern on which the signal transmission unit and the transformer are mounted.
[Clause B54]

The semiconductor package according to clause B53, in which the second control circuit chip is mounted on another ground pattern electrically insulated from the signal transmission unit and the transformer.
[Clause B55]

The semiconductor package according to any one of clauses B50 to B54, in which the wiring pattern includes a first signal pattern that transmits a control signal for the first transistor to the first control circuit chip, and a second signal pattern that transmits a control signal for the second transistor to the second control circuit chip, and
the first signal pattern and the second signal pattern are each electrically connected to the signal transmission unit.
[Clause B56]

The semiconductor package according to any one of clauses B50 to B55, in which the transformer includes a first transformer that transmits a control signal for controlling an operation of the first transistor to the first control circuit chip, and a second transformer that transmits a control signal for controlling an operation of the second transistor to the second control circuit chip, and
the first transformer and the second transformer are provided in separate chips.
[Clause B57]

The semiconductor package according to clause B56, in which the signal transmission unit includes a first signal transmission unit that transmits the control signal for the first transistor to the first control circuit chip, and a second signal transmission unit that transmits the control signal for the second transistor to the second control circuit chip, and
the first signal transmission unit and the second signal transmission unit are provided in separate chips, the first signal transmission unit is located adjacent to the first transformer, and the second signal transmission unit is located adjacent to the second transformer.
[Clause B58]

The semiconductor package according to clause B57, in which the wiring pattern includes a first signal pattern that transmits the control signal for the first transistor to the first control circuit chip, and a second signal pattern that transmits the control signal for the second transistor to the second control circuit chip, and
the first signal pattern is electrically connected to the first signal transmission unit, and the second signal pattern is electrically connected to the second signal transmission unit.
[Clause B59]

The semiconductor package according to clause B57 or B58, in which the wiring pattern includes a first island portion, a second island portion, a third island portion, and a fourth island portion, the first control circuit chip is mounted on the first island portion, the second control circuit chip is mounted on the second island portion, the first signal transmission unit and the first transformer are mounted on the third island portion, the second signal transmission unit and the second transformer are mounted on the fourth island portion, the first island portion is formed adjacent to the third island portion, and the second island portion is formed adjacent to the fourth island portion.
[Clause B60]

The semiconductor package according to clause B59, in which the wiring pattern further includes a connection wiring connecting the first island portion and the second island portion to each other.
[Clause B61]

The semiconductor package according to any one of clauses B50 to B55, in which the signal transmission unit includes a first signal transmission unit that transmits the control signal for controlling an operation of the first transistor to the first control circuit chip, and a second signal transmission unit that transmits the control signal for controlling an operation of the second transistor to the second control circuit chip,
the transformer includes a first transformer that transmits a signal of the first signal transmission unit to the first control circuit chip, and a second transformer that transmits a signal of the second signal transmission unit to the second control circuit chip, the semiconductor package further including a first signal reception unit that receives the signal from the first transformer,
the first signal transmission unit, the first transformer, and the first signal reception unit are integrated into a first signal transmission circuit in a single chip, and
the second signal transmission unit, the second transformer, and the second control circuit chip are integrated into a second signal transmission circuit in a single chip.
[Clause B62]

The semiconductor package according to clause B61, in which the wiring pattern includes a first signal pattern that transmits the control signal for the first transistor to the first control circuit chip, and a second signal pattern that transmits the control signal for the second transistor to the second control circuit chip, the first signal pattern is electrically connected to the first signal transmission circuit, and the second signal pattern is electrically connected to the second signal transmission circuit.
[Clause B63]

The semiconductor package according to clause B61 or B62, in which the wiring pattern includes a ground pattern that electrically connects the first signal transmission circuit and the second signal transmission circuit.
[Clause B64]

The semiconductor package according to any one of clauses B61 to B63, in which the wiring pattern includes a power source pattern that electrically connects the first signal transmission circuit and the second signal transmission circuit, and supplies a source voltage to the first signal transmission circuit and the second signal transmission circuit.
[Clause B65]

The semiconductor package according to any one of clauses B57 to B60, including a plurality of the first transistors, in which a plurality of the first signal transmission units, a plurality of the first transformers, and a plurality of the first control circuit chips are provided, in accordance with the number of the first transistors.
[Clause B66]

The semiconductor package according to any one of clauses B38 to B65, further including a diode electrically connected to the first control circuit chip.
[Clause B67]

The semiconductor package according to clause B66, further including a capacitor connected to the diode.
[Clause B68]

The semiconductor package according to clause B67, in which the capacitor is mounted on the wiring pattern.
[Clause B69]

The semiconductor package according to any one of clauses B38 to B68, in which the wiring pattern includes at least one of a third intermediary wiring provided halfway on a connection path between a control terminal that controls an operation of the first transistor and the first control circuit chip, and a fourth intermediary wiring provided halfway on a connection path between a control terminal that controls an operation of the second transistor and the second control circuit chip.
[Clause B70]

The semiconductor package according to clause B69, in which the wiring pattern includes the third intermediary wiring, and the semiconductor chip includes a plurality of the first transistors,
the third intermediary wiring is formed on a connection path between a control terminal of the first transistor, most distant from the first control circuit chip among the plurality of first transistors, and the first control circuit chip.
[Clause B71]

The semiconductor package according to clause B69 or B70, in which the wiring pattern includes the fourth intermediary wiring, and the semiconductor chip includes a plurality of the second transistors, and
the fourth intermediary wiring is formed on a connection path between a control terminal of the second transistor, most distant from the second control circuit chip among the plurality of second transistors, and the second control circuit chip.
[Clause B72]

The semiconductor package according to clause B71, in which the wiring pattern includes the fourth intermediary wiring, the semiconductor chip includes a plurality of the second transistors, the fourth intermediary wiring is individually formed on each of the connection paths between the plurality of second transistors and the second control circuit chip.
[Clause B73]

The semiconductor package according to any one of clauses B22 to B72, in which the semiconductor chip is a SiC MOSFET.

1. A semiconductor device comprising:
a substrate that is insulating and includes a substrate main surface and a substrate back surface;
a plurality of wiring patterns formed on a substrate main surface of the substrate;
a plurality of semiconductor switching chips that include a first electrode and a control electrode formed on a chip main surface side and a second electrode formed on a chip back surface and perform switching operation between the first electrode and the second electrode in response to a signal input to the control electrode;
a control chip that generates a signal to be input to the control electrode;
a plurality of first leads to be electrically connected to the first electrode or the second electrode;
a plurality of second leads to be electrically connected to the control chip;
an encapsulating resin covering at least a part of the plurality of first leads and the plurality of second leads, the substrate, the plurality of wiring patterns, and the plurality of semiconductor switching chips; and
a non-conductive bonding material extending outwardly from an outer periphery of the control chip, in a direction parallel to the substrate main surface,
wherein at least a part of the plurality of wiring patterns is arranged in a middle of a path connecting the control electrode and the control chip as an independent wiring pattern.

2. The semiconductor device according to claim 1, wherein a minimum separation between the plurality of wiring patterns is smaller than a minimum separation between the plurality of first leads.

3. The semiconductor device according to claim 1, wherein the plurality of first leads are exposed only from one lateral side of the encapsulating resin.

4. The semiconductor device according to claim 1, wherein a separation between two adjacent ones of the plurality of first leads is larger than a separation between two adjacent ones of the plurality of second leads.

5. The semiconductor device according to claim 1, wherein the encapsulating resin has a recess formed at a part of the encapsulating resin where the plurality of second leads are exposed from the encapsulating resin.

6. The semiconductor device according to claim 1, wherein each of the semiconductor switching chips is a metal-oxide-semiconductor field-effect transistor (MOSFET) formed on a silicon carbide (SiC) substrate, and
the first electrode is a source electrode, the second electrode is a drain electrode, and the control electrode is a gate electrode.

7. The semiconductor device according to claim 6, wherein the gate electrode of the MOSFET has a trench structure.

8. The semiconductor device according to claim 1, wherein heights of the semiconductor switching chips and a height of the control chip are different from each other when seen along a direction orthogonal to the substrate main surface.

9. The semiconductor device according to claim 8, wherein a thickness of the wiring patterns is smaller than a thickness of the first leads.

10. The semiconductor device according to claim 1, wherein the substrate is made of at least one ceramic selected from alumina (Al2O3), silicon nitride (SiN), aluminum nitride (AlN), and zirconia-containing alumina.

11. The semiconductor device according to claim 1, wherein the semiconductor chips comprise low-voltage side switching elements and high-voltage side switching elements serially connected between a first power source and a second power source.

12. The semiconductor device according to claim 1, wherein the control chip includes a first integrated circuit element to control an operation of the high-voltage side switching elements, and a second integrated circuit element to control an operation of the low-voltage side switching elements.

13. The semiconductor device according to claim 12, further comprising a plurality of boot diodes electrically connected to the first integrated circuit element.

14. The semiconductor device according to claim 1, wherein among the plurality of first leads, an external first lead covered by the encapsulating resin includes a part that faces inwards.

15. The semiconductor device according to claim 1, wherein each of the semiconductor switching chips is a SiC-MOSFET or an IGBT including electrodes on a front surface and a back surface.

16. The semiconductor device according to claim 1, wherein a first voltage level of an electrical signal applied to the second lead is lower than a second voltage level for driving the control chip.

17. The semiconductor device according to claim 1, wherein heights of the plurality of semiconductor switching chips and heights of the control chips are different with respect to a direction orthogonal to the substrate main surface.

18. The semiconductor device according to claim 1,
wherein as seen in a plan view, one semiconductor switching chip among the plurality of semiconductor switching chips is oriented along a direction orthogonal to a direction along which remaining ones of the plurality of semiconductor switching chips are oriented.

19. The semiconductor device according to claim 1,
wherein the independent wiring pattern is of a band-like shape having one end and another end,
the one end is electrically connected to the control chip and the other end is electrically connected to the control electrode, and
a line width of the other end is larger than a line width of a portion between the one end and the other end.
